(19) United States
(12) Patent Application Publication
(10) Pub. No.: US 2017/0123268 A1
(43) Pub. Date: May 4, 2017

(54) DISPLAY DEVICE, ELECTRONIC DEVICE, AND METHOD FOR MANUFACTURING DISPLAY DEVICE AND ELECTRONIC DEVICE

(71) Applicant: Semiconductor Energy Laboratory Co., Ltd., Atsugi-shi (JP)

(72) Inventors: Toshiki SASAKI, Isehara (JP); Satoshi SEO, Sagamihara (JP); Nobuharu OHSAWA, Zama (JP); Kohei YOKOYAMA, Fujisawa (JP); Yasuhiro JINBO, Isehara (JP)

(21) Appl. No.: 15/334,495

(22) Filed: Oct. 26, 2016

(30) Foreign Application Priority Data
Oct. 30, 2015 (JP) 2015-214087
Dec. 1, 2015 (JP) 2015-234396

(51) Int. Cl. G02F 1/1335; H01L 27/32; G02F 1/1343; H01L 27/15

(52) U.S. Cl. CPC G02F 1/133553; H01L 27/15; H01L 27/3267; H01L 27/3232; G02F 1/134309; G02F 1/1336; H01L 29/7869

(57) ABSTRACT

A novel display device that is highly convenient with low power consumption is provided. The display device includes a display element including a liquid crystal layer, a display element including a light-emitting layer, a first transistor, and a second transistor. The first transistor is electrically connected to an electrode of the display element including the liquid crystal layer, and the second transistor is electrically connected to an electrode of the display element including the light-emitting layer. The electrode of the display element including the liquid crystal layer and the electrode of the display element including the light-emitting layer each include a reflective film and a conductive film. The reflective film of the display element including the liquid crystal layer has a region containing a metal contained in the reflective film of the display element including the light-emitting layer.

### TECHNICAL FIELD

One embodiment of the present invention relates to a display device or an electronic device including the display device, and a manufacturing method of the display device and the electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, a method for driving any of them, and a method for manufacturing any of them.

### BACKGROUND ART

There is a liquid crystal display device in which a surface-emitting light source is provided as a backlight and combined with a transmissive liquid crystal display element in order to reduce power consumption and suppress a reduction in display quality (see, e.g., Patent Document 1).

A display device including a self-luminous light-emitting element has been developed. The display device including a self-luminous light-emitting element has advantages of high visibility, no need of backlight which is necessary for a transmissive liquid crystal display device, and the like.

### REFERENCE

### Patent Document

[Patent Document 1] Japanese Published Patent Application No. 2011-248351

### DISCLOSURE OF INVENTION

A display device including a light-emitting element or a transmissive liquid crystal display element has a problem that the visibility is reduced when displaying images in a bright environment, such as under strong external light. In addition, when the display device outputs high luminance for high visibility in the bright environment, it consumes more power. In contrast, a display device including a reflective liquid crystal display element has problems of dark display, low color reproducibility, and low visibility when displaying images in a dark environment. Accordingly, a convenient display device with high visibility and low power consumption both in bright and dark environments is required.

In view of the above, an object of one embodiment of the present invention is to provide a display device with high visibility that is highly convenient. Another object of one embodiment of the present invention is to provide a display device with low power consumption. Another object of one embodiment of the present invention is to provide a display device with high color reproducibility. Another object of one embodiment of the present invention is to provide a highly reliable display device. Another object of one embodiment of the present invention is to provide a novel display device. Another object of one embodiment of the present invention is to provide a method for manufacturing a novel display device.

Note that the description of the above object does not disturb the existence of other objects. In one embodiment of the present invention, there is no need to achieve all the objects. Other objects are apparent from and can be derived from the description of the specification and the like.

One embodiment of the present invention is a display device capable of driving a first display element including a liquid crystal layer using a first transistor and driving a second display element including a light-emitting layer using a second transistor. In addition, an electrode of the first display element including the liquid crystal layer and an electrode of the second display element including the light-emitting layer each include a reflective film, and both of the reflective films contain the same metal.

That is, one embodiment of the present invention is a display device including a first display element, a second display element, a first transistor, and a second transistor. The first display element includes a first electrode and a liquid crystal layer. The second display element includes a second electrode and a light-emitting layer. The first transistor is electrically connected to the first electrode. The second transistor is electrically connected to the second electrode. The first electrode includes a first reflective film and a first conductive film. The second electrode includes a second reflective film and a second conductive film. The first reflective film includes a region containing a metal contained in the second reflective film.

In the above structure, the first reflective film and the second reflective film preferably each contain at least one of Ag and Al.

Another embodiment of the present invention is a display device including a first display element, a second display element, a first transistor, and a second transistor. The first display element includes a first electrode and a liquid crystal layer. The second display element includes a second electrode, a third electrode, and a light-emitting layer. The first transistor is electrically connected to the first electrode. The second transistor is electrically connected to the second electrode. The first electrode includes a first reflective film and a first conductive film. The second electrode includes a second reflective film and a second conductive film. The third electrode includes a third reflective film. The first reflective film includes a region containing a metal contained in the second reflective film. The second reflective film includes a region containing a metal contained in the third reflective film.

In the above structure, the first reflective film, the second reflective film, and the third reflective film preferably each contain at least one of Ag and Al.

In each of the above structures, the first conductive film and the second conductive film preferably each contain at least one of In and Zn.

In each of the above structures, it is preferable that the first electrode further include a third conductive film, that the second electrode further include a fourth conductive film, that the first reflective film include a region interposed between the first conductive film and the third conductive film, and that the second reflective film include a region interposed between the second conductive film and the fourth conductive film.

In the above structure, the third conductive film and the fourth conductive film preferably each contain at least one of In and Zn. In addition, it is preferable that the third conductive film include a region containing a metal contained in the first conductive film and that the fourth conductive film include a region containing a metal contained in the second conductive film.

In each of the above structures, it is preferable that the first reflective film have an opening and that the opening include a region overlapping with the first conductive film, the second reflective film, and the second conductive film. In addition, it is preferable that the second display element be configured to emit light toward the opening and that the second display element be configured to perform display in the same direction as the first display element.

In each of the above structures, the first transistor and the second transistor preferably each contain an oxide semiconductor.

Another embodiment of the present invention is an electronic device including the display device, and at least one of a housing and a touch sensor. The category of one embodiment of the present invention includes not only a display device but also an electronic device including a display device. Therefore, a display device in this specification refers to an image display device. One embodiment of the present invention is the following modules in its category: a module in which a connector such as a flexible printed circuit (FPC) or a tape carrier package (TCP) is attached to a display device; a module having a TCP provided with a printed wiring board at the end thereof; and a module having an integrated circuit (IC) directly mounted on a display device by a chip on glass (COG) method.

One embodiment of the present invention provides a display device with high visibility that is highly convenient, a display device with low power consumption, a display device with high color reproducibility, a highly reliable display device, a novel display device, or a method for manufacturing a novel display device.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF DRAWINGS

FIGS. 1A, 1B-1, and 1B-2 illustrate a structure of a display device of one embodiment of the present invention.

FIGS. 2A to 2C are cross-sectional views illustrating a structure of a display device of one embodiment of the present invention.

FIG. 3 is a diagram illustrating a pixel circuit of a display device of one embodiment of the present invention.

FIGS. 4A, 4B-1, and 4B-2 illustrate a structure of a display device of one embodiment of the present invention.

FIGS. 5A and 5B are cross-sectional views each illustrating a structure of a display device of one embodiment of the present invention.

FIGS. 6A and 6B are cross-sectional views each illustrating a structure of a display device of one embodiment of the present invention.

FIGS. 7A and 7B are cross-sectional views each illustrating a structure of a display device of one embodiment of the present invention.

FIGS. 8A and 8B are cross-sectional views illustrating a structure of a display device of one embodiment of the present invention.

FIGS. 9A and 9B are cross-sectional views each illustrating a structure of a display device of one embodiment of the present invention.

FIGS. 10A and 10B are cross-sectional views each illustrating a structure of a display device of one embodiment of the present invention.

FIG. 11 is a cross-sectional view illustrating a structure of a display device of one embodiment of the present invention.

FIG. 12 is a cross-sectional view illustrating a structure of a display device of one embodiment of the present invention.

FIG. 13 is a cross-sectional view illustrating a structure of a display device of one embodiment of the present invention.

FIG. 14 is a cross-sectional view illustrating a structure of a display device of one embodiment of the present invention.

FIG. 15 is a cross-sectional view illustrating a structure of a display device of one embodiment of the present invention.

FIGS. 16A and 16B are cross-sectional views illustrating a method for manufacturing a display device of one embodiment of the present invention.

FIGS. 17A and 17B are cross-sectional views illustrating a method for manufacturing a display device of one embodiment of the present invention.

FIGS. 18A and 18B are cross-sectional views illustrating a method for manufacturing a display device of one embodiment of the present invention.

FIGS. 19A and 19B are cross-sectional views illustrating a method for manufacturing a display device of one embodiment of the present invention.

FIG. 20 is a cross-sectional view illustrating a method for manufacturing a display device of one embodiment of the present invention.

FIG. 21 is a cross-sectional view illustrating a method for manufacturing a display device of one embodiment of the present invention.

FIGS. 22A and 22B are cross-sectional views illustrating a method for manufacturing a display device of one embodiment of the present invention.

FIG. 23 is a cross-sectional view illustrating a method for manufacturing a display device of one embodiment of the present invention.

FIGS. 24A and 24B are cross-sectional views each illustrating a structure of a light-emitting element of a display device of one embodiment of the present invention.

FIGS. 25A and 25B are cross-sectional views each illustrating a structure of a light-emitting element of a display device of one embodiment of the present invention.

FIGS. 26A and 26C are cross-sectional views each illustrating a structure of a light-emitting element of a display device of one embodiment of the present invention, and FIGS. 26B and 26D each illustrate the correlation of energy levels.

FIG. 27A is a cross-sectional view illustrating a structure of a light-emitting element of a display device of one embodiment of the present invention, and FIG. 27B illustrates the correlation of energy levels.

FIGS. 28A to 28C are a top view and cross-sectional views illustrating an example of a transistor.

FIGS. 29A to 29C are a top view and cross-sectional views illustrating an example of a transistor.

FIGS. 30A to 30D are cross-sectional views illustrating an example of a transistor.

FIGS. 31A to 31D are cross-sectional views illustrating examples of a transistor.

FIGS. 32A to 32C are a top view and cross-sectional views illustrating an example of a transistor.

FIGS. 33A to 33C are a top view and cross-sectional views illustrating an example of a transistor.

FIGS. 34A to 34C are a top view and cross-sectional views illustrating an example of a transistor.

FIGS. 35A to 35C are a top view and cross-sectional views illustrating an example of a transistor.

FIGS. 36A to 36F are cross-sectional views illustrating an example of a manufacturing process of a transistor.

FIGS. 37A to 37F are cross-sectional views illustrating an example of a manufacturing process of a transistor.

FIGS. 38A to 38F are cross-sectional views illustrating an example of a manufacturing process of a transistor.

FIGS. 39A and 39B are model diagrams illustrating oxygen moving in an oxide semiconductor film.

FIGS. 40A to 40C each show the range of the atomic ratio of an oxide semiconductor of one embodiment of the present invention.

FIG. 41 illustrates three crystals of InMZnO₄.

FIGS. 42A and 42B are band diagrams of a stacked-layer structure of oxide semiconductors.

FIGS. 43A to 43E show structural analysis of a CAAC-OS and a single crystal oxide semiconductor by XRD and selected-area electron diffraction patterns of a CAAC-OS.

FIGS. 44A to 44E show a cross-sectional TEM image and plan-view TEM images of a CAAC-OS and images obtained through analysis thereof.

FIGS. 45A to 45D show electron diffraction patterns and a cross-sectional TEM image of an nc-OS.

FIGS. 46A and 46B are cross-sectional TEM images of an a-like OS.

FIG. 47 shows a change of crystal parts of an In—Ga—Zn oxide owing to electron irradiation.

FIG. 48 illustrates a structure of an input/output device of one embodiment of the present invention.

FIGS. 49A to 49C are a block diagram and projection views illustrating a structure of a data processing device of one embodiment of the present invention.

FIGS. 50A to 50C are block diagrams and a circuit diagram illustrating the structure of a display portion of one embodiment of the present invention.

FIGS. 51A and 51B are flow charts illustrating programs of one embodiment of the present invention.

FIG. 52 is a schematic diagram illustrating image data of one embodiment of the present invention.

FIGS. 53A to 53C are a cross-sectional view and circuit diagrams illustrating structures of semiconductor devices of one embodiment of the present invention.

FIG. 54 is a block diagram illustrating a structure of a CPU of one embodiment of the present invention.

FIG. 55 is a circuit diagram illustrating a structure of a memory element of one embodiment of the present invention.

FIGS. 56A to 56H illustrate electronic devices of one embodiment of the present invention.

FIG. 57 shows current efficiency-luminance characteristics of light-emitting elements in an example.

FIG. 58 shows luminance-voltage characteristics of the light-emitting elements in the example.

FIG. 59 shows electroluminescence spectra of the light-emitting elements in the example.

FIGS. 60A and 60B show angle distribution of luminance of light-emitting elements and viewing angle dependence of chromaticity in the example.

FIG. 61 shows a display example of a display device in an example.

FIG. 62 shows electroluminescence spectra of a display device in the example.

FIGS. 63A and 63B show viewing angle dependence of chromaticity of a display device in the example.

FIG. 64 is a chromaticity diagram of a display device in the example.

### BEST MODE FOR CARRYING OUT THE INVENTION

Embodiments of the present invention will be explained below with reference to the drawings. Note that the present invention is not limited to description to be given below, and modes and details thereof can be variously modified without departing from the purpose and the scope of the present invention. Thus, the present invention should not be interpreted as being limited to the description of the embodiments.

Note that the position, the size, the range, or the like of each structure illustrated in drawings and the like is not accurately represented in some cases for easy understanding. Therefore, the disclosed invention is not necessarily limited to the position, the size, the range, or the like disclosed in the drawings and the like.

In each of the diagrams, independent blocks show elements, which are classified according to their functions. However, it may be practically difficult to completely separate the elements according to their functions; in some cases, one element can involve a plurality of functions.

Note that the ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those which specify one embodiment of the present invention.

In describing structures of the invention with reference to the drawings in this specification and the like, common reference numerals are used for the same portions in different drawings in some cases.

In this specification and the like, the terms “film” and “layer” can be interchanged with each other. For example, the term “conductive layer” can be changed into the term “conductive film” in some cases, and the term “insulating film” can be changed into the term “insulating layer” in some cases.

In this specification and the like, a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification and the like can be called an “insulator” in some cases. Similarly, an “insulator” in this specification and the like can be called a “semiconductor” in some cases. Alternatively, an “insulator” in this specification and the like can be called a “semi-insulator” in some cases.

In this specification and the like, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification and the like can be called a “conductor” in some cases. Similarly, a “conductor” in this specification and the like can be called a “semiconductor” in some cases.

Furthermore, in this specification and the like, one of a first electrode and a second electrode of a transistor refers to a source electrode and the other refers to a drain electrode.

The terms “source terminal” and “drain terminal” included in a transistor can interchange with each other depending on the polarity of the transistor or the levels of potentials applied to the respective terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, although connection relation of the transistor is described assuming that the source and the drain are fixed in some cases for convenience, actually, the names of the source and the drain interchange with each other depending on the relation of the potentials.

In this specification, a state in which transistors are connected in series means, for example, a state in which only one of a source and a drain of a first transistor is connected to only one of a source and a drain of a second transistor. In addition, a state in which transistors are connected to each other in parallel means a state in which one of a source and a drain of a first transistor is connected to one of a source and a drain of a second transistor and the other of the source and the drain of the first transistor is connected to the other of the source and the drain of the second transistor.

In this specification, even when a circuit diagram illustrates independent components that are connected to each other, there is a case where one conductive film has functions of a plurality of components, such as the case where part of a wiring functions as an electrode. The term “connection” in this specification and the like also means such a case where one conductive film has functions of a plurality of components.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. In addition, the term “perpendicular” indicates that the angle formed between two straight lines is greater than or equal to 80° and less than or equal to 100°, and accordingly also includes the case where the angle is greater than or equal to 85° and less than or equal to 95°. A term “substantially perpendicular” indicates that the angle formed between two straight lines is greater than or equal to 60° and less than or equal to 120°.

In this specification, trigonal and rhombohedral crystal systems are included in a hexagonal crystal system.

In this specification and the like, a singlet excited state (S*) refers to a singlet state having excitation energy. An S1 level means the lowest level of the singlet excitation energy level, that is, the excitation energy level of the lowest singlet excited state. A triplet excited state (T*) refers to a triplet state having excitation energy. A T1 level means the lowest level of the triplet excitation energy level, that is, the excitation energy level of the lowest triplet excited state. Note that in this specification and the like, simple expressions “singlet excited state” and “singlet excitation energy level” mean the lowest singlet excited state and the S1 level, respectively, in some cases. In addition, simple expressions “triplet excited state” and “triplet excitation energy level” mean the lowest triplet excited state and the T1 level, respectively, in some cases.

In this specification and the like, a fluorescent material refers to a material that emits light in the visible light region when the relaxation from the singlet excited state to the ground state occurs. A phosphorescent material refers to a material that emits light in the visible light region at room temperature when the relaxation from the triplet excited state to the ground state occurs. That is, a phosphorescent material refers to a material that can convert triplet excitation energy into visible light.

Phosphorescence emission energy or a triplet excitation energy can be obtained from a wavelength of a phosphorescence emission peak (including a shoulder) or a rising portion on the shortest wavelength side of phosphorescence emission. Note that the phosphorescence emission can be observed by time-resolved photoluminescence in a low-temperature (e.g., 10 K) environment. A thermally activated delayed fluorescence emission energy can be obtained from a wavelength of an emission peak (including a shoulder) or a rising portion on the shortest wavelength side of thermally activated delayed fluorescence.

In this specification and the like, a wavelength range of blue refers to a wavelength range greater than or equal to 400 nm and less than 490 nm, and blue light has at least one peak in that range in an emission spectrum. A wavelength range of green refers to a wavelength range greater than or equal to 490 nm and less than 550 nm, and green light has at least one peak in that range in an emission spectrum. A wavelength range of yellow refers to a wavelength range greater than or equal to 550 nm and less than 590 nm, and yellow light has at least one peak in that range in an emission spectrum. A wavelength range of red refers to a wavelength range greater than or equal to 590 nm and less than or equal to 740 nm, and red light has at least one peak in that range in an emission spectrum.

Note that in this specification and the like, “room temperature” refers to a temperature ranging from 0° C. to 40° C.

### Embodiment 1

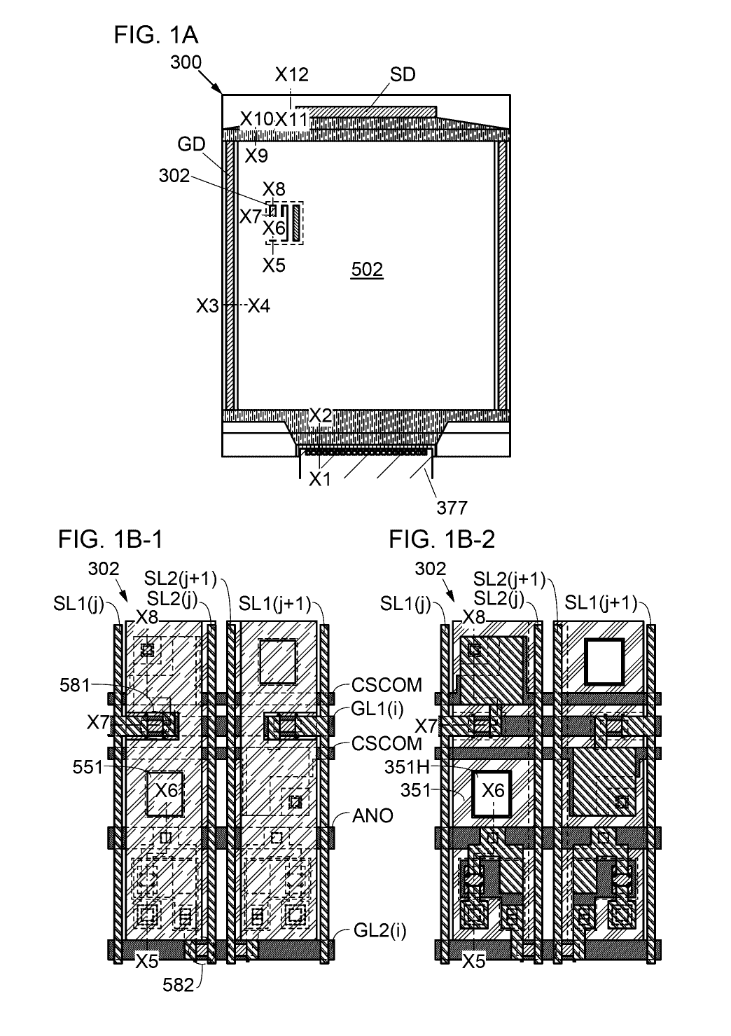

In this embodiment, display devices of embodiments of the present invention will be described below with reference to FIGS. 1A, 1B-1, and 1B-2, FIGS. 2A to 2C, FIG. 3, FIGS. 4A, 4B-1, and 4B-2, FIGS. 5A and 5B, FIGS. 6A and 6B, FIGS. 7A and 7B, FIGS. 8A and 8B, FIGS. 9A and 9B, FIGS. 10A and 10B, FIG. 11, FIG. 12, FIG. 13, FIG. 14, FIG. 15, FIGS. 16A and 16B, FIGS. 17A and 17B, FIGS. 18A and 18B, FIGS. 19A and 19B, FIG. 20, FIG. 21, FIGS. 22A and 22B, FIG. 23, FIGS. 24A and 24B, and FIGS. 25A and 25B.

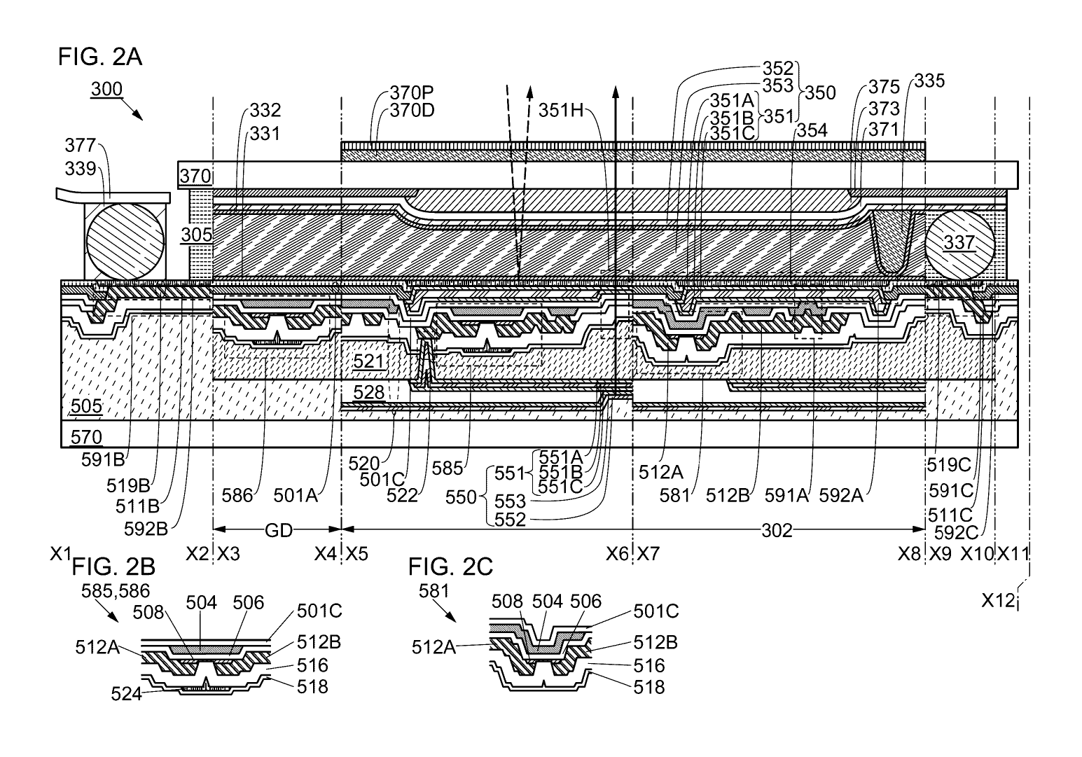

FIG. 1A is a bottom view illustrating the structure of a display device 300 of one embodiment of the present invention. FIG. 1B-1 is a bottom view illustrating part of FIG. 1A. FIG. 1B-2 is a bottom view omitting some components illustrated in FIG. 1B-1.

FIGS. 2A to 2C are cross-sectional views illustrating the structure of the display device 300 of one embodiment of the present invention. FIG. 2A is a cross-sectional view taken along dashed-dotted lines X1-X2, X3-X4, X5-X6, X7-X8, X9-X10, and X11-X12 in FIG. 1A. FIG. 2B is a cross-sectional view illustrating part of the display device 300, and FIG. 2C is a cross-sectional view illustrating another part of the display device 300.

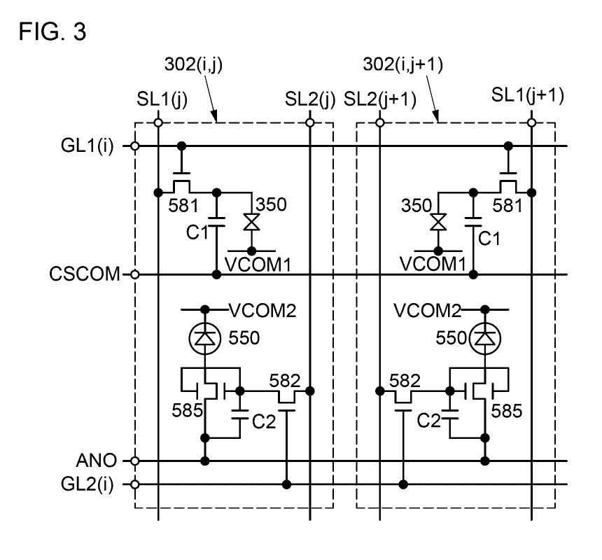

FIG. 3 illustrates a pixel circuit 302 included in the display device 300 of one embodiment of the present invention.

### <Structure Example 1 of Display Device>

As illustrated in FIG. 1A, the display device 300 of one embodiment of the present invention includes a pixel portion 502, and a driver circuit GD and a driver circuit SD placed outside the pixel portion 502. The pixel portion 502 includes the pixel circuit 302.

The pixel circuit 302 includes a first display element 350 and a second display element 550 (see FIG. 3). The pixel circuit 302 includes a switch 581, and the switch 581 includes a transistor. The pixel circuit 302 includes a transistor 585 (see FIGS. 2A to 2C).

The first display element 350 and the second display element 550 perform display in the same direction. For example, a dashed line arrow in FIG. 2A denotes the direction in which the first display element 350 performs display by adjusting the intensity of external light reflection. A solid line arrow in FIG. 2A denotes the direction in which the second display element 550 performs display.

The first display element 350 has a function of reflecting incident light and a function of adjusting the intensity of the reflected light. The first display element 350 thus includes a reflective film 351B having a function of reflecting incident light and a layer containing a material having a function of adjusting the intensity of the reflected light.

A reflective liquid crystal element is preferably used as the first display element 350. Specifically, the first display element 350 preferably includes a liquid crystal layer 353, an electrode 351, and an electrode 352. The electrode 351 preferably includes the reflective film 351B having a function of reflecting light. In addition, the liquid crystal layer 353 contains a liquid crystal material. Note that the electrode 352 is provided so that an electric field for controlling the alignment of the liquid crystal material is generated between the electrode 352 and the electrode 351. In addition, the liquid crystal layer 353 preferably has a function of adjusting the intensity of light which enters the first display element 350 and is reflected by the reflective film 351B.

It is preferable that the electrode 351 have a structure in which a conductive film 351A and a conductive film 351C are provided so as to interpose the reflective film 351B therebetween. Interposing the reflective film 351B between the conductive films 351A and 351C suppresses diffusion of an element contained in the reflective film 351B into another layer. Moreover, it is possible to suppress contamination of the reflective film 351B due to impurities entering from the outside.

It is preferable that the conductive films 351A and 351C each have a function of transmitting light. Light incident on the first display element 350 from the outside can be efficiently reflected by the reflective film 351B owing to the function of transmitting light of the conductive film 351A. Moreover, light emitted from the second display element 550 as will be shown later can be efficiently extracted to the outside owing to the function of transmitting light of the conductive film 351C.

Note that the materials of the conductive films 351A and 351C may be the same or different. The same material is preferably used for the conductive films 351A and 351C, in which case patterning by etching in the process for forming the electrode 351 can be performed easily and manufacturing cost of the display device 300 can be reduced. Each of the conductive films 351A and 351C may have a stacked-layer structure of two or more layers.

In addition, the display device 300 includes an alignment film 331 and an alignment film 332. The liquid crystal layer 353 is interposed between the alignment films 331 and 332.

The display device 300 includes a coloring layer 375, a light-blocking film 373, an insulating film 371, a functional film 370D, and a functional film 370P in a region overlapping with the pixel circuit 302.

The coloring layer 375 has a region overlapping with the first display element 350. The light-blocking film 373 has an opening in a region overlapping with the first display element 350. With the coloring layer 375, light incident on the first display element 350 from the outside enters the reflective film 351B through the coloring layer 375 and light reflected by the reflective film 351B is extracted to the outside through the coloring layer 375. Accordingly, light incident on the first display element 350 from the outside and reflected can be extracted to the outside with a predetermined color.

The insulating film 371 is provided between the coloring layer 375 and the liquid crystal layer 353 or between the light-blocking film 373 and the liquid crystal layer 353. Owing to this, impurity diffusion from the light-blocking film 373, the coloring layer 375, or the like to the liquid crystal layer 353 can be suppressed. The insulating film 371 may be provided to eliminate unevenness due to the thickness of the coloring layer 375.

The functional films 370D and 370P each include a region overlapping with the first display element 350. A substrate 370 is interposed between the functional film 370D and the first display element 350. As the functional films 370D and 370P, a film having a function of displaying clearer images of the first display element 350 and the second display element 550, a film having a function of protecting the surface of the display device 300, or the like can be used. Note that either the functional film 370D or 370P may be used.

The display device 300 includes the substrate 370, a substrate 570, and a functional layer 520.

The substrate 370 has a region overlapping with the substrate 570. The functional layer 520 is provided between the substrates 570 and 370.

The functional layer 520 includes the transistor included in the pixel circuit 302, the second display element 550, an insulating film 521, and an insulating film 528.

The insulating film 521 is provided between the transistor included in the pixel circuit 302 and the second display element 550. The insulating film 521 is preferably formed so that steps due to components overlapping with the insulating film 521 can be covered to form a flat surface.

A light-emitting element is preferably used as the second display element 550. Specifically, an organic electroluminescence element (organic EL element), an inorganic electroluminescence element (inorganic EL element), a light-emitting diode (LED), or the like can be used.

The second display element 550 includes an electrode 551, an electrode 552, and a light-emitting layer 553. The electrode 552 has a region overlapping with the electrode 551. The light-emitting layer 553 is provided between the electrodes 551 and 552. The electrode 551 is electrically connected to the transistor 585 included in the pixel circuit 302 in a connection portion 522.

In addition, the insulating film 528 has a region interposed between the electrodes 551 and 552. The insulating film 528 has an insulating property and thus can avoid a short circuit between the electrodes 551 and 552. In order to avoid a short circuit, a side end portion of the electrode 551 preferably has a region in contact with the insulating film 528. In addition, the insulating film 528 includes an opening in a region overlapping with the second display element 550. In the opening, the second display element 550 emits light.

The light-emitting layer 553 preferably contains an organic material or an inorganic material as a light-emitting material. Specifically, a fluorescent organic light-emitting material or a phosphorescent organic light-emitting material can be used. In addition, an inorganic light-emitting material such as quantum dots can be used.

The reflective film 351B of the first display element 350 includes an opening 351H. The opening 351H has a region overlapping with the conductive films 351A and 351C each having a function of transmitting light. The second display element 550 has a function of emitting light toward the opening 351H. In other words, the first display element 350 has a function of performing display in a region overlapping with the reflective film 351B, and the second display element 550 has a function of performing display in a region overlapping with the opening 351H.

In addition, the first display element 350 has a function of performing display in a region overlapping with the reflective film 351B, and the second display element 550 has a function of performing display in a region overlapping with the opening 351H; therefore, the second display element 550 has a function of performing display in a region surrounded by the display region of the first display element 350 (see FIGS. 1B-1 and 1B-2).

It is thus preferable that the opening which is provided in the insulating film 528 have a region overlapping with the opening 351H and have an area almost equal to the area of the opening 351H. This can achieve efficient extraction of light from the second display element 550 emitting in the opening which is provided in the insulating film 528 through the opening 351H. Specifically, the area of the opening 351H when the area of the opening which is provided in the insulating film 528 is 1 is preferably greater than or equal to 0.5 and less than or equal to 2, further preferably greater than or equal to 0.7 and less than or equal to 1.4.

Note that it is preferable in order to efficiently reflect light entering from the outside in the first display element 350 that the area of the opening 351H be smaller than the area of the opening provided in the insulating film 528. Alternatively, it is preferable in order to extract light emitted from the second display element 550 to the outside as much as possible that the area of the opening 351H be larger than that of the opening provided in the insulating film 528.

With the above-described structure in which a reflective liquid crystal element and a light-emitting element are used as the first display element 350 and the second display element 550, respectively, the display device can perform display using the reflective liquid crystal element (the first display element 350) in a bright environment, whereas using light from the light-emitting element (the second display element 550) in a dark environment. Thus, a convenient display device with high visibility and low power consumption both in bright and dark environments can be provided. In addition, the display device can perform display in a dim environment using both the reflective liquid crystal element (utilizing external light) and light from the light-emitting element. Thus, a convenient display device with high visibility and low power consumption can be provided.

### <Components of Second Display Element>

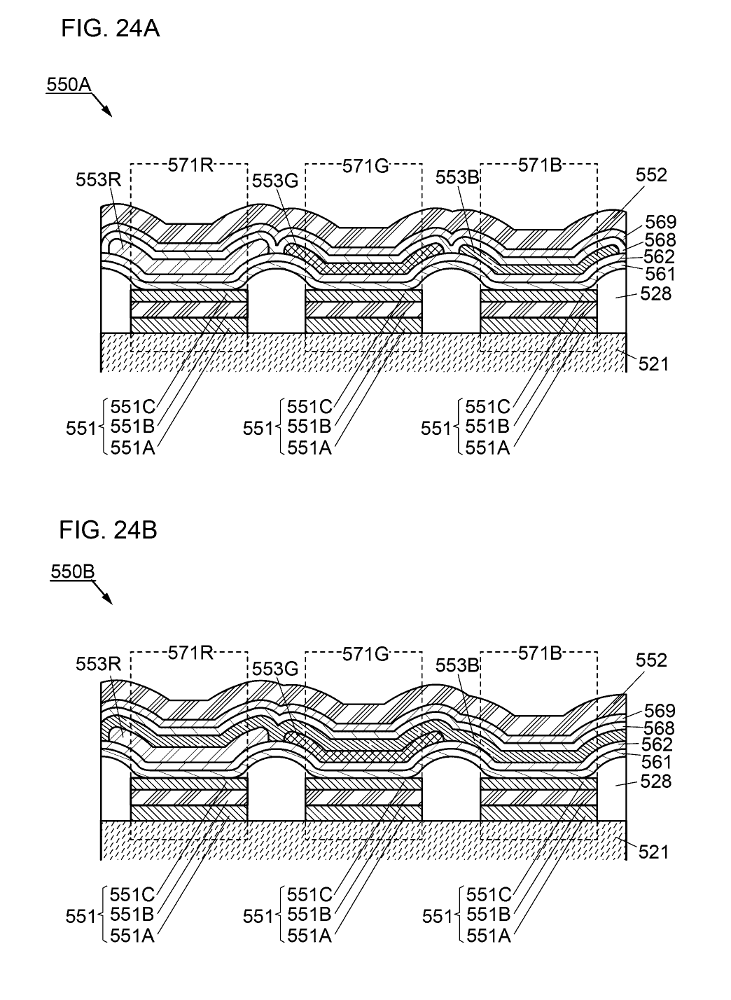

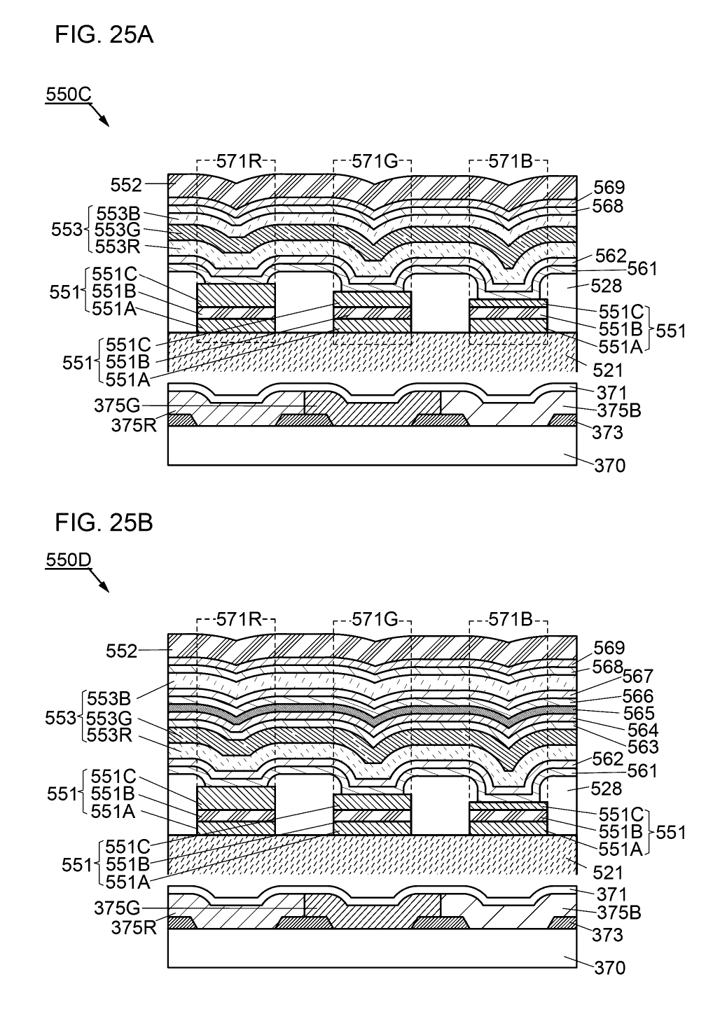

Here, the structure of the second display element 550 is described with reference to FIGS. 24A and 24B and FIGS. 25A and 25B.

### Structure Example 1

FIG. 24A is a cross-sectional view of a light-emitting element of the display device 300 of one embodiment of the present invention. A light-emitting element 550A that can be used as the second display element 550 includes a pair of electrodes (the electrodes 551 and 552) and the light-emitting layer 553 provided between the pair of electrodes. The light-emitting element 550A preferably includes a hole-injection layer 561, a hole-transport layer 562, an electron-transport layer 568, and an electron-injection layer 569 in addition to the light-emitting layer 553.

The structure of the light-emitting element 550A is not limited thereto, and a structure including at least one layer selected from the hole-injection layer 561, the hole-transport layer 562, the electron-transport layer 568, and the electron-injection layer 569 may be employed. Alternatively, the light-emitting element used as the second display element 550 may include a layer which is capable of lowering a hole- or electron-injection barrier, improving a hole- or electron-transport property, inhibiting a hole- or electron-transport property, or suppressing a quenching phenomenon by an electrode, for example. Note that the above layers may each be a single layer or stacked layers.

The light-emitting layer 553 preferably has a function of emitting light of blue, green, red, yellow, white, or the like. The second display element 550 includes a light-emitting element emitting light of at least three different colors. Therefore, light-emitting layers 553R, 553G, and 553B are illustrated in FIG. 24A as the light-emitting layer 553.

The light-emitting layers 553R, 553G, and 553B preferably contain light-emitting materials having functions of emitting light of different colors. For example, when the light-emitting layer 553R contains a light-emitting material having a function of emitting red light, a region 571R emits red light. When the light-emitting layer 553G contains a light-emitting material having a function of emitting green light, a region 571G emits green light. When the light-emitting layer 553B contains a light-emitting material having a function of emitting blue light, a region 571B emits blue light. The light-emitting element having such a structure is used in a pixel of the display device 300, whereby a full-color display device can be fabricated.

Note that the thicknesses of the light-emitting layers may be the same or different. Any one or a plurality of the light-emitting layers 553R, 553G, and 553B may have a stacked-layer structure of two or more layers, in which a layer containing no light-emitting material may be included.

In the display device of one embodiment of the present invention, the coloring layer 375, the functional film, 370D, and the functional film 370P each functioning as an optical element (e.g., a coloring layer, a color conversion layer (e.g., quantum dot), a polarizing plate, and an anti-reflective film) are provided in a region overlapping with the second display element 550. Therefore, the color purity of light emitted from the light-emitting element 550A can be improved and thus the color purity of the display device 300 can be improved. Alternatively, the contrast ratio of the display device 300 can be enhanced.

In the light-emitting element 550A, voltage application between the pair of electrodes (the electrodes 551 and 552) allows electrons and holes to be injected from the cathode and the anode, respectively, into the light-emitting element and thus current flows. By recombination of the injected electrons and holes, a light-emitting material of the light-emitting layer 553 (the light-emitting layers 553R, 553G, and 553B) is brought into an excited state to provide light emission.

The light-emitting layer 553 contains at least the light-emitting material, preferably an organic light-emitting material or an inorganic light-emitting material. A material emitting fluorescence (a fluorescent material) can be used as the organic light-emitting material. The organic light-emitting material preferably has a function of converting triplet excitation energy into light emission and is preferably a material capable of exhibiting phosphorescence (a phosphorescent material) because of high emission efficiency. As the inorganic light-emitting material, quantum dots are preferably used because they have small half width of an emission spectrum and a function of emitting light with high color purity.

As a method for forming a light-emitting layer, the following methods can be given: a method in which light-emitting layers having a function of emitting light of different colors are formed in a common region and emission colors are changed using coloring layers (also referred to as color filters), i.e. a color filter method; and a method in which light-emitting layers having a function of emitting light of different colors are formed in the respective regions, i.e. a separate coloring method. In the separate coloring method, it is not necessary to change an emission color using a coloring layer; therefore, use efficiency of light emitted from a light-emitting layer is high and thus a light-emitting element with high emission efficiency can be fabricated.

However, in the separate coloring method, it is necessary to form light-emitting layers having a function of emitting light of different colors in the respective regions using a shadow mask (also referred to as a fine metal mask); thus, openings of the shadow mask need to be arranged (aligned) at predetermined positions with high accuracy. When a display device has high pixel density and high resolution, the alignment accuracy needs to be high, which decreases yield at manufacturing the display device. Therefore, it is preferable that the number of steps of forming light-emitting layers using a shadow mask be small.

A structure with a smaller number of steps of forming light-emitting layers using a shadow mask is described with reference to FIG. 24B. In a light-emitting element 550B illustrated in FIG. 24B, the light-emitting layer 553R is formed in a region overlapping with the region 571R, the light-emitting layer 553G is formed in a region overlapping with the region 571G, and the light-emitting layer 553B is formed in a region overlapping with the regions 571R, 571G, and 571B, whereby the number of steps of forming light-emitting layers using a shadow mask can be reduced.

In the light-emitting element 550B, the hole-injection layer 561, the hole-transport layer 562, the light-emitting layer 553B, the electron-transport layer 568, the electron-injection layer 569, and the electrode 552 can be formed in common in the regions 571R, 571G, and 571B; accordingly, two steps of forming light-emitting layers, i.e., the light-emitting layers 553R and 553G, are performed using a shadow mask. Therefore, the productivity in manufacturing the light-emitting element 550B can be improved as compared with that of the light-emitting element 550A.

In the light-emitting element 550B, it is preferable that the light-emitting layer 553B do not contribute to light emission in the regions 571R and 571G. For example, for the light-emitting layer 553B, a material with a high electron-transport property and a low hole-transport property or a material having a lower highest occupied molecular orbital (HOMO) level than materials of the light-emitting layers 553R and 553G is used. That is, the light-emitting layer 553B functions as a light-emitting layer in the region 571B and functions as an electron-transport layer in the regions 571R and 571G.

For example, in the case where the light-emitting layers 553R and 553G each include a host material and a guest material, it is preferable that the host material have a material having a hole-transport property (a hole-transport material) and a material having an electron-transport property (an electron-transport material). With such a structure, the light-emitting layers 553R and 553G have a bipolar property and the light-emitting layers can have favorable carrier balance.

The wavelength of light emitted from the light-emitting layer 553R and the wavelength of light emitted from the light-emitting layer 553G are preferably longer than the wavelength of light emitted from the light-emitting layer 553B. Thus, it is possible to suppress light emission caused by excitation of a light-emitting material of the light-emitting layer 553B by energies of light emitted from the light-emitting layer 553R and light emitted from the light-emitting layer 553G. Even when the light-emitting layer 553B emits light in the regions 571R and 571G, light emitted from the light-emitting layer 553B is absorbed by the light-emitting layers 553R and 553G so as to be converted into light emitted from the light-emitting layer 553R and light emitted from the light-emitting layer 553G; accordingly, light emitted from the light-emitting layer 553B is prevented from emitting to the outside in the regions 571R and 571G.

In such a structure, for example, it is preferable that the light-emitting layer 553R contain a phosphorescent material having a function of emitting red light, the light-emitting layer 553G contain a phosphorescent material having a function of emitting green light, and the light-emitting layer 553B contain a fluorescent material having a function of emitting blue light. With such a structure, a light-emitting element achieving both high emission efficiency and high reliability can be fabricated. Alternatively, the light-emitting layer 553B may include a phosphorescent material having a function of emitting blue light.

Note that in the steps of forming the light-emitting layers 553R and 553G, a hole-transport layer and a light-emitting layer may be sequentially formed, so that the thickness between the electrodes 551 and 552 can be set to a thickness with which light is easily emitted to the outside from the light-emitting layer.

Although the light-emitting elements 550A and 550B in FIGS. 24A and 24B preferably have a bottom-emission structure in which light is extracted through the electrode 551, they may have a top-emission structure in which light is extracted in the direction opposite to the electrode 551.

In the case where the light-emitting elements 550A and 550B each have a bottom-emission structure, the electrode 552 preferably has a function of reflecting light. Therefore, it is preferable that the electrode 552 include a reflective film having a function of reflecting light. The electrode 551 preferably has a function of transmitting light. Moreover, the electrode 551 preferably includes a reflective film 551B having functions of transmitting light and reflecting light. With the reflective film 551B, the electrode 551 has functions of transmitting light and reflecting light, and a microcavity structure in which light is resonated between the electrodes 551 and 552 can be formed.

Specifically, the electrode 551 preferably includes a conductive film 551A, the reflective film 551B over the conductive film 551A, and a conductive film 551C over the reflective film 551B. That is, the electrode 551 preferably has a region in which the reflective film 551B is interposed between the conductive films 551A and 551C.

The reflective film 551B in the second display element 550 preferably has a region containing the same material as the reflective film 351B in the first display element 350. The reflective film 551B has the region containing the same material as the reflective film 351B, so that manufacturing cost of the display device can be reduced.

The materials of the reflective films 551B and 351B are preferably a metal having a function of reflecting light and further preferably at least one of silver (Ag) and aluminum (Al). Note that Al can reduce manufacturing cost of the display device when used for a reflective film owing to advantages of Al of high reflectance, a low material cost, and easiness to perform patterning. In addition, Ag particularly has high reflectance and thus can increase the reflectance of the reflective film and reduce power consumption of the display device. Having a low absorptance, Ag having a thickness that allows transmission of light (preferably, a thickness greater than or equal to 1 nm and less than or equal to 30 nm) is used, whereby a reflective film having functions of transmitting light and reflecting light can be formed.

Therefore, the reflective film 551B preferably has a region having a thickness smaller than that of the reflective film 351B.

From the above reason, it is preferable that the reflective film of the electrode 552 contain the same material as the reflective film 551B and that the reflective film 551B contain the same material as the reflective film 351B. The materials are preferably a metal having a function of reflecting light and further preferably at least one of silver (Ag) and aluminum (Al).

Therefore, the reflective film 551B preferably has a region having a thickness smaller than that of the reflective film of the electrode 552.

The conductive films 551A and 551C in the second display element 550 preferably each have a region containing the same material as the conductive films 351A and 351C in the first display element 350. The conductive films 551A and 551C have the regions containing the same materials as the conductive films 351A and 351C, so that manufacturing cost of the display device can be reduced.

The conductive film 551A preferably has a region containing the same metal as the conductive film 551C, in which case patterning by etching in the process for forming the electrode 551 can be performed easily. The conductive film 351A preferably has a region containing the same metal as the conductive film 351C, in which case patterning by etching in the process for forming the electrode 351 can be performed easily.

The materials of the conductive films 551C and 351C preferably have a function of transmitting light, and the materials are preferably a metal oxide. The materials of the conductive films 551A and 351A preferably have a function of transmitting light, and the materials are preferably a metal oxide. Further, these metal oxides preferably contain at least one of indium (In) and zinc (Zn). With the metal oxides containing In and/or Zn, conductivity and light transmittance can be improved. Moreover, manufacturing cost of the display device can be reduced with the use of Zn for the conductive films because of a low material cost of Zn.

Note that in the case where a material containing Al is in direct contact with an oxide containing In, the material containing Al and the oxide containing In differ in ionization tendency; thus, electrons are donated and accepted between the material and the oxide, resulting in electrolytic corrosion between electrodes containing the material and the oxide. Therefore, it is preferable that the material containing Al is not in direct contact with the oxide containing In. This also indicates that Ag is particularly preferable as a metal contained in the reflective films 351B and 551B.

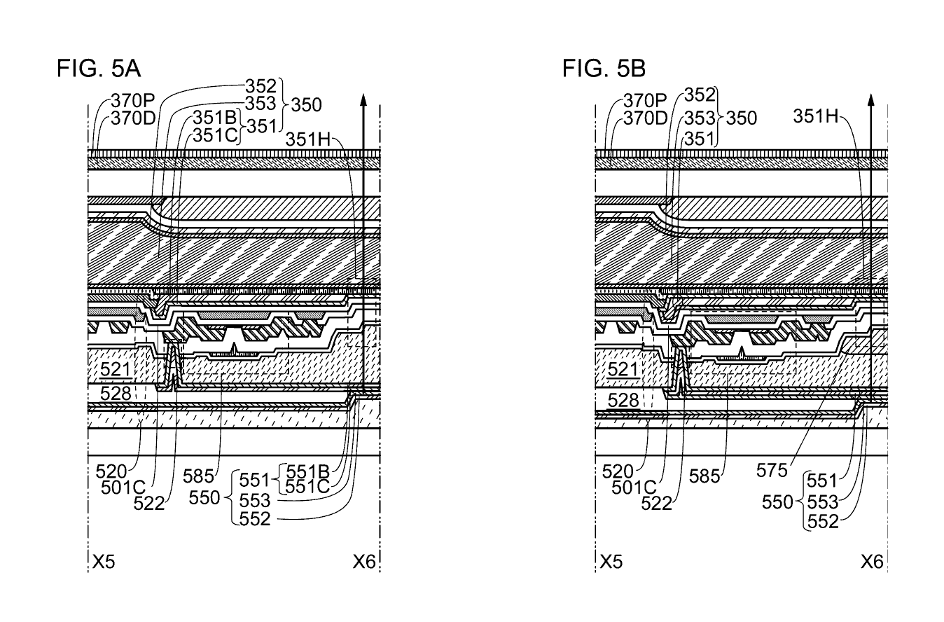

Note that as illustrated in FIG. 5A, the electrode 551 may include either the conductive film 551A or 551C. In addition, the electrode 351 may include either the conductive film 351A or 351C.

### <<Microcavity Structure>>

The light-emitting element that can be used as the second display element 550 preferably has a microcavity structure.

Since the electrode 551 includes the reflective film 551B and the electrode 552 includes the reflective film, light emitted from the light-emitting layer 553 (the light-emitting layers 553R, 553G, and 553B) is resonated between a pair of electrodes (the electrodes 551 and 552). Therefore, the light-emitting layer 553 is preferably formed in such a position as to intensify the light of a desired wavelength among light to be emitted. For example, by adjusting the optical length from a reflective region of the electrode 551 to the light-emitting region of the light-emitting layer 553R and the optical length from a reflective region of the electrode 552 to the light-emitting region of the light-emitting layer 553R, the light of a desired wavelength among light emitted from the light-emitting layer 553R can be intensified. By adjusting the optical length from the reflective region of the electrode 551 to the light-emitting region of the light-emitting layer 553G and the optical length from the reflective region of the electrode 552 to the light-emitting region of the light-emitting layer 553G, the light of a desired wavelength among light emitted from the light-emitting layer 553G can be intensified. By adjusting the optical length from the reflective region of the electrode 551 to the light-emitting region of the light-emitting layer 553B and the optical length from the reflective region of the electrode 552 to the light-emitting region of the light-emitting layer 553B, the light of a desired wavelength among light emitted from the light-emitting layer 553B can be intensified. In the case of a light-emitting element including a plurality of light-emitting layers (here, the light-emitting layers 553R, 553G, and 553B), the optical lengths of the light-emitting elements are preferably optimized.

For example, in each of the light-emitting elements 550A and 550B, by adjusting the thickness of the light-emitting layer in each region (the region 571R, 571G, or 571B), the light of a desired wavelength among light emitted from the light-emitting layers 553R, 553G, and 553B can be intensified. By adjusting the thickness of the conductive film 551C in each region (the region 571R, 571G, or 571B), the light of a desired wavelength among light emitted from the light-emitting layers 553R, 553G, and 553B can be intensified. The thickness of at least one of the hole-injection layer 561 and the hole-transport layer 562 or at least one of the electron-injection layer 569 and the electron-transport layer 568 may differ between the regions (the regions 571R, 571G, and 571B) to increase intensity of the light emitted from the light-emitting layers 553R, 553G, and 553B.

For example, in the case where the refractive index of the material of the reflective film 551B in the electrode 551 is lower than the refractive index of the light-emitting layer 553R, the thickness between the electrodes 551 and 552 in the region 571R is adjusted so that the optical length between the electrodes 551 and 552 in the region 571R is m_{R}λ_{R}/2 (m_{R} is a natural number and λ_{R} is the wavelength of light intensified in the region 571R). Similarly, the thickness between the electrodes 551 and 552 in the region 571G is adjusted so that the optical length between the electrodes 551 and 552 in the region 571G is m_{G}λ_{G}/2 (m_{G} is a natural number and λ_{G} is the wavelength of light intensified in the region 571G). Furthermore, the thickness between the electrodes 551 and 552 in the region 571B is adjusted so that the optical length between the electrodes 551 and 552 in the region 571B is m_{B}×_{B}/2 (m_{B} is a natural number and λ_{B} is the wavelength of light intensified in the region 571B).

In the case where it is difficult to precisely determine the reflective regions of the electrodes 551 and 552, the optical length for increasing the intensity of light emitted from the light-emitting layers 553R, 553G, and 553B may be derived on the assumption that certain regions of the electrodes are the reflective regions. In the case where it is difficult to precisely determine the light-emitting regions of the light-emitting layers 553R, 553G, and 553B, the optical length for increasing the intensity of light emitted from each light-emitting layer may be derived on the assumption that certain regions of the light-emitting layers are the light-emitting regions.

In the above manner, with the microcavity structure, in which the optical length between the pair of electrodes in the respective regions is adjusted, scattering and absorption of light in the vicinity of the electrodes can be suppressed, resulting in high light extraction efficiency. The emission spectra of extracted light are narrowed, and thus light emission with high color purity can be achieved.

That is, with the microcavity structure of the second display element 550, power consumption of the display device 300 can be reduced. In addition, the color reproducibility of the display device can be improved.

In the above structure, it is preferable that the conductive films 551A and 551C each have a function of transmitting light. The materials of the conductive films 551A and 551C may be the same or different. The same material is preferably used for the conductive films 551A and 551C, in which case patterning by etching in the process for forming the electrode 551 can be performed easily and manufacturing cost of the light-emitting element 550A can be reduced. Each of the conductive films 551A and 551C may have a stacked-layer structure of two or more layers.

Note that in each of the light-emitting elements 550A and 550B, the insulating film 528 is provided between the regions 571R, 571G, and 571B, which are interposed between the electrodes 551 and 552. The insulating film 528 covers end portion of the electrode 551 and has openings overlapping with the electrode. With the insulating film 528, the electrode 551 in the regions can be divided into island shapes.

Note that the light-emitting layers 553R and 553G may overlap with each other in a region where they overlap with the insulating film 528. The light-emitting layers 553G and 553B may overlap with each other in a region where they overlap with the insulating film 528. The light-emitting layers 553R and 553B may overlap with each other in a region where they overlap with the insulating film 528.

### Structure Example 2

The light-emitting element used as the second display element 550 may be formed by a color filter method. A light-emitting element 550C and a light-emitting element 550D illustrated in FIGS. 25A and 25B as examples are each a light-emitting element in which light-emitting layers having a function of emitting light of different colors are formed in common in the regions 571R, 571G, and 571B.

It is not necessary to use a shadow mask in steps of forming the light-emitting elements 550C and 550D; therefore, the light-emitting elements can be fabricated with high productivity.

In each of the light-emitting elements 550C and 550D, the optical length between the electrodes 551 and 552 is adjusted with the microcavity structure, resulting in high light extraction efficiency.

Note that in each of the light-emitting elements 550C and 550D, by adjusting the thicknesses of the conductive film 551C in each region (the region 571R, 571G, or 571B), light emitted from the light-emitting layers 553R, 553G, and 553B can be intensified.

As in the light-emitting element 550D in FIG. 25B, the light-emitting element used as the second display element 550 may have a structure in which a charge-generation layer is provided and at least two light-emitting units are stacked so as to interpose the charge-generation layer. The charge-generation layer provided between the two light-emitting units may have any structure having a function of injecting electrons into one light-emitting unit and injecting holes into the other light-emitting unit when a voltage is applied between a pair of electrodes. For example, the charge-generation layer may have either a structure in which an acceptor material that is an electron acceptor is added to a hole-transport material or a structure in which a donor material that is an electron donor is added to an electron-transport material. Alternatively, both of these structures may be stacked.

Note that one light-emitting unit includes at least a light-emitting layer, and a hole-injection layer, a hole-transport layer, an electron-transport layer, and an electron-injection layer are included in addition to the light-emitting layer. Specifically, the light-emitting element 550D includes a charge-generation layer 565; one of the light-emitting units which interpose the charge-generation layer 565 includes the hole-injection layer 561, the hole-transport layer 562, the light-emitting layer 553R, the light-emitting layer 553G, an electron-transport layer 563, and an electron-injection layer 564; and the other light-emitting unit includes a hole-injection layer 566, a hole-transport layer 567, the light-emitting layer 553B, the electron-transport layer 568, and the electron-injection layer 569, for example. Note that in the case where the charge-generation layer 565 can serve as a hole-injection layer or an electron-injection layer, a hole-injection layer or an electron-injection layer need not be provided. The light-emitting element used as the second display element 550 does not necessarily have the above structure.

One or both of the light-emitting layers of the two light-emitting units may be divided into layers and the divided layers may contain light-emitting materials having a function of emitting light of different colors.

The above structure is suitable for obtaining white light emission. For example, white light emission can be obtained using a light-emitting material emitting blue light and a light-emitting material emitting green light and red light. Alternatively, white light emission can be obtained using a light-emitting material emitting blue light and a light-emitting material emitting yellow light. Note that white light emission is not necessarily white and may include at least light emission of blue and another color (one or more of green, red, and yellow). A light-emitting element having a function of emitting white light is used for the display device of one embodiment of the present invention; therefore, a display device having high resolution can be fabricated.

The light-emitting element having two light-emitting units has been described with reference to FIG. 25B; however, the above structure can be applied to a light-emitting element in which three or more light-emitting units are stacked. With a plurality of light-emitting units partitioned by the charge-generation layer between a pair of electrodes as illustrated as an example in the light-emitting element 550D, it is possible to provide a light-emitting element which can emit light having high luminance with the current density kept low and has a long lifetime. Furthermore, a light-emitting element with low power consumption can be provided.

The display device of one embodiment of the present invention in FIGS. 2A to 2C, for example, includes the coloring layer 375 functioning as an optical element in a region overlapping with the second display element. For example, in the light-emitting elements 550C and 550D in FIGS. 25A and 25B, red light is emitted from the region 571R through a coloring layer 375R, green light is emitted from the region 571G through a coloring layer 375G, and blue light is emitted from the region 571B through a coloring layer 375B.

Note that as illustrated in FIG. 5B, in the pixel circuit 302, a coloring layer 575 may be provided in a region interposed between the first display element 350 and the second display element 550 and overlapping with the opening 351H. The coloring layer 575 has a region overlapping with the second display element 550, and light emitted from the second display element 550 is emitted to the outside through the coloring layer 575 and the coloring layer 375. Therefore, with the coloring layer 575, the color purity of light emitted from the second display element 550 can be improved.

### <Components of Pixel Circuit>

The pixel circuit 302 includes an insulating film 501C and an intermediate film 354. The pixel circuit 302 includes the switch 581, and the switch 581 includes a transistor. The pixel circuit 302 includes the transistor 585. These transistors preferably include a semiconductor film 508. The semiconductor film 508 preferably includes an oxide semiconductor.

The transistor that can be used as the switch 581, the transistor 585, and a transistor 586 each include a conductive film 504 and an insulating film 506 each having a region overlapping with the semiconductor film 508 in addition to the semiconductor film 508. The transistors each include conductive films 512A and 512B and insulating films 516 and 518 (see FIGS. 2B and 2C).

The conductive film 504 and the insulating film 506 function as a gate electrode and a gate insulating film of each of the transistors, respectively. The conductive film 512A functions as one of a source electrode and a drain electrode, and the conductive film 512B functions as the other.

The transistors 585 and 586 preferably each include a conductive film 524. The semiconductor film 508 is provided between the conductive film 504 and the conductive film 524 (see FIG. 2B). The conductive film 524 functions as a gate electrode of each of the transistors.

The insulating films 516 and 518 each have a region functioning as a protective insulating film of the transistor that can be used as the switch 581. The insulating film 516 has a region functioning as a gate insulating film of each of the transistors 585 and 586, and the insulating film 518 has a region functioning as a protective insulating film of each of the transistors 585 and 586.

That is, the semiconductor film 508 has a region overlapping with the insulating film 506 and a region overlapping with the insulating films 516 and 518. Moreover, the semiconductor film 508 has regions overlapping with the insulating films 501C and 521.

As described above, the functional layer 520 includes insulating films such as the insulating films 501C, 506, 516, and 518 in addition to the insulating films 521 and 528. Therefore, light emission of the second display element 550 from the opening 351H is made through these insulating films. It is preferable that the number of insulating films in a region overlapping with the opening 351H be small to increase the intensity of light emitted from the second display element 550. Alternatively, when there is a plurality of insulating films in the region overlapping with the opening 351H, a difference in refractive index of two insulating films which are in contact with each other is preferably small and the refractive indices are further preferably the same.

That is, the semiconductor film 508 preferably has regions overlapping with the conductive film functioning as a gate electrode and the insulating film functioning as a protective insulating film, and the number of insulating films having a region overlapping with the opening 351H is preferably small. Therefore, in the display device of one embodiment of the present invention, the number of insulating films having a region overlapping with the opening 351H is preferably smaller than the number of insulating films having a region overlapping with the semiconductor film 508.

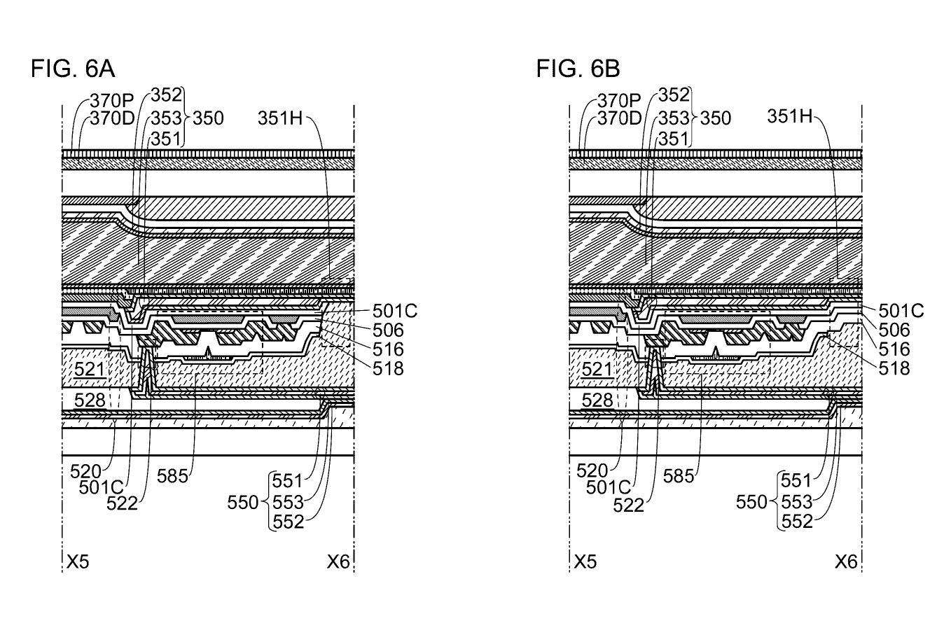

For example, as illustrated in FIG. 6A, as a structure of the display device of one embodiment of the present invention, a structure in which the insulating films 501C, 506, 516, and 518 each have an opening in a region overlapping with the opening 351H is preferably employed.

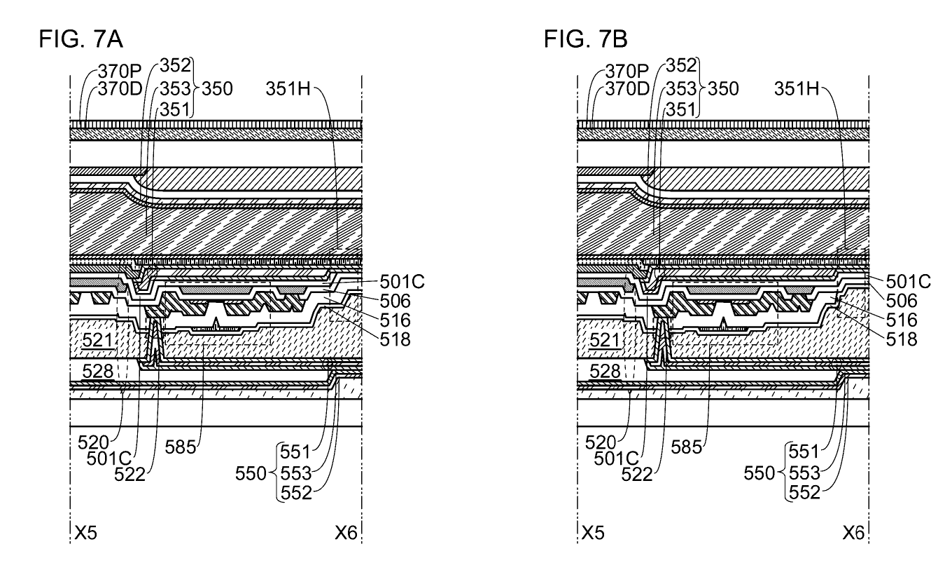

Note that the structure of the display device of one embodiment of the present invention is not limited to the structure illustrated as an example in FIG. 6A. For example, as illustrated in FIG. 6B, a structure in which the insulating film 518 has an opening in a region overlapping with the opening 351H is preferably used. Alternatively, for example, as illustrated in FIG. 7A, a structure in which the insulating film 501C has an opening in a region overlapping with the opening 351H is preferably used. Alternatively, for example, as illustrated in FIG. 7B, a structure in which the insulating film 516 has an opening in a region overlapping with the opening 351H is preferably used. In the structure illustrated in FIG. 7B, the side end portion of the insulating film 516 has a region interposed between the insulating films 506 and 518; therefore, entry of impurities into the semiconductor film 508 can be effectively suppressed, which is preferable to obtain a highly reliable display device.

The structures illustrated above as examples each may include the coloring layer 575 in a region interposed between the first display element 350 and the second display element 550 and overlapping with the opening 351H. With such a structure, light emitted from the second display element 550 is extracted to the outside through the coloring layers 575 and 375; therefore, the color purity of the light emitted from the second display element 550 can be improved and the intensity of light emitted from the second display element 550 can be increased.

As described above, the structure not including any one of the insulating films allows to improve transmittance of a region overlapping with the opening 351H. It is preferable that a difference in refractive index of two insulating films which are in contact with each other be small to improve transmittance of the region overlapping with the opening 351H.

For example, when light enters a layer containing a material with a low refractive index from a layer containing a material with a high refractive index, the angle of travel of light is changed in accordance with Snell's law. For example, in the case where an organic EL element is used as the second display element 550, the refractive index of a light-emitting material used for the organic EL element is in general 1.7 to 1.9. Therefore, a refractive index of a layer (layer A) containing the light-emitting material is higher than a refractive index of general glass or the like. When light emitted from the layer containing the light-emitting material enters a layer (layer B) containing a material whose refractive index is lower than that of the light-emitting material, for example, the angle of travel of light is changed, and light that enters the layer B from the layer A at an angle wider than a critical angle θ is difficult to be extracted to the outside of the layer B. Note that β is arcsin(n_{A}/n_{B}), and n_{A} and n_{B} represent a refractive index of a material A and a refractive index of B, respectively, when light enters a layer containing the material B from a layer containing the material A. To prevent this, a decrease in light intensity based on a difference in refractive index can be made small in such a manner that one of two layers different in refractive index is not included or a difference between refractive indices of the two layers is made small.

For example, a decrease in light intensity based on a difference in refractive index can be eliminated in such a manner that a structure including a layer containing a material with a high refractive index and a layer containing a material with a low refractive index is changed to a structure including a layer containing a material with a high refractive index and not including a layer containing a material with a low refractive index. Accordingly, transmittance of the layer through which light of a light-emitting element passes can be improved. Alternatively, a decrease in light intensity based on a difference in refractive index can be made small in such a manner that the materials of the two layers are changed to materials with a small difference in refractive index; accordingly, transmittance of the layers through which light of the light-emitting element passes can be improved.

Specifically, a refractive index of silicon oxide is lower than a refractive index of silicon nitride; therefore, a decrease in light intensity based on a difference in refractive index between silicon oxide and silicon nitride is likely to occur in a structure having a region where silicon oxide and silicon nitride are in contact with each other. Therefore, for example, a decrease in light intensity based on a difference in refractive index between an insulating film containing silicon oxide and an insulating film containing silicon nitride can be eliminated when the insulating film containing silicon oxide is not included. Moreover, for example, a decrease in light intensity based on a difference in refractive index between the insulating film containing silicon oxide and the insulating film containing silicon nitride can be eliminated when the insulating film containing silicon nitride is not included.

Note that even when the number of insulating films is the same, transmittance is changed by influence of interference of light by changing the thicknesses of the insulating films. Therefore, it is preferable to adjust the thicknesses of the insulating films so that desired transmittance can be obtained.

Other components of the display device 300 of one embodiment of the present invention are described below.

The pixel circuit 302 includes a first conductive film and a second conductive film.

The first conductive film is electrically connected to the first display element 350. For example, the first conductive film can be used for the electrode 351 of the first display element 350 (see FIG. 2A).

The second conductive film has a region overlapping with the first conductive film. The transistors included in the pixel circuit 302 are electrically connected to the second conductive film. For example, the second conductive film can be used as the conductive film 512B functioning as a source electrode or a drain electrode of the transistor that can be used as the switch 581 (see FIG. 2A and FIG. 3).

The insulating film 501C has a region interposed between the first conductive film and the second conductive film. The insulating film 501C has an opening 591A (see FIG. 2A).

The second conductive film is electrically connected to the first conductive film through the opening 591A. For example, the conductive film 512B that also serves as the second conductive film is electrically connected to the electrode 351 that also serves as the first conductive film. That is, the electrode 351 is electrically connected to the transistor that can be used as the switch 581. Note that the electrode 351 has a side end portion in contact with the insulating film 501C. In this specification and the like, the first conductive film electrically connected to the second conductive film in the opening 591A can be referred to as a through electrode in some cases.

The intermediate film 354 has a region in contact with the electrode 351 that also serves as the first conductive film, and the electrode 351 is interposed between the insulating film 501C and part of the intermediate film 354.

The insulating film 501C has a region interposed between an insulating film 501A and a conductive film 511B. The insulating film 501C has an opening 591B in the region interposed between the insulating film 501A and the conductive film 511B and has an opening 591C in a region interposed between the insulating film 501A and a conductive film 511C.

The display device 300 includes a terminal 519B, and the terminal 519B includes the conductive film 511B and the intermediate film 354. In addition, the display device 300 includes a terminal 519C and a conductor 337, and the terminal 519C includes the conductive film 511C and the intermediate film 354 (see FIG. 2A).

The conductive film 511B is electrically connected to the pixel circuit 302. For example, when the electrode 351 or the first conductive film is used as the reflective film 351B, a surface functioning as a contact with the terminal 519B is oriented in the same direction as a surface of the electrode 351 facing light incident on the first display element 350.

A flexible printed circuit 377 can be electrically connected to the terminal 519B using a conductive material 339. Thus, power or signals can be supplied to the pixel circuit 302 through the terminal 519B.

The conductive film 511C is electrically connected to the pixel circuit 302. For example, when the electrode 351 or the first conductive film is used as the reflective film 351B, a surface functioning as a contact with the terminal 519C is oriented in the same direction as a surface of the electrode 351 facing light incident on the first display element 350.

The conductor 337 is interposed between the terminal 519C and the electrode 352 for electrically connecting them. For example, a conductive particle can be used as the conductor 337.

The insulating film 501A has an opening 592A, an opening 592B, and an opening 592C. The opening 592A has a region overlapping with the intermediate film 354 and the electrode 351. The opening 592B has a region overlapping with the intermediate film 354 and the conductive film 511B. The opening 592C has a region overlapping with the intermediate film 354 and the conductive film 511C. The insulating film 501A has a region interposed between the intermediate film 354 and the insulating film 501C in the end portion of the opening 592A.

The display device 300 includes a bonding layer 505, a sealant 305, and a structure body 335.

The bonding layer 505 is provided between the functional layer 520 and the substrate 570 and has a function of bonding the functional layer 520 and the substrate 570.

The sealant 305 is provided between the functional layer 520 and the substrate 370 and has a function of bonding the functional layer 520 and the substrate 370.

The structure body 335 has a function of making a predetermined space between the functional layer 520 and the substrate 370.

### <Arrangement Examples of Pixels, Wirings, and the Like>

The display device 300 includes the driver circuit GD and the driver circuit SD (see FIG. 1A).

The driver circuit GD is electrically connected to a scan line GL1 and a scan line GL2. The driver circuit GD includes the transistor 586, for example. Specifically, a transistor including a semiconductor film which can be formed through the same process as the transistor included in the pixel circuit 302 (e.g., the transistor included in the switch 581) can be used as the transistor 586 (see FIGS. 2A and 2B).

The driver circuit SD is electrically connected to a signal line SL1 and a signal line SL2. The driver circuit SD is electrically connected to a terminal using a conductive material, for example. The terminal can be formed through the same process as the terminal 519B or the terminal 519C.

The pixel circuit 302(i,j) is electrically connected to the signal line SL1(j) (see FIG. 3). Note that it is preferable that the conductive film 512A be electrically connected to the signal line SL1(j) (see FIG. 2A and FIG. 3).

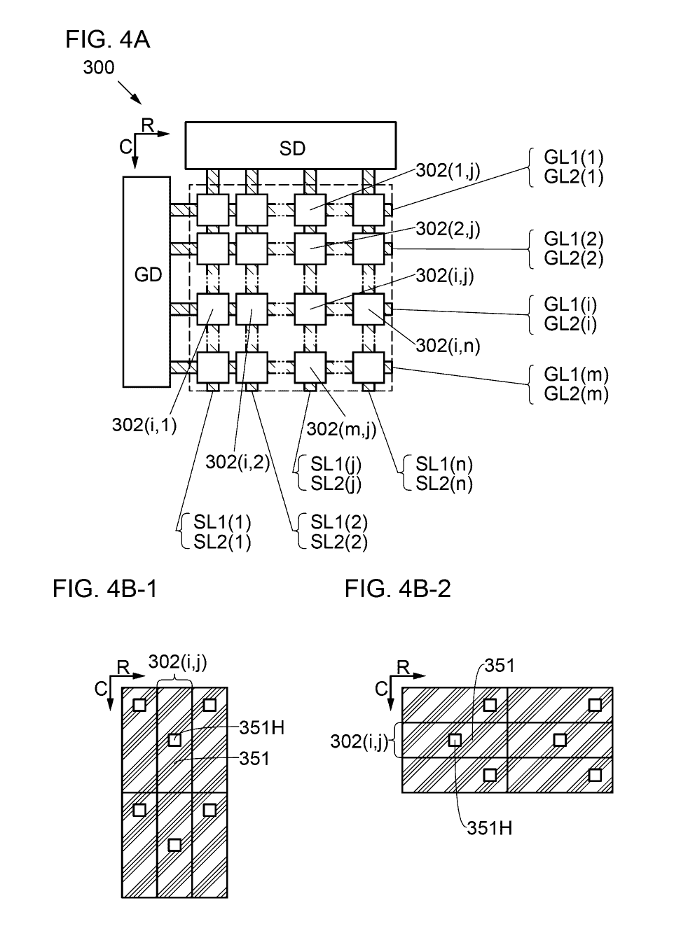

FIG. 4A is a block diagram illustrating arrangement of pixel circuits, wirings, and the like which can be used for the display device 300 of one embodiment of the present invention. FIGS. 4B-1 and 4B-2 are schematic views illustrating arrangement of the openings 351H which can be used for the display device 300 of one embodiment of the present invention.

Note that the display device 300 of one embodiment of the present invention preferably includes a plurality of pixel circuits 302; for example, the display device 300 includes a group of pixel circuits 302(i,1) to 302(i,n) and another group of pixel circuits 302(1,j) to 302(m,j) as illustrated in FIG. 4A. Note that i is an integer greater than or equal to 1 and less than or equal to m, j is an integer greater than or equal to 1 and less than or equal to n, and each of m and n is an integer greater than or equal to 1.

The group of pixel circuits 302(i,1) to 302(i,n) each include the first display element 350, the second display element 550, the switch 581, the transistor 585, and the like. The group of pixel circuits 302(i,1) to 302(i,n) are arranged in a row direction (indicated by an arrow R in FIG. 4A). The group of pixel circuits 302(1,j) to 302(m,j) each include the first display element 350, the second display element 550, the switch 581, the transistor 585, and the like. The group of pixel circuits 302(1,j) to 302(m,j) are arranged in a column direction (indicated by an arrow C in FIG. 4A) intersecting with the row direction.

The group of pixel circuits 302(i,1) to 302(i,n) arranged in the row direction are electrically connected to the scan line GL1(i). The group of pixel circuits 302(1,j) to 302(m,j) arranged in the column direction are electrically connected to the signal line SL1(j).

For example, a pixel adjacent to the pixel circuit 302(i,j) in the row direction (indicated by an arrow R in FIG. 4B-1) includes an opening in a position different from that of the opening 351H in the pixel circuit 302(i,j). In addition, for example, a pixel adjacent to the pixel circuit 302(i,j) in the column direction (indicated by an arrow C in FIG. 4B-2) includes an opening in a position different from that of the opening 351H in the pixel circuit 302(i,j).

Note that when a belt-like light-emitting layer that extends in the column direction along the signal line SL1(j) is used as the light-emitting layer 553(j), a belt-like light-emitting layer that extends in the column direction along the signal line SL1(j+1) and emits light of a color different from that of light emitted from the light-emitting layer can be used for the light-emitting layer 553(j+1). At this time, the pixel circuit 302(i,j) emits light of a color different from that of light emitted from the pixel circuit 302(i,j+1). In other words, the light-emitting element included in the pixel circuit 302(i,j) has a function of emitting light of a color different from that of light emitted from the pixel circuit 302(i,j+1).

Note that a light-emitting layer having a function of emitting white light may be used as the light-emitting layers 553(j) and 553(j+1). Specifically, a stack of a blue light-emitting layer, a green light-emitting layer, and a red light-emitting layer or a stack of a blue light-emitting layer and a yellow light-emitting layer can be used as the light-emitting layers 553(j) and 553(j+1).

As described above, the display device 300 of one embodiment of the present invention includes the pixel circuit 302; the pixel circuit 302 includes the first display element 350 and the second display element 550; the electrode 351 included in the first display element 350 is electrically connected to the transistor that can be used as the switch 581 included in the pixel circuit 302; the electrode 551 included in the second display element 550 is electrically connected to the transistor 585 included in the pixel circuit 302; the second display element 550 has a function of emitting light through the opening 351H; and the first display element 350 has a function of reflecting light entering the display device 300.

Thus, the first display element 350 and the second display element 550 can be driven using transistors that can be formed through the same process, for example.

Next, a structure example of the first display element that forms the display device of one embodiment of the present invention is described.

### <Components of First Display Element>

A display element having a function of controlling transmission or reflection of light can be used as the first display element 350. For example, a combined structure of a polarizing plate and a liquid crystal element or a MEMS shutter display element can be used. The use of a reflective display element can reduce power consumption of the display device. Specifically, a reflective liquid crystal display element is preferably used as the first display element 350.

Specifically, a liquid crystal element that can be driven by any of the following driving methods can be used: an in-plane-switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super-view (ASV) mode can be used.

Other examples of the driving method of the first display element 350 include a polymer-dispersed liquid crystal (PDLC) mode, a polymer network liquid crystal (PNLC) mode, and a guest-host mode. Note that one embodiment of the present invention is not limited to the above, and various liquid crystal elements and driving methods can be employed.

<Materials which can be Used for First Display Element>

A liquid crystal material or the like which can be used for a liquid crystal element may be used for the first display element 350. For example, thermotropic liquid crystal, low-molecular liquid crystal, high-molecular liquid crystal, polymer-dispersed liquid crystal, ferroelectric liquid crystal, or anti-ferroelectric liquid crystal can be used. Alternatively, a liquid crystal material which exhibits a cholesteric phase, a smectic phase, a cubic phase, a chiral nematic phase, an isotropic phase, or the like can be used. Alternatively, a liquid crystal material which exhibits a blue phase can be used.

Alternatively, liquid crystal exhibiting a blue phase for which an alignment film is unnecessary may be used. A blue phase is a liquid crystal phase which is generated just before a cholesteric phase changes into an isotropic phase while the temperature of cholesteric liquid crystal is increased. Since the blue phase appears only in a narrow temperature range, a liquid crystal composition in which 5 wt. % or more of a chiral material is mixed is used for the liquid crystal layer in order to widen the temperature range. The liquid crystal composition that includes the liquid crystal exhibiting a blue phase and a chiral material has a short response time of 1 msec or less, and has optical isotropy, which makes the alignment process unnecessary and the viewing angle dependence small. In addition, since an alignment film does not need to be provided, rubbing treatment is unnecessary. Therefore, electrostatic discharge damage caused by the rubbing treatment can be prevented and thus defects and damage of a liquid crystal display device in the manufacturing process can be reduced. Accordingly, productivity of the liquid crystal display device can be increased.

Furthermore, it is possible to use a method called domain multiplication or multi-domain design in which a pixel is divided into some regions (subpixels) and molecules are aligned in different directions in their respective regions.

<Materials which can be Used for Second Display Element>

Described below is a material which can be used for a light-emitting element which is preferable as the second display element 550.

### <<Light-Emitting Layer>>

For example, the following materials can be used for the light-emitting layer.

### <<Phosphorescent Material>>

As the phosphorescent material, an iridium-, rhodium-, or platinum-based organometallic complex or metal complex can be used; in particular, an organoiridium complex such as an iridium-based ortho-metalated complex is preferable. As an ortho-metalated ligand, a 4H-triazole ligand, a 1H-triazole ligand, an imidazole ligand, a pyridine ligand, a pyrimidine ligand, a pyrazine ligand, an isoquinoline ligand, and the like can be given. As the metal complex, a platinum complex having a porphyrin ligand and the like can be given.

Examples of the substance that has an emission peak in the blue or green wavelength range include organometallic iridium complexes having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: Ir(mpptz-dmp)₃), tris(5-methyl-3,4-diphenyl-4H-1,2,4-triazolato)iridium(III) (abbreviation: Ir(Mptz)₃), tris[4-(3-biphenyl)-5-isopropyl-3-phenyl-4H-1,2,4-triazolato]iridium(III) (abbreviation: Ir(iPrptz-3b)₃), and tris[3-(5-biphenyl)-5-isopropyl-4-phenyl-4H-1,2,4-triazolato]iridium(III) (abbreviation: Ir(iPr5btz)₃); organometallic iridium complexes having a 1H-triazole skeleton, such as tris[3-methyl-1-(2-methylphenyl)-5-phenyl-1H-1,2,4-triazolato]iridium(III) (abbreviation: Ir(Mptz1-mp)₃) and tris(1-methyl-5-phenyl-3-propyl-1H-1,2,4-triazolato)iridium(III) (abbreviation: Ir(Prptz1-Me)₃); organometallic iridium complexes having an imidazole skeleton, such as fac-tris[1-(2,6-diisopropylphenyl)-2-phenyl-1H-imidazole]iridium(III) (abbreviation: Ir(iPrpmi)₃) and tris[3-(2,6-dimethylphenyl)-7-methylimidazo[1,2-J]phenanthridinato]iridium(III) (abbreviation: Ir(dmpimpt-Me)₃); and organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis {2-[3′,5′-bis(trifluoromethyl)phenyl]pyridinato-N,C²′ }iridium(III)picolinate (abbreviation: Ir(CF₃ppy)₂(pic)), and bis[2-(4′,6′-difluorophenyl)pyridinato-N,C²′]iridium(III) acetylacetonate (abbreviation: FIr(acac)).

Examples of the substance that has an emission peak in the green or yellow wavelength range include organometallic iridium complexes having a pyrimidine skeleton, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(III) (abbreviation: Ir(tBuppm)₂(acac)), (acetylacetonato)bis[4-(2-norbomyl)-6-phenylpyrimidinato]iridium(III) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), (acetylacetonato)bis {4,6-dimethyl-2-[6-(2,6-dimethylphenyl)-4-pyrimidinyl-κN3]phenyl-κC}iridium(III) (abbreviation: Ir(dmppm-dmp)₂(acac)), and (acetylacetonato)bis(4,6-diphenylpyrimidinato)iridium(III) (abbreviation: Ir(dppm)₂(acac)); organometallic iridium complexes having a pyrazine skeleton, such as (acetylacetonato)bis(3,5-dimethyl-2-phenylpyrazinato)iridium(III) (abbreviation: Ir(mppr-Me)₂(acac)) and (acetylacetonato)bis(5-isopropyl-3-methyl-2-phenylpyrazinato)iridium(III) (abbreviation: Ir(mppr-iPr)₂(acac)); organometallic iridium complexes having a pyridine skeleton, such as tris(2-phenylpyridinato-N, C²′)iridium(III) (abbreviation: Ir(ppy)₃), bis(2-phenylpyridinato-N, C²′)iridium(III) acetylacetonate (abbreviation: Ir(ppy)₂(acac)), bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N, C^{2′})iridium(III) (abbreviation: Ir(pq)₃), and bis(2-phenylquinolinato-N, C²′)iridium(III) acetylacetonate (abbreviation: Ir(pq)₂(acac)); organometallic iridium complexes such as bis(2,4-diphenyl-1,3-oxazolato-N,C²′)iridium(III)acetylacetonate (abbreviation: Ir(dpo)₂(acac)), bis {2-[4′-(perfluorophenyl)phenyl]pyridinato-N,C²′ }iridium(III)acetylacetonate (abbreviation: Ir(p-PF-ph)₂(acac)), and bis(2-phenylbenzothiazolato-N,C^{2′})iridium(III)acetylacetonate (abbreviation: Ir(bt)₂(acac)); and a rare earth metal complex such as tris(acetylacetonato)(monophenanthroline)terbium(III) (abbreviation: Tb(acac)₃(Phen)). Among the materials given above, the organometallic iridium complexes having a pyrimidine skeleton have distinctively high reliability and emission efficiency and are thus particularly preferable.

Examples of the substance that has an emission peak in the yellow or red wavelength range include organometallic iridium complexes having a pyrimidine skeleton, such as (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), and bis[4,6-di(naphthalen-1-yl)pyrimidinato](dipivaloylmethanato)iridium(III) (abbreviation: Ir(d1npm)₂(dpm)); organometallic iridium complexes having a pyrazine skeleton, such as (acetylacetonato)bis(2,3,5-triphenylpyrazinato)iridium(III) (abbreviation: Ir(tppr)₂(acac)), bis(2,3,5-triphenylpyrazinato) (dipivaloylmethanato)iridium(III) (abbreviation: Ir(tppr)₂(dpm)), and (acetylacetonato)bis[2,3-bis(4-fluorophenyl)quinoxalinato]iridium(III) (abbreviation: Ir(Fdpq)₂(acac)); organometallic iridium complexes having a pyridine skeleton, such as tris(1-phenylisoquinolinato-N,C²′)iridium(III) (abbreviation: Ir(piq)₃) and bis(1-phenylisoquinolinato-N,C²′)iridium(III)acetylacetonate (abbreviation: Ir(piq)₂(acac)); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: Eu(DBM)₃(Phen)) and tris[1-(2-thenoyl)-3,3,3-trifluoroacetonato](monophenanthroline)europium(III) (abbreviation: Eu(TTA)₃(Phen)). Among the materials given above, the organometallic iridium complexes having a pyrimidine skeleton have distinctively high reliability and emission efficiency and are thus particularly preferable. Further, the organometallic iridium complexes having a pyrazine skeleton can provide red light emission with favorable chromaticity.

As the organic light-emitting material included in the light-emitting layer, any material can be used as long as the material can convert the triplet excitation energy into light emission. As an example of the material that can convert triplet excitation energy into light emission, a thermally activated delayed fluorescence material can be given in addition to the phosphorescent material. Therefore, the term “phosphorescent material” in the description can be replaced with the term “thermally activated delayed fluorescence material”. Note that the thermally activated delayed fluorescence material is a material having a small energy difference between the singlet excitation energy level and the triplet excitation energy level and has a function of converting the triplet excitation energy into the singlet excitation energy by reverse intersystem crossing. Thus, the thermally activated delayed fluorescence material can up-convert a triplet excited state into a singlet excited state (i.e., reverse intersystem crossing is possible) using a little thermal energy and efficiently exhibit light emission (fluorescence) from the singlet excited state. Conditions for efficiently obtaining thermally activated delayed fluorescence are as follows: the energy difference between the triplet excitation energy level and the singlet excitation energy level is preferably greater than 0 eV and less than or equal to 0.2 eV and further preferably greater than 0 eV and less than or equal to 0.1 eV.

As the thermally activated delayed fluorescence material, any of the following materials can be used, for example. First, a fullerene, a derivative thereof, an acridine derivative such as proflavine, eosin, and the like can be given. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

As the thermally activated delayed fluorescence material composed of one kind of material, a heterocyclic compound including a π-electron rich heteroaromatic ring and a π-electron deficient heteroaromatic ring can also be used. Specifically, 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. The heterocyclic compound is preferably used because of having the π-electron rich heteroaromatic ring and the π-electron deficient heteroaromatic ring, for which the electron-transport property and the hole-transport property are high. Note that a substance in which the π-electron rich heteroaromatic ring is directly bonded to the π-electron deficient heteroaromatic ring is particularly preferably used because the donor property of the π-electron rich heteroaromatic ring and the acceptor property of the π-electron deficient heteroaromatic ring are both increased and the difference between the level of the singlet excited state and the level of the triplet excited state becomes small. Note that an aromatic ring to which an electron-withdrawing group such as a cyano group is bonded may be used instead of the π-electron deficient heteroaromatic ring.

### <<Fluorescent Material>>

Note that a fluorescent material may be used for the light-emitting layer. The fluorescent material is preferably, but not particularly limited to, an anthracene derivative, a tetracene derivative, a chrysene derivative, a phenanthrene derivative, a pyrene derivative, a perylene derivative, a stilbene derivative, an acridone derivative, a coumarin derivative, a phenoxazine derivative, a phenothiazine derivative, or the like, and for example, any of the following materials can be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPm), N,N′-bis(3-methylphenyl)-N,N-bis[3-(9-phenyl-9H-fluoren-9-yl)phenyl]pyrene-1,6-diamine (abbreviation: 1,6mMemFLPAPm), N,N′-bis[4-(9-phenyl-9H-fluoren-9-yl)phenyl]-N,N′-bis(4-tert-butylphenyl)pyrene-1,6-diamine (abbreviation: 1,6tBu-FLPAPm), N,N′-diphenyl-N,N′-bis[4-(9-phenyl-9H-fluoren-9-yl)phenyl]-3, 8-dicyclohexylpyrene-1,6-diamine (abbreviation: ch-1,6FLPAPm), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N′,N′,N′,N″,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N, 9-triphenylanthracen-9-amine (abbreviation: DPhAPhA), coumarin 6, coumarin 545T, N,N′-diphenylquinacridone (abbreviation: DPQd), rubrene, 2,8-di-tert-butyl-5,11-bis(4-tert-butylphenyl)-6,12-diphenyltetracene (abbreviation: TBRb), Nile red, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), and 5,10,15,20-tetraphenylbisbenzo[5,6]indeno[1,2,3-cd:1′,2′,3′-lm]perylene.

### <<Host Material>>

In the light-emitting layer, the light-emitting material is preferably dispersed in the host material. In this case, the weight ratio of the host material to the light-emitting material is larger. A variety of materials can be used as the host material. For example, a material having a function of transporting a hole (a hole-transport material) and a material having a function of transporting an electron (an electron-transport material) can be used. Furthermore, a bipolar material having a hole-transport property and an electron-transport property can be used.

As the host material, a material having a property of transporting more electrons than holes can be used, and a material having an electron mobility of 1×10⁻⁶ cm²/Vs or higher is preferable. A compound including a π-electron deficient heteroaromatic ring skeleton such as a nitrogen-containing heteroaromatic compound, or a zinc- or aluminum-based metal complex can be used, for example, as the material which easily accepts electrons (the material having an electron-transport property). Specific examples include a compound such as an oxadiazole derivative, a triazole derivative, a benzimidazole derivative, a quinoxaline derivative, a dibenzoquinoxaline derivative, a phenanthroline derivative, a pyridine derivative, a bipyridine derivative, a pyrimidine derivative, and a triazine derivative. In addition, as examples, metal complexes having a quinoline ligand, a benzoquinoline ligand, an oxazole ligand, and a thiazole ligand can be given.

Specific examples include metal complexes having a quinoline or benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq) and bis(8-quinolinolato)zinc(II) (abbreviation: Znq). Alternatively, a metal complex having an oxazole-based or thiazole-based ligand, such as bis[2-(2-benzoxazolyl)phenolate]zinc(II) (abbreviation: ZnPBO) or bis[2-(2-benzothiazolyl)phenolato]zinc(II) (abbreviation: ZnBTZ) can be used. Other than such metal complexes, any of the following can be used: heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 9-[4-(4,5-diphenyl-4H-1,2,4-triazol-3-yl)phenyl]-9H-carbazole (abbreviation: CzTAZ1), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), bathophenanthroline (abbreviation: BPhen), 2,9-bis(naphthalen-2-yl)-4,7-diphenyl-1,10-phenanthroline (abbreviation: NBPhen), and bathocuproine (abbreviation: BCP); heterocyclic compounds having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-[3-(3,9′-bi-9H-carbazol-9-yl)phenyl]dibenzo[f,h]quinoxaline (abbreviation: 2mCzCzPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), and 4,6-bis[3-(9H-carbazol-9-yl)phenyl]pyrimidine (abbreviation: 4,6mCzP2Pm); heterocyclic compounds having a triazine skeleton such as 2-{4-[3-(N-phenyl-9H-carbazol-3-yl)-9H-carbazol-9-yl]phenyl}-4,6-diphenyl-1,3,5-triazine (abbreviation: PCCzPTzn); heterocyclic compounds having a pyridine skeleton such as 3,5-bis[3-(9H-carbazol-9-yl)phenyl]pyridine (abbreviation: 35DCzPPy); and heteroaromatic compounds such as 4,4′-bis(5-methylbenzoxazol-2-yl)stilbene (abbreviation: BzOs). Among the above heterocyclic compounds, the heterocyclic compounds having a triazine skeleton, a diazine skeleton (pyrimidine, pyrazine, pyridazine), or a pyridine skeleton are highly reliable and stable and is thus preferably used. In addition, the heterocyclic compounds having the skeletons have a high electron-transport property to contribute to a reduction in drive voltage. Further alternatively, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can be used. The substances described here are mainly substances having an electron mobility of 1×10⁻⁶ cm²/Vs or higher. Note that other substances may also be used as long as their electron-transport properties are higher than their hole-transport properties.

Alternatively, as the host material, any of the following hole-transport materials can be used.

As the hole-transport material, a material having a property of transporting more holes than electrons can be used, and a material having a hole mobility of 1×10⁻⁶ cm²/Vs or higher is preferable. Specifically, an aromatic amine, a carbazole derivative, an aromatic hydrocarbon, a stilbene derivative, or the like can be used. Furthermore, the hole-transport material may be a high molecular compound.

Specific examples of the material having a high hole-transport property are N,N′-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N′-bis {4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B).

Specific examples of the carbazole derivative are 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples of the carbazole derivative are 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene.

Examples of the aromatic hydrocarbon are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples are pentacene and coronene. The aromatic hydrocarbon having a hole mobility of 1×10⁻⁶ cm²/Vs or higher and having 14 to 42 carbon atoms is particularly preferable.

The aromatic hydrocarbon may have a vinyl skeleton. Examples of the aromatic hydrocarbon having a vinyl group are 4,4′-bis(2,2-diphenylvinyl)biphenyl (abbreviation: DPVBi) and 9,10-bis[4-(2,2-diphenylvinyl)phenyl]anthracene (abbreviation: DPVPA).

Other examples are high molecular compounds such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine](abbreviation: poly-TPD).

Examples of the material having a high hole-transport property are aromatic amine compounds such as 4,4′-bis[N-(1-naphthyl)-N-phenylamino]biphenyl (abbreviation: NPB or α-NPD), N,N′-bis(3-methylphenyl)-N,N-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), 2-[N-(9-phenylcarbazol-3-yl)-N-phenylamino]spiro-9,9′-bifluorene (abbreviation: PCASF), 2,7-bis[N-(4-diphenylaminophenyl)-N-phenylamino]spiro-9,9′-bifluorene (abbreviation: DPA2SF), N-[4-(9H-carbazol-9-yl)phenyl]-N-(4-phenyl)phenylaniline (abbreviation: YGA1BP), and N,N-bis[4-(carbazol-9-yl)phenyl]-N,N′-diphenyl-9,9-dimethylfluorene-2,7-diamine (abbreviation: YGA2F). Other examples are amine compounds, carbazole compounds, thiophene compounds, furan compounds, fluorene compounds; triphenylene compounds; phenanthrene compounds, and the like such as 3-[4-(1-naphthyl)-phenyl]-9-phenyl-9H-carbazole (abbreviation: PCPN), 3-[4-(9-phenanthryl)-phenyl]-9-phenyl-9H-carbazole (abbreviation: PCPPn), 3,3′-bis(9-phenyl-9H-carbazole) (abbreviation: PCCP), 1,3-bis(N-carbazolyl)benzene (abbreviation: mCP), 3,6-bis(3,5-diphenylphenyl)-9-phenylcarbazole (abbreviation: CzTP), 3,6-di(9H-carbazol-9-yl)-9-phenyl-9H-carbazole (abbreviation: PhCzGI), 2,8-di(9H-carbazol-9-yl)-dibenzothiophene (abbreviation: Cz2DBT), 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), 1,3,5-tri(dibenzothiophen-4-yl)benzene (abbreviated as DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylene-2-yl)phenyl]dibenzothiophene (abbreviation: mDBTPTp-II). Among the above compounds, compounds including a pyrrole skeleton, a furan skeleton, a thiophene skeleton, or an aromatic amine skeleton are preferred because of their high stability and reliability. In addition, the compounds having the skeletons have a high hole-transport property to contribute to a reduction in drive voltage.

Note that it is preferable that the host material and the phosphorescent material be selected such that the emission peak of the host material overlaps with an absorption band, specifically an absorption band on the longest wavelength side, of a triplet metal to ligand charge transfer (MLCT) transition of the phosphorescent material. This makes it possible to provide a light-emitting element with drastically improved emission efficiency. Note that in the case where a thermally activated delayed fluorescent material is used instead of the phosphorescent material, it is preferable that the absorption band on the longest wavelength side be a singlet absorption band.

Note that the host material may be a mixture of a plurality of kinds of substances, and in the case of using a mixed host material, it is preferable to mix a material having an electron-transport property with a material having a hole-transport property. By mixing the material having an electron-transport property with the material having a hole-transport property, the carrier transport property of the light-emitting layer can be easily adjusted and a recombination region can be easily controlled. The content ratio of the material having an electron-transport property to the material having a hole-transport property is preferably 1:9 to 9:1.

An exciplex may be formed by these mixed substances. It is preferable that the combination of the substances to be mixed be selected so as to form an exciplex that exhibits light emission whose wavelength overlaps with a wavelength of a lowest-energy-side absorption band of the light-emitting material, in which case excitation energy is transferred smoothly from the exciplex to the light-emitting material, light emission can be obtained efficiently from the light-emitting material, and the driving voltage can be reduced.

In the light-emitting layer, a material other than the host material and the light-emitting material may be contained. Besides the above materials, a high molecular compound (e.g., an oligomer, a dendrimer, and a polymer) or an inorganic compound such as a quantum dot may be used.

### <<Quantum Dot>>

A quantum dot is a semiconductor nanocrystal with a size of several nanometers to several tens of nanometers and contains approximately 1×10³ to 1×10⁶ atoms. Since energy shift of quantum dots depend on their size, quantum dots made of the same substance emit light with different wavelengths depending on their size. Thus, emission wavelengths can be easily adjusted by changing the size of quantum dots.

Since a quantum dot has an emission spectrum with a narrow peak, emission with high color purity can be obtained. In addition, a quantum dot is said to have a theoretical internal quantum efficiency of 100%, which far exceeds that of a fluorescent organic compound, i.e., 25%, and is comparable to that of a phosphorescent organic compound. Therefore, a quantum dot can be used as a light-emitting material to obtain a light-emitting element having high luminous efficiency. Furthermore, since a quantum dot which is an inorganic material has high inherent stability, a light-emitting element which is favorable also in terms of lifetime can be obtained.

Examples of a material of a quantum dot include a Group 14 element in the periodic table, a Group 15 element in the periodic table, a Group 16 element in the periodic table, a compound of a plurality of Group 14 elements in the periodic table, a compound of an element belonging to any of Groups 4 to 14 in the periodic table and a Group 16 element in the periodic table, a compound of a Group 2 element in the periodic table and a Group 16 element in the periodic table, a compound of a Group 13 element in the periodic table and a Group 15 element in the periodic table, a compound of a Group 13 element in the periodic table and a Group 17 element in the periodic table, a compound of a Group 14 element in the periodic table and a Group 15 element in the periodic table, a compound of a Group 11 element in the periodic table and a Group 17 element in the periodic table, iron oxides, titanium oxides, spinel chalcogenides, and semiconductor clusters.

Specific examples include, but are not limited to, cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot, whose composition is represented by a given ratio, may be used. For example, an alloyed quantum dot of cadmium, selenium, and sulfur is a means effective in obtaining blue light because the emission wavelength can be changed by changing the content ratio of elements.

As the quantum dot, any of a core-type quantum dot, a core-shell quantum dot, a core-multishell quantum dot, and the like can be used. Note that when a core is covered with a shell formed of another inorganic material having a wider band gap, the influence of defects and dangling bonds existing at the surface of a nanocrystal can be reduced. Since such a structure can significantly improve the quantum efficiency of light emission, it is preferable to use a core-shell or core-multishell quantum dot. Examples of the material of a shell include zinc sulfide and zinc oxide.

Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability. Examples of the protective agent (or the protective group) include polyoxyethylene alkyl ethers such as polyoxyethylene lauryl ether, polyoxyethylene stearyl ether, and polyoxyethylene oleyl ether; trialkylphosphines such as tripropylphosphine, tributylphosphine, trihexylphosphine, and trioctylphoshine; polyoxyethylene alkylphenyl ethers such as polyoxyethylene n-octylphenyl ether and polyoxyethylene n-nonylphenyl ether; tertiary amines such as tri(n-hexyl)amine, tri(n-octyl)amine, and tri(n-decyl)amine; organophosphorus compounds such as tripropylphosphine oxide, tributylphosphine oxide, trihexylphosphine oxide, trioctylphosphine oxide, and tridecylphosphine oxide; polyethylene glycol diesters such as polyethylene glycol dilaurate and polyethylene glycol distearate; organic nitrogen compounds such as nitrogen-containing aromatic compounds, e.g., pyridines, lutidines, collidines, and quinolones; animoalkanes such as hexylamine, octylamine, decylamine, dodecylamine, tetradecylamine, hexadecylamine, and octadecylamine; dialkylsulfides such as dibutylsulfide; dialkylsulfoxides such as dimethylsulfoxide and dibutylsulfoxide; organic sulfur compounds such as sulfur-containing aromatic compounds, e.g., thiophene; higher fatty acids such as a palmitin acid, a stearic acid, and an oleic acid; alcohols; sorbitan fatty acid esters; fatty acid modified polyesters; tertiary amine modified polyurethanes; and polyethyleneimines.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength region of a spectrum of an ultraviolet region, a visible light region, and an infrared region by changing the size of quantum dots. The range of size (diameter) of quantum dots which is usually used is 0.5 nm to 20 nm, preferably 1 nm to 10 nm. The emission spectra are narrowed as the size distribution of the quantum dots gets smaller, and thus light can be obtained with high color purity. The shape of the quantum dots is not particularly limited and may be spherical shape, a rod shape, a circular shape, or the like. Quantum rods which are rod-like shape quantum dots have a function of emitting directional light; thus, quantum rods can be used as a light-emitting material to obtain a light-emitting element with higher external quantum efficiency.

However, in most organic EL elements, to improve emission efficiency, light-emitting materials are dispersed in host materials and concentration quenching of the light-emitting materials is suppressed. The host materials need to be materials each having a singlet excitation energy level or a triplet excitation energy level higher than or equal to that of the light-emitting material. In the case of using a blue phosphorescent material as the light-emitting material, it is necessary to develop a host material which has a triplet excitation energy level higher than or equal to that of the blue phosphorescent material and which is excellent in terms of a lifetime, but its development is particularly difficult. Here, even when a light-emitting layer is composed of quantum dots and made without a host material, the quantum dots enable emission efficiency to be ensured; thus, a light-emitting element which is favorable in terms of a lifetime can be obtained. In the case where the light-emitting layer is composed of quantum dots, the quantum dots preferably have core-shell structures (including core-multishell structures).

In the case of using quantum dots as the light-emitting material in the light-emitting layer, the thickness of the light-emitting layer is set to 3 nm to 100 nm, preferably 10 nm to 100 nm, and the light-emitting layer is made to contain 1 volume % to 100 volume % of the quantum dots. Note that it is preferable that the light-emitting layer be composed of the quantum dots. To form a light-emitting layer in which the quantum dots are dispersed as light-emitting materials in host materials, the quantum dots may be dispersed in the host materials, or the host materials and the quantum dots may be dissolved or dispersed in an appropriate liquid medium, and then a wet process (e.g., a spin coating method, a casting method, a die coating method, blade coating method, a roll coating method, an ink-jet method, a printing method, a spray coating method, a curtain coating method, or a Langmuir-Blodgett method) may be employed. For a light-emitting layer containing a phosphorescent light-emitting material, a vacuum evaporation method, as well as the wet process, can be suitably employed.

An example of the liquid medium used for the wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

### <<Hole-Injection Layer>>

The hole-injection layer has a function of reducing a barrier for hole injection from the anode or the charge-generation layer to promote hole injection and is formed using a transition metal oxide, a phthalocyanine derivative, or an aromatic amine, for example. As the transition metal oxide, molybdenum oxide, vanadium oxide, ruthenium oxide, tungsten oxide, manganese oxide, or the like can be given. As the phthalocyanine derivative, phthalocyanine, metal phthalocyanine, or the like can be given. As the aromatic amine, a benzidine derivative, a phenylenediamine derivative, or the like can be given. It is also possible to use a high molecular compound such as polythiophene or polyaniline; a typical example thereof is poly(ethylenedioxythiophene)/poly(styrenesulfonic acid), which is self-doped polythiophene.

As the hole-injection layer, a layer containing a composite material of a material having a function of transporting a hole (a hole-transport material) and a material having a property of accepting electrons (an acceptor property) from the hole-transport material can also be used. Alternatively, a stack of a layer containing a material having an electron accepting property (an acceptor property) and a layer containing a hole-transport material may also be used. In a steady state or in the presence of an electric field, electric charge can be transferred between these materials. As examples of the material having an electron-accepting property, organic acceptors such as a quinodimethane derivative, a chloranil derivative, and a hexaazatriphenylene derivative can be given. A specific example is a compound having an electron-withdrawing group (a halogen group or a cyano group), such as 7,7,8,8-tetracyano-2,3,5,6-tetrafluoroquinodimethane (abbreviation: F4-TCNQ), chloranil, or 2,3,6,7,10,11-hexacyano-1,4,5,8,9,12-hexaazatriphenylene (abbreviation: HAT-CN). Alternatively, a transition metal oxide such as an oxide of a metal from Group 4 to Group 8 can also be used. Specifically, vanadium oxide, niobium oxide, tantalum oxide, chromium oxide, molybdenum oxide, tungsten oxide, manganese oxide, rhenium oxide, titanium oxide, ruthenium oxide, zirconium oxide, hafnium oxide, silver oxide, or the like can be used. In particular, molybdenum oxide is preferable because it is stable in the air, has a low hygroscopic property, and is easily handled.

A material having a property of transporting more holes than electrons can be used as the hole-transport material, and a material having a hole mobility of 1×10⁻⁶ cm²/Vs or higher is preferable. Specifically, any of the aromatic amine, carbazole derivative, aromatic hydrocarbon, stilbene derivative, and the like described as examples of the hole-transport material that can be used in the light-emitting layer can be used. Furthermore, the hole-transport material may be a high molecular compound.

### <<Hole-Transport Layer>>

The hole-transport layer is a layer containing a hole-transport material and can be formed using any of the hole-transport materials given as examples of the material of the hole-injection layer. In order that the hole-transport layer has a function of transporting holes injected into the hole-injection layer to the light-emitting layer, the highest occupied molecular orbital (HOMO) level of the hole-transport layer is preferably equal or close to the HOMO level of the hole-injection layer.

As the hole-transport material, a substance having a hole mobility of 1×10⁻⁶ cm²/Vs or higher is preferably used. Note that any substance other than the above substances may be used as long as the hole-transport property is higher than the electron-transport property. The layer including a substance having a high hole-transport property is not limited to a single layer, and two or more layers containing the aforementioned substances may be stacked.

### <<Electron-Transport Layer>>

The electron-transport layer has a function of transporting, to the light-emitting layer, electrons injected from the cathode or the charge-generation layer through the electron-injection layer. A material having a property of transporting more electrons than holes can be used as the electron-transport material, and a material having an electron mobility of 1×10⁻⁶ cm²/Vs or higher is preferable. As the compound which easily accepts electrons (the material having an electron-transport property), a π-electron deficient heteroaromatic compound such as a nitrogen-containing heteroaromatic compound, or a metal complex can be used, for example. Specifically, a metal complex having a quinoline ligand, a benzoquinoline ligand, an oxazole ligand, or a thiazole ligand, which is described as the electron-transport material that can be used in the light-emitting layer, can be given. In addition, an oxadiazole derivative, a triazole derivative, a benzimidazole derivative, a quinoxaline derivative, a dibenzoquinoxaline derivative, a phenanthroline derivative, a pyridine derivative, a bipyridine derivative, a pyrimidine derivative, a triazine derivative, and the like can be given. A substance having an electron mobility of 1×10⁻⁶ cm²/Vs or higher is preferable. Note that other than these substances, any substance that has a property of transporting more electrons than holes may be used for the electron-transport layer. The electron-transport layer is not limited to a single layer, and may include stacked two or more layers containing the aforementioned substances.

Between the electron-transport layer and the light-emitting layer, a layer that controls transfer of electron carriers may be provided. The layer that controls transfer of electron carriers is a layer formed by addition of a small amount of a substance having a high electron-trapping property to a material having a high electron-transport property described above, and the layer is capable of adjusting carrier balance by suppressing transfer of electron carriers. Such a structure is very effective in preventing a problem (such as a reduction in element lifetime) caused when electrons pass through the light-emitting layer.

An n-type compound semiconductor may also be used, and an oxide such as titanium oxide, zinc oxide, silicon oxide, tin oxide, tungsten oxide, tantalum oxide, barium titanate, barium zirconate, zirconium oxide, hafnium oxide, aluminum oxide, yttrium oxide, or zirconium silicate; a nitride such as silicon nitride; cadmium sulfide; zinc selenide; or zinc sulfide can be used, for example.

### <<Electron-Injection Layer>>

The electron-injection layer has a function of reducing a barrier for electron injection from the cathode or the charge-generation layer to promote electron injection and can be formed using a Group 1 metal or a Group 2 metal, or an oxide, a halide, or a carbonate of any of the metals, for example. Alternatively, a composite material containing an electron-transport material (described above) and a material having a property of donating electrons to the electron-transport material can also be used. As the material having an electron-donating property, a Group 1 metal, a Group 2 metal, an oxide of any of the metals, or the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound like erbium fluoride (ErF₃) can be used. Electride may also be used for the electron-injection layer. Examples of the electride include a substance in which electrons are added at high concentration to calcium oxide-aluminum oxide. The electron-injection layer can be formed using the substance that can be used for the electron-transport layer.

A composite material in which an organic compound and an electron donor (donor) are mixed may also be used for the electron-injection layer. Such a composite material is excellent in an electron-injection property and an electron-transport property because electrons are generated in the organic compound by the electron donor. In this case, the organic compound is preferably a material that is excellent in transporting the generated electrons. Specifically, the aforementioned substances for forming the electron-transport layer (e.g., the metal complexes and heteroaromatic compounds) can be used, for example. As the electron donor, a substance showing an electron-donating property with respect to the organic compound may be used. Specifically, an alkali metal, an alkaline earth metal, and a rare earth metal are preferable, and lithium, sodium, cesium, magnesium, calcium, erbium, ytterbium, and the like are given. In addition, an alkali metal oxide or an alkaline earth metal oxide is preferable, and lithium oxide, calcium oxide, barium oxide, and the like are given. A Lewis base such as magnesium oxide can also be used. An organic compound such as tetrathiafulvalene (abbreviation: TTF) can also be used.

Note that the light-emitting layer, the hole-injection layer, the hole-transport layer, the electron-transport layer, and the electron-injection layer described above can each be formed by an evaporation method (including a vacuum evaporation method), an ink-jet method, a coating method, a gravure printing method, or the like. Besides the above materials, an inorganic compound or a high molecular compound (e.g., an oligomer, a dendrimer, and a polymer) may be used in the light-emitting layer, the hole-injection layer, the hole-transport layer, the electron-transport layer, and the electron-injection layer.

### <<Charge-Generation Layer>>

In the case where the charge-generation layer contains a composite material of an organic compound and an acceptor material, the composite material that can be used for the hole-injection layer may be used for the composite material. As the organic compound, a variety of compounds such as an aromatic amine compound, a carbazole compound, an aromatic hydrocarbon, and a high molecular compound (e.g., an oligomer, a dendrimer, and a polymer) can be used. A compound having a hole mobility of 1×10⁻⁶ cm²/Vs or higher is preferably used as the organic compound. Note that any other material may be used as long as it has a property of transporting more holes than electrons. Since the composite material of an organic compound and an acceptor material has excellent carrier-injection and carrier-transport properties, low-voltage driving or low-current driving can be achieved.

The charge-generation layer may have a stacked-layer structure of a layer containing the composite material of an organic compound and an acceptor material and a layer containing another material. For example, the charge-generation layer may be formed using a combination of a layer containing the composite material of an organic compound and an acceptor material with a layer containing one compound selected from among electron-donating materials and a compound having a high electron-transport property. Furthermore, the charge-generation layer may be formed using a combination of a layer containing the composite material of an organic compound and an acceptor material with a layer containing a transparent conductive film.

Note that in terms of light extraction efficiency, the charge-generation layer preferably has a visible light transmittance (specifically, a visible light transmittance of higher than or equal to 40%). The charge-generation layer functions even if it has lower conductivity than the pair of electrodes (the electrodes 551 and 552).

Note that forming the charge-generation layer by using any of the above materials can suppress an increase in drive voltage caused by the stack of the light-emitting layers.

### <<Pair of Electrodes>>

The electrodes 551 and 552 function as an anode and a cathode of each light-emitting element. The electrodes 551 and 552 can be formed using a metal, an alloy, or a conductive compound, a mixture or a stack thereof, or the like.

The electrode 552 includes the reflective film which is preferably formed using a conductive material having a function of reflecting light. Examples of the conductive material include aluminum (Al) and an alloy containing Al. Examples of the alloy containing Al include an alloy containing Al and L (L represents one or more of titanium (Ti), neodymium (Nd), nickel (Ni), and lanthanum (La)), such as an alloy containing Al and Ti and an alloy containing Al, Ni, and La. Aluminum has low resistance and high light reflectance. Aluminum is included in earth's crust in large amount and is inexpensive; therefore, it is possible to reduce costs for manufacturing a light-emitting element with aluminum. Alternatively, silver (Ag), an alloy of Ag and N (N represents one or more of yttrium (Y), Nd, magnesium (Mg), ytterbium (Yb), Al, Ti, gallium (Ga), zinc (Zn), indium (In), tungsten (W), manganese (Mn), tin (Sn), iron (Fe), Ni, copper (Cu), palladium (Pd), iridium (Ir), or gold (Au)) can be used. Examples of the alloy containing silver include an alloy containing silver, palladium, and copper, an alloy containing silver and copper, an alloy containing silver and magnesium, an alloy containing silver and nickel, an alloy containing silver and gold, and an alloy containing silver and ytterbium. Besides, a transition metal such as tungsten, chromium (Cr), molybdenum (Mo), copper, or titanium can be used.

Light emitted from the light-emitting layer is extracted through the electrode 551. Thus, the electrode 551 is preferably formed using a conductive material having a function of transmitting light. As the conductive material, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used.

The electrode 551 preferably includes a conductive film having a function of transmitting light and a reflective film having a function of reflecting light, and the conductive film and the reflective film are preferably formed using a conductive material having a function of transmitting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. For example, one or more kinds of conductive metals and alloys, and conductive compounds can be used. Specifically, a metal oxide such as a conductive metal oxide containing indium, zinc oxide, or zinc oxide containing gallium, for example, indium tin oxide (hereinafter referred to as ITO), indium tin oxide containing silicon or silicon oxide (ITSO), indium oxide-zinc oxide (indium zinc oxide), indium oxide-tin oxide containing titanium, indium titanium oxide, or indium oxide containing tungsten oxide and zinc oxide can be used. A metal thin film having a thickness that allows transmission of light (preferably, a thickness greater than or equal to 1 nm and less than or equal to 30 nm) can also be used. As the metal, for example, Ag, an alloy of Ag and Al, an alloy of Ag and Mg, an alloy of Ag and Au, or an alloy of Ag and Yb can be used.

Alternatively, the electrode 551 is preferably a stack of a reflective film having a function of reflecting light and a conductive film having a function of transmitting light. In that case, the electrode 551 can have a function of adjusting the optical path length so that desired light emitted from each light-emitting layer is resonated and intensified; thus, such a structure is preferable.

In this specification and the like, as the material transmitting light, a material that transmits visible light and has conductivity is used. Examples of the material include, in addition to the above-described oxide conductor typified by an ITO, an oxide semiconductor and an organic conductor containing an organic substance. Examples of the organic conductor containing an organic substance include a composite material in which an organic compound and an electron donor (donor material) are mixed and a composite material in which an organic compound and an electron acceptor (acceptor material) are mixed. Alternatively, an inorganic carbon-based material such as graphene may be used. The resistivity of the material is preferably lower than or equal to 1×10⁵ Ω·cm and further preferably lower than or equal to 1×10⁴ Ω·cm.

Alternatively, the electrode 551 and/or the electrode 552 may be formed by stacking two or more of these materials.

In the case where the electrode 551 or the electrode 552 functions as the cathode, the electrode preferably contains a material having a low work function (lower than or equal to 3.8 eV). The examples include an element belonging to Group 1 or 2 of the periodic table (e.g., an alkali metal such as lithium, sodium, or cesium, an alkaline earth metal such as calcium or strontium, or magnesium), an alloy containing any of these elements (e.g., Ag—Mg or Al—Li), a rare earth metal such as europium (Eu) or Yb, an alloy containing any of these rare earth metals, and an alloy containing aluminum and silver.

In the case where the electrode 551 or the electrode 552 is used as an anode, a material having a high work function (higher than or equal to 4.0 eV) is preferably used.

As the method for forming the electrodes 551 and 552, a sputtering method, an evaporation method, a printing method, a coating method, a molecular beam epitaxy (MBE) method, a chemical vapor deposition (CVD) method, a pulsed laser deposition method, an atomic layer deposition (ALD) method, or the like can be used as appropriate.

### <Components of Display Device>

Next, other components that form the display device of one embodiment of the present invention are described. In some cases, the components cannot be clearly distinguished from each other and one component also serves as another component or includes part of another component.

### <<Substrate>>

The substrates 570 and 370 can be formed using a material having heat resistance high enough to withstand heat treatment in the manufacturing process. Specifically, a 0.7- or 0.5-mm-thick non-alkali glass substrate can be used, for example.

For example, a large-sized glass substrate having any of the following sizes can be used as the substrates 570 and 370: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

An organic material, an inorganic material, a composite material of an organic material and an inorganic material, or the like can be used. For example, an inorganic material such as glass, ceramics, or a metal can be used. Specifically, non-alkali glass, soda-lime glass, potash glass, crystal glass, quartz, sapphire, or the like can be used. In addition, an inorganic oxide, an inorganic nitride, an inorganic oxynitride, or the like can be used. For example, silicon oxide, silicon nitride, silicon oxynitride, or aluminum oxide, can be used. A metal containing iron, aluminum, or the like can be used.

Moreover, a single crystal semiconductor substrate or a polycrystalline semiconductor substrate of silicon or silicon carbide, a compound semiconductor substrate of silicon germanium, an SOI substrate, or the like can be used. Thus, a semiconductor element can be formed over the substrate 570 or the like.

Alternatively, an organic material such as a resin, a resin film, or plastic can be used, for example. A flexible substrate may also be used. Specifically, a resin film or a resin plate of polyester, polyolefin, polyamide (nylon, aramid, or the like), polyimide, polycarbonate, polyurethane, an acrylic resin, an epoxy resin, or the like can be used. Alternatively, a material that includes a resin having a siloxane bond such as silicone can be used. Specifically, polyethylene terephthalate (PET), polyethylene naphthalate (PEN), polyethersulfone (PES), can be used. Paper, wood, or the like may be used.

A composite material, such as a resin film to which a metal plate, a thin glass plate, or an inorganic film is bonded can be used. For example, a composite material formed by dispersing a fibrous or particulate metal, glass, an inorganic material, or the like into a resin film can be used. For example, a composite material formed by dispersing a fibrous or particulate resin, organic material, or the like into an inorganic material can be used.

A single-layer material or a stacked-layer material in which a plurality of layers are stacked can be used. For example, a stacked-layer material in which a substrate, an insulating film that prevents diffusion of impurities contained in the substrate, and the like are stacked can be used. Specifically, a stacked-layer material in which glass and one or a plurality of films that prevent diffusion of impurities contained in the glass and that are selected from silicon oxide, silicon nitride, silicon oxynitride, and the like are stacked can be used. Alternatively, a stacked-layer material in which a resin and a film for preventing diffusion of impurities that penetrate the resin, such as silicon oxide, silicon nitride, or silicon oxynitride, are stacked can be used.

Note that a transistor, a capacitor, or the like can be directly formed on the substrate. Alternatively, a transistor, a capacitor, or the like can be formed over a substrate for use in manufacturing process that can withstand heat applied in the manufacturing process and can be transferred to the substrate 570 or the like. Thus, a transistor, a capacitor, or the like can be formed over a flexible substrate, for example.

Note that another substrate can be used as long as it can function as a support through manufacturing processes of the light-emitting element and the display element. Any material can be used as long as it has a function of protecting the light-emitting element and the display element.

Note that a light-transmitting material is preferably used for the substrate 370. Specifically, a 0.7- or 0.5-mm-thick non-alkali glass or a non-alkali glass polished to a thickness of approximately 0.1 mm to 0.2 mm can be used.

### <<Structure Body 335>>

An organic material, an inorganic material, or a composite material of an organic material and an inorganic material can be used for the structure body 335. Thus, components between which the structure body 335 is provided can have a predetermined space. Specifically, polyester, polyolefin, polyamide, polyimide, polycarbonate, polysiloxane, an acrylic resin, or the like, or a composite material of a plurality of kinds of resins selected from these can be used. Alternatively, a photosensitive material may be used.

### <<Sealant 305>>

For the sealant 305, an inorganic material, an organic material, a composite material of an inorganic material and an organic material, or the like can be used. An organic material such as a thermally fusible resin or a curable resin can be used. An organic material such as a reactive curable adhesive, a photo-curable adhesive, a thermosetting adhesive, and/or an anaerobic adhesive can be used. Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, or an ethylene vinyl acetate (EVA) resin, or the like can be used.

### <<Bonding Layer 505>>

For example, a material which can be used for the sealant 305 can be used for the bonding layer 505.

### <<Insulating Film>>

For example, an inorganic insulating material, an organic insulating material, or an insulating composite material containing an inorganic material and an organic material can be used for the insulating films 521, 528, 501C, 506, 516, 518, and 371. Specifically, an inorganic oxide film, an inorganic nitride film, an inorganic oxynitride film, a material obtained by stacking any of these films, or the like can be used. For example, a film containing silicon oxide, silicon nitride, silicon oxynitride, aluminum oxide, or aluminum nitride or a film including a material obtained by stacking any of these can be used. In addition, polyester, polyolefin, polyamide, polyimide, polycarbonate, polysiloxane, acrylic, or the like, or a stacked material or a composite material of a plurality of kinds of resins selected from these can be used. Alternatively, a photosensitive material may be used.

Note that a silicon oxynitride film refers to a film in which the proportion of oxygen is higher than that of nitrogen. The silicon oxynitride film preferably contains oxygen, nitrogen, silicon, and hydrogen in the ranges of 55 atomic % to 65 atomic %, 1 atomic % to 20 atomic %, 25 atomic % to 35 atomic %, and 0.1 atomic % to 10 atomic %, respectively. A silicon nitride oxide film refers to a film in which the proportion of nitrogen is higher than that of oxygen. The silicon nitride oxide film preferably contains nitrogen, oxygen, silicon, and hydrogen in the ranges of 55 atomic % to 65 atomic %, 1 atomic % to 20 atomic %, 25 atomic % to 35 atomic %, and 0.1 atomic % to 10 atomic %, respectively.

The insulating film 521 is preferably formed so that steps due to components overlapping with the insulating film 521 can be covered to form a flat surface. Therefore, an organic insulating material is preferably used for the insulating film 521.

It is preferable that the insulating film 528 have a function of preventing a short circuit between the electrodes 551 and 552. Thus, an organic insulating material is preferably used for the insulating film 528; for example, a 1-μm-thick film containing polyimide is preferably used.

A material containing silicon and oxygen is preferably used for the insulating film 501C. Thus, impurity diffusion into the transistor included in the pixel circuit or the second display element 550 can be suppressed. For example, a 200-nm-thick film containing silicon, oxygen, and nitrogen can be used as the insulating film 501C.

Polyimide, an epoxy resin, an acrylic resin, or the like is preferably used for the insulating film 371.

### <<Intermediate Film>>

For example, a material having a function of allowing hydrogen passage or supplying hydrogen can be used for the intermediate film 354. A conductive material can be used for the intermediate film 354. A light-transmitting material can be used for the intermediate film 354.

The intermediate film 354 preferably contains an oxide conductor or an oxide semiconductor. Specifically, a material containing indium and oxygen, a material containing indium, gallium, zinc, and oxygen, a material containing indium, tin, and oxygen, or the like can be used for the intermediate film 354. Note that these materials have a function of allowing hydrogen passage.

For example, the thickness of the intermediate film 354 is preferably greater than or equal to 10 nm and less than or equal to 500 nm and further preferably greater than or equal to nm and less than or equal to 100 nm. Specifically, a 50- or 100-nm-thick film containing indium, gallium, zinc, and oxygen can be used.

Note that a material obtained by stacking films functioning as an etching stopper can be used as the intermediate film 354. Alternatively, a film functioning as an etching stopper can be stacked over the intermediate film 354. Specifically, a material obtained by stacking a 50-nm-thick film containing indium, gallium, zinc, and oxygen and a 20-nm-thick film containing indium, tin, and oxygen, in this order, can be used for the intermediate film 354. Alternatively, a 50-nm-thick film containing indium, gallium, zinc, and oxygen may be used as the intermediate film 354 and a 20-nm-thick film containing indium, tin, and oxygen may be stacked over the intermediate film 354.

### <<Wiring, Terminal, and Conductive Film>>

A conductive material can be used for a wiring, a terminal, a conductive film, and the like. Specifically, the conductive material can be used for the signal line SL1(j), the signal line SL2(j), the scan line GL1(i), the scan line GL2(i), a wiring CSCOM, a wiring ANO, the terminal 519B, the terminal 519C, the first conductive film, the second conductive film, the conductive film 511B, the conductive film 511C, the conductive film 512B, or the like.

For example, an inorganic conductive material, an organic conductive material, a metal material, a conductive ceramic material, or the like can be used. Specifically, a metal element selected from aluminum, gold, platinum, silver, copper, chromium, tantalum, titanium, molybdenum, tungsten, nickel, iron, cobalt, palladium, and manganese, or the like can be used. Alternatively, an alloy containing any of the above-described metal elements, or the like can be used. In particular, an alloy of copper and manganese is suitably used in microfabrication with the use of a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, or the like can be used.

Alternatively, a conductive oxide such as indium oxide, indium tin oxide, indium zinc oxide, zinc oxide, or zinc oxide to which gallium is added can be used.

Alternatively, a film containing graphene or graphite can be used. For example, a film containing graphene oxide is formed and is reduced, so that a film containing graphene can be formed. As a method for reducing graphene oxide, a method using heat, a method using a reducing agent, or the like can be employed. Further alternatively, a conductive high molecule may be used.

The first conductive film can be used for the electrode 351, the wiring, or the like.

The wiring, the conductive film 512B of the transistor that can be used as the switch 581, or the like can be used for the second conductive film.

### <<Electrode 351>>

The material used for the electrode 551 is preferably used for the electrode 351. For example, a material used for the wiring or the like can be used. Specifically, the reflective film included in the electrode 351 preferably contains the same metal as the reflective film included in the electrode 551.

### <<Reflective Film>>

For example, a material reflecting visible light can be used for the reflective film 351B. Specifically, a material containing silver is preferably used for the reflective film 351B. For example, a material containing silver and palladium or a material containing silver and copper can be used for the reflective film 351B.

The reflective film 351B reflects light which passes through the liquid crystal layer 353. This allows the first display element 350 to serve as a reflective liquid crystal element. Alternatively, a material with an uneven surface can be used for the reflective film 351B. In that case, incident light can be reflected in various directions so that a white image can be displayed.

Note that other structures may be used as the electrode 351 without limitation to the reflective film 351B. For example, a structure in which the reflective film 351B is provided between the liquid crystal layer 353 and the electrode 351, or a structure in which the electrode 351 having a light-transmitting property is provided between the reflective film 351B and the liquid crystal layer 353 can be used.

### <<Electrode 352>>

A material having a visible-light transmitting property and conductivity can be used for the electrode 352. For example, a conductive oxide, a metal film thin enough to transmit light, or a metal nanowire can be used as the electrode 352. Specifically, a conductive oxide containing indium, a metal thin film whose thickness is greater than or equal to 1 nm and less than or equal to 10 nm, or a metal nanowire containing silver can be used for the electrode 352.

Specifically, indium oxide, indium tin oxide, indium zinc oxide, zinc oxide, zinc oxide to which gallium is added, zinc oxide to which aluminum is added, or the like can be used.

### <<Pixel Circuit 302>>

The pixel circuit 302(i,j) is electrically connected to the signal line SL1(j), the signal line SL2(j), the scan line GL1(i), the scan line GL2(i), the wiring CSCOM, and the wiring ANO (see FIG. 3).

The pixel circuit 302(i,j+1) is electrically connected to the signal line SL1(j+1), the signal line SL2(j+1), the scan line GL1(i), a scan line GB2(i), the wiring CSCOM, and the wiring ANO.

In the case where a voltage of a signal supplied to the signal line SL2(j) is different from a voltage of a signal supplied to the signal line SL1(j+1), the signal line SL1(j+1) is positioned apart from the signal line SL2(j). Specifically, the signal line SL2(j+1) is positioned adjacent to the signal line SL2(j).

The pixel circuit 302 includes the switch 581, a capacitor C1, a switch 582, the transistor 585, and a capacitor C2.

For example, a transistor including a gate electrode electrically connected to the scan line GL1(i) and a first electrode electrically connected to the signal line SL1(j) can be used as the switch 581.

The capacitor C1 includes a first electrode electrically connected to a second electrode of the transistor that is used as the switch 581 and a second electrode electrically connected to the wiring CSCOM.

For example, a transistor including a gate electrode electrically connected to the scan line GL2(i) and a first electrode electrically connected to the signal line SL2(j) can be used as the switch 582.

The transistor 585 includes a gate electrode electrically connected to a second electrode of the transistor that is used as the switch 582 and a first electrode electrically connected to the wiring ANO.

Note that a transistor including a conductive film provided such that a semiconductor film is provided between a gate electrode and the conductive film can be used as the transistor 585. For example, a conductive film electrically connected to the wiring supplying the same potential as that supplied to the first electrode of the transistor 585 can be used as the conductive film.

The capacitor C2 includes a first electrode electrically connected to the second electrode of the transistor that is used as the switch 582 and a second electrode electrically connected to the first electrode of the transistor 585.

Note that the first electrode and the second electrode of the first display element 350 are electrically connected to the second electrode of the transistor that is used as the switch 581 and the wiring VCOM1, respectively. With such a structure, the first display element 350 can be driven.

The first electrode and the second electrode of the second display element 550 are electrically connected to a second electrode of the transistor 585 and the wiring VCOM2, respectively. With such a structure, the second display element 550 can be driven.

### <<Switch 581, Switch 582, Transistor 585, and Transistor 586>>

For example, a bottom-gate transistor, a top-gate transistor, or the like can be used as the switch 581, the switch 582, the transistor 585, the transistor 586, or the like.

For example, a semiconductor containing an element belonging to Group 14 can be used for a semiconductor film of the transistor. Specifically, a semiconductor containing silicon can be used for the semiconductor film of the transistor. For example, single crystal silicon, polysilicon, microcrystalline silicon, or amorphous silicon can be used for the semiconductor film of the transistor.

For example, a transistor whose semiconductor film includes an oxide semiconductor can be used for the switch 581, the switch 582, the transistor 585, the transistor 586, or the like. Specifically, an oxide semiconductor containing indium or an oxide semiconductor containing indium, gallium, and zinc can be used for a semiconductor film.

For example, a transistor having a lower leakage current in an off state than a transistor that uses amorphous silicon for a semiconductor film can be used for the switch 581, the switch 582, the transistor 585, the transistor 586, or the like. Specifically, a transistor using an oxide semiconductor for the semiconductor film 508 can be used as the switch 581, the switch 582, the transistor 585, the transistor 586, or the like.

Thus, a pixel circuit can hold an image signal for a longer time than a pixel circuit including a transistor using amorphous silicon for a semiconductor film. Specifically, a selection signal can be supplied at a frequency of lower than 30 Hz, preferably lower than 1 Hz, and further preferably less than once per minute, while flickering is suppressed. Consequently, eyestrain on a user of a data processing device can be reduced, and power consumption for driving can be reduced.

An oxide semiconductor containing indium can be used for the semiconductor film 508 having a region functioning as a channel of the transistor. For example, a 25-nm-thick film containing indium, gallium, and zinc can be used.

The material used for the wiring or the like can be used for the conductive film 504 having a region functioning as a gate electrode of the transistor. For example, a conductive film formed by stacking a 10-nm-thick film containing tantalum and nitrogen and a 300-nm-thick film containing copper, in this order, can be used.

The insulating film used for the insulating film 501C can be used as the insulating film 506 having a region functioning as a gate insulating film of the transistor. For example, a material obtained by stacking a 400-nm-thick film containing silicon and nitrogen and a 200-nm-thick film containing silicon, oxygen, and nitrogen, in this order, can be used.

The material of the wiring or the like can be used for the conductive film 512A or 512B having a region functioning as a source electrode or a drain electrode of the transistor. For example, a conductive film formed by stacking a 50-nm-thick film containing tungsten, a 400-nm-thick film containing aluminum, and a 100-nm-thick film containing titanium, in this order, can be used.

### <<Opening 351H>>

If the ratio of the total area of the opening 351H to the total area of the reflective film 351B included in the first display element 350 other than the opening is too large, display performed using the first display element 350 is dark. In contrast, if the ratio of the total area of the opening 351H to the total area other than the opening is too small, display performed using the second display element 550 is dark. If the area of the opening 351H in the reflective film 351B is too small, light emitted from the second display element 550 is not efficiently extracted. Thus, the ratio of the area of the opening 351H to the pixel circuit 302 is preferably 1% to 10%.

In the case where a light-emitting element having an emission area larger than the area of the opening 351H (e.g., an LED) is used as the second display element 550, the area of the opening 351H might be reduced, in which case the intensity of light emitted from the second display element 550 is also lowered. In other words, the intensity of light emitted from the second display element 550 is proportional to the area of the opening 351H. Thus, higher power is consumed in the second display element 550 in order to maintain the intensity of light emitted from the second display element 550 when the area of the opening 351H is reduced.

However, in one embodiment of the present invention, a current-driving-type light-emitting element, such as an organic EL element or an inorganic EL element, is used as the second display element 550 so that the area of the opening 351H can be almost equal to the area of an emission part of the second display element 550. As a result, the intensity of light emitted from the second display element 550 can be maintained with little change in power consumption in the second display element 550 even if the area of the opening 351H is reduced.

The opening 351H can have a polygonal shape (e.g., a quadrangular shape or a cross-like shape), an elliptical shape, a circular shape, or the like. The opening 351H may have a stripe shape, a slit-like shape, or a checkered pattern. The opening 351H may be moved to the side of an adjacent pixel. Preferably, the opening 351H is provided to the side of another pixel having a function of emitting light of the same color. With this structure, a phenomenon in which light emitted from the second display element 550 enters a coloring film of the adjacent pixel (i.e., cross talk) can be suppressed.

### <<Alignment Films 331 and 332>>

An organic material can be used for the alignment films 331 and 332. For example, a material containing polyimide or the like can be used. Specifically, a material formed to have alignment in the predetermined direction by rubbing treatment or an optical alignment technique can be used.

For example, a film containing soluble polyimide can be used as the alignment film 331 or 332.

### <<Coloring Layer>>

A material that transmits light of a predetermined color can be used for the coloring layers 375 and 575. Thus, the coloring layers 375 and 575 can be used as, for example, a color filter.

For example, the coloring layers 375 and 575 can be formed using a material transmitting light of blue, green, red, yellow, or white.

### <<Light-Blocking Film 373>>

A material that prevents light transmission can be used for the light-blocking film 373. Thus, the light-blocking film 373 can be used as, for example, a black matrix.

### <<Functional Film>>

For example, a polarizing plate, a retardation plate, a diffusing film, an anti-reflective film, a condensing film, or the like can be used as the functional films 370D and 370P. Alternatively, a polarizing plate containing a dichromatic pigment can be used.

Alternatively, an antistatic film preventing the attachment of a foreign substance, a water repellent film suppressing the attachment of stain, a hard coat film suppressing generation of a scratch in use, or the like can be used as the functional films 370D and 370P.

### <<Driver Circuit GD>>

Any of a variety of sequential circuits, such as a shift register, can be used as the driver circuit GD. For example, the transistor 586, a capacitor, and the like can be used in the driver circuit GD. Specifically, a transistor that can be formed in the same process as the transistor 585 can be used.

A transistor whose structure is different from the transistor that can be used as the switch 581 can be used as the transistor 586. Specifically, a transistor including the conductive film 524 can be used as the transistor 586 (see FIG. 2B).

The conductive film 524 is provided such that the semiconductor film 508 is interposed between the conductive film 504 and the conductive film 524. The insulating film 516 is provided between the conductive film 524 and the semiconductor film 508. The insulating film 506 is provided between the semiconductor film 508 and the conductive film 504. For example, the conductive film 524 is electrically connected to a wiring supplying the same potential as that supplied to the conductive film 504.

Note that a transistor having the same structure as the transistor 585 can be used as the transistor 586.

For example, an integrated circuit may be used in the driver circuit GD. Specifically, an integrated circuit formed on a silicon substrate can be used as the driver circuit GD.

### <<Driver Circuit SD>>

For example, an integrated circuit can be used in the driver circuit SD. Specifically, an integrated circuit formed on a silicon substrate can be used as the driver circuit SD.

For example, a chip on glass (COG) method can be used to mount the driver circuit SD on a pad electrically connected to the pixel circuit 302. Specifically, an anisotropic conductive film can be used to mount the integrated circuit on the pad.

Note that the pad can be formed through the same process as the terminal 519B or 519C.

### <Structure Example 2 of Display Device>

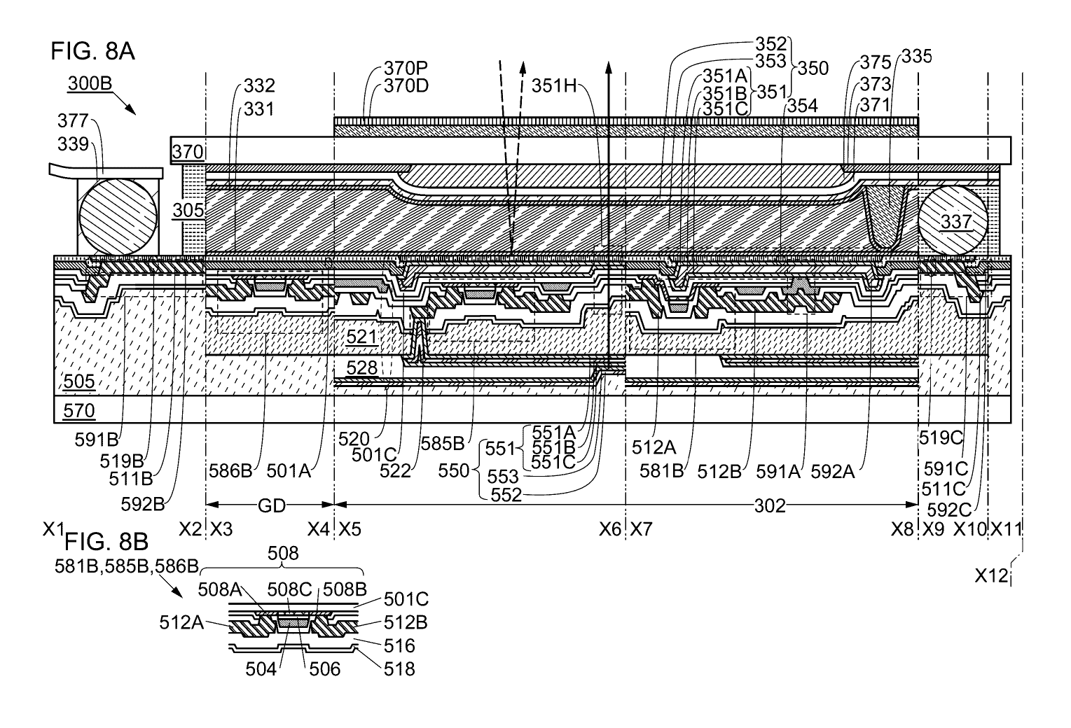

FIGS. 8A and 8B are cross-sectional views illustrating the structure of a display device 300B of one embodiment of the present invention. FIG. 8A is a cross-sectional view taken along dashed-dotted lines X1-X2, X3-X4, X5-X6, X7-X8, X9-X10, and X11-X12 in FIG. 1A. FIG. 8B is a cross-sectional view illustrating part of the display device 300B.

The display device 300B is different from the display device 300 in FIGS. 2A to 2C in that it includes a top-gate transistor instead of a bottom-gate transistor. Here, the description of FIGS. 2A to 2C is referred to for the other similar structures, and different structures will be described in detail.

### <<Switch 581B, Transistor 585B, and Transistor 586B>>

The transistor 586B includes the conductive film 504 having a region overlapping with the insulating film 501C and the semiconductor film 508 having a region located between the insulating film 501C and the conductive film 504. Note that the conductive film 504 functions as a gate electrode (see FIG. 8B).

The semiconductor film 508 includes a first region 508A, a second region 508B, and a third region 508C. The first region 508A and the second region 508B do not overlap with the conductive film 504. The third region 508C is located between the first region 508A and the second region 508B and overlaps with the conductive film 504.

The transistor 586B includes the insulating film 506 between the third region 508C and the conductive film 504. Note that the insulating film 506 functions as a gate insulating film.

The first region 508A and the second region 508B have a lower resistivity than the third region 508C, and function as a source region and a drain region.

Note that, for example, a method for controlling the resistivity of the oxide semiconductor that is described later can be used in forming the first region 508A and the second region 508B in the semiconductor film 508. Specifically, plasma treatment using a gas containing a rare gas can be employed.

For example, the conductive film 504 can be used as a mask. The use of the conductive film 504 as a mask allows the shape of part of the third region 508C to be self-aligned with the shape of an end of the conductive film 504.

The transistor 586B includes the conductive film 512A and the conductive film 512B which are in contact with the first region 508A and the second region 508B, respectively. The conductive film 512A and the conductive film 512B function as a source electrode and a drain electrode.

A transistor that can be formed in the same process as the transistor 586B can be used as a transistor 585B and a transistor of a switch 581B.

The structures of the electrodes 351 and 551 included in the display device 300B can be similar to those of the electrode 351 and 551 included in the display device 300.

That is, it is preferable that the electrode 351 include the reflective film 351B and that the reflective film 351B have a region interposed between the conductive films 351A and 351C. In addition, it is preferable that the electrode 551 include the reflective film 551B and that the reflective film 551B have a region interposed between the conductive films 551A and 551C.

With this structure, manufacturing cost of the display device can be reduced. Moreover, the power consumption of the display device can be reduced.

With the microcavity structure of the second display element 550, power consumption of the display device can be reduced. In addition, light emission with high color purity can be obtained; therefore, the color reproducibility of the display device can be improved.

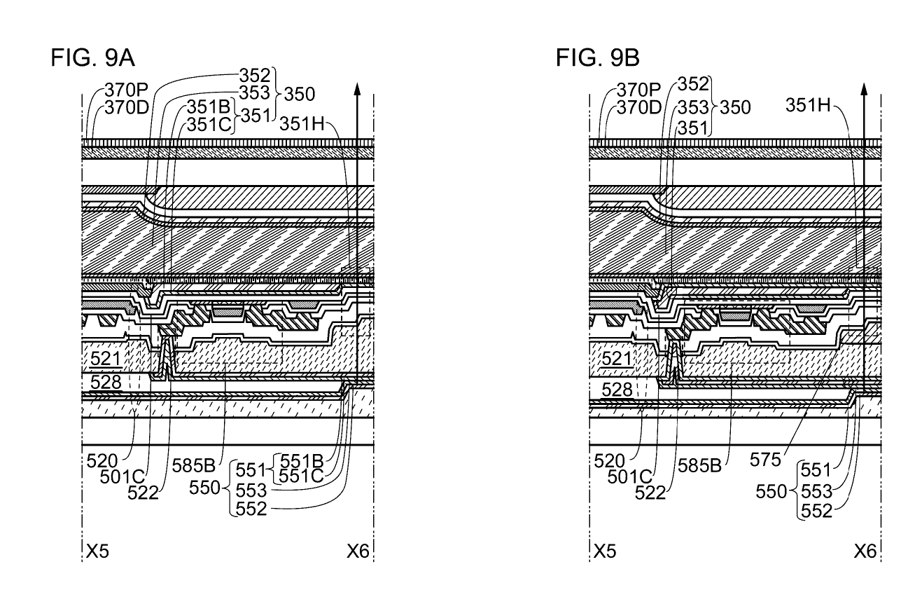

Note that as illustrated in FIG. 9A, the electrode 551 may include either the conductive film 551A or 551C. In addition, the electrode 351 may include either the conductive film 351A or 351C.

Note that as illustrated in FIG. 9B, in the display device 300B, the coloring layer 575 may be provided in a region interposed between the first display element 350 and the second display element 550 and overlapping with the opening 351H. The coloring layer 575 has a region overlapping with the second display element 550, and light emitted from the second display element 550 is emitted to the outside through the coloring layer 575 and the coloring layer 375. Therefore, with the coloring layer 575, the color purity of light emitted from the second display element 550 can be improved.

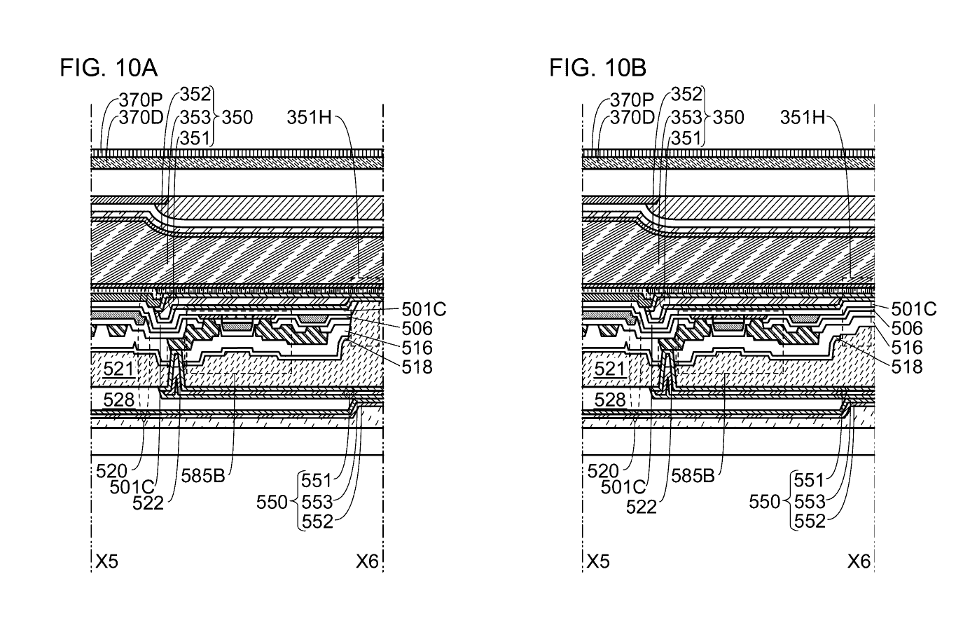

In the display device 300B, the number of insulating films having a region overlapping with the opening 351H may be smaller than the number of insulating films having a region overlapping with the semiconductor film 508. For example, as illustrated in FIG. 10A, the opening 351H does not necessarily have a region overlapping with the insulating films 501C, 506, 516, and 518. In addition, for example, as illustrated in FIG. 10B, the opening 351H does not necessarily have a region overlapping with the insulating film 518.

### <Method for Controlling Resistivity of Oxide Semiconductor Film>

The method for controlling the resistivity of an oxide semiconductor film will be described.

An oxide semiconductor film with a predetermined resistivity can be used for the semiconductor film 508 or the conductive film 524.

For example, a method for controlling the concentration of impurities such as hydrogen and water contained in the oxide semiconductor film and/or the oxygen vacancies in the film can be used as the method for controlling the resistivity of the oxide semiconductor film.

Specifically, plasma treatment can be used as a method for increasing or decreasing the concentration of impurities such as hydrogen and water and/or the oxygen vacancies in the film.

Plasma treatment using a gas containing one or more kinds selected from a rare gas (He, Ne, Ar, Kr, or Xe), hydrogen, boron, phosphorus, and nitrogen can be employed. For example, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, or plasma treatment in a nitrogen atmosphere can be employed. Thus, the oxide semiconductor film can have a high carrier density and a low resistivity.

Alternatively, hydrogen, boron, phosphorus, or nitrogen is added to the oxide semiconductor film by an ion implantation method, an ion doping method, a plasma immersion ion implantation method, or the like, so that the oxide semiconductor film can have a low resistivity.

Alternatively, an insulating film containing hydrogen is formed in contact with the oxide semiconductor film, and the hydrogen is diffused from the insulating film to the oxide semiconductor film, so that the oxide semiconductor film can have a high carrier density and a low resistivity.

For example, an insulating film with a hydrogen concentration greater than or equal to 1×10²² atoms/cm³ is formed in contact with the oxide semiconductor film, whereby hydrogen can be effectively supplied to the oxide semiconductor film. Specifically, a silicon nitride film can be used as the insulating film formed in contact with the oxide semiconductor film.

Hydrogen contained in the oxide semiconductor film reacts with oxygen bonded to a metal atom to be water, and an oxygen vacancy is formed in a lattice from which oxygen is released (or a portion from which oxygen is released). Due to entry of hydrogen into the oxygen vacancy, an electron serving as a carrier is generated in some cases. Furthermore, bonding of part of hydrogen to oxygen bonded to a metal atom causes generation of an electron serving as a carrier in some cases. Thus, the oxide semiconductor film can have a high carrier density and a low resistivity.

Specifically, an oxide semiconductor film with a hydrogen concentration measured by secondary ion mass spectrometry (SIMS) greater than or equal to 8×10¹⁹ atoms/cm³, preferably greater than or equal to 1×10²⁰ atoms/cm³ and further preferably greater than or equal to 5×10²⁰ atoms/cm³, can be suitably used as the conductive film 524.

On the other hand, an oxide semiconductor film with a high resistivity can be used as a semiconductor film where a channel of a transistor is formed. Specifically, the oxide semiconductor film can be suitably used as the semiconductor film 508.

For example, an insulating film containing oxygen, in other words, an insulating film capable of releasing oxygen, is formed in contact with an oxide semiconductor film, and the oxygen is supplied from the insulating film to the oxide semiconductor film, so that oxygen vacancies in the film or at the interface can be filled. Thus, the oxide semiconductor film can have a high resistivity.

For example, silicon oxide or silicon oxynitride can be used for the insulating film capable of releasing oxygen.

The oxide semiconductor film in which oxygen vacancy is filled with oxygen and the concentration of hydrogen is reduced can be referred to as a highly purified intrinsic or substantially highly purified intrinsic oxide semiconductor film. The term “substantially intrinsic” refers to a state where an oxide semiconductor film has a carrier density lower than 8×10¹¹ cm⁻³, preferably lower than 1×10¹¹ cm⁻³ and further preferably lower than 1×10¹⁰ cm⁻³. A highly purified intrinsic or substantially highly purified intrinsic oxide semiconductor film has few carrier generation sources, and thus can have a low carrier density. The highly purified intrinsic or substantially highly purified intrinsic oxide semiconductor film has a low density of defect states and accordingly can have a low density of trap states.

Furthermore, a transistor including the highly purified intrinsic or substantially highly purified intrinsic oxide semiconductor film has an extremely low off-state current; even when an element has a channel width of 1×10⁶ μm and a channel length L of 10 μm, the off-state current can be lower than or equal to the measurement limit of a semiconductor parameter analyzer, that is, lower than or equal to 1×10⁻¹³ A, at a voltage (drain voltage) between a source electrode and a drain electrode of from 1 V to 10 V.

The transistor in which a channel region is formed in the oxide semiconductor film that is a highly purified intrinsic or substantially highly purified intrinsic oxide semiconductor film can have a small change in electrical characteristics and high reliability.

Specifically, an oxide semiconductor having a hydrogen concentration which is measured by secondary ion mass spectrometry (SIMS) lower than or equal to 2×10²⁰ atoms/cm³, preferably lower than or equal to 5×10¹⁹ atoms/cm³, further preferably lower than or equal to 1×10¹⁹ atoms/cm³, further preferably lower than 5×10¹⁸ atoms/cm³, further preferably lower than or equal to 1×10¹⁸ atoms/cm³, further preferably lower than or equal to 5×10¹⁷ atoms/cm³, and still further preferably lower than or equal to 1×10¹⁶ atoms/cm³, can be favorably used for a semiconductor where a channel of a transistor is formed.

An oxide semiconductor film that has a higher hydrogen concentration and/or a larger number of oxygen vacancies and that has a lower resistivity than the semiconductor film 508 is used as the conductive film 524.

A film whose hydrogen concentration is twice or more, preferably ten times or more, the hydrogen concentration in the semiconductor film 508 can be used as the conductive film 524.

A film whose resistivity is greater than or equal to 1×10⁻⁸ times and less than 1×10⁻¹ times the resistivity of the semiconductor film 508 can be used as the conductive film 524.

Specifically, a film with a resistivity greater than or equal to 1×10⁻³ Ω·cm and less than 1×10⁴ Ω·cm, preferably greater than or equal to 1×10⁻³ Ω·cm and less than 1×10⁻¹ Ω·cm, can be used as the conductive film 524.

### <Structure Example 3 of Display Device>

A touch panel may be provided in the display device 300 illustrated in FIGS. 2A to 2C. As the touch panel, a capacitive touch panel (a surface capacitive touch panel or a projected capacitive touch panel) can be preferably used.

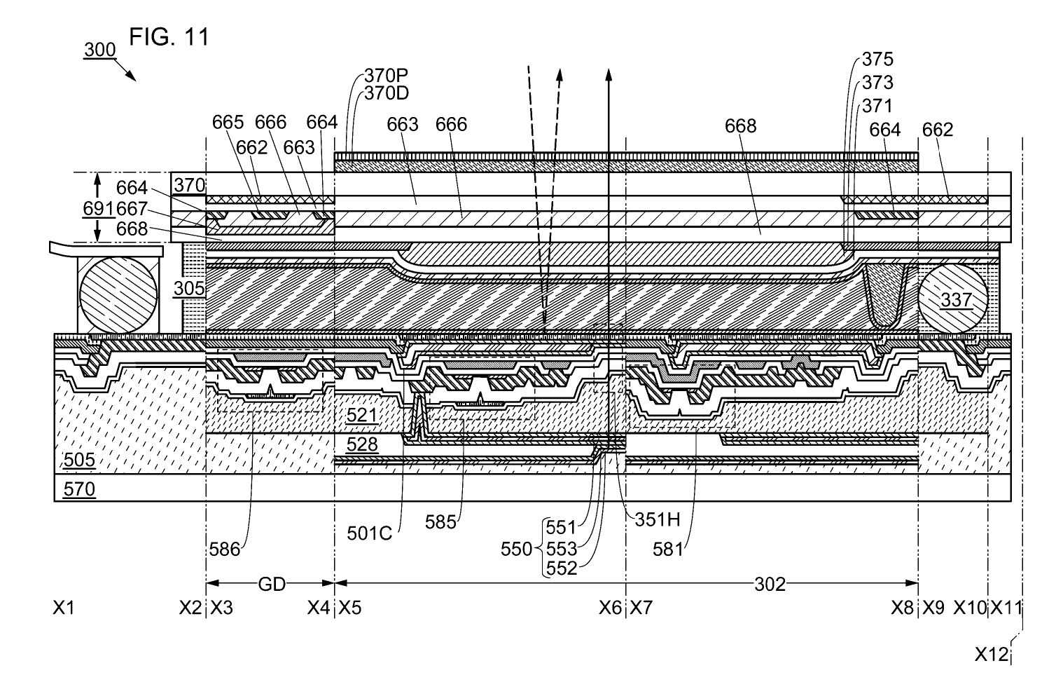

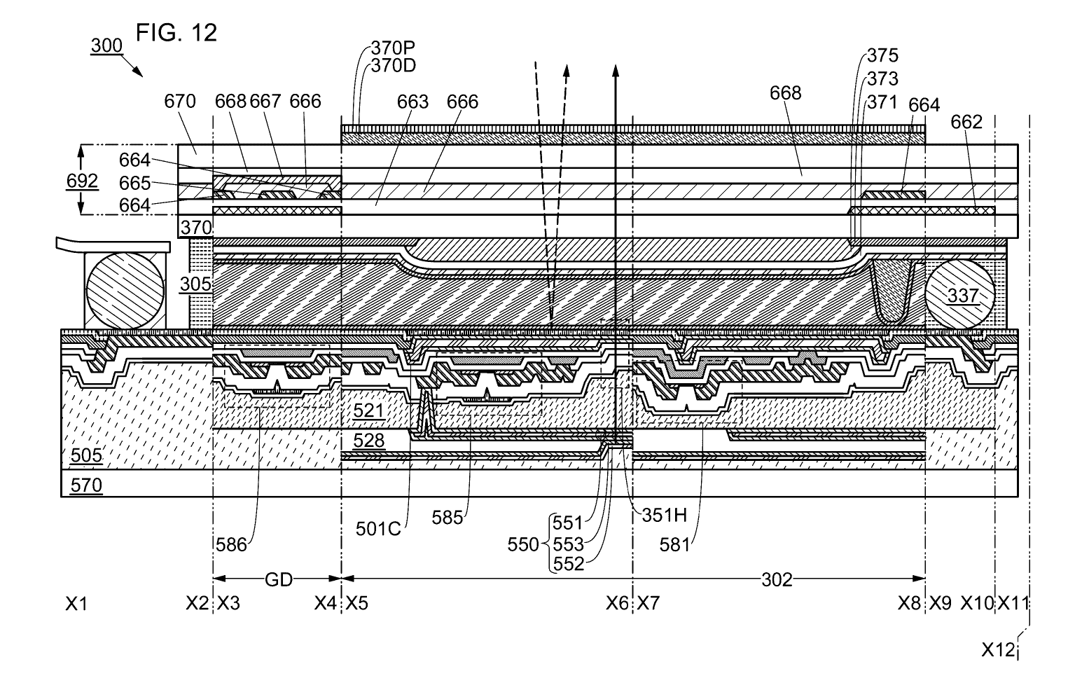

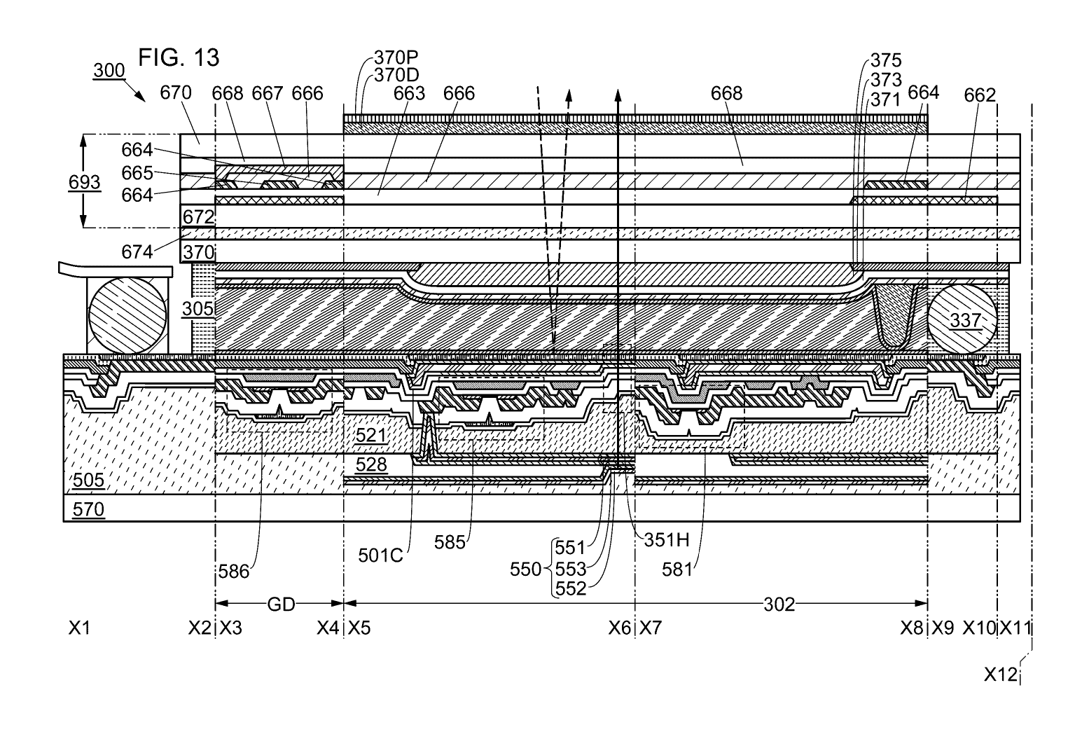

A structure in which a touch panel is provided in the display device 300 is described with reference to FIG. 11, FIG. 12, and FIG. 13.

FIG. 11 is a cross-sectional view of a structure in which a touch panel 691 is provided in the display device 300. FIG. 12 is a cross-sectional view of a structure in which a touch panel 692 is provided in the display device 300. FIG. 13 is a cross-sectional view of a structure in which a touch panel 693 is provided in the display device 300.

The touch panel 691 illustrated in FIG. 11 is a so-called in-cell touch panel which is provided between the substrate 370 and the coloring layer 375. The touch panel 691 is formed over the substrate 370 before the light-blocking film 373 and the coloring layer 375 are formed.

The touch panel 691 includes a light-blocking film 662, an insulating film 663, a conductive film 664, a conductive film 665, an insulating film 666, a conductive film 667, and an insulating film 668. The mutual capacitance of the conductive films 664 and 665 is changed when an object such as a finger or a stylus approaches, for example. Thus, the touch panel 691 can detect the object by sensing the amount of change.

An intersection portion of the conductive films 664 and 665 is shown above the transistor 586 illustrated in FIG. 11. The conductive film 667 is electrically connected to the two conductive films 664 between which the conductive film 665 is interposed through openings provided in the insulating film 666. Although a region in which the conductive film 667 is provided is located in a region corresponding to the driver circuit GD in FIG. 11, it is not limited thereto, and the region in which the conductive film 667 is provided may be provided in a region in which the pixel circuit 302 is provided, for example.

The conductive films 664 and 665 are provided in a region overlapping with the light-blocking film 662. As illustrated in FIG. 11, it is preferable that the conductive film 664 do not overlap with the second display element 550. In other words, the conductive film 664 has openings in regions overlapping with the second display element 550. That is, the conductive film 664 has a mesh shape. With this structure, the conductive film 664 does not block light emitted from the second display element 550. Therefore, since luminance is hardly reduced even when the touch panel 691 is provided, a display device with high visibility and low power consumption can be obtained. Note that the conductive film 665 can have a structure similar to that of the conductive film 664.

Since the conductive films 664 and 665 do not overlap with the second display element 550, a metal material whose transmittance of visible light is low can be used for the conductive films 664 and 665. Therefore, as compared to the case of using an oxide material whose transmittance of visible light is high, resistance of the conductive films 664 and 665 can be reduced, whereby sensitivity of the sensor of the touch panel can be increased.

Note that a material that can be used for the light-blocking film 373 can be used for the light-blocking film 662. For the insulating films 663, 666, and 668, a material that can be used for the insulating films 521, 528, 501C, and 371 can be used. For the conductive films 664, 665, and 667, a material that can be used for the first conductive film, the second conductive film, the conductive films 511B, 511C, and 512B can be used.

Conductive nanowires may be used for the conductive films 664, 665, and 667. The nanowires may have a mean diameter greater than or equal to 1 nm and less than or equal to 100 nm, preferably greater than or equal to 5 nm and less than or equal to 50 nm and further preferably greater than or equal to 5 nm and less than or equal to 25 nm. As the nanowire, a carbon nanotube or a metal nanowire such as an Ag nanowire, a Cu nanowire, or an Al nanowire may be used. For example, in the case of using an Ag nanowire for one or all of the conductive films 664, 665, and 667, a visible light transmittance of 89% or higher and a sheet resistance of Ω/square or more and 100 Ω/square or less can be achieved.

The touch panel 692 illustrated in FIG. 12 is a so-called on-cell touch panel which is provided above the substrate 370. The touch panel 692 is formed over a substrate 670, which is different from the touch panel 691. Other structures of the touch panel 692 are similar to the touch panel 691.

The touch panel 693 illustrated in FIG. 13 is provided over a substrate 672 and is bonded to the substrate 370 with an adhesive agent 674. The touch panel 693 is a so-called out-cell touch panel (also referred to as an externally attached touch panel). Other structures of the touch panel 693 are similar to the touch panel 691. In this manner, the display device of one embodiment of the present invention can be combined with various types of touch panels.

### <Structure Example 4 of Display Device>

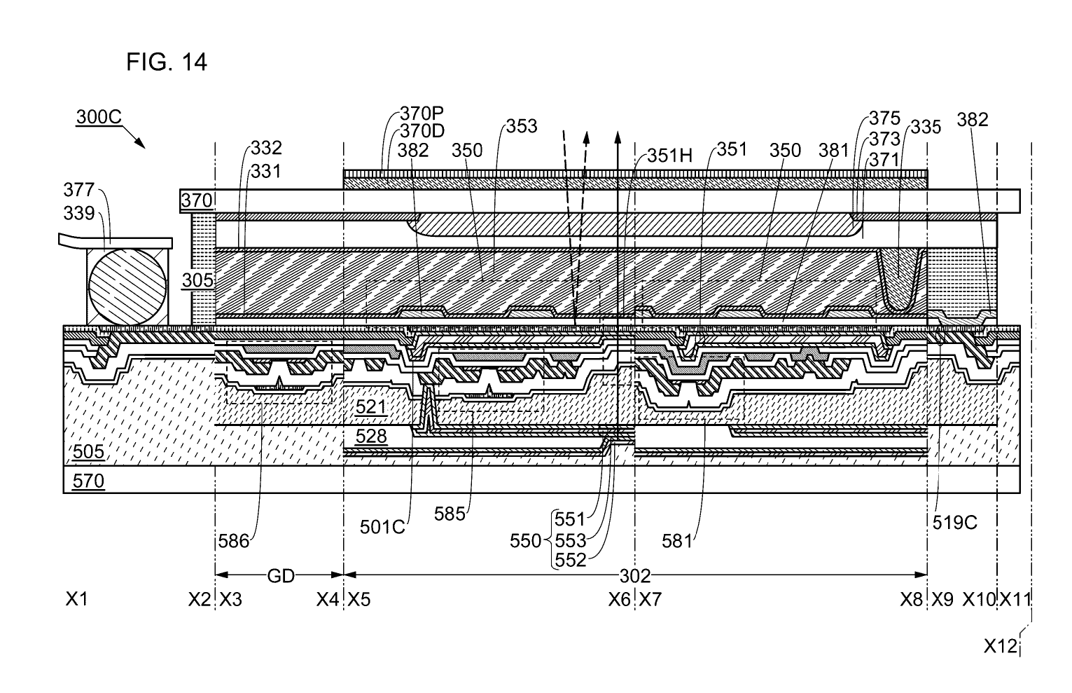

FIG. 14 illustrates a structure example where a liquid crystal element of a horizontal electric field mode (here, an FFS mode) is used for the display device 300 illustrated in FIGS. 2A to 2C.

A display device 300C illustrated in FIG. 14 includes an insulating film 381 over the electrode 351 and the terminal 519C and a conductive film 382 over the insulating film 381, in addition to the above-mentioned components.

The insulating film 381 has an opening in a region taken along the dashed-dotted line X9-X10, and the conductive film 382 is electrically connected to the terminal 519C through the opening. In FIG. 14, the conductor 337 included in the sealant 305 is not provided.

The conductive film 382 functions as a common electrode. The conductive film 382 may have a comb-like shape or a shape having a slit when seen from the above. Since the conductive film 382 is provided in the display device 300C illustrated in FIG. 14, the electrode 352 provided on the substrate 370 side is not provided. Note that the conductive film 382 may be provided and the electrode 352 may be further provided on the substrate 370 side.

For the insulating film 381, a material that can be used for the insulating films 521, 528, 501C, and 371 can be used. For the conductive film 382, a material that can be used for the first conductive film, the second conductive film, the conductive films 511B, 511C, and 512B can be used.

When the conductive film 382 is formed using a light-transmitting material, a light-transmitting capacitor can be formed. The light-transmitting capacitor includes the conductive film 382 and the insulating film 381 overlapping with the conductive film 382. This structure is preferable because the amount of charge accumulated in the capacitor can be increased.

### <Structure Example 5 of Display Device>

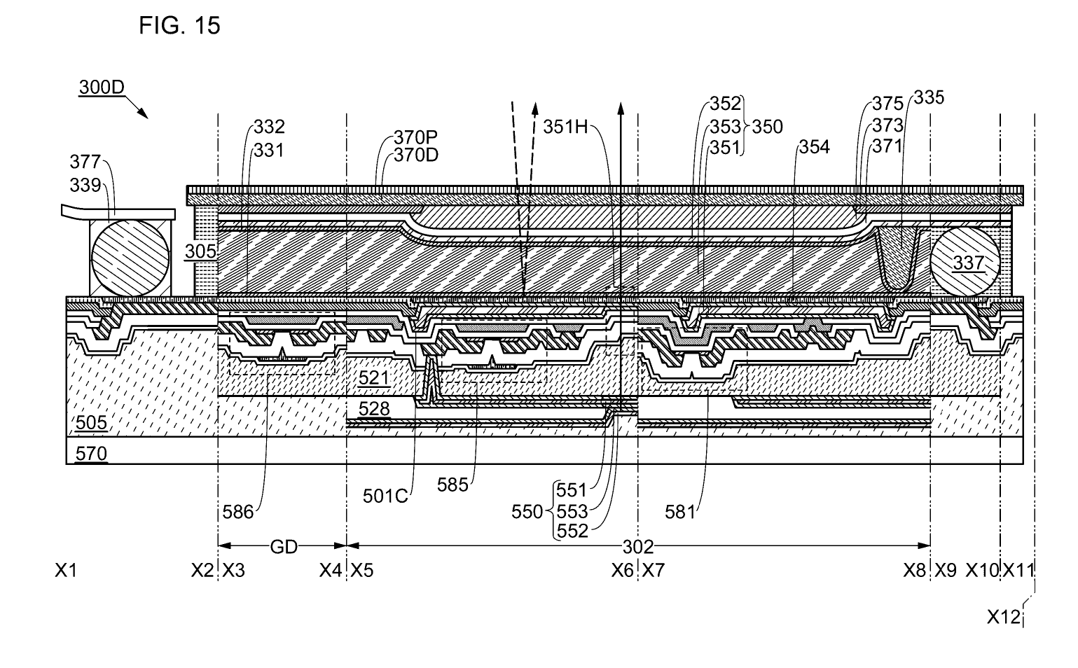

The display device 300 illustrated in FIGS. 2A to 2C does not necessarily include the substrate 370 as a display device 300D illustrated in FIG. 15. In that case, the functional films 370D and 370P each may include the coloring layer 375, the light-blocking film 373, the insulating film 371, the electrode 352, and the alignment film 332. The thickness of the display device 300D without the substrate 370 can be small. In addition, the display device 300D can display clearer images. Note that the coloring layer 375, the light-blocking film 373, the insulating film 371, the electrode 352, and the alignment film 332 may be directly formed on the functional film 370D. Alternatively, the coloring layer 375, the light-blocking film 373, the insulating film 371, the electrode 352, and the alignment film 332 may be formed over a substrate for use in manufacturing processes (a process substrate) which is described below, be separated from the process substrate, and be bonded to the functional film 370D.

### <Manufacturing Method of Display Device>

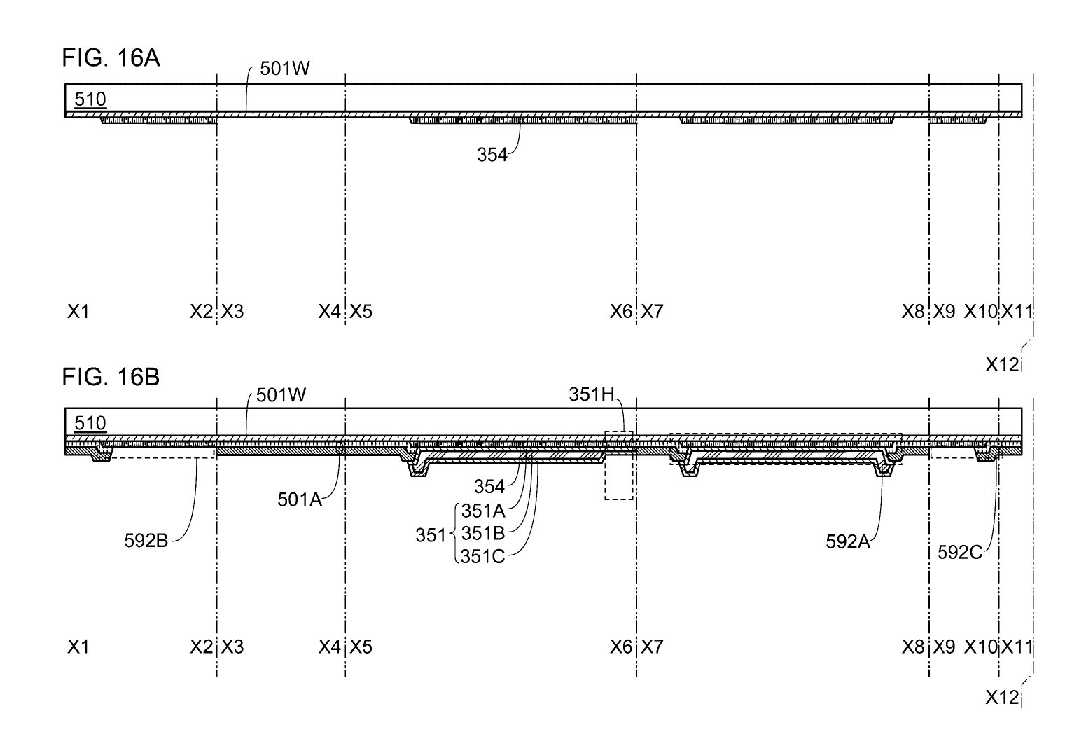

Next, a method for manufacturing a display device of one embodiment of the present invention will be described with reference to FIGS. 16A and 16B, FIGS. 17A and 17B, FIGS. 18A and 18B, FIGS. 19A and 19B, FIG. 20, FIG. 21, FIGS. 22A and 22B, and FIG. 23. FIGS. 16A and 16B, FIGS. 17A and 17B, FIGS. 18A and 18B, FIGS. 19A and 19B, FIG. 20, FIG. 21, FIGS. 22A and 22B, and FIG. 23 illustrate the method for manufacturing the display device 300 of one embodiment of the present invention. FIGS. 16A and 16B, FIGS. 17A and 17B, FIGS. 18A and 18B, FIGS. 19A and 19B, FIG. 20, FIG. 21, FIGS. 22A and 22B, and FIG. 23 are cross-sectional views taken along section lines X1-X2, X3-X4, X5-X6, X7-X8, X9-X10, and X11-X12 in FIG. 1A.

The method for manufacturing the display device described in this embodiment includes the following nine steps.

### <<First Step>>

In the first step, a separation film 501W is formed over a substrate 510. In the manufacturing process described in this embodiment, the substrate 510 where the separation film 501W is stacked is used as a process substrate (see FIG. 16A).

As the substrate 510, a substrate having heat resistance high enough to withstand heat treatment in the manufacturing process can be used.

For example, a large-sized glass substrate having any of the following sizes can be used as the substrate 510: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

For example, an inorganic material such as glass, ceramic, or a metal can be used for the substrate 510. Specifically, non-alkali glass, soda-lime glass, potash glass, crystal glass, quartz, sapphire, or the like can be used for the substrate 510. Specifically, an inorganic oxide film, an inorganic nitride film, an inorganic oxynitride film, or the like can be used for the substrate 510. For example, silicon oxide, silicon nitride, silicon oxynitride, aluminum oxide, or the like can be used for the substrate 510. A metal containing iron, aluminum, or the like can be used for the substrate 510.

For the separation film 501W, an inorganic material or a resin can be used, for example. For example, a single-layer material or a layered material including a plurality of films can be used for the separation film 501W. Specifically, an inorganic material such as a metal containing an element selected from tungsten, molybdenum, titanium, tantalum, niobium, nickel, cobalt, zirconium, zinc, ruthenium, rhodium, palladium, osmium, iridium, and silicon, an alloy including any of the elements, or a compound including any of the elements can be used for the separation film 501W.

It is particularly preferable to use, as the separation film 501W, a film containing tungsten or a material obtained by stacking a film containing tungsten and a film containing an oxide of tungsten.

The film containing an oxide of tungsten can be formed on a film containing tungsten by a method in which another film is stacked on a film containing tungsten. Specifically, a film containing silicon and oxygen is stacked on the film containing tungsten. For example, the film containing silicon and oxygen is stacked on the film containing tungsten with the use of a gas containing nitrous oxide.

The film containing an oxide of tungsten may be formed by subjecting a surface of a film containing tungsten to thermal oxidation treatment, oxygen plasma treatment, nitrous oxide plasma treatment, treatment with a solution with high oxidizing power (e.g., ozone water), or the like.

Specifically, a 30-nm-thick film containing tungsten having a surface subjected to plasma treatment in an atmosphere containing nitrous oxide can be used as the separation film 501W.

An organic material such as polyimide, polyester, polyolefin, polyamide, polycarbonate, or an acrylic resin can be used for the separation film 501W. Specifically, a film containing polyimide that has heat resistance higher than or equal to 200° C., preferably higher than or equal to 250° C., further preferably higher than or equal to 300° C., and still further preferably higher than or equal to 350° C., can be used as the separation film 501W.

Next, an intermediate film having a region overlapping with the process substrate is formed. A material that can be separated from the process substrate in a later step can be used for the intermediate film. This allows the separation film 501W to remain on the substrate 510 side after the intermediate film is separated from the process substrate. In another case, the separation film 501W can be separated together with the intermediate film from the substrate 510.

Note that a material obtained by stacking films serving as an etching stopper can be used as the intermediate film. Specifically, a material obtained by stacking a film containing indium, gallium, zinc, and oxygen and a film containing indium, tin, and oxygen, in this order, can be used for the intermediate film. A film containing indium, tin, silicon, and oxygen can alternatively be used as the intermediate film. Accordingly, a reduction in the thickness of the intermediate film in processing the insulating film 501A into a predetermined shape can be suppressed, for example. For example, the thickness of the intermediate film is preferably greater than or equal to 10 nm and less than or equal to 100 nm.

In this embodiment, a 50-nm-thick film containing indium, gallium, zinc, and oxygen is used as the intermediate film. The intermediate film can be formed by a sputtering method, for example. Specifically, a sputtering method using a material containing indium, gallium, and zinc at a ratio of 1:1:1.2 as a target can be employed. Alternatively, a sputtering method using a material containing indium, gallium, and zinc at a ratio of 4:2:4.1 as a target can be employed.

Next, the intermediate film is processed into a predetermined shape, so that the intermediate film 354 is formed (see FIG. 16A).

For example, a photolithography method and an etching method are used for the processing into a predetermined shape.

### <<Second Step>>

In the second step, the insulating film 501A and the first conductive film each having a region overlapping with the intermediate films 354 are formed (see FIG. 16B).

First, an insulating film to be the insulating film 501A later is formed so as to cover the intermediate films 354. Note that a material that can be separated from the process substrate in a later step can be used for the insulating film 501A. Specifically, the insulating film to be the insulating film 501A later can be formed by a chemical vapor deposition method using silane or the like as a source gas. A material containing silicon and oxygen or a material containing silicon, oxygen, and nitrogen can be used. Note that the thickness of the insulating film is preferably greater than or equal to 200 nm and less than or equal to 600 nm.

In this embodiment, the insulating film is formed to a thickness of approximately 200 nm using a material containing silicon and nitrogen.

Next, the insulating film to be the insulating film 501A later is heated. For example, the insulating film is heated at 450° C. for one hour. Thus, the insulating film releases hydrogen, and hydrogen diffuses toward the interface between the insulating film and the separation film 501W. Alternatively, hydrogen released from the insulating film penetrates the intermediate films 354 and diffuses to an interface between the intermediate films 354 and the separation film 501W. Accordingly, in a later step, a structure with which the intermediate films 354 and the insulating film 501A can be separated from the process substrate is formed between the intermediate films 354 and the process substrate and between the insulating film 501A and the process substrate.

Next, the insulating film is patterned so that the openings 592A, 592B, and 592C are formed, whereby the insulating film 501A is formed. For example, a photolithography method and an etching method are used for the processing into a predetermined shape.

A conductive film is formed over the insulating film 501A formed in the above manner and processed into a predetermined shape by a photolithography method and an etching method, so that the first conductive film is formed. Specifically, the opening 351H and a region for reflecting external light which enters through the intermediate film 354 are formed. Note that the first conductive film can be used for the electrode 351 (see FIG. 16B).

For example, a material obtained by stacking a 20-nm-thick conductive film 351A containing indium, tin, and oxygen, a 100-nm-thick reflective film 351B containing silver, and a 100-nm-thick conductive film 351C containing indium, tin, and oxygen, in this order, can be used for the first conductive film. Alternatively, for example, a material obtained by stacking a 20-nm-thick conductive film 351A containing indium, tin, silicon, and oxygen, a 100-nm-thick reflective film 351B containing silver, and a 100-nm-thick conductive film 351C containing indium, tin, silicon, and oxygen, in this order, can be used for the first conductive film. With the use of the films functioning as an etching stopper as the first conductive film, a reduction in the thickness of the first conductive film in processing the insulating film 501C into a predetermined shape in a later step can be suppressed.

### <<Third Step>>

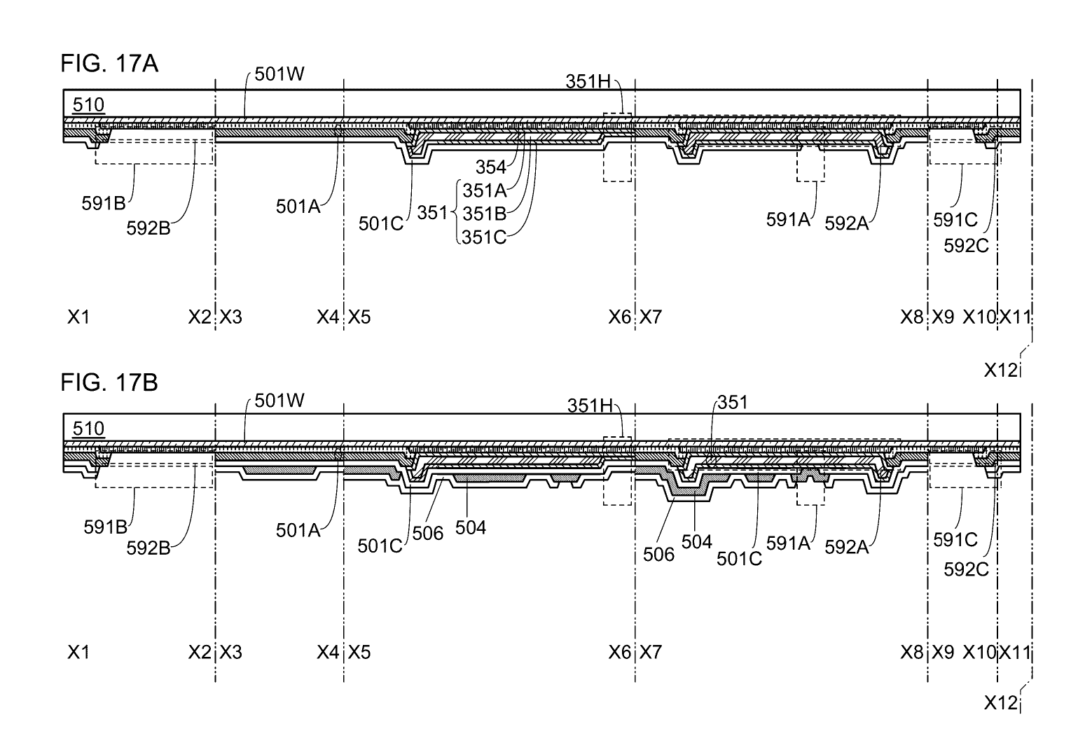

In the third step, the insulating film 501C covering the insulating film 501A, the intermediate films 354, and the first conductive film, having the opening 591A in a region overlapping with the first conductive film, and having the openings 592B and 592C each in a region overlapping with the intermediate film 354 is formed (see FIG. 17A).

For example, a photolithography method and an etching method are used for the processing into a predetermined shape.

The insulating film 501C can be formed by a chemical vapor deposition method using silane or the like as a source gas, for example.

For example, an insulating film with a thickness greater than or equal to 200 nm and less than or equal to 600 nm can be used as the insulating film 501C. In addition, a material containing silicon and oxygen or a material containing silicon, oxygen, and nitrogen can be used for the insulating film 501C. Note that the insulating film 501C may be either a single film or a stacked film.

### <<Fourth Step>>

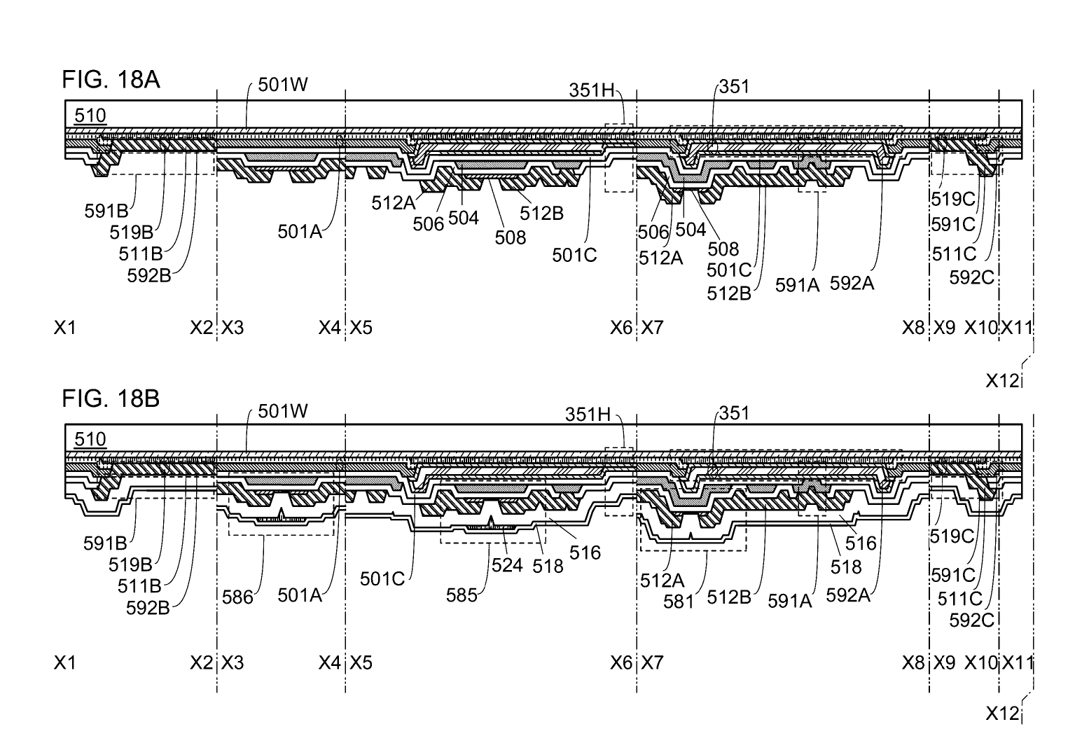

In the fourth step, the transistors included in the pixel circuit 302 are formed. In addition, a second conductive film overlapping with the opening 591A is formed (see FIGS. 17B, 18A, and 18B).

The transistors included in the pixel circuit 302 can be formed through the film formation and patterning of a conductive film, a semiconductor film, and an insulating film in a predetermined order, as described below.

For example, a conductive film having a region overlapping with the insulating film 501C is formed and processed into a predetermined shape. The conductive film can be used as the conductive film 504 having a region functioning as a gate electrode of each of the transistor 585, the transistor 586, and a transistor that can be used as the switch 581, for example.

In addition, an insulating film is formed in a region overlapping with the conductive film 504 and the insulating film 501C, and is processed into a predetermined shape. The insulating film can be used as the insulating film 506 having a region functioning as a gate insulating film of each of the transistor 585, the transistor 586, and the transistor that can be used as the switch 581, for example. In addition, the insulating film has openings in regions overlapping with the openings 591A, 591B, and 591C, for example (see FIG. 17B).

Then, a semiconductor film having a region overlapping with the conductive film 504 is formed and processed into a predetermined shape. The semiconductor film functions as the semiconductor film 508 included in each of the transistor 585, the transistor 586, and the transistor that can be used as the switch 581, for example.

In addition, a second conductive film which can be electrically connected to the first conductive film in the opening 591A and electrically connected to the intermediate films 354 in the openings 591B, 592B, 591C, and 592C is formed and processed into a predetermined shape. The second conductive film can be used as the conductive films 512A and 512B included in each of the transistor 585, the transistor 586, and the transistor that can be used as the switch 581, for example (see FIG. 18A).

The first conductive film and the second conductive film can be electrically connected to each other using another conductive film including a region overlapping with the opening 591A. For example, a conductive film that can be formed in the same process as the conductive film 504 can be used as the conductive film.

Next, an insulating film having a region overlapping with the semiconductor film 508, the second conductive film, and the insulating film 501C is formed. The insulating film can be used as the insulating film 516 included in each of the transistor 585, the transistor 586, and the transistor that can be used as the switch 581, for example.

In addition, a conductive film having a region overlapping with the insulating film 516, the semiconductor film 508, and the conductive film 504 functioning as a gate electrode is formed and processed into a predetermined shape. The conductive film can be used as the conductive film 524 included in each of the transistors 585 and 586, for example.

The conductive film 524 is preferably formed so that the semiconductor film 508 can be interposed between the conductive films 524 and 504. In addition, an insulating film having a region overlapping with the insulating film 516 and the conductive film 524 is formed. The insulating film can be used as the insulating film 518 included in each of the transistor 585, the transistor 586, and the transistor that can be used as the switch 581, for example (see FIG. 18B).

### <<Fifth Step>>

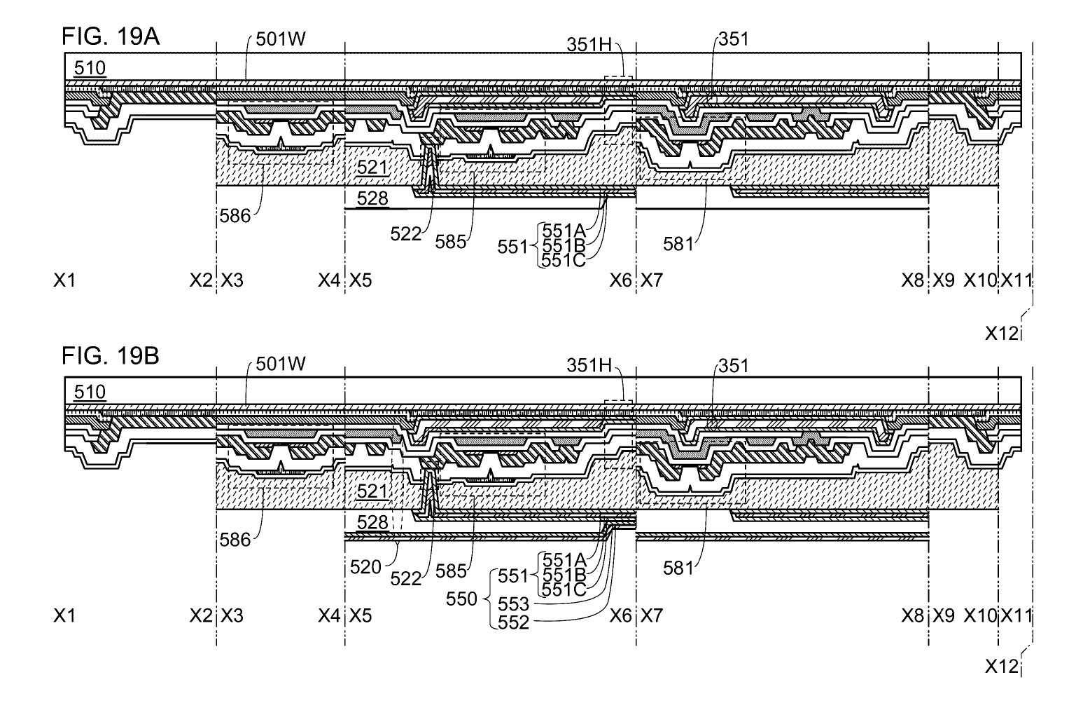

In the fifth step, the second display element 550 electrically connected to the transistor 585 included in the pixel circuit 302 is formed (see FIGS. 19A and 19B).

The second display element 550 can be formed in the following manner, for example.

For example, the insulating film 521 is formed over the transistor 585 and processed into a predetermined shape. The insulating film 521 is preferably formed so that steps due to the transistor 585 and the like which overlap with the insulating film 521 can be eliminated (see FIG. 19A).

In addition, the insulating film 521 has the connection portion 522 in a region overlapping with the second conductive film. A conductive material is deposited in a region overlapping with the insulating film 521 and the transistor 585 and is processed into a predetermined shape to form the electrode 551.

For example, a material obtained by stacking a 70-nm-thick conductive film 551A containing indium, tin, and oxygen, a 20-nm-thick reflective film 551B containing silver, and a 10-nm-thick conductive film 551C containing indium, tin, and oxygen, in this order, can be used for the electrode 551. Alternatively, for example, a material obtained by stacking a 70-nm-thick conductive film 551A containing indium, tin, silicon, and oxygen, a 20-nm-thick reflective film 551B containing silver, and a 10-nm-thick conductive film 551C containing indium, tin, silicon, and oxygen, in this order, can be used for the electrode 551.

When the reflective film 551B is formed to have a small thickness enough to transmit light as described above, the electrode 551 has functions of transmitting light and reflecting light. The electrode 551 functions as a cathode or an anode of the second display element 550. The electrode 551 is electrically connected to the transistor 585 in the connection portion 522 which is provided in the insulating film 521.

In addition, an insulating film is formed in a region overlapping with the insulating film 521 and with the side end portion of the electrode 551 and is processed into a predetermined shape to form the insulating film 528. The insulating film 528 has an opening in a region overlapping with the electrode 551 (see FIG. 19A).

Next, the light-emitting layer 553 is formed in a region overlapping with the electrode 551 and the insulating film 528. The light-emitting layer 553 preferably contains an organic light-emitting material or an inorganic light-emitting material. In addition, the electrode 552 is formed in a region overlapping with the light-emitting layer 553, the electrode 551, and the insulating film 528. Note that in addition to the light-emitting layer 553, at least one of layers functioning as a hole-injection layer, a hole-transport layer, an electron-transport layer, an electron-injection layer, a charge-generation layer, and the like may be formed in a region overlapping with the electrode 551 and the insulating film 528.

The electrode 552 includes a reflective film, and the reflective film is preferably formed with a conductive material having a function of reflective light. The electrode 552 functions as an anode or a cathode of the second display element 550 (see FIG. 19B).

### <<Sixth Step>>

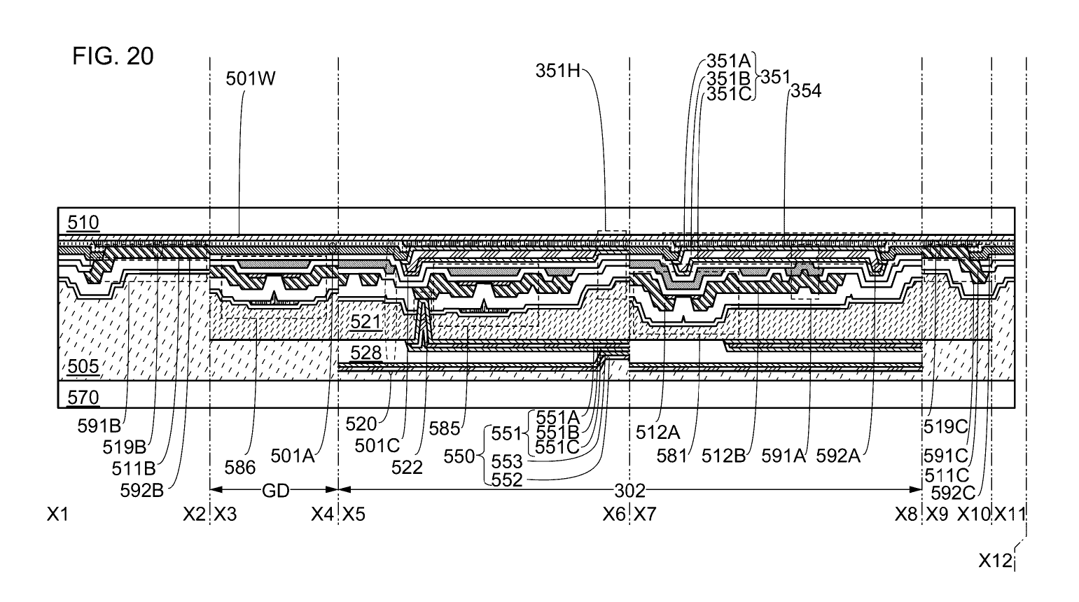

In the sixth step, the substrate 570 is stacked such that the second display element 550 is interposed between the process substrate and the substrate 570 (see FIG. 20).

The bonding layer 505 is formed over the process substrate by a printing method or a coating method, for example, and the substrate 570 is bonded to the process substrate using the bonding layer 505.

### <<Seventh Step>>

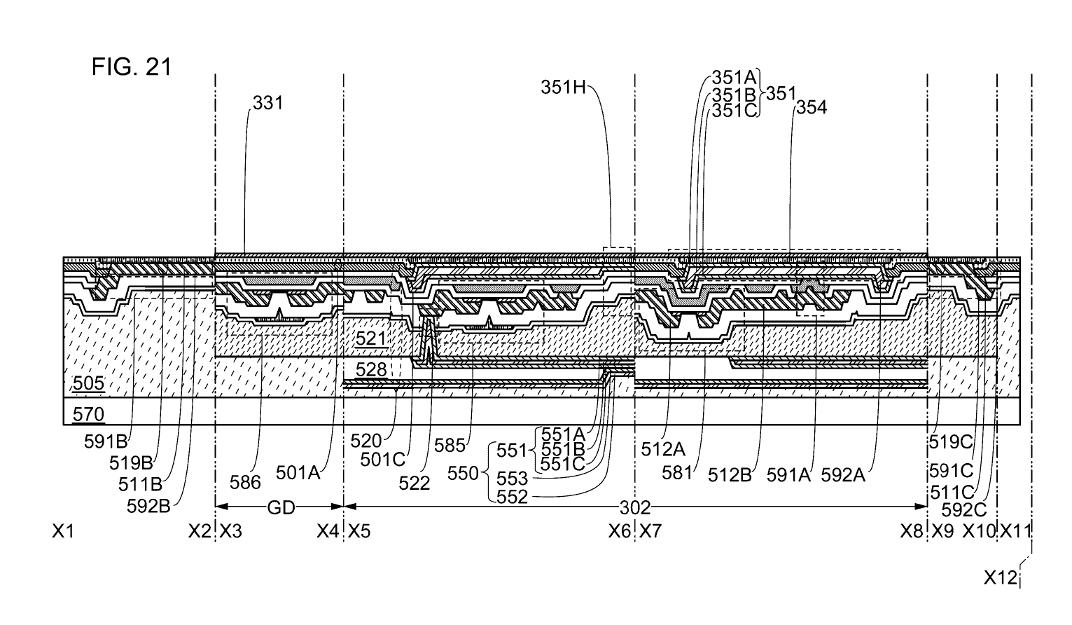

In the seventh step, the process substrate is separated, and the alignment film 331 is formed such that the intermediate film 354 is interposed between the first conductive film and the alignment film 331 (see FIG. 21).

For example, the insulating film 501A and the intermediate film 354 are separated along the separation film 501W. For example, part of the insulating film 501A is separated from the process substrate, thereby forming a separation starting point, so that the insulating film 501A and the intermediate film 354 are separated from the process substrate. In the case of forming the separation starting point, the insulating film 501A and the intermediate film 354 can be separated from the process substrate in the following manner: a region where the insulating film 501A or the intermediate film 354 is separated from the process substrate is gradually increased from the separation starting point. The separation starting point can be formed by a method using a laser or the like (specifically, a laser ablation method) or a method using a cutter with a cutting edge, for example.

Note that a polar solvent (typically water), a nonpolar solvent, or the like is preferably added to the interface between the separation film 501W and the insulating film 501A and the intermediate film 354 when the insulating film 501A and the intermediate film 354 are separated from the separation film 501W. For example, the use of water can reduce damage caused by electrification in the separation.

In the display device of one embodiment of the present invention, in order to form the alignment film 331 in a region overlapping with the first display element 350, a polyimide-containing film serving as the alignment film 331 is formed over the first conductive film by a printing method, for example. For example, the polyimide-containing film serving as the alignment film 331 can be formed by a method using a soluble polyimide or a method using a precursor of polyimide, such as a polyamic acid. Note that the temperature of heat transferred to the second display element 550 in formation of the alignment film 331 by the method using a soluble polyimide can be lower than that when a method using a precursor of polyimide, such as a polyamic acid, is employed. Accordingly, damage caused by heat applied to the second display element 550 can be reduced. Thus, a highly reliable display device can be provided.

### <<Eighth Step>>

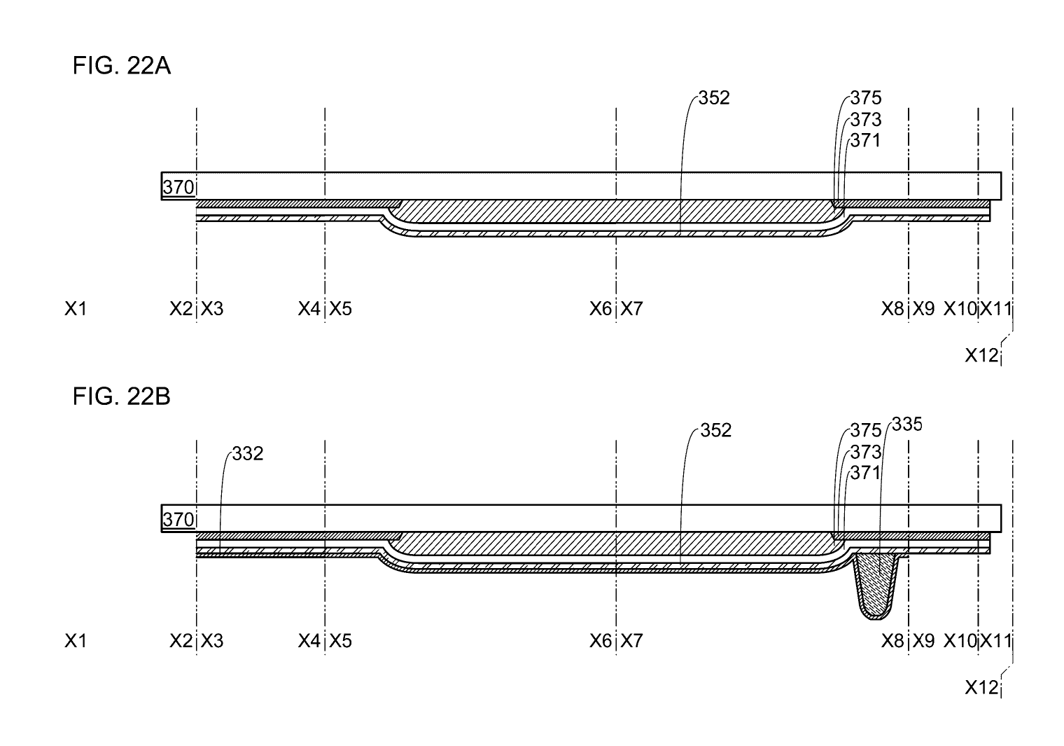

In the eighth step, the coloring layer 375, the structure body 335, and the alignment film 332 which are necessary for the first display element 350 are formed over the substrate 370 (see FIGS. 22A and 22B).

First, the light-blocking film 373 is formed over the substrate 370. Then, the coloring layer 375 is formed over the substrate 370 and the light-blocking film 373. For example, a titanium film can be used as the light-blocking film 373. For example, an acrylic resin containing pigment can be used for the coloring layer 375. The insulating film 371 is formed over the light-blocking film 373 and the coloring layer 375. Then, the electrode 352 is formed over the insulating film 371 (see FIG. 22A). For example, an acrylic resin can be used for the insulating film 371. For example, ITSO can be used for the electrode 352.

Next, the structure body 335 is formed in a desired region over the electrode 352. In addition, the alignment film 332 is formed over the electrode 352 and the structure body 335 (see FIG. 22B). For example, an acrylic resin can be used for the structure body 335. For example, a polyimide-containing film can be formed as the alignment film 332. Note that the alignment film 332 is not necessarily provided. Although the structure body 335 is provided over the substrate 370 in this embodiment, one embodiment of the present invention is not limited thereto. For example, the structure body 335 may be formed over the second display element 550 which is formed over the substrate 570.

### <<Ninth Step>>

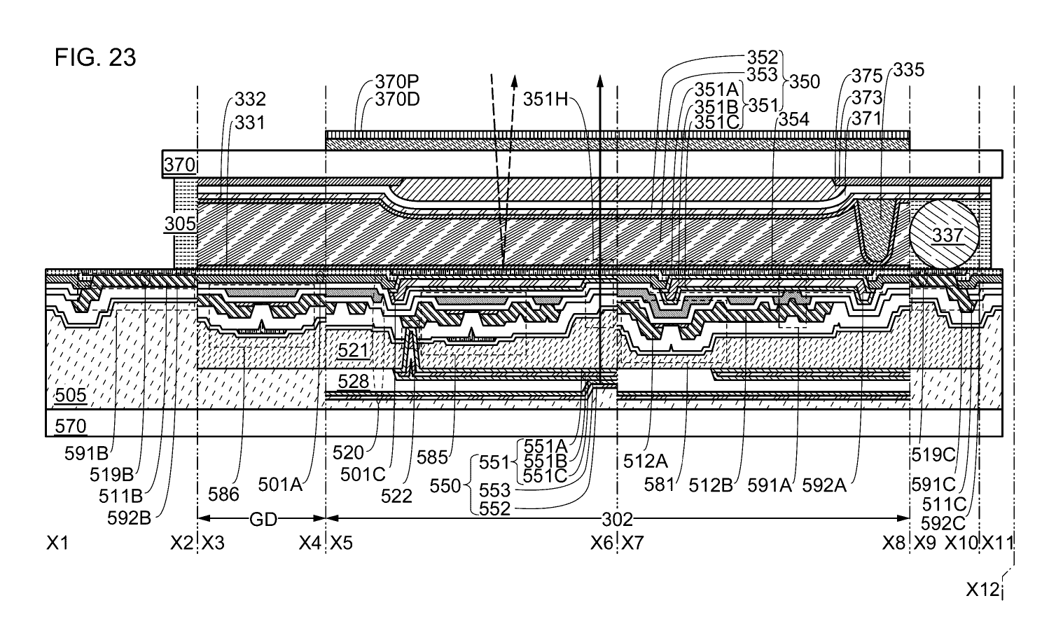

In the ninth step, the substrates 570 and 370 are bonded and sealed with the sealant 305. Then, the liquid crystal layer 353 is provided between the alignment films 331 and 332 to form the first display element 350. Alternatively, the first display element 350 is formed in such a manner that the liquid crystal layer 353 is provided over the alignment film 331 and the substrates 570 and 370 are bonded and sealed with the sealant 305 (see FIG. 23).

The sealant 305 on the terminal 519C includes the conductor 337. As for the conductor 337, conductive particles may be dispersed in a desired region of the sealant 305 using a dispenser method or the like. Note that the terminal 519C is electrically connected to the electrode 352 through the conductor 337.

Next, the functional films 370D and 370P are formed over the substrate 370. Note that the functional film 370D and/or 370P is not necessarily formed.

Then, the flexible printed circuit 377 is bonded onto the terminal 519B with the conductive material 339 (see FIG. 2A). Note that an anisotropic conductive film (ACF) or an anisotropic conductive paste (ACP) can be used as the conductive material 339, for example.

Through the above-described process, the display device 300 of one embodiment of the present invention can be manufactured.

The manufacturing method of the display device of one embodiment of the present invention includes a step of forming an intermediate film; a step of forming a first conductive film; a step of forming an insulating film having an opening overlapping with the first conductive film; a step of forming a transistor such that the insulating film is interposed between the first conductive film and part of the transistor and the transistor is electrically connected to the first conductive film; a step of forming a second display element such that it is electrically connected to the transistor; and a step of forming a first display element such that it is electrically connected to the first conductive film. In this method, the display device can be manufactured through processes performed in the following descending order of the temperature and the degree of vacuum required in the manufacturing process and the degree of difficulty: a process for forming the transistor that requires a high temperature; a process for forming the second display element that requires a high degree of vacuum; and a process for forming the first display element that does not require a high temperature or a high degree of vacuum. Thus, a highly reliable novel display device can be provided. In addition, a method for manufacturing a highly reliable novel display device can be provided.

In this embodiment, one embodiment of the present invention has been described. In other embodiments, other embodiments of the present invention will be described. Note that one embodiment of the present invention is not limited to these embodiments. In other words, various embodiments of the invention are described in this embodiment and the other embodiments, and one embodiment of the present invention is not limited to a particular embodiment. For example, in one embodiment of the present invention, an example where a light-emitting element and a reflective liquid crystal element are used as display elements has been described; however, one embodiment of the present invention is not limited to this example. Depending on circumstances or conditions, in one embodiment of the present invention, a light-emitting element and a reflective liquid crystal element are not necessarily used, for example. For example, in one embodiment of the present invention, an example where a reflective film included in a liquid crystal element contains the same metal as a reflective film included in a light-emitting element has been described; however, one embodiment of the present invention is not limited to this example. Depending on circumstances or conditions, in one embodiment of the present invention, a reflective film included in a liquid crystal element does not necessarily contain the same metal as a reflective film included in a light-emitting element, for example.

### Embodiment 2

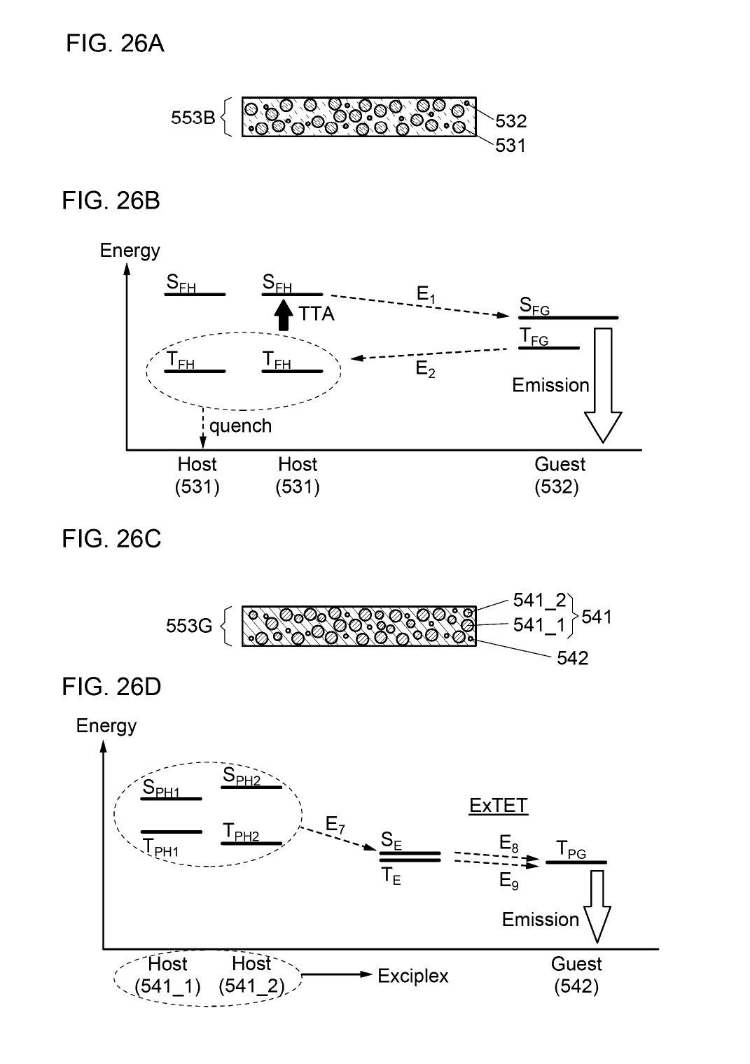

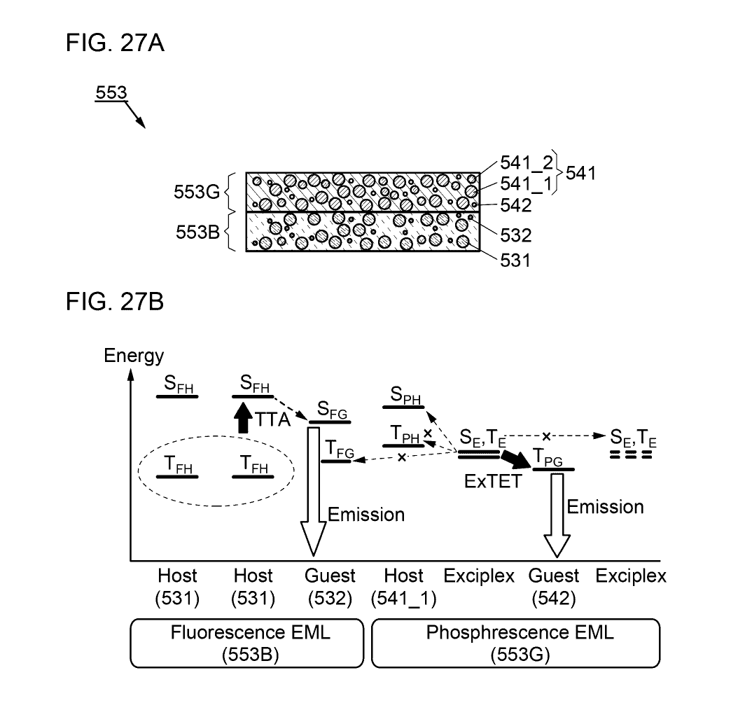

In this embodiment, the structure of the light-emitting layer of the light-emitting element that can be used in the display device described in Embodiment 1 will be described with reference to FIGS. 26A to 26D and FIGS. 27A and 27B. In FIGS. 26A to 26D and FIGS. 27A and 27B, a portion having a function similar to that in FIGS. 24A and 24B and FIGS. 25A and 25B is represented by the same hatch pattern as in FIGS. 24A and 24B and FIGS. 25A and 25B and not especially denoted by a reference numeral in some cases. In addition, common reference numerals are used for portions having similar functions, and a detailed description of the portions is omitted in some cases.

### <Structure Example 1 of Light-Emitting Element>

FIG. 26A is a schematic cross-sectional view of the light-emitting layer 553B that can be used for each of the light-emitting elements illustrated in FIGS. 24A and 24B and FIGS. 25A and 25B.

The light-emitting layer 553B contains a host material 531 and a guest material 532 as illustrated as an example in FIG. 26A. Note that the guest material 532 is described below as a fluorescent material.

### <<Light Emission Mechanism of Light-Emitting Layer 553B>>

The light emission mechanism of the light-emitting layer 553B is described below.

Excitons are formed by recombination of the electrons and holes injected from the pair of electrodes (the electrodes 551 and 552) or the charge-generation layer in the light-emitting layer 553B. Because the amount of the host material 531 is larger than that of the guest material 532, the host material 531 is brought into an excited state by the exciton generation.

Note that the term “exciton” refers to a carrier (electron and hole) pair. Since excitons have energy, a material where excitons are generated is brought into an excited state.

In the case where the formed excited state of the host material 531 is a singlet excited state, singlet excitation energy transfers from the lowest level of the singlet excitation energy level (S1 level) of the host material 531 to the S1 level of the guest material 532, thereby forming the singlet excited state of the guest material 532.

Since the guest material 532 is a fluorescent material, when a singlet excited state is formed in the guest material 532, the guest material 532 immediately emits light. To obtain high emission efficiency in this case, the fluorescence quantum yield of the guest material 532 is preferably high. The same can apply to a case where a singlet excited state is formed by recombination of carriers in the guest material 532.

Next, a case where recombination of carriers forms a triplet excited state of the host material 531 is described. The correlation of energy levels of the host material 531 and the guest material 532 in this case is illustrated in FIG. 26B. The following explains what terms and signs in FIG. 26B represent. Note that because it is preferable that the lowest level of the triplet excitation energy level (T1 level) of the host material 531 be lower than the T1 level of the guest material 532, FIG. 26B illustrates this preferable case. However, the T1 level of the host material 531 may be higher than the T1 level of the guest material 532.

Host (531): the host material 531;

Guest (532): the guest material 532 (the fluorescent material);

S_{FH}: the S1 level of the host material 531;

T_{FH}: the T1 level of the host material 531;

S_{FG}: the S1 level of the guest material 532 (the fluorescent material); and

T_{FG}: the T1 level of the guest material 532 (the fluorescent material).

As illustrated in FIG. 26B, triplet excitons formed by carrier recombination interact with each other, and excitation energy is transferred and spin angular momenta are exchanged; as a result, a reaction in which one of the triplet excitons are converted into singlet exciton having energy of the S1 level of the host material 531 (S_{FH}), that is, triplet-triplet annihilation (TTA) occurs (see TTA in FIG. 26B). The singlet excitation energy of the host material 531 is transferred from S_{FH} to the S1 level of the guest material 532 (S_{FG}) having a lower energy than S_{FH} (see Route E₁ in FIG. 26B), and a singlet excited state of the guest material 532 is formed, whereby the guest material 532 emits light.

Note that in the case where the density of triplet excitons in the light-emitting layer 553B is sufficiently high (e.g., 1×10⁻¹² cm⁻³ or higher), only the reaction of two triplet excitons close to each other can be considered whereas deactivation of a single triplet exciton can be ignored.

In the case where a triplet excited state of the guest material 532 is formed by carrier recombination, the triplet excited state of the guest material 532 is thermally deactivated and is difficult to use for light emission. However, in the case where the T1 level of the host material 531 (T_{FH}) is lower than the T1 level of the guest material 532 (T_{FG}), the triplet excitation energy of the guest material 532 can be transferred from the T1 level of the guest material 532 (T_{FG}) to the T1 level of the host material 531 (T_{FH}) (see Route E₂ in FIG. 26B) and is then utilized for TTA.

In other words, the host material 531 preferably has a function of converting triplet excitation energy into singlet excitation energy by causing TTA, so that the triplet excitation energy generated in the light-emitting layer 553B can be partly converted into singlet excitation energy by TTA in the host material 531. The singlet excitation energy can be transferred to the guest material 532 and extracted as fluorescence. In order to achieve this, the S1 level of the host material 531 (S_{FH}) is preferably higher than the S1 level of the guest material 532 (S_{FG}). In addition, the T1 level of the host material 531 (T_{FH}) is preferably lower than the T1 level of the guest material 532 (T_{FG}).

Note that particularly in the case where the T1 level of the guest material 532 (T_{FG}) is lower than the T1 level of the host material 531 (T_{FH}), the weight ratio of the guest material 532 to the host material 531 is preferably low. Specifically, the weight ratio of the guest material 532 to the host material 531 is preferably greater than 0 and less than or equal to 0.05, in which case the probability of carrier recombination in the guest material 532 can be reduced. In addition, the probability of energy transfer from the T1 level of the host material 531 (T_{FH}) to the T1 level of the guest material 532 (T_{FG}) can be reduced.

Note that the host material 531 may be composed of a single compound or a plurality of compounds.

### <Structure Example 2 of Light-Emitting Element>

A structure example different from the light-emitting layer illustrated in FIGS. 26A and 26B are described below with reference to FIGS. 26C and 26D. FIG. 26C is a schematic cross-sectional view of the light-emitting layer 553G.

The light-emitting layer 553G contains a host material 541 and a guest material 542 as illustrated in FIG. 26C. The host material 541 contains an organic compound 541_1 and an organic compound 541_2. Note that in the description below, the guest material 542 in the light-emitting layer 553G is a phosphorescent material.

### <<Light Emission Mechanism of Light-Emitting Layer 553G>>

The light emission mechanism of the light-emitting layer 553G is described below.

The organic compounds 541_1 and 541_2 included in the light-emitting layer 553G form an exciplex.

Although it is acceptable as long as the combination of the organic compounds 541_1 and 541_2 can form an exciplex, it is preferable that one of them be a compound having a hole-transport property and the other be a compound having an electron-transport property.

FIG. 26D illustrates the correlation of energy levels of the organic compound 541_1, the organic compound 541_2, and the guest material 542 in the light-emitting layer 553G. The following explains what terms and signs in FIG. 26D represent:

Host (541_1): the organic compound 541_1 (the host material);

Host (541_2): the organic compound 541_2 (the host material);

Guest (542): the guest material 542 (the phosphorescent material);

S_{PH1}: the S1 level of the organic compound 541_1 (the host material);

T_{PH1}: the T1 level of the organic compound 541_1 (the host material);

S_{PH2}: the S1 level of the organic compound 541_2 (the host material);

T_{PH2}: the T1 level of the organic compound 541_2 (the host material);

T_{PG}: the T1 level of the guest material 542 (the phosphorescent material);

S_{E}: the S1 level of the exciplex; and

T_{E}: the T1 level of the exciplex.

The organic compounds 541_1 and 541_2 form an exciplex, and the S1 level (S_{E}) and the T1 level (T_{E}) of the exciplex are energy levels adjacent to each other (see Route E₇ in FIG. 26D).

One of the organic compounds 541_1 and 541_2 receives a hole and the other receives an electron to readily form an exciplex. Alternatively, when one of the organic compounds is brought into an excited state, the other immediately interacts with the one to form an exciplex. Consequently, most excitons formed in the light-emitting layer 553G exist as exciplexes. Because the excitation energy levels (S_{E} and T_{E}) of the exciplex are lower than the S1 levels (S_{PH1} and S_{PH2}) of the organic compounds (the organic compounds 541_1 and 541_2) that form the exciplex, the excited state of the host material 541 can be formed with lower excitation energy. This can reduce the drive voltage of the light emitting element.

Both energies of S_{E} and T_{E} of the exciplex are then transferred to the T1 level of the guest material 542 (the phosphorescent material); thus, light emission is obtained (see Routes E₈ and E₉ in FIG. 26D).

Furthermore, the T1 level (T_{E}) of the exciplex is preferably higher than the T1 level (T_{PG}) of the guest material 542. Thus, the singlet excitation energy and the triplet excitation energy of the formed exciplex can be transferred from the S1 level (S_{E}) and the T1 level (T_{E}) of the exciplex to the T1 level (T_{PG}) of the guest material 542.

Note that in order to efficiently transfer excitation energy from the exciplex to the guest material 542, the T1 level (T_{E}) of the exciplex is preferably lower than or equal to the T1 levels (T_{PH1} and T_{PH2}) of the organic compounds (the organic compounds 541_1 and 541_2) which form the exciplex. Thus, quenching of the triplet excitation energy of the exciplex due to the organic compounds (the organic compounds 541_1 and 541_2) is less likely to occur, resulting in efficient energy transfer from the exciplex to the guest material 542.

In order to efficiently form an exciplex by the organic compounds 541_1 and 541_2, it is preferable to satisfy the following: the HOMO level of one of the organic compounds 541_1 and 541_2 is higher than that of the other and the LUMO level of the one of the organic compounds 541_1 and 541_2 is higher than that of the other. For example, when the organic compound 541_1 has a hole-transport property and the organic compound 541_2 has an electron-transport property, it is preferable that the HOMO level of the organic compound 541_1 be higher than the HOMO level of the organic compound 541_2 and the LUMO level of the organic compound 541_1 be higher than the LUMO level of the organic compound 541_2. Alternatively, when the organic compound 541_2 has a hole-transport property and the organic compound 541_1 has an electron-transport property, it is preferable that the HOMO level of the organic compound 541_2 be higher than the HOMO level of the organic compound 541_1 and the LUMO level of the organic compound 541_2 be higher than the LUMO level of the organic compound 541_1. Specifically, the energy difference between the HOMO level of the organic compound 541_1 and the HOMO level of the organic compound 541_2 is preferably greater than or equal to 0.05 eV, further preferably greater than or equal to 0.1 eV, and still further preferably greater than or equal to 0.2 eV. Alternatively, the energy difference between the LUMO level of the organic compound 541_1 and the LUMO level of the organic compound 541_2 is preferably greater than or equal to 0.05 eV, further preferably greater than or equal to 0.1 eV, and still further preferably greater than or equal to 0.2 eV.

In the case where the combination of the organic compounds 541_1 and 541_2 is a combination of a compound having a hole-transport property and a compound having an electron-transport property, the carrier balance can be easily controlled by adjusting the mixture ratio. Specifically, the weight ratio of the compound having a hole-transport property to the compound having an electron-transport property is preferably within a range of 1:9 to 9:1. Since the carrier balance can be easily controlled with the structure, a carrier recombination region can also be controlled easily.

### <Energy Transfer Mechanism>

Next, factors controlling the processes of intermolecular energy transfer between the host material 541 and the guest material 542 will be described. As mechanisms of the intermolecular energy transfer, two mechanisms, i.e., Förster mechanism (dipole-dipole interaction) and Dexter mechanism (electron exchange interaction), have been proposed. Although the intermolecular energy transfer process between the host material 541 and the guest material 542 is described here, the same can apply to a case where the host material 541 is an exciplex.

### <<Förster Mechanism>>

In Förster mechanism, energy transfer does not require direct contact between molecules and energy is transferred through a resonant phenomenon of dipolar oscillation between the host material 541 and the guest material 542. By the resonant phenomenon of dipolar oscillation, the host material 541 provides energy to the guest material 542, and thus, the host material 541 in an excited state is brought to a ground state and the guest material 542 in a ground state is brought to an excited state. Note that the rate constant k_{h*→g} of Förster mechanism is expressed by Formula (1).

$$\begin{matrix}[ Formula 1 ] & \\ {k}_{{h}^{*} -> g} = \frac{9000 {c}^{4} {K}^{2} φ ln 10}{128 {π}^{5} {n}^{4} N τ {R}^{6}} \int \frac{{f}_{h}^{′} ( v ) {ɛ}_{g} ( v )}{{v}^{4}} d v & ( 1 )\end{matrix}$$

In Formula (1), v denotes a frequency, f′ₕ(v) denotes a normalized emission spectrum of the host material 541 (a fluorescence spectrum in energy transfer from a singlet excited state, and a phosphorescence spectrum in energy transfer from a triplet excited state), ∈_{g}(v) denotes a molar absorption coefficient of the guest material 542, N denotes Avogadro's number, n denotes a refractive index of a medium, R denotes an intermolecular distance between the host material 541 and the guest material 542, r denotes a measured lifetime of an excited state (fluorescence lifetime or phosphorescence lifetime), c denotes the speed of light, φ denotes a luminescence quantum yield (a fluorescence quantum yield in energy transfer from a singlet excited state, and a phosphorescence quantum yield in energy transfer from a triplet excited state), and K² denotes a coefficient (0 to 4) of orientation of a transition dipole moment between the host material 541 and the guest material 542. Note that K²=⅔ in random orientation.

### <<Dexter Mechanism>>

In Dexter mechanism, the host material 541 and the guest material 542 are close to a contact effective range where their orbitals overlap, and the host material 541 in an excited state and the guest material 542 in a ground state exchange their electrons, which leads to energy transfer. Note that the rate constant k_{k*→g} of Dexter mechanism is expressed by Formula (2).

$$\begin{matrix}[ Formula 2 ] & \\ {k}_{{h}^{*} -> g} = ( \frac{2 π}{h} ) {K}^{2} exp ( - \frac{2 R}{L} ) \int {f}_{h}^{′} ( v ) {ɛ}_{g}^{′} ( v ) d v & ( 2 )\end{matrix}$$

In Formula (2), h denotes a Planck constant, K denotes a constant having an energy dimension, v denotes a frequency, f′ₕ(v) denotes a normalized emission spectrum of the host material 541 (a fluorescence spectrum in energy transfer from a singlet excited state, and a phosphorescence spectrum in energy transfer from a triplet excited state), ∈′_{g}(v) denotes a normalized absorption spectrum of the guest material 542, L denotes an effective molecular radius, and R denotes an intermolecular distance between the host material 541 and the guest material 542.

Here, the efficiency of energy transfer from the host material 541 to the guest material 542 (energy transfer efficiency φ_{ET}) is expressed by Formula (3). In the formula, kᵣ denotes a rate constant of a light-emission process (fluorescence in energy transfer from a singlet excited state, and phosphorescence in energy transfer from a triplet excited state) of the host material 541, kₙ denotes a rate constant of a non-light-emission process (thermal deactivation or intersystem crossing) of the host material 541, and τ denotes a measured lifetime of an excited state of the host material 541.

$$\begin{matrix}[ Formula 3 ] & \\ {φ}_{ET} = \frac{{k}_{{h}^{*} -> g}}{{k}_{r} + {k}_{n} + {k}_{{h}^{*} -> g}} = \frac{{k}_{{h}^{*} -> g}}{( \frac{1}{τ} ) + {k}_{{h}^{*} -> g}} & \end{matrix}$$

According to Formula (3), it is found that the energy transfer efficiency φ_{ET} can be increased by increasing the rate constant k_{h*→g} of energy transfer so that another competing rate constant kᵣ+kₙ (=1/τ) becomes relatively small.

### <<Concept for Promoting Energy Transfer>>

In energy transfer by Förster mechanism, high energy transfer efficiency φ_{ET} is obtained when emission quantum yield φ (a fluorescence quantum yield in energy transfer from a singlet excited state, and a phosphorescence quantum yield in energy transfer from a triplet excited state) is high. Furthermore, it is preferable that the emission spectrum (the fluorescence spectrum in energy transfer from the singlet excited state) of the host material 541 largely overlap with the absorption spectrum (absorption corresponding to the transition from the singlet ground state to the triplet excited state) of the guest material 542. Moreover, it is preferable that the molar absorption coefficient of the guest material 542 be also high. This means that the emission spectrum of the host material 541 overlaps with the absorption band of the absorption spectrum of the guest material 542 that is on the longest wavelength side.

In energy transfer by Dexter mechanism, in order to make the rate constant k_{h*→g} large, it is preferable that the emission spectrum (a fluorescence spectrum in energy transfer from a singlet excited state, and a phosphorescence spectrum in energy transfer from a triplet excited state) of the host material 541 largely overlap with the absorption spectrum (absorption corresponding to transition from a singlet ground state to a triplet excited state) of the guest material 542. Therefore, the energy transfer efficiency can be optimized by making the emission spectrum of the host material 541 overlap with the absorption band of the absorption spectrum of the guest material 542 that is on the longest wavelength side.

In a manner similar to that of the energy transfer from the host material 541 to the guest material 542, the energy transfer by both Förster mechanism and Dexter mechanism also occurs in the energy transfer process from the exciplex to the guest material 542.

In other words, the host material 541 is an exciplex having a function of an energy donor capable of efficiently transferring energy to the guest material 542, and includes the organic compounds 541_1 and 541_2 which are a combination for forming the exciplex. The excitation energy for forming the exciplex by the organic compounds 541_1 and 541_2 can be lower than the excitation energy of the organic compound 541_1 in the excited state and lower than the excitation energy of the organic compound 541_2 in the excited state. Therefore, the driving voltage of the light-emitting element can be reduced.

Furthermore, in order to facilitate energy transfer from the S1 level of the exciplex to the T1 level of the guest material 542 having a function of an energy acceptor, it is preferable that the emission spectrum of the exciplex overlap with the absorption band of the guest material 542 which is on the longest wavelength side (low energy side). Thus, the efficiency of generating the triplet excited state of the guest material 542 can be increased.

The exciplex generated in the light-emitting layer 553G has a feature in that the singlet excitation energy level is close to the triplet excitation energy level. Therefore, by overlapping the emission spectrum of the exciplex and the absorption band of the guest material 542 which is on the longest wavelength side (lowest energy side), energy transfer from the triplet excitation energy level of the exciplex to the triplet excitation energy level of the guest material 542 can be facilitated.

When the light-emitting layer 553G has the above-described structure, light emission from the guest material 542 (the phosphorescent material) of the light-emitting layer 553G can be obtained efficiently.

Note that the above-described processes through Routes E₇, E₈, and E₉ may be referred to as exciplex-triplet energy transfer (ExTET) in this specification and the like. In other words, in the light-emitting layer 553G, excitation energy is transferred from the exciplex to the guest material 542. In this case, the efficiency of reverse intersystem crossing from T_{E} to S_{E} and the emission quantum yield from S_{E} are not necessarily high; thus, materials can be selected from a wide range of options.

### <Structure Example 3 of Light-Emitting Element>

A structure example different from the light-emitting layer illustrated in FIGS. 26A to 26D are described below with reference to FIGS. 27A and 27B.

FIG. 27A is a schematic cross-sectional view of the light-emitting layer 553.

As illustrated in FIG. 27A, the light-emitting layer 553 includes the light-emitting layers 553B and 553G. The light-emitting layer 553B contains the host material 531 and the guest material 532. The light-emitting layer 553G contains the host material 541 and the guest material 542. The host material 541 contains the organic compounds 541_1 and 541_2. Note that in the description below, the guest material 532 is a fluorescent material and the guest material 542 is a phosphorescent material.

### <<Light Emission Mechanism of Light-Emitting Layer 553>>

The light emission mechanism of the light-emitting layer 553B is similar to that of the light-emitting layer 553B illustrated in FIGS. 26A and 26B. The light-emitting mechanism of the light-emitting layer 553G is similar to that of the light-emitting layer 553G illustrated in FIGS. 26C and 26D.

As illustrated in FIG. 27A, in the case where the light-emitting layers 553B and 553G are in contact with each other, even when energy is transferred from the exciplex of the light-emitting layer 553G to the host material 531 of the light-emitting layer 553B (in particular, when energy of the triplet excited level is transferred) at an interface between the light-emitting layers 553B and 553G, triplet excitation energy can be converted into light emission in the light-emitting layer 553B.

The T1 level of the host material 531 of the light-emitting layer 553B is preferably lower than T1 levels of the organic compounds 541_1 and 541_2 of the light-emitting layer 553G. In the light-emitting layer 553B, an S1 level of the host material 531 is preferably higher than an S1 level of the guest material 532 (the fluorescent material) while the T1 level of the host material 531 is preferably lower than the T1 level of the guest material 532 (the fluorescent material).

FIG. 27B illustrates a correlation of energy levels in the case where TTA is utilized in the light-emitting layer 553B and ExTET is utilized in the light-emitting layer 553G. The following explains what terms and signs in FIG. 27B represent:

Fluorescence EML (553B): the light-emitting layer 553B (the fluorescent light-emitting layer);

Phosphorescence EML (553G): the light-emitting layer 553G (the phosphorescent light-emitting layer);

Host (531): the host material 531;

Guest (532): the guest material 532 (the fluorescent material);

Host (541_1): a host material (the organic compound 541_1);

Guest (542): the guest material 542 (the phosphorescent material);

Exciplex: an exciplex (the organic compounds 541_1 and 541_2);

S_{FH}: the S1 level of the host material 531;

T_{FH}: the T1 level of the host material 531;

S_{FG}: the S1 level of the guest material 532 (the fluorescent material);

T_{FG}: the T1 level of the guest material 532 (the fluorescent material);

S_{PH}: the S1 level of the host material (the organic compound 541_1);

T_{PH}: the T1 level of the host material (the organic compound 541_1);

T_{PG}: the T1 level of the guest material 542 (the phosphorescent material);

S_{E}: the S1 level of the exciplex; and

T_{E}: the T1 level of the exciplex.

As illustrated in FIG. 27B, the exciplex exists only in an excited state; thus, exciton diffusion between the exciplexes is less likely to occur. In addition, because the excited energy levels of the exciplex (S_{E} and T_{E}) are lower than the excited energy levels of the organic compound 541_1 (i.e., the host material of the phosphorescent material) of the light-emitting layer 553G (S_{PH} and T_{PH}), energy diffusion from the exciplex to the organic compound 541_1 does not occur. That is, emission efficiency of the phosphorescent light-emitting layer (the light-emitting layer 553G) can be maintained because an exciton diffusion distance of the exciplex is short in the phosphorescent light-emitting layer (the light-emitting layer 553G). In addition, even when part of the triplet excitation energy of the exciplex of the phosphorescent light-emitting layer (the light-emitting layer 553G) diffuses into the fluorescent light-emitting layer (the light-emitting layer 553B) through the interface between the fluorescent light-emitting layer (the light-emitting layer 553B) and the phosphorescent light-emitting layer (the light-emitting layer 553G), energy loss can be reduced because the triplet excitation energy in the fluorescent light-emitting layer (the light-emitting layer 553B) caused by the diffusion is converted into light emission through TTA.

The light-emitting element using the light-emitting layer 553 can have high emission efficiency because ExTET is utilized in the light-emitting layer 553G and TTA is utilized in the light-emitting layer 553B as described above so that energy loss is reduced. As in the light-emitting layer 553, in the case where the light-emitting layers 553B and 553G are in contact with each other, the number of organic layers as well as the energy loss can be reduced. Therefore, a light-emitting element with low manufacturing cost can be obtained.

Note that the light-emitting layers 553B and 553G are not necessarily in contact with each other. In that case, it is possible to prevent energy transfer by the Dexter mechanism (particularly triplet energy transfer) from the organic compounds 541_1 and 541_2 in an excited state or the guest material 542 (the phosphorescent material) in an excited state which is generated in the light-emitting layer 553G to the host material 531 or the guest material 532 (the fluorescent material) in the light-emitting layer 553B. Therefore, the thickness of a layer provided between the light-emitting layers 553B and 553G needs several nanometers; specifically, the thickness is preferably greater than or equal to 1 nm and less than or equal to 5 nm, in which case an increase in driving voltage can be suppressed.

The layer provided between the light-emitting layers 553B and 553G may contain a single material or both a hole-transport material and an electron-transport material. In the case of a single material, a bipolar material may be used. The bipolar material here refers to a material in which the ratio between the electron mobility and the hole mobility is 100 or less. Alternatively, the hole-transport material, the electron-transport material, or the like may be used. At least one of materials contained in the layer may be the same as the host material (the organic compound 541_1 or 541_2) of the light-emitting layer 553G. This facilitates the manufacture of the light-emitting element and reduces the drive voltage. Furthermore, the hole-transport material and the electron-transport material may form an exciplex, which effectively prevents exciton diffusion. Specifically, it is possible to prevent energy transfer from the host material (the organic compound 541_1 or 541_2) in an excited state or the guest material 542 (the phosphorescent material) in an excited state of the light-emitting layer 553G to the host material 531 or the guest material 532 (the fluorescent material) in the light-emitting layer 553B.

Note that in the light-emitting layer, a carrier recombination region is preferably distributed to some extent. Therefore, it is preferable that the light-emitting layer 553B or 553G have an appropriate degree of carrier-trapping property. It is particularly preferable that the guest material 542 (the phosphorescent material) in the light-emitting layer 553G have an electron-trapping property. Alternatively, the guest material 532 (fluorescent material) in the light-emitting layer 553B preferably has a hole-trapping property.

Note that light emitted from the light-emitting layer 553B preferably has a peak on the shorter wavelength side than light emitted from the light-emitting layer 553G. The luminance of a light-emitting element using the phosphorescent material emitting light with a short wavelength tends to degrade quickly. In view of the above, fluorescence is used for light emission with a short wavelength, so that a light-emitting element with less degradation of luminance can be provided.

Furthermore, the light-emitting layers 553B and 553G are made to emit light with different emission wavelengths, so that the light-emitting element can be a multicolor light-emitting element. In that case, the emission spectrum is formed by combining light having different emission peaks, and thus has at least two peaks.

The above-described structure is suitable for obtaining white light emission. When the light-emitting layers 553B and 553G emit light of complementary colors, white light emission can be obtained.

In addition, white light emission with a high color rendering property that is formed of three primary colors or four or more colors can be obtained by using a plurality of light-emitting materials emitting light with different wavelengths for one or both of the light-emitting layers 553B and 553G. In that case, the light-emitting layer may be divided into layers and each of the divided layers may contain a different light-emitting material from the others.

<Materials that can be Used in Light-Emitting Layers>

Next, materials that can be used in the light-emitting layers 553B and 553G are described.

<<Materials that can be Used for Light-Emitting Layer 553B>>

In the light-emitting layer 553B, the host material 531 is present in the highest proportion by weight, and the guest material 532 (the fluorescent material) is dispersed in the host material 531. The S1 level of the host material 531 is preferably higher than the S1 level of the guest material 532 (the fluorescent material) while the T1 level of the host material 531 is preferably lower than the T1 level of the guest material 532 (the fluorescent material).

In the light-emitting layer 553B, the guest material 532 is preferably, but not particularly limited to, an anthracene derivative, a tetracene derivative, a chrysene derivative, a phenanthrene derivative, a pyrene derivative, a perylene derivative, a stilbene derivative, an acridone derivative, a coumarin derivative, a phenoxazine derivative, a phenothiazine derivative, or the like, and for example, any of the materials described in Embodiment 1 can be used.

In the light-emitting layer 553B, although a material that can be used as the host material 531 is not particularly limited, for example, any of the materials which are described as examples in Embodiment 1 can be used.

The light-emitting layer 553B can have a structure in which two or more layers are stacked. For example, in the case where the light-emitting layer 553B is formed by stacking a first light-emitting layer and a second light-emitting layer in this order from the hole-transport layer side, the first light-emitting layer is formed using a substance having a hole-transport property as the host material and the second light-emitting layer is formed using a substance having an electron-transport property as the host material.

In the light-emitting layer 553B, the host material 531 may be composed of one kind of compound or a plurality of compounds. The light-emitting layer 553B may include a material other than the host material 531 and the guest material 532.

<<Materials that can be Used for Light-Emitting Layer 553G>>

In the light-emitting layer 553G, the host material 541 is present in the highest proportion by weight, and the guest material 542 (the fluorescent material) is dispersed in the host material 541. The T1 level of the host material 541 (the organic compounds 541_1 and 541_2) of the light-emitting layer 553G is preferably higher than the T1 level of the guest material 542.

Examples of the organic compound 541_1 include a zinc- or aluminum-based metal complex, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, and a phenanthroline derivative. Other examples are an aromatic amine and a carbazole derivative. Specifically, the electron-transport material and the hole-transport material described in Embodiment 1 can be used.

As the organic compound 541_2, a substance which can form an exciplex together with the organic compound 541_1 is preferably used. Specifically, the electron-transport material and the hole-transport material described in Embodiment 1 can be used. In that case, it is preferable that the organic compound 541_1, the organic compound 541_2, and the guest material 542 (phosphorescent material) be selected such that the emission peak of the exciplex formed by the organic compounds 541_1 and 541_2 overlaps with an absorption band, specifically an absorption band on the longest wavelength side, of a triplet metal to ligand charge transfer (MLCT) transition of the guest material 542 (phosphorescent material). This makes it possible to provide a light-emitting element with drastically improved emission efficiency. Note that in the case where a thermally activated delayed fluorescent material is used instead of the phosphorescent material, it is preferable that the absorption band on the longest wavelength side be a singlet absorption band.

As the guest material 542 (phosphorescent material), an iridium-, rhodium-, or platinum-based organometallic complex or metal complex can be used; in particular, an organoiridium complex such as an iridium-based ortho-metalated complex is preferable. As an ortho-metalated ligand, a 4H-triazole ligand, a 1H-triazole ligand, an imidazole ligand, a pyridine ligand, a pyrimidine ligand, a pyrazine ligand, an isoquinoline ligand, and the like can be given. As the metal complex, a platinum complex having a porphyrin ligand and the like can be given. Specifically, the phosphorescent material described in Embodiment 1 can be used.

As the light-emitting material included in the light-emitting layer 553G, any material can be used as long as the material can convert the triplet excitation energy into light emission. As an example of the material that can convert triplet excitation energy into light emission, a thermally activated delayed fluorescence material can be given in addition to a phosphorescent material. Therefore, the term “phosphorescent material” in the description can be replaced with the term “thermally activated delayed fluorescence material”.

The material that exhibits thermally activated delayed fluorescence may be a material that can form a singlet excited state from a triplet excited state by reverse intersystem crossing or may be a combination of a plurality of materials which form an exciplex.

In the case where the material exhibiting thermally activated delayed fluorescence is formed of one kind of material, any of the thermally activated delayed fluorescence materials described in Embodiment 1 can be specifically used.

In the case where the thermally activated delayed fluorescence material is used as the host material, it is preferable to use a combination of two kinds of compounds which form an exciplex. In this case, it is particularly preferable to use the above-described combination of a compound that easily accepts electrons and a compound that easily accepts holes, which forms an exciplex.

There is no limitation on the emission colors of the light-emitting materials contained in the light-emitting layers 553B and 553G, and they may be the same or different. Light emitted from the light-emitting materials is mixed and extracted out of the element; therefore, for example, in the case where their emission colors are complementary colors, the light-emitting element can emit white light. In consideration of the reliability of the light-emitting element, the emission peak wavelength of the light-emitting material contained in the light-emitting layer 553B is preferably shorter than that of the light-emitting material contained in the light-emitting layer 553G.

Note that the light-emitting layers 553B and 553G can be formed by an evaporation method (including a vacuum evaporation method), an ink-jet method, a coating method, gravure printing, or the like.

The structure described in this embodiment can be used in appropriate combination with any of the structures described in the other embodiments and examples.

### Embodiment 3

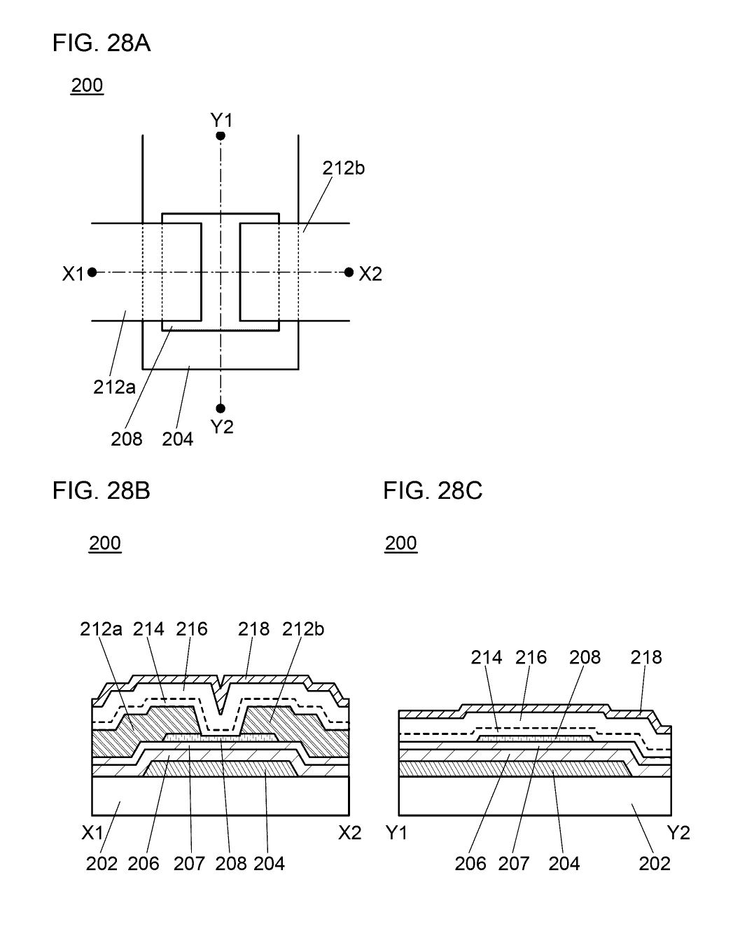

In this embodiment, a transistor that can be used in a display device of one embodiment of the present invention will be described with reference to FIGS. 28A to 28C, FIGS. 29A to 29C, FIGS. 30A to 30D, FIGS. 31A to 31D, FIGS. 32A to 32C, FIGS. 33A to 33C, FIGS. 34A to 34C, FIGS. 35A to 35C, FIGS. 36A to 36F, FIGS. 37A to 37F, FIGS. 38A to 38F, FIGS. 39A and 39B, FIGS. 40A to 40C, FIG. 41, and FIGS. 42A and 42B.

### <Structure Example 1 of Transistor>

FIG. 28A is a top view of a transistor 200 that can be used in a display device of one embodiment of the present invention. FIG. 28B is a cross-sectional view taken along a dashed-dotted line X1-X2 in FIG. 28A. FIG. 28C is a cross-sectional view taken along a dashed-dotted line Y1-Y2 in FIG. 28A. Note that in FIG. 28A, some components of the transistor 200 (e.g., an insulating film functioning as a gate insulating film) are not illustrated to avoid complexity. Furthermore, the direction of the dashed-dotted line X1-X2 may be referred to as a channel length direction, and the direction of the dashed-dotted line Y1-Y2 may be referred to as a channel width direction. As in FIG. 28A, some components are not illustrated in some cases in top views of transistors described below.

The transistor 200 includes a conductive film 204 functioning as a gate electrode over a substrate 202, an insulating film 206 over the substrate 202 and the conductive film 204, an insulating film 207 over the insulating film 206, an oxide semiconductor film 208 over the insulating film 207, a conductive film 212a functioning as a source electrode electrically connected to the oxide semiconductor film 208, and a conductive film 212b functioning as a drain electrode electrically connected to the oxide semiconductor film 208. Over the transistor 200, specifically, over the conductive films 212a and 212b and the oxide semiconductor film 208, an insulating film 214, an insulating film 216, and an insulating film 218 are provided. The insulating films 214, 216, and 218 function as protective insulating films for the transistor 200.

Furthermore, the insulating films 206 and 207 function as gate insulating films of the transistor 200.

Components of the transistor will be described below in detail.

### <<Substrate>>

There is no particular limitation on a material and the like of the substrate 202 as long as the material has heat resistance high enough to withstand at least heat treatment to be performed later. For example, a glass substrate, a ceramic substrate, a quartz substrate, or a sapphire substrate may be used as the substrate 202. Alternatively, a single crystal semiconductor substrate or a polycrystalline semiconductor substrate made of silicon or silicon carbide, a compound semiconductor substrate made of silicon germanium or the like, an SOI substrate, or the like may be used as the substrate 202. Further alternatively, any of these substrates provided with a semiconductor element may be used as the substrate 202. In the case where a glass substrate is used as the substrate 202, a large-area glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured. Such a large-area substrate is preferably used because the manufacturing cost can be reduced.

Alternatively, a flexible substrate may be used as the substrate 202, and the transistor 200 may be provided directly on the flexible substrate. Further alternatively, a separation layer may be provided between the substrate 202 and the transistor 200. The separation layer can be used when part or the whole of a semiconductor device formed over the separation layer is completed and separated from the substrate 202 and transferred to another substrate. In such a case, the transistor 200 can be transferred to a substrate having low heat resistance or a flexible substrate as well.

### <<Conductive Films Functioning as Gate Electrode, Source Electrode, and Drain Electrode>>

The conductive film 204 functioning as a gate electrode, the conductive film 212a functioning as a source electrode, and the conductive film 212b functioning as a drain electrode can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these metal elements; or the like.

The conductive films 204, 212a, and 212b may have a single-layer structure or a stacked-layer structure of two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, and a three-layer structure in which a titanium film, an aluminum film, and a titanium film are stacked in this order can be given. Alternatively, an alloy film or a nitride film in which aluminum and one or more elements selected from titanium, tantalum, tungsten, molybdenum, chromium, neodymium, and scandium are combined may be used.

The conductive films 204, 212a, and 212b can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

A Cu—X alloy film (X is Mn, Ni, Cr, Fe, Co, Mo, Ta, or Ti) may be used for the conductive films 204, 212a, and 212b. Use of a Cu—X alloy film enables the manufacturing cost to be reduced because wet etching process can be used in the processing.

It is especially favorable that the conductive films 204, 212a, and 212b include at least one of titanium, tungsten, tantalum, and molybdenum. When the conductive films 204, 212a, and 212b include at least one of titanium, tungsten, tantalum, and molybdenum, copper in the conductive films 204, 212a, and 212b can be prevented from being diffused to the outside, so that a function of what is called a barrier metal can be obtained.

Furthermore, the conductive films 204, 212a, and 212b preferably include a nitride containing nitrogen and tantalum or a nitride containing nitrogen and titanium. Such a nitride has conductivity and a high barrier property against copper or hydrogen. In addition, a film of such a nitride releases little hydrogen and can be favorably used as a metal in contact with the oxide semiconductor film.

### <<Insulating Film Functioning as Gate Insulating Film>>

As each of the insulating films 206 and 207 functioning as gate insulating films of the transistor 200, an insulating layer including at least one of the following films formed by a plasma-enhanced chemical vapor deposition (PECVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that instead of the stacked-layer structure of the insulating films 206 and 207, an insulating film of a single layer formed using a material selected from the above or an insulating film of three or more layers may be used.

The insulating film 206 functions as a blocking film which inhibits penetration of oxygen. For example, in the case where excess oxygen is supplied to the insulating film 207, the insulating film 214, the insulating film 216, and/or the oxide semiconductor film 208, the insulating film 206 can inhibit penetration of oxygen.

Note that the insulating film 207 that is in contact with the oxide semiconductor film 208 functioning as a channel region of the transistor 200 is preferably an oxide insulating film and preferably includes a region including oxygen in excess of the stoichiometric composition (oxygen-excess region). In other words, the insulating film 207 is an insulating film capable of releasing oxygen. In order to provide the oxygen-excess region in the insulating film 207, the insulating film 207 is formed in an oxygen atmosphere, for example. Alternatively, the oxygen-excess region may be formed by introduction of oxygen into the insulating film 207 after the deposition. As a method for introducing oxygen, an ion implantation method, an ion doping method, a plasma immersion ion implantation method, plasma treatment, or the like may be employed.

In the case where hafnium oxide is used as the insulating film 207, the following effect is attained. Hafnium oxide has a higher dielectric constant than silicon oxide and silicon oxynitride. Therefore, hafnium oxide can reduce the leakage current due to tunnel current because the use of hafnium oxide can increase the thickness of the insulating film 207 as compared with the use of silicon oxide. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited thereto.

In this embodiment, a silicon nitride film is formed as the insulating film 206, and a silicon oxide film is formed as the insulating film 207. The silicon nitride film has a higher dielectric constant than a silicon oxide film and needs a larger thickness for capacitance equivalent to that of the silicon oxide film. Thus, when the silicon nitride film is included as the gate insulating film of the transistor 200, the thickness of the insulating film can be physically increased. This makes it possible to reduce a decrease in withstand voltage of the transistor 200 and furthermore to increase the withstand voltage, thereby reducing electrostatic discharge damage to the transistor 200.

### <<Oxide Semiconductor Film>>

As the oxide semiconductor film 208, an oxide semiconductor can be used. An oxide semiconductor will be described below.

An oxide semiconductor preferably contains at least indium or zinc. In particular, indium and zinc are preferably contained. Furthermore, in addition to these, aluminum, gallium, yttrium, tin, or the like is preferably contained. One or more elements selected from boron, silicon, titanium, iron, nickel, germanium, zirconium, molybdenum, lanthanum, cerium, neodymium, hafnium, tantalum, tungsten, magnesium, and the like may be contained.

Here, the case where an oxide semiconductor contains indium, an element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, and magnesium. Note that two or more of the above elements may be used in combination as the element M.

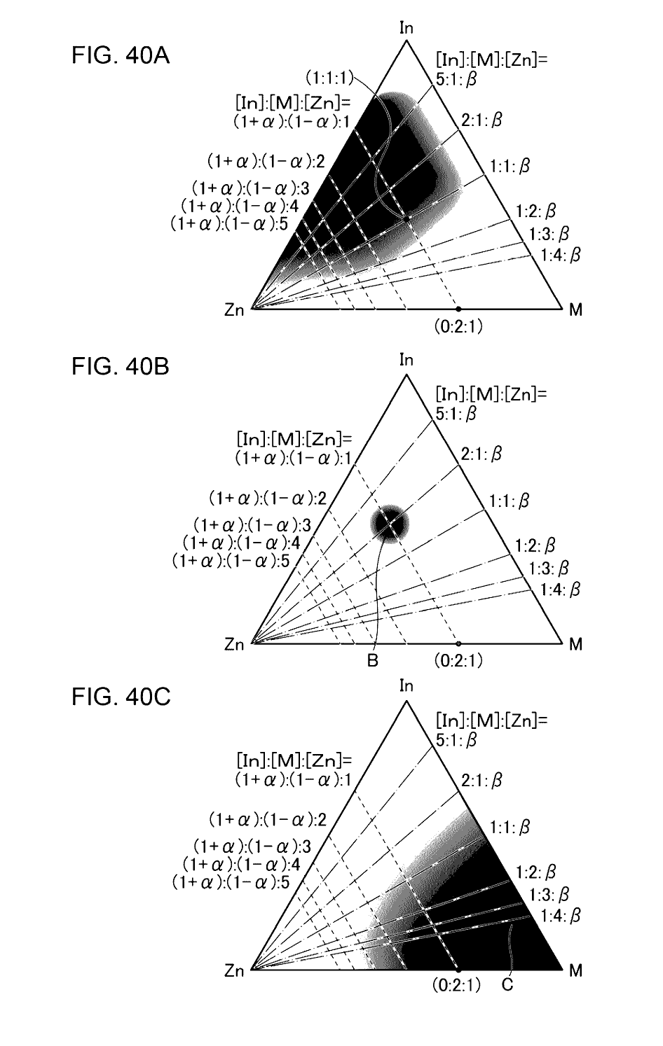

First, preferred ranges of the atomic ratio of indium, the element M, and zinc contained in an oxide semiconductor of one embodiment of the present invention are described with reference to FIGS. 40A to 40C. Note that the proportion of oxygen atoms is not illustrated in FIGS. 40A to 40C. The terms of the atomic ratio of indium, the element M, and zinc contained in the oxide semiconductor are denoted by [In], [M], and [Zn], respectively.

In FIGS. 40A to 40C, broken lines indicate a line where the atomic ratio [In]:[M]:[Zn] is (1+α):(1−α):1, where −1≦α≦1, a line where the atomic ratio [In]:[M]:[Zn] is (1+α):(1−α):2, a line where the atomic ratio [In]:[M]:[Zn] is (1+α):(1−α):3, a line where the atomic ratio [In]:[M]:[Zn] is (1+α):(1−α):4, and a line where the atomic ratio [In]:[M]:[Zn] is (1+α):(1−α):5.

Dashed-dotted lines indicate a line where the atomic ratio [In]:[M]:[Zn] is 1:1:β, where β≧0, a line where the atomic ratio [In]:[M]:[Zn] is 1:2:β, a line where the atomic ratio [In]:[M]:[Zn] is 1:3:β, a line where the atomic ratio [In]:[M]:[Zn] is 1:4:β, a line where the atomic ratio [In]:[M]:[Zn] is 2:1:β, and a line where the atomic ratio [In]:[M]:[Zn] is 5:1:β.

The oxide semiconductor shown in FIGS. 40A to 40C with an atomic ratio of [In]:[M]:[Zn]=0:2:1 or an atomic ratio which is in the neighborhood is likely to have a spinel crystal structure.

FIGS. 40A and 40B illustrate examples of the preferred ranges of the atomic ratio of indium, the element M, and zinc contained in an oxide semiconductor of one embodiment of the present invention.

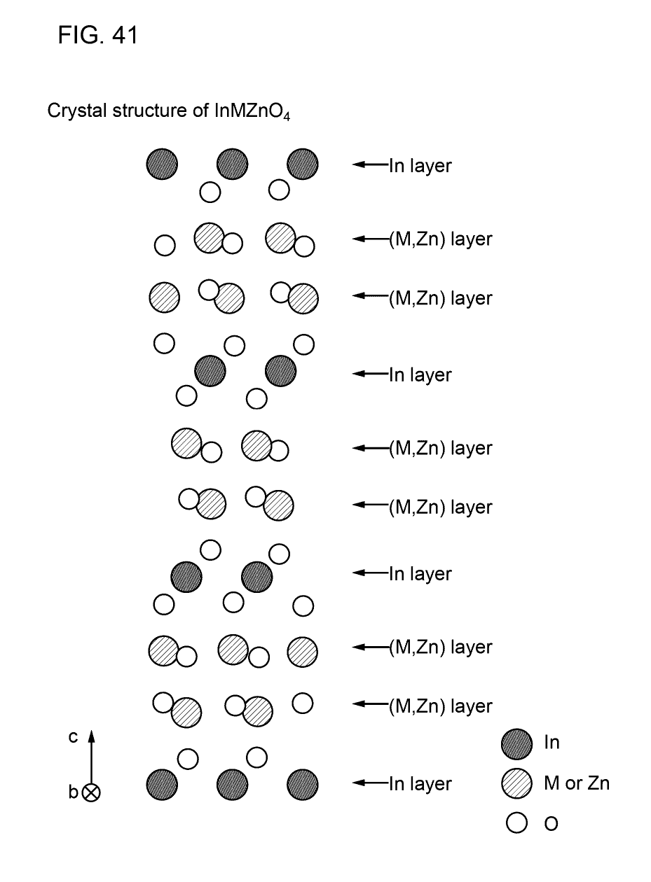

FIG. 41 illustrates an example of the crystal structure of InMZnO₄ whose atomic ratio [In]:[M]:[Zn] is 1:1:1. The crystal structure illustrated in FIG. 41 is InMZnO₄ observed from a direction parallel to a b-axis. Note that a metal element in a layer that contains M, Zn, and oxygen (hereinafter, this layer is referred to as an “(M,Zn) layer”) in FIG. 41 represents the element M or zinc. In that case, the proportion of the element M is the same as the proportion of zinc. The element M and zinc can be replaced with each other, and their arrangement is random.

Note that InMZnO₄ has a layered crystal structure (also referred to as a layered structure) and includes one layer that contains indium and oxygen (hereinafter referred to as an In layer) for every two (M,Zn) layers that contain the element M, zinc, and oxygen, as illustrated in FIG. 41.

Indium and the element M can be replaced with each other. Therefore, when the element M in the (M,Zn) layer is replaced by indium, the layer can also be referred to as an (In,M,Zn) layer. In that case, a layered structure that contains one In layer for every two (In,M,Zn) layers is obtained.

An oxide semiconductor whose atomic ratio [In]:[M]:[Zn] is 1:1:2 has a layered structure that includes one In layer for every three (M,Zn) layers. In other words, if [Zn] is larger than [In] and [M], the proportion of the (M,Zn) layer to the In layer becomes higher when the oxide semiconductor is crystallized.

Note that in the case where the number of (M,Zn) layers for every In layer is not an integer in the oxide semiconductor, the oxide semiconductor might have plural kinds of layered structures where the number of (M,Zn) layers for every In layer is an integer. For example, in the case of [In]:[M]:[Zn]=1:1:1.5, the oxide semiconductor might have the following layered structures: a layered structure of one In layer for every two (M,Zn) layers and a layered structure of one In layer for every three (M,Zn) layers.

For example, in the case where the oxide semiconductor is deposited with a sputtering apparatus, a film having an atomic ratio deviated from the atomic ratio of a target is formed. In particular, [Zn] in the film might be smaller than [Zn] in the target depending on the substrate temperature in deposition.

A plurality of phases (e.g., two phases or three phases) exist in the oxide semiconductor in some cases. For example, with an atomic ratio [In]:[M]:[Zn] that is close to 0:2:1, two phases of a spinel crystal structure and a layered crystal structure are likely to exist. In addition, with an atomic ratio [In]:[M]:[Zn] that is close to 1:0:0, two phases of a bixbyite crystal structure and a layered crystal structure are likely to exist. In the case where a plurality of phases exist in the oxide semiconductor, a grain boundary might be formed between different crystal structures.

In addition, the oxide semiconductor containing indium in a higher proportion can have high carrier mobility (electron mobility). This is because in an oxide semiconductor containing indium, the element M, and zinc, the s orbital of heavy metal mainly contributes to carrier transfer, and when the indium content in the oxide semiconductor is increased, overlaps of the s orbitals of indium atoms are increased; therefore, an oxide semiconductor having a high content of indium has higher carrier mobility than that of an oxide semiconductor having a low content of indium.

In contrast, when the indium content and the zinc content in an oxide semiconductor become lower, carrier mobility becomes lower. Thus, with an atomic ratio of [In]:[M]:[Zn]=0:1:0 and the vicinity thereof (e.g., a region C in FIG. 40C), insulation performance becomes better.

Accordingly, an oxide semiconductor of one embodiment of the present invention preferably has an atomic ratio represented by a region A in FIG. 40A. With the atomic ratio, a layered structure with high carrier mobility and a few grain boundaries is easily obtained.

A region B in FIG. 40B represents an atomic ratio of [In]:[M]:[Zn]=4:2:3 to 4:2:4.1 and the vicinity thereof. The vicinity includes an atomic ratio of [In]:[M]:[Zn]=5:3:4. An oxide semiconductor having an atomic ratio represented by the region B is an excellent oxide semiconductor that has particularly high crystallinity and high carrier mobility.

Note that a condition where an oxide semiconductor has a layered structure is not uniquely determined by an atomic ratio. The atomic ratio affects difficulty in forming a layered structure. Even with the same atomic ratio, whether a layered structure is formed or not depends on a formation condition. Therefore, the illustrated regions each represent an atomic ratio with which an oxide semiconductor has a layered structure, and boundaries of the regions A to C are not clear.

Next, the case where the oxide semiconductor is used for a transistor is described.

Note that when the oxide semiconductor is used for a transistor, carrier scattering or the like at a grain boundary can be reduced; thus, the transistor can have high field-effect mobility. In addition, the transistor can have high reliability.

An oxide semiconductor with low carrier density is preferably used for the transistor. For example, an oxide semiconductor whose carrier density is lower than 8×10¹¹/cm³, preferably lower than 1×10¹¹/cm³ and further preferably lower than 1×10¹⁰/cm³, and higher than or equal to 1×10⁻⁹/cm³ is used.

A highly purified intrinsic or substantially highly purified intrinsic oxide semiconductor has few carrier generation sources and thus can have a low carrier density. The highly purified intrinsic or substantially highly purified intrinsic oxide semiconductor has a low density of defect states and accordingly has a low density of trap states in some cases.

Charge trapped by the trap states in the oxide semiconductor takes a long time to be released and may behave like fixed charge. Thus, a transistor whose channel region is formed in an oxide semiconductor having a high density of trap states has unstable electrical characteristics in some cases.

To obtain stable electrical characteristics of the transistor, it is effective to reduce the concentration of impurities in the oxide semiconductor. In addition, to reduce the concentration of impurities in the oxide semiconductor, the concentration of impurities in a film that is adjacent to the oxide semiconductor is preferably reduced. Examples of impurities include hydrogen, nitrogen, an alkali metal, an alkaline earth metal, iron, nickel, and silicon.

Here, the influence of impurities in the oxide semiconductor is described.

When silicon or carbon that is one of Group 14 elements is contained in the oxide semiconductor, defect states are formed. Thus, the concentration of silicon or carbon in the oxide semiconductor and around an interface with the oxide semiconductor (measured by secondary ion mass spectrometry (SIMS)) is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated, in some cases. Thus, a transistor including an oxide semiconductor that contains an alkali metal or an alkaline earth metal is likely to be normally-on. Therefore, it is preferable to reduce the concentration of an alkali metal or an alkaline earth metal in the oxide semiconductor. Specifically, the concentration of an alkali metal or an alkaline earth metal in the oxide semiconductor measured by SIMS is set lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase of carrier density. Thus, a transistor whose semiconductor includes an oxide semiconductor that contains nitrogen is likely to be normally-on. For this reason, nitrogen in the oxide semiconductor is preferably reduced as much as possible; the nitrogen concentration measured by SIMS is set, for example, lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in an oxide semiconductor reacts with oxygen bonded to a metal atom to be water, and thus causes an oxygen vacancy, in some cases. Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, a transistor including an oxide semiconductor that contains hydrogen is likely to be normally-on. Accordingly, it is preferable that hydrogen in the oxide semiconductor be reduced as much as possible. Specifically, the hydrogen concentration measured by SIMS is set lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurity concentration is used for a channel formation region in a transistor, the transistor can have stable electrical characteristics.

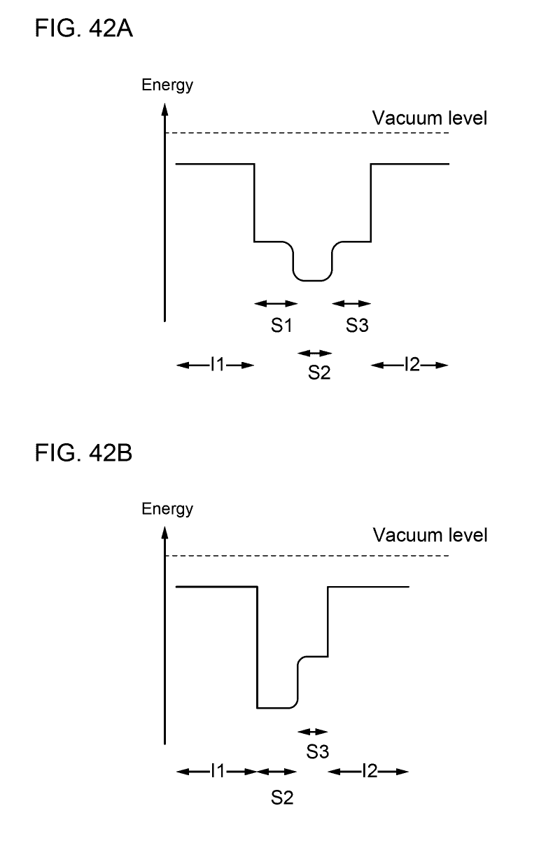

Next, the case where the oxide semiconductor has a two-layer structure or a three-layer structure is described. A band diagram of insulators that are in contact with a stacked-layer structure of an oxide semiconductor S1, an oxide semiconductor S2, and an oxide semiconductor S3 and a band diagram of insulators that are in contact with a stacked-layer structure of the oxide semiconductor S2 and the oxide semiconductor S3 are described with reference to FIGS. 42A and 42B.

FIG. 42A is an example of a band diagram of a stacked-layer structure including an insulator I1, the oxide semiconductor S1, the oxide semiconductor S2, the oxide semiconductor S3, and an insulator I2 in a thickness direction. FIG. 42B is an example of a band diagram of a stacked-layer structure including the insulator I1, the oxide semiconductor S2, the oxide semiconductor S3, and the insulator I2 in a thickness direction. Note that for easy understanding, the band diagrams show the energy level of the conduction band minimum (Ec) of each of the insulator I1, the oxide semiconductor S1, the oxide semiconductor S2, the oxide semiconductor S3, and the insulator I2.

The energy level of the conduction band minimum of each of the oxide semiconductors S1 and S3 is closer to the vacuum level than that of the oxide semiconductor S2. Typically, a difference between the energy level of the conduction band minimum of the oxide semiconductor S2 and the energy level of the conduction band minimum of each of the oxide semiconductors S1 and S3 is preferably greater than or equal to 0.15 eV or greater than or equal to 0.5 eV, and less than or equal to 2 eV or less than or equal to 1 eV. That is, the electron affinity of the oxide semiconductor S2 is higher than the electron affinity of each of the oxide semiconductors S1 and S3, and the difference between the electron affinity of each of the oxide semiconductors S1 and S3 and the electron affinity of the oxide semiconductor S2 is greater than or equal to 0.15 eV or greater than or equal to 0.5 eV, and less than or equal to 2 eV or less than or equal to 1 eV.

As illustrated in FIGS. 42A and 42B, the energy level of the conduction band minimum of each of the oxide semiconductors S1 to S3 is gradually varied. In other words, the energy level of the conduction band minimum is continuously varied or continuously connected. To obtain such a band diagram, the density of defect states in a mixed layer formed at an interface between the oxide semiconductors S1 and S2 or an interface between the oxide semiconductors S2 and S3 is preferably made low.

Specifically, when the oxide semiconductors S1 and S2 or the oxide semiconductors S2 and S3 contain the same element (as a main component) in addition to oxygen, a mixed layer with a low density of defect states can be formed. For example, in the case where the oxide semiconductor S2 is an In—Ga—Zn oxide semiconductor, it is preferable to use an In—Ga—Zn oxide semiconductor, a Ga—Zn oxide semiconductor, gallium oxide, or the like as each of the oxide semiconductors S1 and S3.

At this time, the oxide semiconductor S2 serves as a main carrier path. Since the density of defect states at the interface between the oxide semiconductors S1 and S2 and the interface between the oxide semiconductors S2 and S3 can be made low, the influence of interface scattering on carrier conduction is small, and a high on-state current can be obtained.

When an electron is trapped in a trap state, the trapped electron behaves like fixed charge; thus, the threshold voltage of the transistor is shifted in a positive direction. The oxide semiconductors S1 and S3 can make the trap state apart from the oxide semiconductor S2. This structure can prevent the positive shift of the threshold voltage of the transistor.

A material whose conductivity is sufficiently lower than that of the oxide semiconductor S2 is used for the oxide semiconductors S1 and S3. In that case, the oxide semiconductor S2, the interface between the oxide semiconductors S1 and S2, and the interface between the oxide semiconductors S2 and S3 mainly function as a channel region. For example, an oxide semiconductor with high insulation performance and the atomic ratio represented by the region C in FIG. 40C can be used as the oxide semiconductors S1 and S3. Note that the region C in FIG. 40C represents the atomic ratio of [In]:[M]:[Zn]=0:1:0 or the vicinity thereof.

In the case where an oxide semiconductor having the atomic ratio represented by the region A is used as the oxide semiconductor S2, it is particularly preferable to use an oxide semiconductor with [M]/[In] of greater than or equal to 1, preferably greater than or equal to 2, as each of the oxide semiconductors S1 and S3. In addition, it is suitable to use an oxide semiconductor with sufficiently high insulation performance and [M]/([Zn]+[In]) of greater than or equal to 1 as the oxide semiconductor S3.

### <<Insulating Film Functioning as Protective Insulating Film for Transistor>>

The insulating films 214 and 216 each have a function of supplying oxygen to the oxide semiconductor film 208. The insulating film 218 functions as a protective insulating film for the transistor 200. The insulating films 214 and 216 contain oxygen. Furthermore, the insulating film 214 is an insulating film which is permeable to oxygen. Note that the insulating film 214 functions also as a film which relieves damage to the oxide semiconductor film 208 at the time of forming the insulating film 216 later.

A silicon oxide film, a silicon oxynitride film, or the like with a thickness greater than or equal to 5 nm and less than or equal to 150 nm, preferably greater than or equal to 5 nm and less than or equal to 50 nm, can be used as the insulating film 214.

In addition, it is preferable that the amount of defects in the insulating film 214 be small; as a typical example, the spin density corresponding to a signal that appears at around g=2.001 due to a dangling bond of silicon be lower than or equal to 3×10¹⁷ spins/cm³ by electron spin resonance (ESR) measurement. This is because if the density of defects in the insulating film 214 is high, oxygen is bonded to the defects and the amount of oxygen that passes through the insulating film 214 is decreased.

Note that not all oxygen entering the insulating film 214 from the outside move to the outside of the insulating film 214 and some oxygen remains in the insulating film 214. Furthermore, movement of oxygen occurs in the insulating film 214 in some cases in such a manner that oxygen enters the insulating film 214 and oxygen contained in the insulating film 214 moves to the outside of the insulating film 214. When an oxide insulating film which is permeable to oxygen is formed as the insulating film 214, oxygen released from the insulating film 216 provided over the insulating film 214 can be moved to the oxide semiconductor film 208 through the insulating film 214.

The insulating film 214 can be formed using an oxide insulating film having a low density of states due to nitrogen oxide. Note that the density of states due to nitrogen oxide can be formed between the energy level of the valence band maximum (Eᵥ_{_}ₒₛ) and the energy level of the conduction band minimum (E_{c}_{_}ₒₛ) of the oxide semiconductor film. A silicon oxynitride film that releases less nitrogen oxide, an aluminum oxynitride film that releases less nitrogen oxide, or the like can be used as the oxide insulating film.

Note that a silicon oxynitride film that releases less nitrogen oxide is a film of which the amount of released ammonia is larger than the amount of released nitrogen oxide in thermal desorption spectroscopy analysis; as a typical example, the amount of released ammonia molecules is greater than or equal to 1×10¹⁸ molecules/cm³ and less than or equal to 5×10¹⁹ molecules/cm³. Note that the amount of released ammonia is the amount of ammonia released by heat treatment with which the surface temperature of the film becomes a temperature higher than or equal to 50° C. and lower than or equal to 650° C., preferably higher than or equal to 50° C. and lower than or equal to 550° C.

Nitrogen oxide (NOₓ; x is greater than 0 and less than or equal to 2, preferably greater than or equal to 1 and less than or equal to 2), typified by NO₂ or NO, forms a level in the insulating film 214, for example. The level is positioned in the energy gap of the oxide semiconductor film 208. Therefore, when nitrogen oxide is diffused to the interface between the insulating film 214 and the oxide semiconductor film 208, an electron is in some cases trapped by the level on the insulating film 214 side. As a result, the trapped electron remains in the vicinity of the interface between the insulating film 214 and the oxide semiconductor film 208; thus, the threshold voltage of the transistor is shifted in the positive direction.

Nitrogen oxide reacts with ammonia and oxygen in heat treatment. Since nitrogen oxide contained in the insulating film 214 reacts with ammonia contained in the insulating film 216 in heat treatment, nitrogen oxide contained in the insulating film 214 is reduced. Therefore, an electron is hardly trapped at the interface between the insulating film 214 and the oxide semiconductor film 208.

With such an oxide insulating film, the insulating film 214 can reduce a shift in the threshold voltage of the transistor, which leads to a smaller change in the electrical characteristics of the transistor.

Note that in an ESR spectrum at 100 K or lower of the insulating film 214 subjected to heat treatment of a manufacturing process of the transistor, typically, heat treatment at a temperature lower than 400° C. or lower than 375° C. (preferably higher than or equal to 340° C. and lower than or equal to 360° C.), a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The width of the split between the first and second signals and the width of the split between the second and third signals that are obtained by ESR measurement using an X-band are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is lower than 1×10¹⁸ spins/cm³, typically higher than or equal to 1×10¹⁷ spins/cm³ and lower than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than 0 and less than or equal to 2, preferably greater than or equal to 1 and less than or equal to 2). Typical examples of nitrogen oxide include nitrogen monoxide and nitrogen dioxide. In other words, the smaller the sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is, the lower the content of nitrogen oxide in the oxide insulating film is.

The concentration of nitrogen of the above oxide insulating film measured by SIMS is lower than or equal to 6×10²⁰ atoms/cm³.

The above oxide insulating film is formed by a PECVD method at a substrate temperature higher than or equal to 220° C. and lower than or equal to 350° C. using silane and dinitrogen monoxide, whereby a dense and hard film can be formed.

The insulating film 216 is formed using an oxide insulating film whose oxygen content is higher than that in the stoichiometric composition. Part of oxygen is released by heating from the oxide insulating film whose oxygen content is higher than that in the stoichiometric composition. The oxide insulating film whose oxygen content is higher than that in the stoichiometric composition is an oxide insulating film of which the amount of released oxygen converted into oxygen atoms is greater than or equal to 1.0×10¹⁹ atoms/cm³, preferably greater than or equal to 3.0×10²⁰ atoms/cm³ in thermal desorption spectroscopy (TDS). Note that the surface temperature of the film in the TDS is preferably higher than or equal to 100° C. and lower than or equal to 700° C., or higher than or equal to 100° C. and lower than or equal to 500° C.

A silicon oxide film, a silicon oxynitride film, or the like with a thickness greater than or equal to 30 nm and less than or equal to 500 nm, preferably greater than or equal to 50 nm and less than or equal to 400 nm, can be used as the insulating film 216.

It is preferable that the amount of defects in the insulating film 216 be small; as a typical example, the spin density corresponding to a signal which appears at g=2.001 due to a dangling bond of silicon be lower than 1.5×10¹⁸ spins/cm³, further preferably lower than or equal to 1×10¹⁸ spins/cm³, by ESR measurement. Note that the insulating film 216 is provided more apart from the oxide semiconductor film 208 than the insulating film 214 is; thus, the insulating film 216 may have higher defect density than the insulating film 214.

Furthermore, the insulating films 214 and 216 can be formed using insulating films formed of the same kinds of materials; thus, a boundary between the insulating films 214 and 216 cannot be clearly observed in some cases. Thus, in this embodiment, the boundary between the insulating films 214 and 216 is shown by a dashed line. Although a two-layer structure of the insulating films 214 and 216 is described in this embodiment, the present invention is not limited to this structure. For example, a single-layer structure of either one of the insulating films 214 and 216 may be employed.

The insulating film 218 has a function of blocking oxygen, hydrogen, water, an alkali metal, an alkaline earth metal, or the like. It is possible to prevent outward diffusion of oxygen from the oxide semiconductor film 208, outward diffusion of oxygen included in the insulating films 214 and 216, and entry of hydrogen, water, or the like into the oxide semiconductor film 208 from the outside by providing the insulating film 218.

As the insulating film 218, a nitride insulating film can be used, for example. The nitride insulating film is formed using silicon nitride, silicon nitride oxide, aluminum nitride, aluminum nitride oxide, or the like. Note that instead of the nitride insulating film having a blocking effect against oxygen, hydrogen, water, an alkali metal, an alkaline earth metal, and the like, an oxide insulating film having a blocking effect against oxygen, hydrogen, water, and the like may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, a hafnium oxynitride film, and the like can be given.

### <Structure Example 2 of Transistor>

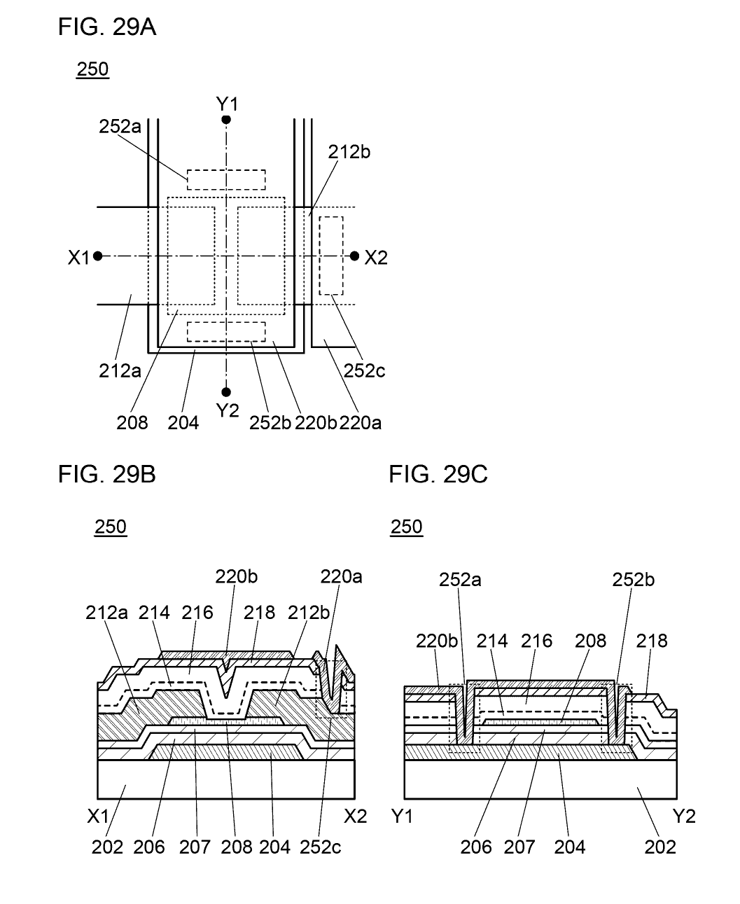

A structure example different from that of the transistor 200 in FIGS. 28A to 28C is described with reference to FIGS. 29A to 29C.

FIG. 29A is a top view of a transistor 250 which can be used in a display device of one embodiment of the present invention. FIG. 29B is a cross-sectional view taken along dashed-dotted line X1-X2 in FIG. 29A, and FIG. 29C is a cross-sectional view taken along dashed-dotted line Y1-Y2 in FIG. 29A.

The transistor 250 includes the conductive film 204 functioning as a first gate electrode over the substrate 202, the insulating film 206 over the substrate 202 and the conductive film 204, the insulating film 207 over the insulating film 206, the oxide semiconductor film 208 over the insulating film 207, the insulating films 214 and 216 over the oxide semiconductor film 208, the conductive film 212a functioning as a source electrode electrically connected to the oxide semiconductor film 208, the conductive film 212b functioning as a drain electrode electrically connected to the oxide semiconductor film 208, the insulating film 218 over the conductive films 212a and 212b and the insulating film 216, and conductive films 220a and 220b over the insulating film 218.

In the transistor 250, the insulating films 214, 216, and 218 function as second gate insulating films of the transistor 250. Furthermore, the conductive film 220a in the transistor 250 functions as, for example, a pixel electrode used for a display device. The conductive film 220a is connected to the conductive film 212b through an opening 252c provided in the insulating films 214, 216, and 218. The conductive film 220b in the transistor 250 functions as a second gate electrode (also referred to as a back gate electrode).

As illustrated in FIG. 29C, the conductive film 220b is connected to the conductive film 204 functioning as the first gate electrode through openings 252a and 252b provided in the insulating films 206, 207, 214, 216, and 218. Accordingly, the conductive film 220b and the conductive film 204 are supplied with the same potential.

Note that although the structure in which the openings 252a and 252b are provided so that the conductive film 220b and the conductive film 204 are connected to each other is described in this embodiment, one embodiment of the present invention is not limited thereto. For example, a structure in which only one of the openings 252a and 252b is provided so that the conductive film 220b and the conductive film 204 are connected to each other, or a structure in which the openings 252a and 252b are not provided and the conductive film 220b and the conductive film 204 are not connected to each other may be employed. Note that in the case where the conductive film 220b and the conductive film 204 are not connected to each other, it is possible to apply different potentials to the conductive film 220b and the conductive film 204.

As illustrated in FIG. 29B, the oxide semiconductor film 208 is positioned to face each of the conductive film 204 functioning as the first gate electrode and the conductive film 220b functioning as the second gate electrode, and is interposed between the two conductive films functioning as gate electrodes. The lengths in the channel length direction and the channel width direction of the conductive film 220b functioning as the second gate electrode are longer than those in the channel length direction and the channel width direction of the oxide semiconductor film 208. The whole oxide semiconductor film 208 is covered with the conductive film 220b with the insulating films 214, 216, and 218 positioned therebetween. Since the conductive film 220b functioning as the second gate electrode is connected to the conductive film 204 functioning as the first gate electrode through the openings 252a and 252b provided in the insulating films 206 and 207 and the insulating films 214, 216, and 218, a side surface of the oxide semiconductor film 208 in the channel width direction faces the conductive film 220b functioning as the second gate electrode with the insulating films 214, 216, and 218 positioned therebetween.

In other words, in the channel width direction of the transistor 250, the conductive film 204 functioning as the first gate electrode and the conductive film 220b functioning as the second gate electrode are connected to each other through the openings provided in the insulating films 206 and 207 functioning as first gate insulating films and the insulating films 214, 216, and 218 functioning as second gate insulating films; and the conductive film 204 and the conductive film 220b surround the oxide semiconductor film 208 with the insulating films 206 and 207 functioning as the first gate insulating films and the insulating films 214, 216, and 218 functioning as the second gate insulating films positioned therebetween.

Such a structure enables the oxide semiconductor film 208 included in the transistor 250 to be electrically surrounded by electric fields of the conductive film 204 functioning as the first gate electrode and the conductive film 220b functioning as the second gate electrode. A device structure of a transistor, like that of the transistor 250, in which electric fields of a first gate electrode and a second gate electrode electrically surround an oxide semiconductor film where a channel region is formed can be referred to as a surrounded channel (s-channel) structure.

Since the transistor 250 has the s-channel structure, an electric field for inducing a channel can be effectively applied to the oxide semiconductor film 208 by the conductive film 204 functioning as the first gate electrode; therefore, the current drive capability of the transistor 250 can be improved and high on-state current characteristics can be obtained. Since the on-state current can be increased, it is possible to reduce the size of the transistor 250. In addition, since the transistor 250 has a structure in which the oxide semiconductor film 208 is surrounded by the conductive film 204 functioning as the first gate electrode and the conductive film 220b functioning as the second gate electrode, the mechanical strength of the transistor 250 can be increased.

### <Structure Example 3 of Transistor>

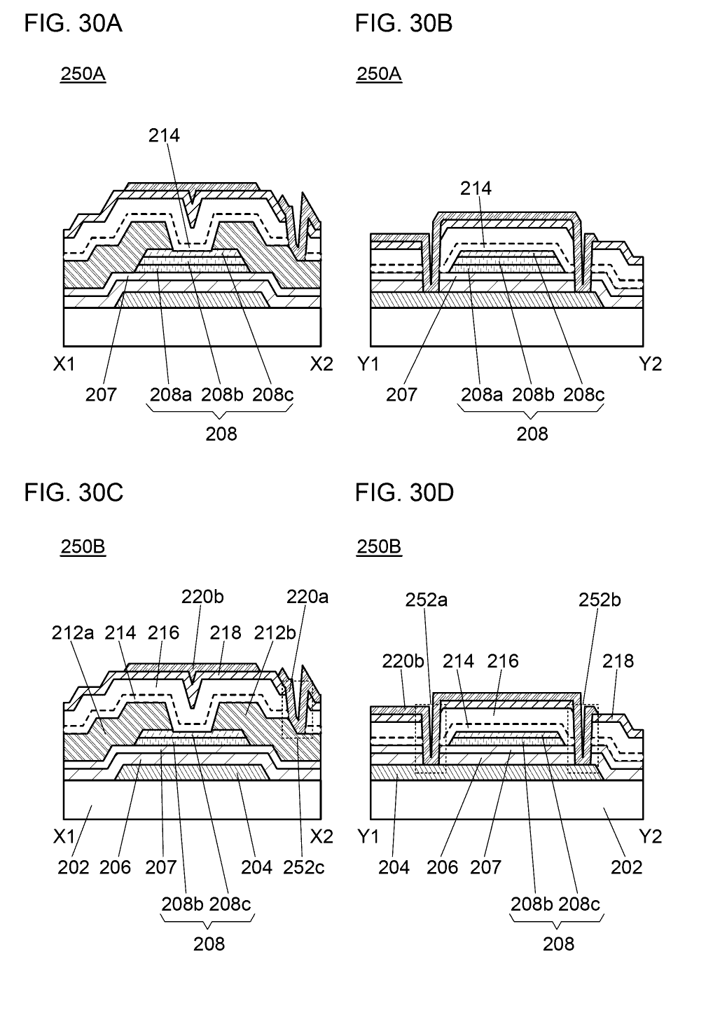

A structure example different from that of the transistor 250 in FIGS. 29A to 29C is described with reference to FIGS. 30A to 30D.

FIGS. 30A and 30B illustrate a cross-sectional view illustrating a variation of the transistor 250 in FIGS. 29B and 29C. FIGS. 30C and 30D illustrate a cross-sectional view illustrating another variation of the transistor 250 in FIGS. 29B and 29C.

A transistor 250A in FIGS. 30A and 30B has the same structure as the transistor 250 in FIGS. 29B and 29C except that the oxide semiconductor film 208 has a three-layer structure. Specifically, the oxide semiconductor film 208 of the transistor 250A includes an oxide semiconductor film 208a, an oxide semiconductor film 208b, and an oxide semiconductor film 208c.

A transistor 250B in FIGS. 30C and 30D has the same structure as the transistor 250 in FIGS. 29B and 29C except that the oxide semiconductor film 208 has a two-layer structure. Specifically, the oxide semiconductor film 208 of the transistor 250B includes the oxide semiconductor film 208b and the oxide semiconductor film 208c.

Here, a band structure including the oxide semiconductor film 208 and insulating films in contact with the oxide semiconductor film 208 is described with reference to FIGS. 42A and 42B. The oxide semiconductor S1, the oxide semiconductor S2, and the oxide semiconductor S3 in FIGS. 42A and 42B correspond to oxide semiconductors which can be used for the oxide semiconductor film 208a, the oxide semiconductor film 208b, and the oxide semiconductor film 208c, respectively. The insulator I1 and the insulator I2 correspond to insulators which can be used for the insulating film 207 and the insulating film 214, respectively.

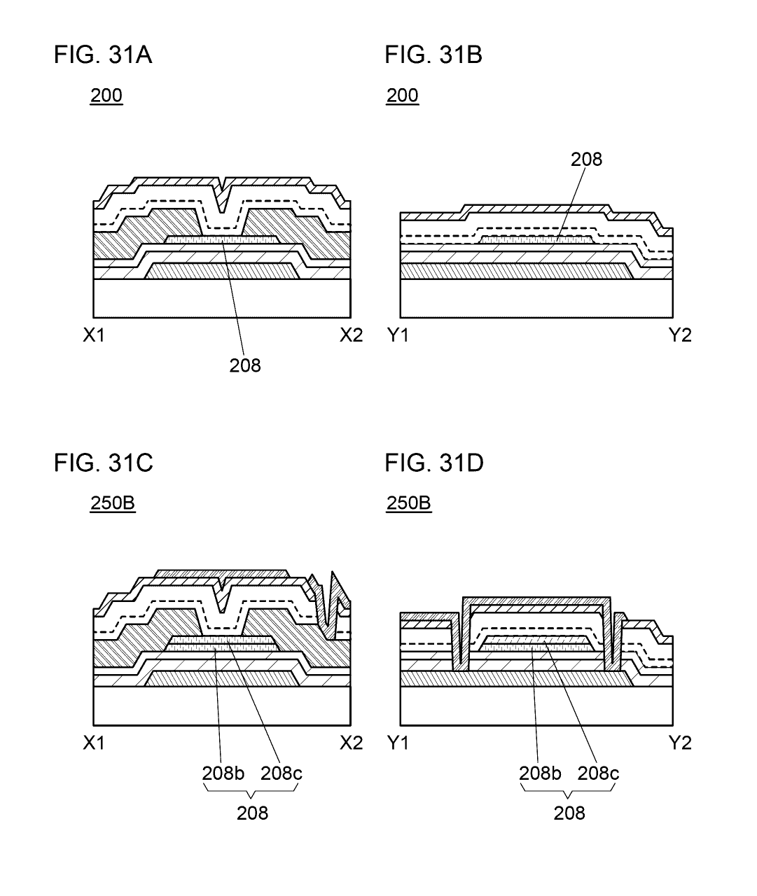

The drawings illustrate an example where the oxide semiconductor film 208 in the transistors 200 and 250 and the oxide semiconductor film 208c in the transistors 250A and 250B have a small thickness in a region which is not covered with the conductive films 212a and 212b, that is, an example where part of the oxide semiconductor film has a depressed portion. However, one embodiment of the present invention is not limited thereto, and the oxide semiconductor film does not necessarily have a depressed portion in a region which is not covered with the conductive films 212a and 212b. FIGS. 31A to 31D illustrate examples in that case. FIGS. 31A to 31D are cross-sectional views illustrating an example of the transistor. FIGS. 31A and 31B illustrate a structure in which the oxide semiconductor film 208 in the transistor 200 does not have a depressed portion, and FIGS. 31C and 31D illustrate a structure in which the oxide semiconductor film 208 in the transistor 250B does not have a depressed portion.

### <Structure Example 4 of Transistor>

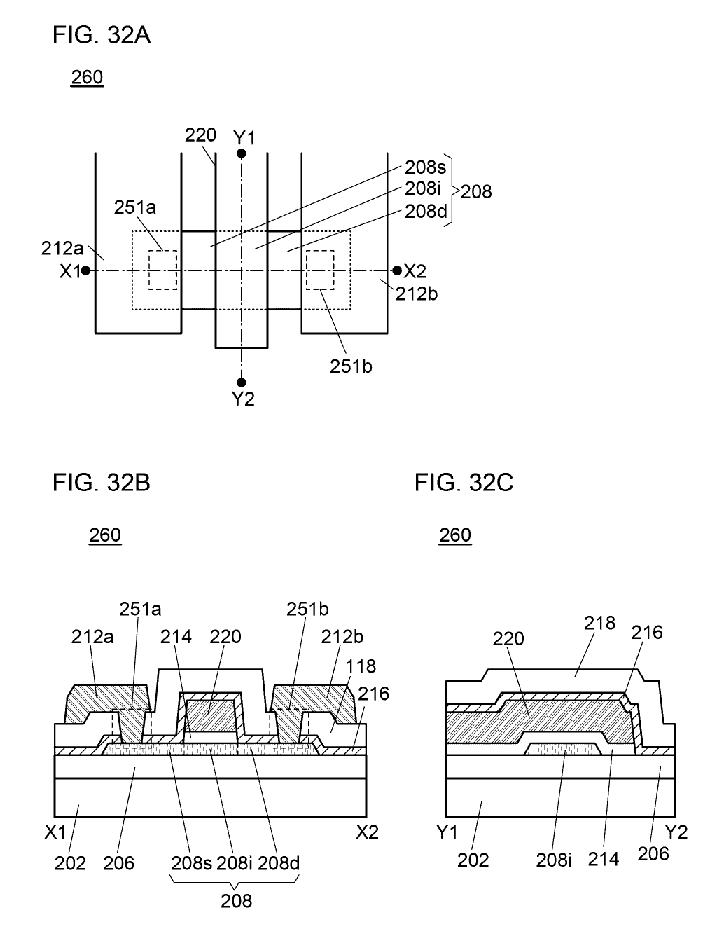

A structure example different from that of the transistor 200 in FIGS. 28A to 28C is described with reference to FIGS. 32A to 32C.

FIG. 32A is a top view of a transistor 260 which can be used in a display device of one embodiment of the present invention. FIG. 32B is a cross-sectional view taken along the dashed dotted line X1-X2 in FIG. 32A. FIG. 32C is a cross-sectional view taken along the dashed dotted line Y1-Y2 in FIG. 32A.

The transistor 260 includes the insulating film 206 over the substrate 202, the oxide semiconductor film 208 over the insulating film 206, the insulating film 214 over the oxide semiconductor film 208, a conductive film 220 functioning as a gate electrode over the insulating film 214, and the insulating film 216 over the insulating film 206, the oxide semiconductor film 208, and the conductive film 220. The oxide semiconductor film 208 has a channel region 208i overlapping with the conductive film 220 and in contact with the insulating film 214, a source region 208s in contact with the insulating film 216, and a drain region 208d in contact with the insulating film 216.

In addition, the transistor 260 includes the insulating film 218 over the insulating film 216, the conductive film 212a electrically connected to the oxide semiconductor film 208 in the source region 208s through an opening 251a provided in the insulating films 216 and 218, and the conductive film 212b electrically connected to the oxide semiconductor film 208 in the drain region 208d through an opening 251b provided in the insulating films 216 and 218.

The transistor 260 preferably has a region in which a side end portion of the insulating film 214 is aligned with a side end portion of the conductive film 220. In other words, in the transistor 260, an upper end portion of the insulating film 214 is substantially aligned with a lower end portion of the conductive film 220. The above structure can be obtained by processing the insulating film 214 with the use of the conductive film 220 as a mask, for example. The other components are the same as those of the transistor 200 and a similar effect can be attained.

### <Structure Example 5 of Transistor>

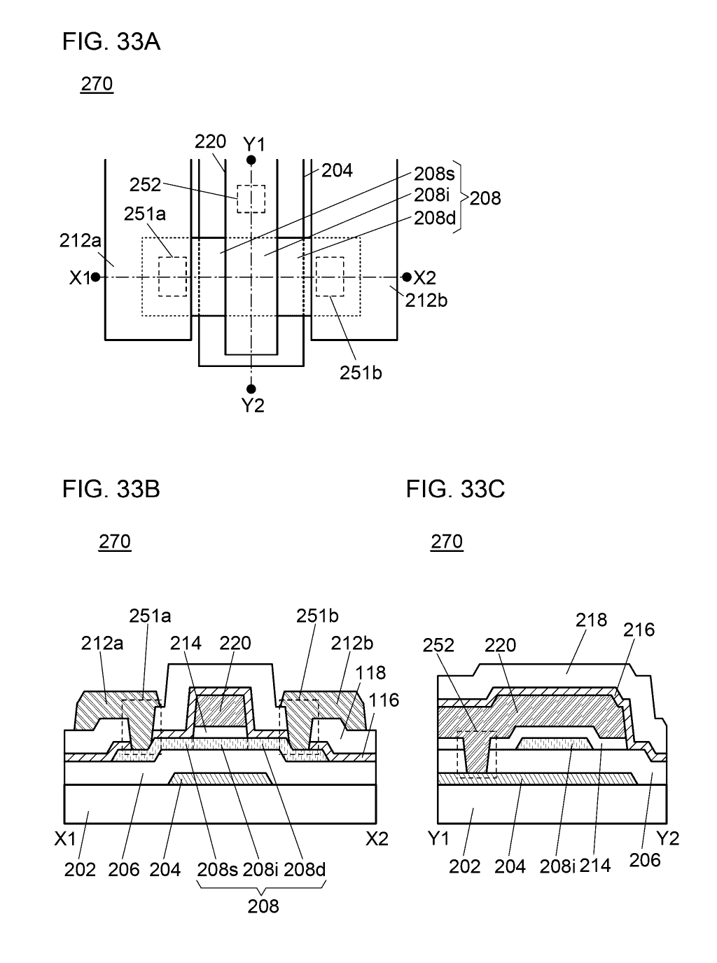

Next, a structure example different from that of the transistor 260 in FIGS. 32A to 32C are described with reference to FIGS. 33A to 33C.

FIG. 33A is a top view of a transistor 270 which can be used in a display device of one embodiment of the present invention. FIG. 33B is a cross-sectional view taken along dashed-dotted line X1-X2 in FIG. 33A, and FIG. 33C is a cross-sectional view taken along dashed-dotted line Y1-Y2 in FIG. 33A.

The transistor 270 includes the conductive film 204 functioning as a first gate electrode (also referred to as bottom gate electrode) over the substrate 202, the insulating film 206 over the substrate 202 and the conductive film 204, the oxide semiconductor film 208 over the insulating film 206, the insulating film 214 over the oxide semiconductor film 208, the conductive film 220 functioning as a second gate electrode (also referred to as top gate electrode) over the insulating film 214, and the insulating film 216 over the insulating film 206, the oxide semiconductor film 208, and the conductive film 220. The oxide semiconductor film 208 has the channel region 208i overlapping with the conductive film 220 and in contact with the insulating film 214, the source region 208s in contact with the insulating film 216, and the drain region 208d in contact with the insulating film 216.

The transistor 270 includes the insulating film 218 over the insulating film 216, the conductive film 212a electrically connected to the oxide semiconductor film 208 in the source region 208s through the opening 251a provided in the insulating films 216 and 218, and the conductive film 212b electrically connected to the oxide semiconductor film 208 in the drain region 208d through the opening 251b provided in the insulating films 216 and 218.

In the transistor 270, the conductive films 204 and 220 are electrically connected through an opening 252 provided in the insulating films 206 and 214. Accordingly, the same potential is applied to the conductive films 204 and 220. In other words, the transistor 270 is a transistor having a surrounded channel (s-channel) structure in which electric fields of a first gate electrode and a second gate electrode electrically surround an oxide semiconductor film where a channel region is formed.

Since the transistor 270 has the s-channel structure, an electric field for inducing a channel can be effectively applied to the oxide semiconductor film 208 by the conductive film 204 functioning as a first gate electrode; therefore, the current drive capability of the transistor 270 can be improved and high on-state current characteristics can be obtained. Since the on-state current can be increased, it is possible to reduce the size of the transistor 270. In addition, since the oxide semiconductor film 208 is surrounded by the conductive film 204 functioning as a first gate electrode and the conductive film 220 functioning as a second gate electrode, the mechanical strength of the transistor 270 can be increased. The other components are the same as those of the transistor 260 and a similar effect can be attained.

### <Structure Example 6 of Transistor>

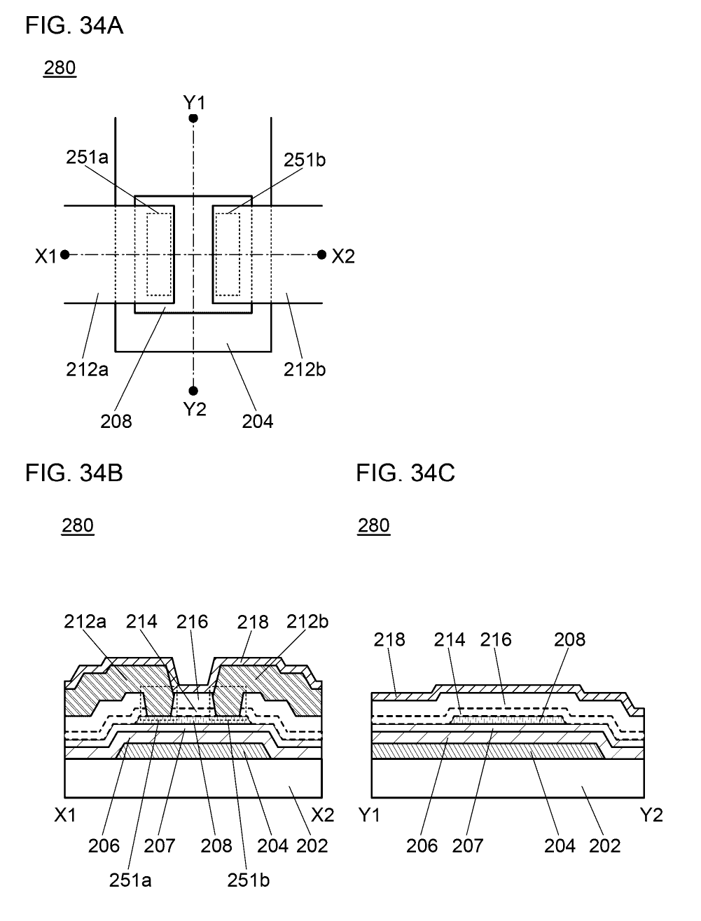

Next, a structure example different from that of the transistor 200 in FIGS. 28A to 28C is described with reference to FIGS. 34A to 34C.

FIG. 34A is a top view of a transistor 280 that can be used in a display device of one embodiment of the present invention. FIG. 34B is a cross-sectional view taken along a dashed-dotted line X1-X2 in FIG. 34A. FIG. 34C is a cross-sectional view taken along a dashed-dotted line Y1-Y2 in FIG. 34A.

The transistor 280 includes the conductive film 204 functioning as a gate electrode over the substrate 202, the insulating film 206 over the substrate 202 and the conductive film 204, the insulating film 207 over the insulating film 206, the oxide semiconductor film 208 over the insulating film 207, the insulating films 214 and 216 over the oxide semiconductor film 208, the conductive film 212a functioning as a source electrode electrically connected to the oxide semiconductor film 208 through the opening 251a provided in the insulating films 214 and 216, and the conductive film 212b functioning as a drain electrode electrically connected to the oxide semiconductor film 208 through the opening 251b provided in the insulating films 214 and 216. Over the transistor 280, specifically over the conductive films 212a and 212b and the insulating film 216, the insulating film 218 is provided. The insulating films 214 and 216 function as protective insulating films for the oxide semiconductor film 208. The insulating film 218 functions as a protective insulating film for the transistor 280.

Although the transistor 200 has a channel-etched structure, the transistor 280 in FIGS. 34A to 34C has a channel-protective structure. In this manner, the oxide semiconductor film of one embodiment of the present invention can be applied to various transistors. The other components are the same as those of the transistor 200 and a similar effect can be attained.

### <Structure Example 7 of Transistor>

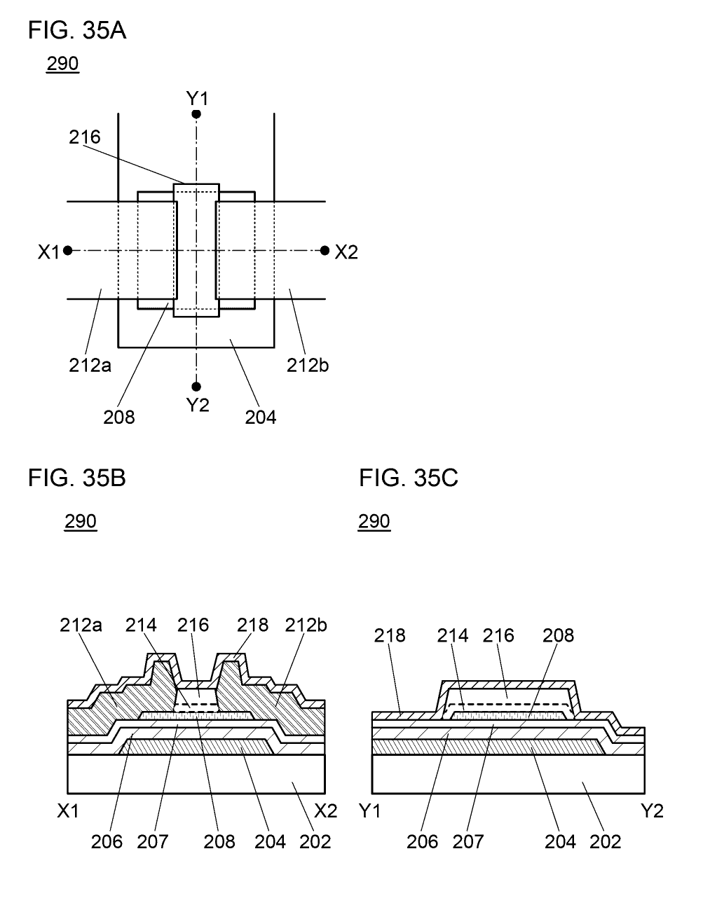

Next, a structure example different from that of the transistor 280 in FIGS. 34A to 34C is described with reference to FIGS. 35A to 35C.

FIG. 35A is a top view of a transistor 290 that can be used in a display device of one embodiment of the present invention. FIG. 35B is a cross-sectional view taken along a dashed-dotted line X1-X2 in FIG. 35A. FIG. 35C is a cross-sectional view taken along a dashed-dotted line Y1-Y2 in FIG. 35A.

The transistor 290 includes the conductive film 204 functioning as a gate electrode over the substrate 202, the insulating film 206 over the substrate 202 and the conductive film 204, the insulating film 207 over the insulating film 206, the oxide semiconductor film 208 over the insulating film 207, the insulating films 214 and 216 over the oxide semiconductor film 208, the conductive film 212a functioning as a source electrode electrically connected to the oxide semiconductor film 208, and the conductive film 212b functioning as a drain electrode electrically connected to the oxide semiconductor film 208. Over the transistor 290, specifically over the conductive films 212a and 212b and the insulating film 216, the insulating film 218 is provided. The insulating films 214 and 216 function as protective insulating films for the oxide semiconductor film 208. The insulating film 218 functions as a protective insulating film for the transistor 290.

The transistor 290 is different from the transistor 280 in FIGS. 34A to 34C in the shape of the insulating films 214 and 216. Specifically, the insulating films 214 and 216 of the transistor 290 have an island shape over a channel region of the oxide semiconductor film 208. The other components are the same as those of the transistor 280 and a similar effect can be attained.

The structures of the transistors of this embodiment can be freely combined with each other.

### <Method for Manufacturing Transistor>

Next, a method for manufacturing the transistor of one embodiment of the present invention is described with reference to drawings.

The films included in the semiconductor device of one embodiment of the present invention (i.e., the conductive film, the insulating film, the oxide semiconductor film, and the like) can be formed by a sputtering method, a chemical vapor deposition (CVD) method, a plasma-enhanced CVD (PECVD) method, a vacuum evaporation method, or a pulsed laser deposition (PLD) method. However, the present invention is not limited thereto, and the films may be formed by a coating method, a printing method, a thermal CVD method, or an atomic layer deposition (ALD) method, for example. By a thermal CVD method such as a metal organic chemical vapor deposition (MOCVD) method, the conductive film, the insulating film, the oxide semiconductor film, and the like may be formed.

A thermal CVD method has an advantage that no defect due to plasma damage is generated because it does not utilize plasma for forming a film.

Deposition by a thermal CVD method may be performed in such a manner that a source gas and an oxidizer are supplied to a chamber at a time while the pressure in the chamber is set to an atmospheric pressure or a reduced pressure, and the source gas and the oxidizer react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced when or after the first source gas is introduced so that the source gases are not mixed, and then a second source gas is introduced. Note that in the case where the first source gas and the inert gas are introduced at a time, the inert gas serves as a carrier gas, and the inert gas may also be introduced at the same time as the second source gas. Alternatively, the first source gas may be exhausted by vacuum evacuation instead of the introduction of the inert gas, and then the second source gas may be introduced. The first source gas is adsorbed on the surface of the substrate to form a first layer; then, the second source gas is introduced to react with the first layer; as a result, a second layer is stacked over the first layer, so that a thin film is formed. The sequence of the gas introduction is repeated a plurality of times until a desired thickness is obtained, whereby a thin film with excellent step coverage can be formed. The thickness of the thin film can be adjusted by the number of repetition times of the sequence of the gas introduction; thus, an ALD method makes it possible to adjust the film thickness accurately and thus is suitable for manufacturing a minute FET.

The above conductive films, insulating films, oxide semiconductor films, the metal oxide films, and the like can be formed by a thermal CVD method such as an MOCVD method. To form an In—Ga—Zn—O film, for example, trimethylindium, trimethylgallium, and dimethylzinc can be used. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium, and diethylzinc (chemical formula: Zn(C₂H₅)₂) can be used instead of dimethylzinc.

For example, in the case where a hafnium oxide film is formed with a deposition apparatus employing ALD, two kinds of gases, i.e., ozone (O₃) as an oxidizer and a source gas which is obtained by vaporizing liquid containing a solvent and a hafnium precursor compound (hafnium alkoxide or hafnium amide such as tetrakis(dimethylamide)hafnium (TDMAH)) are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed with a deposition apparatus employing ALD, two kinds of gases, i.e., H₂O as an oxidizer and a source gas which is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed with a deposition apparatus employing ALD, hexachlorodisilane is adsorbed on the surface where a film is to be formed, chlorine contained in the adsorbate is removed, and radicals of an oxidizing gas (e.g., O₂ or dinitrogen monoxide) are supplied to react with the adsorbate.

For example, in the case where a tungsten film is formed with a deposition apparatus employing an ALD method, a WF₆ gas and a B₂H₆ gas are sequentially introduced a plurality of times to form an initial tungsten film, and then a WF₆ gas and an H₂ gas are sequentially introduced to form a tungsten film. Note that an SiH₄ gas may be used instead of a B₂H₆ gas.

For example, in the case where an oxide semiconductor film, e.g., an In—Ga—Zn—O film is formed with a deposition apparatus employing an ALD method, an In(CH₃)₃ gas and an O₃ gas are sequentially introduced a plurality of times to form an In—O layer, a Ga(CH₃)₃ gas and an O₃ gas are sequentially introduced a plurality of times to form a Ga—O layer, and then a Zn(CH₃)₂ gas and an O₃ gas are sequentially introduced a plurality of times to form a Zn—O layer. Note that the order of these layers is not limited to this example. A mixed compound layer such as an In—Ga—O layer, an In—Zn—O layer, or a Ga—Zn—O layer may be formed by using these gases. Note that although an H₂O gas which is obtained by bubbling water with an inert gas such as Ar may be used instead of an O₃ gas, it is preferable to use an O₃ gas, which does not contain H. Instead of an In(CH₃)₃ gas, an In(C₂H₅)₃ may be used. Instead of a Ga(CH₃)₃ gas, a Ga(C₂H₅)₃ gas may be used. Furthermore, Zn(CH₃)₂ gas may be used.

### <<Method 1 for Manufacturing Transistor>>

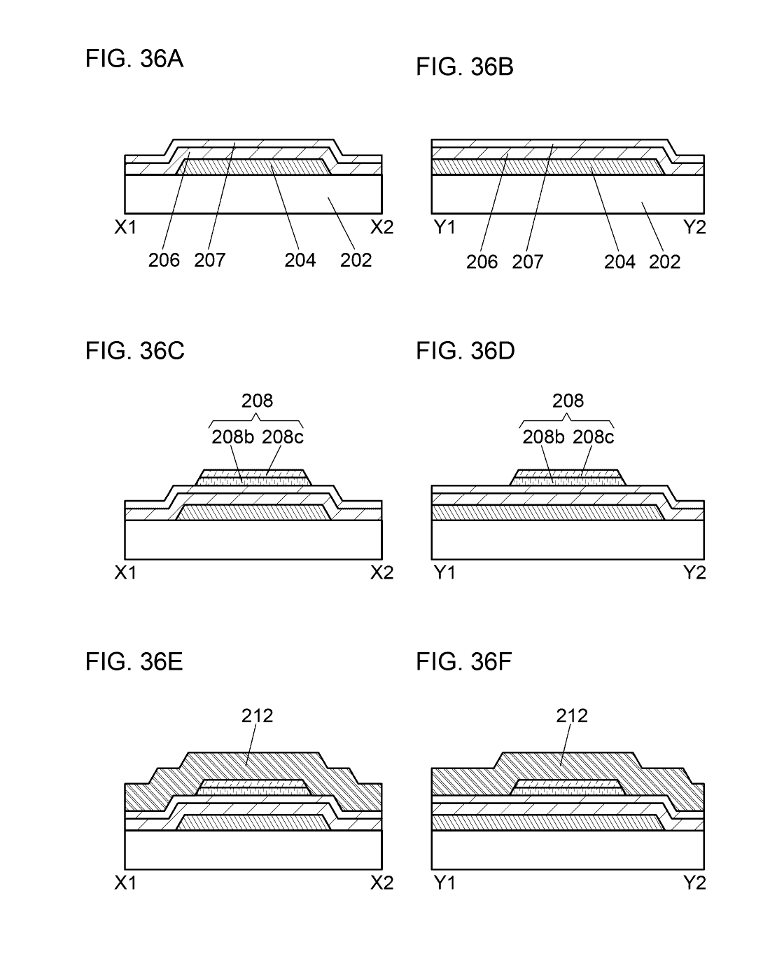

First, a method for manufacturing the transistor 250B that is a transistor of one embodiment of the present invention, which is illustrated in FIGS. 30C and 30D, is described with reference to FIGS. 36A to 36F, FIGS. 37A to 37F, and FIGS. 38A to 38F. FIGS. 36A to 36F, FIGS. 37A to 37F, and FIGS. 38A to 38F are cross-sectional views illustrating a method for manufacturing a semiconductor device. FIGS. 36A, 36C, and 36E, FIGS. 37A, 37C, and 37E, and FIGS. 38A, 38C, and 38E are cross-sectional views in the channel length direction, and FIGS. 36B, 36D, and 36F, FIGS. 37B, 37D, and 37F, and FIGS. 38B, 38D, and 38F are cross-sectional views in the channel width direction.

First, a conductive film is formed over the substrate 202 and processed through a lithography process and an etching process, whereby the conductive film 204 functioning as a gate electrode is formed. Then, the insulating films 206 and 207 functioning as gate insulating films are formed over the conductive film 204 (see FIGS. 36A and 36B).

In this embodiment, a glass substrate is used as the substrate 202, and as the conductive film 204 functioning as a gate electrode, a 100-nm-thick tungsten film is formed by a sputtering method. A 400-nm-thick silicon nitride film as the insulating film 206 and a 50-nm-thick silicon oxynitride film as the insulating film 207 are formed by a PECVD method.

The insulating film 206 can have a stacked-layer structure of silicon nitride films. Specifically, the insulating film 206 can have a three-layer structure of a first silicon nitride film, a second silicon nitride film, and a third silicon nitride film. An example of the three-layer structure can be formed as follows.

For example, the first silicon nitride film can be formed to have a thickness of 50 nm under the conditions where silane at a flow rate of 200 sccm, nitrogen at a flow rate of 2000 sccm, and an ammonia gas at a flow rate of 100 sccm are supplied as a source gas to a reaction chamber of a PECVD apparatus, the pressure in the reaction chamber is controlled to 100 Pa, and a power of 2000 W is supplied using a 27.12 MHz high-frequency power source.

The second silicon nitride film can be formed to have a thickness of 300 nm under the conditions where silane at a flow rate of 200 sccm, nitrogen at a flow rate of 2000 sccm, and an ammonia gas at a flow rate of 2000 sccm are supplied as a source gas to the reaction chamber of the PECVD apparatus, the pressure in the reaction chamber is controlled to 100 Pa, and a power of 2000 W is supplied using a 27.12 MHz high-frequency power source.

The third silicon nitride film can be formed to have a thickness of 50 nm under the conditions where silane at a flow rate of 200 sccm and nitrogen at a flow rate of 5000 sccm are supplied as a source gas to the reaction chamber of the PECVD apparatus, the pressure in the reaction chamber is controlled to 100 Pa, and a power of 2000 W is supplied using a 27.12 MHz high-frequency power source.

Note that the first silicon nitride film, the second silicon nitride film, and the third silicon nitride film can each be formed at a substrate temperature of 350° C. or lower.

When the insulating film 206 has the three-layer structure of silicon nitride films, for example, in the case where a conductive film containing copper (Cu) is used as the conductive film 204, the following effect can be attained.

The first silicon nitride film can inhibit diffusion of a copper (Cu) element from the conductive film 204. The second silicon nitride film has a function of releasing hydrogen and can improve withstand voltage of the insulating film functioning as a gate insulating film. The third silicon nitride film releases a small amount of hydrogen and can inhibit diffusion of hydrogen released from the second silicon nitride film.

The insulating film 207 is preferably an insulating film containing oxygen to improve characteristics of an interface with the oxide semiconductor film 208 (specifically the oxide semiconductor film 208b) formed later.

Next, a stacked-layer film of oxide semiconductors is formed over the insulating film 207 and is processed into a desired shape, so that the island-shaped oxide semiconductor film 208 including the oxide semiconductor films 208b and 208c is formed (see FIGS. 36C and 36D).

The oxide semiconductor film 208 is formed at a temperature higher than or equal to room temperature and lower than 340° C., preferably higher than or equal to room temperature and lower than or equal to 300° C., further preferably higher than or equal to 100° C. and lower than or equal to 250° C., and still further preferably higher than or equal to 100° C. and lower than or equal to 200° C. The oxide semiconductor film 208 is formed while being heated, so that the crystallinity of the oxide semiconductor film 208 can be increased. On the other hand, in the case where a large-sized glass substrate (e.g., the 6th generation to the 10th generation) is used as the substrate 202 and the oxide semiconductor film 208 is formed at a temperature higher than or equal to 150° C. and lower than 340° C., the substrate 202 might be changed in shape (distorted or warped). In the case where a large-sized glass substrate is used, the change in the shape of the glass substrate can be suppressed by forming the oxide semiconductor film 208 at a temperature higher than or equal to 100° C. and lower than 150° C.

The oxide semiconductor films 208b and 208c may be formed at the same substrate temperature or different substrate temperatures. Note that the oxide semiconductor films 208b and 208c are preferably formed at the same substrate temperature, in which case the manufacturing cost can reduced.

In this embodiment, an oxide semiconductor film to be the oxide semiconductor film 208b is deposited by a sputtering method using an In—Ga—Zn metal oxide target (having an atomic ratio of In:Ga:Zn=4:2:4.1), and an oxide semiconductor film to be the oxide semiconductor film 208c is successively deposited in a vacuum by a sputtering method using an In—Ga—Zn metal oxide target (having an atomic ratio of In:Ga:Zn=1:1:1.2). The substrate temperature during the deposition of the oxide semiconductor film to be the oxide semiconductor film 208 is 170° C. Oxygen and argon are used as deposition gases for the oxide semiconductor film to be the oxide semiconductor film 208.

In the case where the oxide semiconductor film is deposited by a sputtering method, as a sputtering gas, a rare gas (typically argon), oxygen, or a mixed gas of a rare gas and oxygen is used as appropriate. In the case of using the mixed gas of a rare gas and oxygen, the proportion of oxygen to a rare gas is preferably increased. In addition, increasing the purity of a sputtering gas is necessary. For example, when a gas which is highly purified to have a dew point of −40° C. or lower, preferably −80° C. or lower, further preferably −100° C. or lower, and still further preferably −120° C. or lower, is used as a sputtering gas, i.e., the oxygen gas or the argon gas, entry of moisture or the like into the oxide semiconductor film can be minimized.

In the case where the oxide semiconductor film is deposited by a sputtering method, the sputtering gas containing oxygen is preferably used. When the oxide semiconductor film is deposited using the sputtering gas containing oxygen, oxygen can be added to a film under the oxide semiconductor (here, the insulating film 207) at the same time as the deposition of the oxide semiconductor film. Therefore, an oxygen-excess region can be provided in the insulating film 207.

In the case where the oxide semiconductor film is deposited by a sputtering method, a chamber in a sputtering apparatus is preferably evacuated to be a high vacuum state (to the degree of about 5×10⁻⁷ Pa to 1×10⁻⁴ Pa) with an adsorption vacuum evacuation pump such as a cryopump in order to remove water or the like, which serves as an impurity for the oxide semiconductor film, as much as possible. Alternatively, a turbo molecular pump and a cold trap are preferably combined so as to prevent a backflow of a gas, especially a gas containing carbon or hydrogen from an exhaust system to the inside of the chamber.

Next, a conductive film 212 to be the source electrode and the drain electrode is formed over the insulating film 207 and the oxide semiconductor film 208 by a sputtering method (see FIGS. 36E and 36F).

In this embodiment, a stacked-layer film in which a 50-nm-thick tungsten film and a 400-nm-thick aluminum film are stacked in this order is formed as the conductive film 212 by a sputtering method. Although the conductive film 212 has a two-layer structure in this embodiment, one embodiment of the present invention is not limited thereto. For example, the conductive film 212 may have a three-layer structure in which a 50-nm-thick tungsten film, a 400-nm-thick aluminum film, and a 100-nm-thick titanium film are stacked in this order.

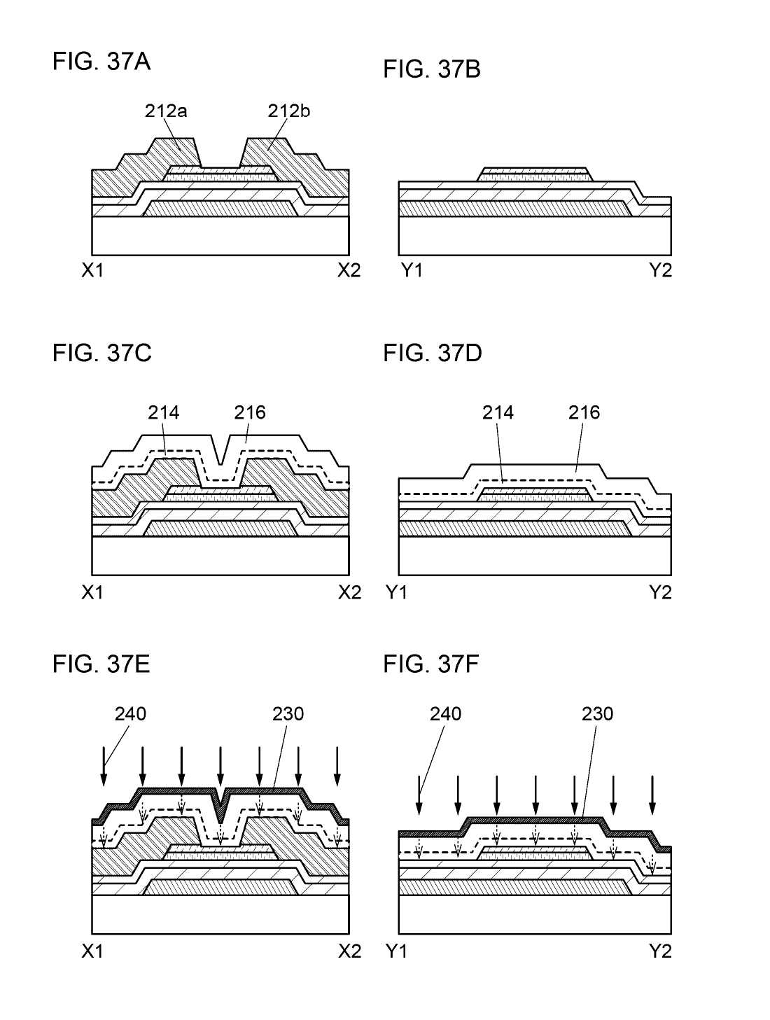

Next, the conductive film 212 is processed into desired shapes, so that the separate conductive films 212a and 212b are formed (see FIGS. 37A and 37B).

In this embodiment, the conductive film 212 is processed with a dry etching apparatus. Note that the method for processing the conductive film 212 is not limited thereto, and a wet etching apparatus may be used, for example. The conductive film 212 can be processed into a finer pattern with a dry etching apparatus than with a wet etching apparatus. On the other hand, the conductive film 212 can be processed at lower manufacturing cost with a wet etching apparatus than with a dry etching apparatus.

After the conductive films 212a and 212b are formed, a surface (on the back channel side) of the oxide semiconductor film 208 (specifically, the oxide semiconductor film 208c) may be cleaned. The cleaning may be performed, for example, using a chemical solution such as phosphoric acid. The cleaning using a chemical solution such as a phosphoric acid can remove impurities (e.g., an element included in the conductive films 212a and 212b) attached to the surface of the oxide semiconductor film 208c. Note that the cleaning is not necessarily performed; in some cases, the cleaning does not need to be performed.

In the step of forming the conductive films 212a and 212b and/or the cleaning step, the thickness of a region of the oxide semiconductor film 208 which is not covered by the conductive films 212a and 212b might be reduced. For example, a region where the oxide semiconductor film 208c has a smaller thickness than the oxide semiconductor film 208b is formed in some cases.

Next, the insulating films 214 and 216 are formed over the oxide semiconductor film 208 and the conductive films 212a and 212b (see FIGS. 37C and 37D).

Note that after the insulating film 214 is formed, the insulating film 216 is preferably formed in succession without exposure to the air. After the insulating film 214 is formed, the insulating film 216 is formed in succession without exposure to the air while at least one of the flow rate of a source gas, pressure, a high-frequency power, and a substrate temperature is adjusted, whereby the concentration of impurities attributed to the atmospheric component at the interface between the insulating films 214 and 216 can be reduced and oxygen in the insulating films 214 and 216 can be moved to the oxide semiconductor film 208; accordingly, the amount of oxygen vacancies in the oxide semiconductor film 208 can be reduced.

As the insulating film 214, a silicon oxynitride film can be formed by a PECVD method, for example. In this case, a deposition gas containing silicon and an oxidizing gas are preferably used as a source gas. Typical examples of the deposition gas containing silicon include silane, disilane, trisilane, and silane fluoride. Examples of the oxidizing gas include dinitrogen monoxide and nitrogen dioxide. An insulating film containing nitrogen and having a small amount of defects can be formed as the insulating film 214 by a PECVD method under the conditions where the flow rate of the oxidizing gas is higher than 20 times and lower than 100 times, preferably higher than or equal to 40 times and lower than or equal to 80 times, that of the deposition gas; and the pressure in a treatment chamber is lower than 100 Pa, preferably lower than or equal to 50 Pa.

In this embodiment, a silicon oxynitride film is formed as the insulating film 214 by a PECVD method under the conditions where the substrate 202 is held at a temperature of 220° C., silane at a flow rate of 50 sccm and dinitrogen monoxide at a flow rate of 2000 sccm are used as a source gas, the pressure in the treatment chamber is 20 Pa, and a high-frequency power of 100 W at 13.56 MHz (1.6×10⁻² W/cm² as the power density) is supplied to parallel-plate electrodes.

As the insulating film 216, a silicon oxide film or a silicon oxynitride film is formed under the following conditions: the substrate placed in a treatment chamber of the PECVD apparatus that is vacuum-evacuated is held at a temperature higher than or equal to 180° C. and lower than or equal to 350° C.; the pressure is greater than or equal to 100 Pa and less than or equal to 250 Pa, preferably greater than or equal to 100 Pa and less than or equal to 200 Pa with introduction of a source gas into the treatment chamber; and a high-frequency power of greater than or equal to 0.17 W/cm² and less than or equal to 0.5 W/cm², preferably greater than or equal to 0.25 W/cm² and less than or equal to 0.35 W/cm², is supplied to an electrode provided in the treatment chamber.

As the deposition conditions of the insulating film 216, the high-frequency power having the above power density is supplied to a reaction chamber having the above pressure, whereby the decomposition efficiency of the source gas in plasma is increased, oxygen radicals are increased, and oxidation of the source gas is promoted; thus, the oxygen content in the insulating film 216 becomes higher than that in the stoichiometric composition. In addition, in the film formed at a substrate temperature within the above temperature range, the bond between silicon and oxygen is weak, and accordingly, part of oxygen in the film is released by heat treatment in a later step. Thus, it is possible to form an oxide insulating film whose oxygen content is higher than that in the stoichiometric composition and from which part of oxygen is released by heating.

Note that the insulating film 214 functions as a protective film for the oxide semiconductor film 208 in the step of forming the insulating film 216. Therefore, the insulating film 216 can be formed using the high-frequency power having a high power density while damage to the oxide semiconductor film 208 is reduced.

Note that in the deposition conditions of the insulating film 216, when the flow rate of the deposition gas containing silicon with respect to the oxidizing gas is increased, the amount of defects in the insulating film 216 can be reduced. As a typical example, it is possible to form an oxide insulating layer in which the amount of defects is small, i.e., the spin density corresponding to a signal which appears at g=2.001 due to a dangling bond of silicon is lower than 6×10¹⁷ spins/cm³, preferably lower than or equal to 3×10¹⁷ spins/cm³ and further preferably lower than or equal to 1.5×10¹⁷ spins/cm³, by ESR measurement. As a result, the reliability of the transistor can be improved.

Heat treatment (hereinafter referred to as first heat treatment) is preferably performed after the insulating films 214 and 216 are formed. The first heat treatment can reduce nitrogen oxide contained in the insulating films 214 and 216. By the first heat treatment, part of oxygen contained in the insulating films 214 and 216 can be moved to the oxide semiconductor film 208, so that the amount of oxygen vacancies included in the oxide semiconductor film 208 can be reduced.

The temperature of the first heat treatment is typically lower than 400° C., preferably lower than 375° C., and further preferably higher than or equal to 150° C. and lower than or equal to 350° C. The first heat treatment may be performed under an atmosphere of nitrogen, oxygen, ultra-dry air (air with a water content of 20 ppm or less, preferably 1 ppm or less, and further preferably 10 ppb or less), or a rare gas (argon, helium, or the like). Note that an electric furnace, a rapid thermal annealing (RTA) apparatus, or the like can be used for the first heat treatment, in which it is preferable that hydrogen, water, and the like not be contained in the atmosphere of nitrogen, oxygen, ultra-dry air, or a rare gas.

Next, a barrier film 230 is formed over the insulating film 216, and oxygen 240 is added to the insulating film 216, the insulating film 214, or the oxide semiconductor film 208 through the barrier film 230 (see FIGS. 37E and 37F).

In FIGS. 37E and 37F, oxygen added to the insulating film 214 or 216 is schematically shown by arrows of broken lines.

The barrier film 230 is permeable to oxygen and inhibits release of oxygen. The barrier film 230 includes, for example, oxygen and a metal (at least one element selected from indium, zinc, titanium, aluminum, tungsten, tantalum, molybdenum, hafnium, and yttrium). In particular, the barrier film 230 preferably includes ITO, ITSO, or indium oxide because an uneven surface can be favorably covered with such a material. Alternatively, as the barrier film 230, the above-described oxide semiconductor (having an atomic ratio of In:Ga:Zn=1:1:1, In:Ga:Zn=1:3:2, In:Ga:Zn=1:3:4, In:Ga:Zn=1:3:6, In:Ga:Zn=3:1:2, In:Ga:Zn=4:2:3, for example) may be used.

The barrier film 230 can be formed by a sputtering method. When the barrier film 230 is thin, oxygen release from the insulating film 216 to the outside is difficult to suppress in some cases. On the other hand, when the barrier film 230 is thick, oxygen cannot be favorably added to the insulating film 216 in some cases. Accordingly, the thickness of the barrier film 230 is preferably greater than or equal to 1 nm and less than or equal to 20 nm, or greater than or equal to 2 nm and less than or equal to 10 nm. In this embodiment, the barrier film 230 is a 5-nm-thick ITSO film.

Examples of the method for adding the oxygen 240 to the insulating film 216 through the barrier film 230 include an ion doping method, an ion implantation method, and a plasma treatment method. Depending on the apparatus or conditions for adding the oxygen 240, the oxygen 240 can be added to the insulating film 214 or the oxide semiconductor film 208 under the insulating film 216 in some cases. As the oxygen 240, excess oxygen, an oxygen radical, or the like can be used. The oxygen 240 can be effectively added to the insulating film 216 by application of a bias to the substrate side. With the use of an ashing apparatus, for example, power density of the bias voltage applied to the ashing apparatus may be greater than or equal to 1 W/cm² and less than or equal to 5 W/cm². By providing the barrier film 230 over the insulating film 216 and adding the oxygen 240, the barrier film 230 functions as a protective film for inhibiting release of oxygen from the insulating film 216. Thus, a larger amount of oxygen can be added to the insulating film 216.

After the oxygen 240 is added to the insulating film 216 through the barrier film 230, heat treatment (hereinafter referred to as second heat treatment) may be performed. The second heat treatment can be performed under conditions similar to those of the first heat treatment.

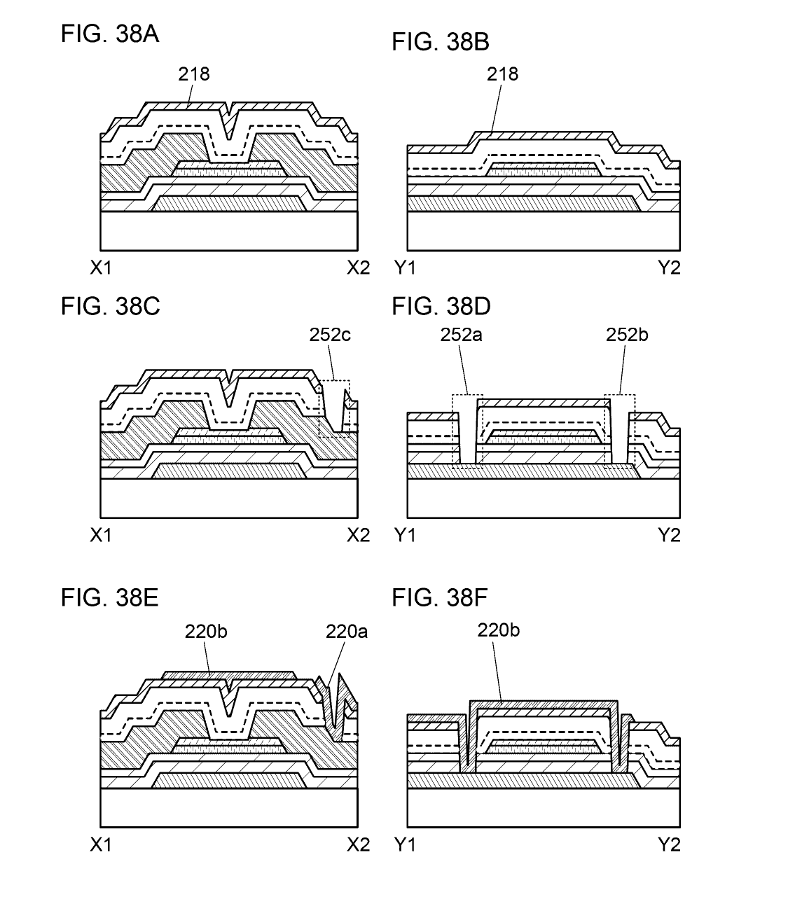

Next, the barrier film 230 is removed to expose a surface of the insulating film 216, and then, the insulating film 218 is formed over the insulating film 216 (see FIGS. 38A and 38B).

When the barrier film 230 is removed, part of the insulating film 216 is also removed in some cases. A method for removing the barrier film 230 is, for example, a dry etching method, a wet etching method, or a combination of a dry etching method and a wet etching method. In this embodiment, a wet etching method is used to remove the barrier film 230. A wet etching method is preferably used as the method for removing the barrier film 230 because of low manufacturing cost.

The insulating film 218 can be formed by a sputtering method or a PECVD method, for example. In the case where the insulating film 218 is formed by a PECVD method, for example, the substrate temperature is lower than 400° C., preferably lower than 375° C., and further preferably higher than or equal to 180° C. and lower than or equal to 350° C. The substrate temperature at which the insulating film 218 is formed is preferably within the above range because a dense film can be formed. Furthermore, when the substrate temperature at which the insulating film 218 is formed is within the above range, oxygen or excess oxygen in the insulating films 214 and 216 can be moved to the oxide semiconductor film 208.

After the insulating film 218 is formed, heat treatment similar to the second heat treatment (hereinafter referred to as third heat treatment) may be performed. Through such heat treatment at lower than 400° C., preferably lower than 375° C., and further preferably higher than or equal to 180° C. and lower than or equal to 350° C., after the addition of the oxygen 240 to the insulating film 216, oxygen or excess oxygen in the insulating film 216 can be moved to the oxide semiconductor film 208 (particularly, the oxide semiconductor film 208b) to fill oxygen vacancies in the oxide semiconductor film 208.

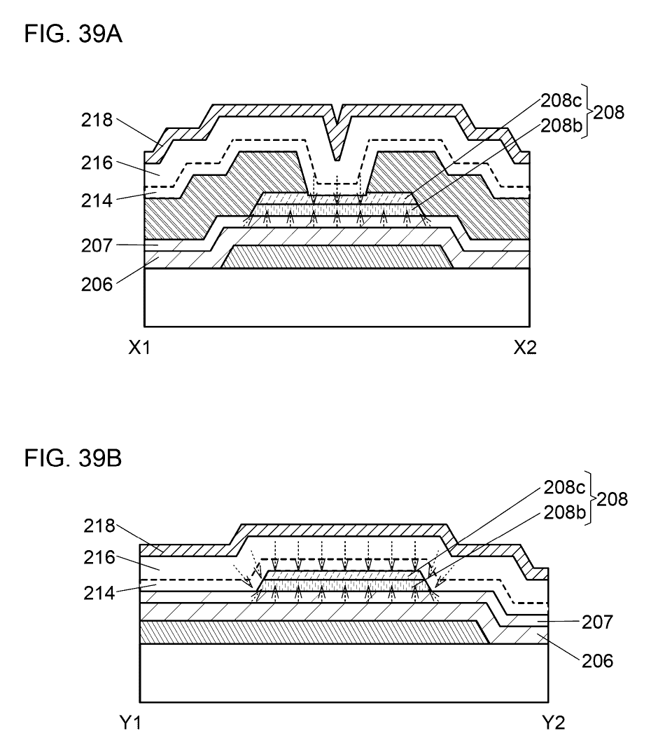

Oxygen moved into the oxide semiconductor film 208 is described with reference to FIGS. 39A and 39B. FIG. 39A is a cross-sectional view in the channel length direction, and FIG. 39B is a cross-sectional view in the channel width direction. FIGS. 39A and 39B are model diagrams illustrating oxygen moved into the oxide semiconductor film 208 due to the substrate temperature at the time of forming the insulating film 218 (typically, lower than 375° C.) or the third heat treatment after the formation of the insulating film 218 (typically, lower than 375° C.). In FIGS. 39A and 39B, oxygen (oxygen radicals, oxygen atoms, or oxygen molecules) moved into the oxide semiconductor film 208 is shown by arrows of broken lines.

In the oxide semiconductor film 208 in FIGS. 39A and 39B, oxygen vacancies are filled with oxygen moved from films in contact with the oxide semiconductor film 208 (here, the insulating film 207 and the insulating film 214). Specifically, in the transistor of one embodiment of the present invention, the insulating film 207 includes an oxygen-excess region because an oxygen gas is used at the time of forming the oxide semiconductor film 208 by sputtering and oxygen is added to the insulating film 206. Since oxygen is added through the barrier film 230, the insulating films 214 and 216 also include an oxygen-excess region. In the oxide semiconductor film 208 between the insulating films including the oxygen-excess regions, oxygen vacancies can be favorably filled.

Furthermore, the insulating film 206 is provided under the insulating film 207, and the insulating film 218 is provided over the insulating films 214 and 216. When the insulating films 206 and 218 are formed using a material having low oxygen permeability, for example, silicon nitride, oxygen contained in the insulating films 207, 214, and 216 can be confined to the oxide semiconductor film 208 side; thus, oxygen can be favorably moved to the oxide semiconductor film 208.

In the case where a silicon nitride film is formed by a PECVD method as the insulating film 218, a deposition gas containing silicon, nitrogen, and ammonia are preferably used as a source gas. As the source gas, a small amount of ammonia compared to the amount of nitrogen is used, whereby ammonia is dissociated in the plasma and activated species are generated. The activated species cut a bond between silicon and hydrogen which are contained in a deposition gas containing silicon and a triple bond between nitrogen molecules. As a result, a dense silicon nitride film having few defects, in which bonds between silicon and nitrogen are promoted and bonds between silicon and hydrogen are few, can be formed. On the other hand, when the amount of ammonia with respect to nitrogen is large, decomposition of a deposition gas containing silicon and decomposition of nitrogen are not promoted, so that a sparse silicon nitride film in which bonds between silicon and hydrogen remain and defects are increased is formed. Therefore, in a source gas, the flow rate of nitrogen is set to be preferably 5 times or more and 50 times or less, and further preferably 10 times or more and 50 times or less, the flow rate of ammonia.

In this embodiment, with the use of a PECVD apparatus, a 50-nm-thick silicon nitride film is formed as the insulating film 218 using silane, nitrogen, and ammonia as a source gas. The flow rate of silane is 50 sccm, the flow rate of nitrogen is 5000 sccm, and the flow rate of ammonia is 100 sccm. The pressure in the treatment chamber is 100 Pa, the substrate temperature is 350° C., and a high-frequency power of 1000 W is supplied to parallel-plate electrodes with a 27.12 MHz high-frequency power source. The PECVD apparatus is a parallel-plate PECVD apparatus in which the electrode area is 6000 cm², and the power per unit area (power density) into which the supplied power is converted is 1.7×10⁻¹ W/cm².

Next, a mask is formed over the insulating film 218 through a lithography process, and the opening 252c is formed in a desired region in the insulating films 214, 216, and 218. In addition, a mask is formed over the insulating film 218 through a lithography process, and the openings 252a and 252b are formed in desired regions in the insulating films 206, 207, 214, 216, and 218. Note that the opening 252c reaches the conductive film 212b. The openings 252a and 252b reach the conductive film 204 (see FIGS. 38C and 38D).

Note that the openings 252a and 252b and the opening 252c may be formed in the same step or may be formed by different steps. In the case where the openings 252a and 252b and the opening 252c are formed in the same step, for example, a gray-tone mask or a half-tone mask can be used. Moreover, the openings 252a and 252b may be formed in a plurality of steps. For example, openings are formed in the insulating films 206 and 207 in advance, and then, openings are formed in the insulating films 214, 216, and 218 over the openings.

Next, a conductive film is formed over the insulating film 218 to cover the openings 252a, 252b, and 252c and processed into desired shapes, so that the conductive films 220a and 220b are formed (see FIGS. 38E and 38F).

For the conductive film to be the conductive films 220a and 220b, for example, a material including one of indium (In), zinc (Zn), and tin (Sn) can be used. In particular, for the conductive films 220a and 220b, a light-transmitting conductive material such as indium oxide containing tungsten oxide, indium zinc oxide containing tungsten oxide, indium oxide containing titanium oxide, indium tin oxide containing titanium oxide, ITO, indium zinc oxide, or ITSO can be used. Moreover, the conductive film to be the conductive films 220a and 220b can be formed by a sputtering method, for example. In this embodiment, a 110-nm-thick ITSO film is formed by a sputtering method.

Through the above process, the transistor 250B illustrated in FIGS. 30C and 30D can be manufactured.

In the entire manufacturing process of the transistor 250B, the substrate temperature is preferably lower than 400° C., further preferably lower than 375° C., and still further preferably higher than or equal to 180° C. and lower than or equal to 350° C., because a change in shape of the substrate (distortion or warp) can be reduced even when a large-sized substrate is used. Typical examples of high substrate temperatures in the manufacturing process of the transistor 250B are as follows: the substrate temperature at the time of forming the insulating films 206 and 207 (lower than 400° C., preferably higher than or equal to 250° C. and lower than or equal to 350° C.), the substrate temperature at the time of forming the oxide semiconductor film 208 (higher than or equal to room temperature and lower than 340° C., preferably higher than or equal to 100° C. and lower than or equal to 200° C., and further preferably higher than or equal to 100° C. and lower than 150° C.), the substrate temperature at the time of forming the insulating films 216 and 218 (lower than 400° C., preferably lower than 375° C., and further preferably higher than or equal to 180° C. and lower than or equal to 350° C.), and the temperature at the time of the first heat treatment or the second heat treatment after the addition of the oxygen 240 (lower than 400° C., preferably lower than 375° C., and further preferably higher than or equal to 180° C. and lower than or equal to 350° C.).

### <<Method 2 for Manufacturing Transistor>>

A manufacturing method different from <<Method 1 for manufacturing transistor>> is described below.

First, steps up to the step illustrated in FIGS. 37C and 37D are performed in a similar manner to that of <<Method 1 for manufacturing transistor>>. Next, the barrier film 230 is formed as illustrated in FIGS. 37E and 37F, and the oxygen 240 is not added. Then, the step illustrated in FIGS. 38A and 38B is not performed, and the steps illustrated in FIGS. 38C to 38F are performed.

In this case, for the barrier film 230, a material having a highly insulating property is selected from the above materials. For the barrier film 230 used in this manufacturing method, aluminum oxide, hafnium oxide, or yttrium oxide is preferably used.

When the barrier film 230 is formed by a sputtering method using aluminum oxide, hafnium oxide, or yttrium oxide, the sputtering gas preferably contains at least oxygen. Oxygen used for the sputtering gas in the formation of the barrier film 230 becomes oxygen radicals in plasma, and the oxygen and/or the oxygen radicals are added to the insulating film 216 in some cases. Therefore, the step of adding the oxygen 240 illustrated in FIGS. 37E and 37F is not necessarily performed. In other words, oxygen adding treatment and the formation of the barrier film 230 can be performed at the same time. Note that the barrier film 230 has a function of adding oxygen in the formation of the barrier film 230 (particularly in an early stage of the formation), whereas the barrier film 230 has a function of blocking oxygen after the formation of the barrier film 230 (particularly in a later stage of the formation).

In the case where the barrier film 230 is formed by a sputtering method using aluminum oxide, for example, a mixed layer might be formed in the vicinity of the interface between the insulating film 216 and the barrier film 230. For example, when the insulating film 216 is a silicon oxynitride film, an AlₓSi_{y}O_{z} layer might be formed as the mixed layer. The mixed layer may include an oxygen-excess region.

When the barrier film 230 is formed using aluminum oxide, hafnium oxide, or yttrium oxide, which have a highly insulating property and a high oxygen barrier property, the step of forming the insulating film 218 illustrated in FIGS. 38A and 38B is not necessarily performed. Instead of the insulating film 218, the barrier film 230 may be used without being removed.

When the substrate temperature in the formation of the barrier film 230 is lower than 400° C., preferably lower than 375° C., and further preferably higher than or equal to 180° C. and lower than or equal to 350° C., oxygen or excess oxygen added to the insulating film 216 can be moved into the oxide semiconductor film 208.

By using aluminum oxide, hafnium oxide, or yttrium oxide for the barrier film 230 as described above, the number of manufacturing steps of the transistor can be reduced, which leads to low manufacturing cost.

The structure and method described in this embodiment can be used in appropriate combination with any of the structures and methods described in the other embodiments and examples.

### Embodiment 4

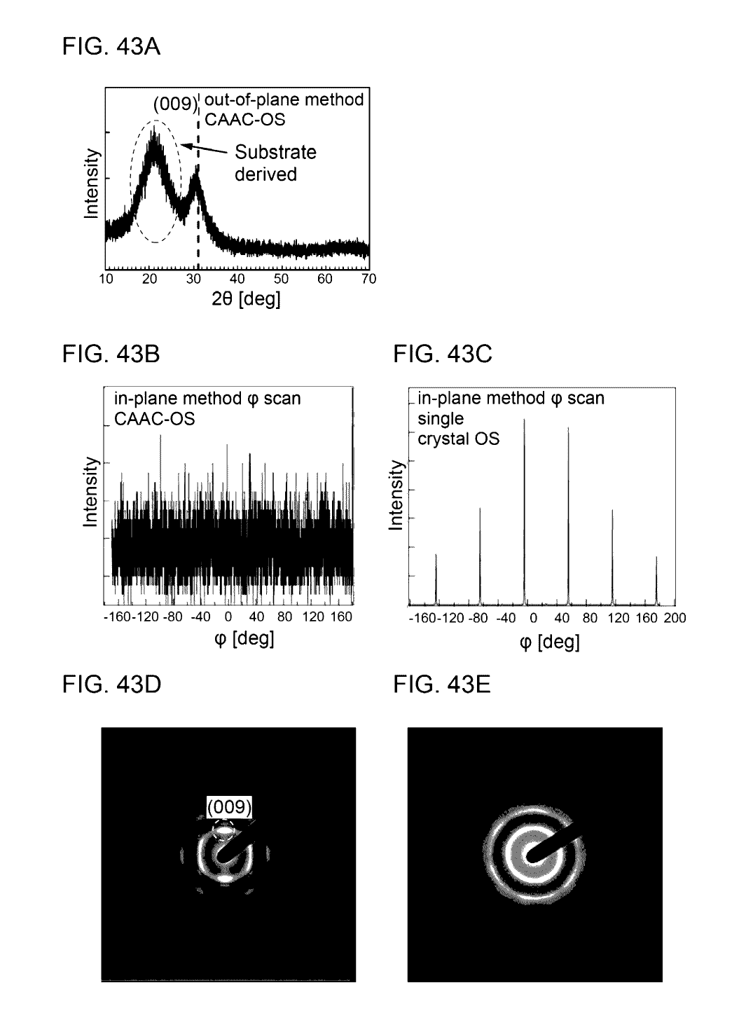

In this embodiment, the structure and the like of an oxide semiconductor will be described with reference to FIGS. 43A to 43E, FIGS. 44A to 44E, FIGS. 45A to 45D, FIGS. 46A and 46B, and FIG. 47.

### <Structure of Oxide Semiconductor>

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

An amorphous structure is generally thought to be isotropic and have no non-uniform structure, to be metastable and not have fixed positions of atoms, to have a flexible bond angle, and to have a short-range order but have no long-range order, for example.

This means that a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS is close to an amorphous oxide semiconductor in terms of physical properties.

### <CAAC-OS>

First, a CAAC-OS is described.

A CAAC-OS is one of oxide semiconductors having a plurality of c-axis aligned crystal parts (also referred to as pellets).

Analysis of a CAAC-OS by X-ray diffraction (XRD) is described. For example, when the structure of a CAAC-OS including an InGaZnO₄ crystal that is classified into the space group R-3m is analyzed by an out-of-plane method, a peak appears at a diffraction angle (2θ) of around 31° as shown in FIG. 43A. This peak is derived from the (009) plane of the InGaZnO₄ crystal, which indicates that crystals in the CAAC-OS have c-axis alignment, and that the c-axes are aligned in a direction substantially perpendicular to a surface over which the CAAC-OS film is formed (also referred to as a formation surface) or the top surface of the CAAC-OS film. Note that a peak sometimes appears at a 2θ of around 36° in addition to the peak at a 2θ of around 31°. The peak at a 2θ of around 36° is derived from a crystal structure that is classified into the space group Fd-3m; thus, this peak is preferably not exhibited in a CAAC-OS.

On the other hand, in structural analysis of the CAAC-OS by an in-plane method in which an X-ray is incident on the CAAC-OS in a direction parallel to the formation surface, a peak appears at a 2θ of around 56°. This peak is attributed to the (110) plane of the InGaZnO₄ crystal. When analysis (φ scan) is performed with 2θ fixed at around 56° and with the sample rotated using a normal vector to the sample surface as an axis (φ axis), as shown in FIG. 43B, a peak is not clearly observed. In contrast, in the case where single crystal InGaZnO₄ is subjected to φ scan with 2θ fixed at around 56°, as shown in FIG. 43C, six peaks that are derived from crystal planes equivalent to the (110) plane are observed. Accordingly, the structural analysis using XRD shows that the directions of a-axes and b-axes are irregularly oriented in the CAAC-OS.

Next, a CAAC-OS analyzed by electron diffraction is described. For example, when an electron beam with a probe diameter of 300 nm is incident on a CAAC-OS including an InGaZnO₄ crystal in a direction parallel to the formation surface of the CAAC-OS, a diffraction pattern (also referred to as a selected-area electron diffraction pattern) shown in FIG. 43D can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 43E shows a diffraction pattern obtained in such a manner that an electron beam with a probe diameter of 300 nm is incident on the same sample in a direction perpendicular to the sample surface. As shown in FIG. 43E, a ring-like diffraction pattern is observed. Thus, the electron diffraction using an electron beam with a probe diameter of 300 nm also indicates that the a-axes and b-axes of the pellets included in the CAAC-OS do not have regular orientation. The first ring in FIG. 43E is considered to be derived from the (010) plane, the (100) plane, and the like of the InGaZnO₄ crystal. The second ring in FIG. 43E is considered to be derived from the (110) plane and the like.

In a combined analysis image (also referred to as a high-resolution TEM image) of a bright-field image and a diffraction pattern of a CAAC-OS, which is obtained using a transmission electron microscope (TEM), a plurality of pellets can be observed. However, even in the high-resolution TEM image, a boundary between pellets, that is, a grain boundary is not clearly observed in some cases. Thus, in the CAAC-OS, a reduction in electron mobility due to the grain boundary is less likely to occur.

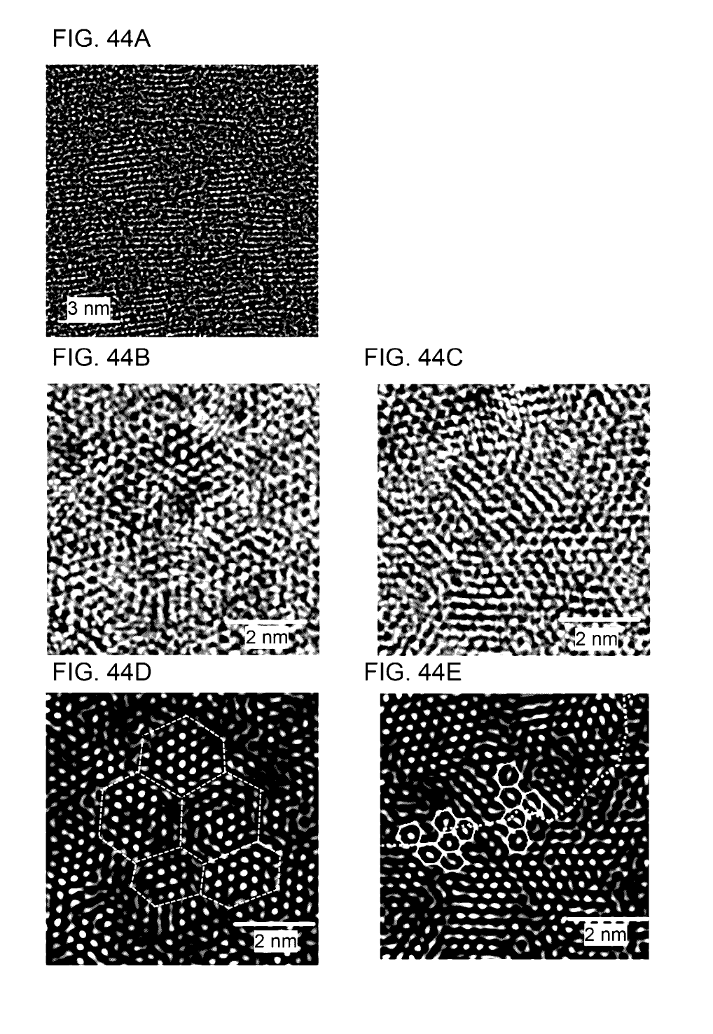

FIG. 44A shows a high-resolution TEM image of a cross section of the CAAC-OS that is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be observed with, for example, an atomic resolution analytical electron microscope JEM-ARM200F manufactured by JEOL Ltd.

FIG. 44A shows pellets in which metal atoms are arranged in a layered manner. FIG. 44A proves that the size of a pellet is greater than or equal to 1 nm or greater than or equal to 3 nm. Therefore, the pellet can also be referred to as a nanocrystal (nc). Furthermore, the CAAC-OS can also be referred to as an oxide semiconductor including c-axis aligned nanocrystals (CANC). A pellet reflects unevenness of a formation surface or a top surface of the CAAC-OS, and is parallel to the formation surface or the top surface of the CAAC-OS.

FIGS. 44B and 44C show Cs-corrected high-resolution TEM images of a plane of the CAAC-OS observed from a direction substantially perpendicular to the sample surface. FIGS. 44D and 44E are images obtained through image processing of FIGS. 44B and 44C. The method of image processing is as follows. The image in FIG. 44B is subjected to fast Fourier transform (FFT), so that an FFT image is obtained. Then, mask processing is performed such that a range of from 2.8 nm⁻¹ to 5.0 nm⁻¹ from the origin in the obtained FFT image remains. After the mask processing, the FFT image is processed by inverse fast Fourier transform (IFFT) to obtain a processed image. The image obtained in this manner is called an FFT filtering image. The FFT filtering image is a Cs-corrected high-resolution TEM image from which a periodic component is extracted, and shows a lattice arrangement.

In FIG. 44D, a portion where a lattice arrangement is broken is denoted with a dashed line. A region surrounded by a dashed line is one pellet. The portion denoted with the dashed line is a junction of pellets. The dashed line draws a hexagon, which means that the pellet has a hexagonal shape. Note that the shape of the pellet is not always a regular hexagon but is a non-regular hexagon in many cases.

In FIG. 44E, a dotted line denotes a portion where the direction of a lattice arrangement changes between a region with a regular lattice arrangement and another region with a regular lattice arrangement. A clear crystal grain boundary cannot be observed even in the vicinity of the dotted line. When a lattice point in the vicinity of the dotted line is regarded as a center and surrounding lattice points are joined, a distorted hexagon, pentagon, and/or heptagon can be formed. That is, a lattice arrangement is distorted so that formation of a crystal grain boundary is inhibited. This is probably because the CAAC-OS can tolerate distortion owing to a low density of the atomic arrangement in an a-b plane direction, the interatomic bond distance changed by substitution of a metal element, and the like.

As described above, the CAAC-OS has c-axis alignment, its pellets (nanocrystals) are connected in an a-b plane direction, and the crystal structure has distortion. For this reason, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

<nc-OS>

Next, an nc-OS is described.

Analysis of an nc-OS by XRD is described. When the structure of an nc-OS is analyzed by an out-of-plane method, a peak indicating orientation does not appear. That is, a crystal of an nc-OS does not have orientation.

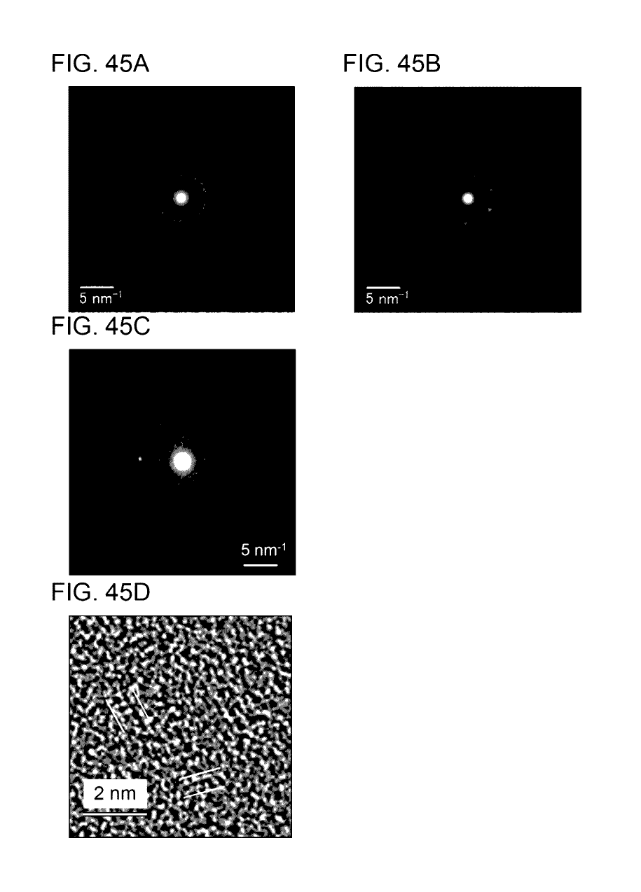

For example, when an electron beam with a probe diameter of 50 nm is incident on a 34-nm-thick region of thinned nc-OS including an InGaZnO₄ crystal in a direction parallel to the formation surface, a ring-shaped diffraction pattern (a nanobeam electron diffraction pattern) shown in FIG. 45A is observed. FIG. 45B shows a diffraction pattern obtained when an electron beam with a probe diameter of 1 nm is incident on the same sample. As shown in FIG. 45B, a plurality of spots are observed in a ring-like region. In other words, ordering in an nc-OS is not observed with an electron beam with a probe diameter of 50 nm but is observed with an electron beam with a probe diameter of 1 nm.

Furthermore, an electron diffraction pattern in which spots are arranged in a regular hexagonal shape is observed in some cases as shown in FIG. 45C when an electron beam having a probe diameter of 1 nm is incident on a region with a thickness of less than 10 nm. This means that an nc-OS has a well-ordered region, i.e., a crystal, in the range of less than 10 nm in thickness. Note that an electron diffraction pattern having regularity is not observed in some regions because crystals are aligned in various directions.

FIG. 45D shows a Cs-corrected high-resolution TEM image of a cross section of an nc-OS observed from the direction substantially parallel to the formation surface. In a high-resolution TEM image, an nc-OS has a region in which a crystal part is observed, such as the part indicated by additional lines in FIG. 45D, and a region in which a crystal part is not clearly observed. In most cases, the size of a crystal part included in the nc-OS is greater than or equal to 1 nm and less than or equal to 10 nm, or specifically, greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

As described above, in the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an a-like OS or an amorphous oxide semiconductor, depending on an analysis method.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-Like OS>

An a-like OS has a structure between those of the nc-OS and the amorphous oxide semiconductor.

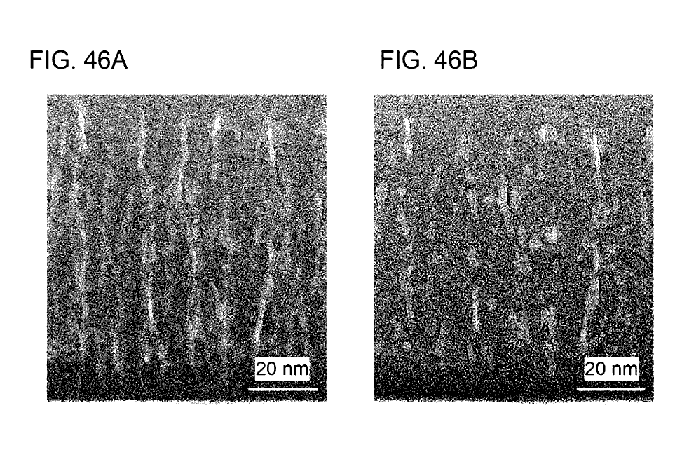

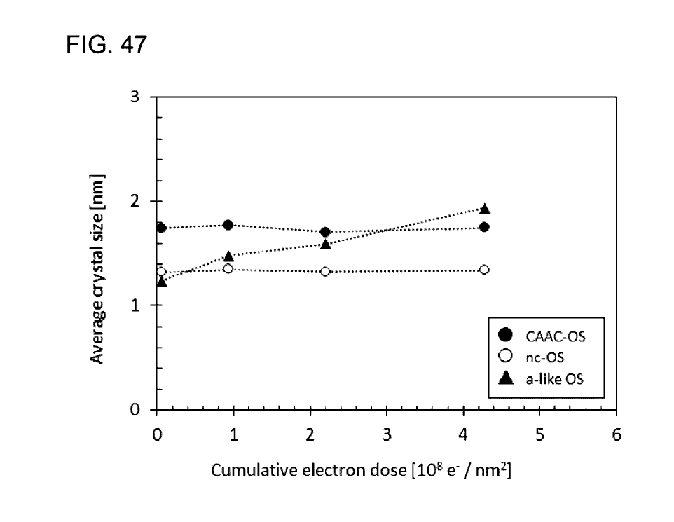

FIGS. 46A and 46B are high-resolution cross-sectional TEM images of an a-like OS. FIG. 46A is the high-resolution cross-sectional TEM image of the a-like OS at the start of the electron irradiation. FIG. 46B is the high-resolution cross-sectional TEM image of a-like OS after the electron (e⁻) irradiation at 4.3×10⁸ e⁻/nm². FIGS. 46A and 46B show that stripe-like bright regions extending vertically are observed in the a-like OS from the start of the electron irradiation. It can be also found that the shape of the bright region changes after the electron irradiation. Note that the bright region is presumably a void or a low-density region.

The a-like OS has an unstable structure because it contains a void. To verify that an a-like OS has an unstable structure as compared with a CAAC-OS and an nc-OS, a change in structure caused by electron irradiation is described below.

An a-like OS, an nc-OS, and a CAAC-OS are prepared as samples. Each of the samples is an In—Ga—Zn oxide.

First, a high-resolution cross-sectional TEM image of each sample is obtained. The high-resolution cross-sectional TEM images show that all the samples have crystal parts.

It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the spacing between lattice fringes is greater than or equal to 0.28 nm and less than or equal to 0.30 nm is regarded as a crystal part of InGaZnO₄ in the following description. Each of lattice fringes corresponds to the a-b plane of the InGaZnO₄ crystal.

FIG. 47 shows a change in the average size of crystal parts (at 22 points to 30 points) in each sample. Note that the crystal part size corresponds to the length of a lattice fringe. FIG. 47 indicates that the crystal part size in the a-like OS increases with an increase in the cumulative electron dose in obtaining TEM images, for example. As shown in FIG. 47, a crystal part of approximately 1.2 nm (also referred to as an initial nucleus) at the start of TEM observation grows to a size of approximately 1.9 nm at a cumulative electron (e⁻) dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². As shown in FIG. 47, the crystal part sizes in an nc-OS and a CAAC-OS are approximately 1.3 nm and approximately 1.8 nm, respectively, regardless of the cumulative electron dose. For the electron beam irradiation and TEM observation, a Hitachi H-9000NAR transmission electron microscope was used. The conditions of electron beam irradiation were as follows: the accelerating voltage was 300 kV; the current density was 6.7×10⁵ e⁻/(nm²·s); and the diameter of irradiation region was 230 nm.

In this manner, growth of the crystal part in the a-like OS is sometimes induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that in the case where an oxide semiconductor having a certain composition does not exist in a single crystal structure, single crystal oxide semiconductors with different compositions are combined at an adequate ratio, which makes it possible to calculate density equivalent to that of a single crystal oxide semiconductor with the desired composition. The density of a single crystal oxide semiconductor with the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked film including two or more films of an amorphous oxide semiconductor, an a-like OS, an nc-OS, and a CAAC-OS, for example.

### <Carrier Density of Oxide Semiconductor>

Next, the carrier density of an oxide semiconductor will be described below.

Examples of a factor affecting the carrier density of an oxide semiconductor include oxygen vacancy (V_{O}) and impurities in the oxide semiconductor.

As the amount of oxygen vacancy in the oxide semiconductor increases, the density of defect states increases when hydrogen is bonded to the oxygen vacancy (this state is also referred to as VoH). The density of defect states also increases with an increase in the amount of impurity in the oxide semiconductor. Hence, the carrier density of an oxide semiconductor can be controlled by controlling the density of defect states in the oxide semiconductor.

A transistor using the oxide semiconductor in a channel region will be described below.

The carrier density of the oxide semiconductor is preferably reduced in order to inhibit the negative shift of the threshold voltage of the transistor or reduce the off-state current of the transistor. In order to reduce the carrier density of the oxide semiconductor, the impurity concentration in the oxide semiconductor is reduced so that the density of defect states can be reduced. In this specification and the like, a state with a low impurity concentration and a low density of defect states is referred to as a highly purified intrinsic or substantially highly purified intrinsic state. The carrier density of a highly purified intrinsic oxide semiconductor is lower than 8×10¹⁵ cm⁻³, preferably lower than 1×10¹¹ cm⁻³, and further preferably lower than 1×10¹⁰ cm⁻³, and higher than or equal to 1×10⁻⁹ cm⁻³.

In contrast, the carrier density of the oxide semiconductor is preferably increased in order to improve the on-state current of the transistor or improve the field-effect mobility of the transistor. In order to increase the carrier density of the oxide semiconductor, the impurity concentration or the density of defect states in the oxide semiconductor is slightly increased. Alternatively, the bandgap of the oxide semiconductor is preferably narrowed. For example, an oxide semiconductor that has a slightly high impurity concentration or a slightly high density of defect states in the range where a favorable on/off ratio is obtained in the I_{d}−V_{g} characteristics of the transistor can be regarded as substantially intrinsic. Furthermore, an oxide semiconductor that has high electron affinity and thus has a narrow bandgap so as to increase the density of thermally excited electrons (carriers) can be regarded as substantially intrinsic. Note that a transistor using an oxide semiconductor with higher electron affinity has a lower threshold voltage.

The aforementioned oxide semiconductor with an increased carrier density has somewhat n-type conductivity; thus, it can be referred to as a “slightly-n” oxide semiconductor.

The carrier density of a substantially intrinsic oxide semiconductor is preferably higher than or equal to 1×10⁵ cm⁻³ and lower than 1×10¹⁸ cm⁻³, further preferably higher than or equal to 1×10⁷ cm⁻³ and lower than or equal to 1×10¹⁷ cm⁻³, still further preferably higher than or equal to 1×10⁹ cm⁻³ and lower than or equal to 5×10¹⁶ cm⁻³, yet further preferably higher than or equal to 1×10¹⁰ cm⁻³ and lower than or equal to 1×10¹⁶ cm⁻³, and yet still further preferably higher than or equal to 1×10¹¹ cm⁻³ and lower than or equal to 1×10¹⁵ cm⁻³.

The structure and method described in this embodiment can be used in appropriate combination with any of the structures and methods described in the other embodiments and examples.

### Embodiment 5

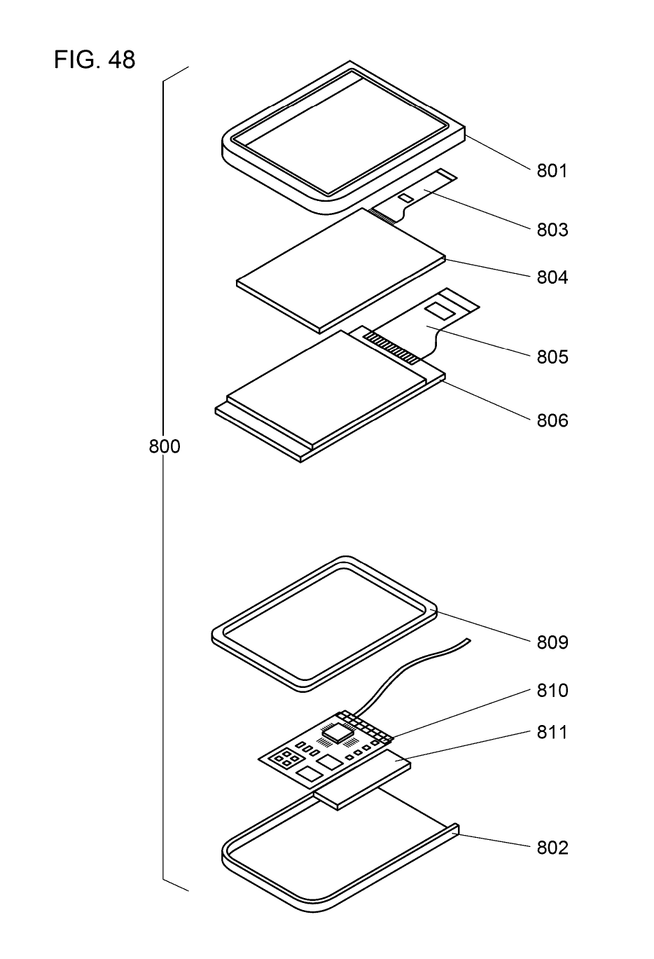

In this embodiment, a structure of an input/output device which includes a display device of one embodiment of the present invention will be described with reference to FIG. 48.

### <Structure Example of Input/Output Device>

FIG. 48 is an exploded view of a structure of an input/output device 800.

The input/output device 800 includes a display device 806 and a touch sensor 804 having a region overlapping with the display device 806. Note that the input/output device 800 can be referred to as a touch panel.

The input/output device 800 is provided with a driver circuit 810 for driving the touch sensor 804 and the display device 806, a battery 811 for supplying power to the driver circuit 810, and a housing where the touch sensor 804, the display device 806, the driver circuit 810, and the battery 811 are stored.

### <<Touch Sensor 804>>

The touch sensor 804 includes a region overlapping with the display device 806. Note that an FPC 803 is electrically connected to the touch sensor 804.

For the touch sensor 804, a resistive touch sensor, a capacitive touch sensor, or a touch sensor using a photoelectric conversion element can be used, for example.

Note that the touch sensor 804 may be used as part of the display device 806.

### <<Display Device 806>>

For example, the display device described in Embodiment 1 can be used as the display device 806. Note that an FPC 805 or the like is electrically connected to the display device 806.

### <<Driver Circuit 810>>

As the driver circuit 810, a power supply circuit or a signal processing circuit can be used, for example. Power supplied to the battery or an external commercial power supply can be utilized.

The signal processing circuit has a function of outputting a video signal, a clock signal, and the like.

The power supply circuit has a function of supplying predetermined power.

### <<Housing>>

An upper cover 801, a lower cover 802 which fits the upper cover 801, and a frame 809 which is stored in a region surrounded by the upper cover 801 and the lower cover 802 can be used for the housing, for example.

The frame 809 has a function of protecting the display device 806, a function of blocking electromagnetic waves generated by the operation of the driver circuit 810, or a function as a radiator plate.

Metal, a resin, an elastomer, or the like can be used for the upper cover 801, the lower cover 802, or the frame 809.

### <<Battery 811>>

The battery 811 has a function of supplying power.

Note that a member such as a polarizing plate, a retardation plate, or a prism sheet can be used for the input/output device 800.

This embodiment can be implemented in appropriate combination with any of the other embodiments and examples in this specification.

### Embodiment 6

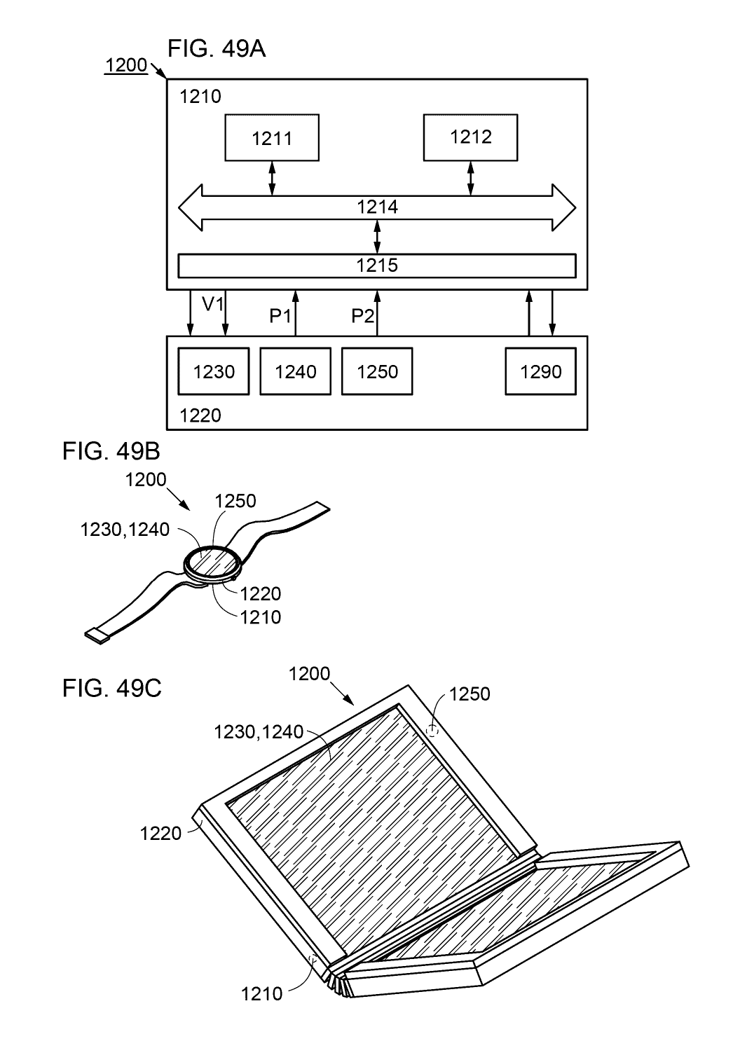

In this embodiment, a structure of a data processing device of one embodiment of the present invention will be described with reference to FIGS. 49A to 49C, FIGS. 50A to 50C, FIGS. 51A and 51B, and FIG. 52.

FIG. 49A is a block diagram illustrating the structure of a data processing device 1200. FIGS. 49B and 49C are projection views illustrating an example of an external view of the data processing device 1200.

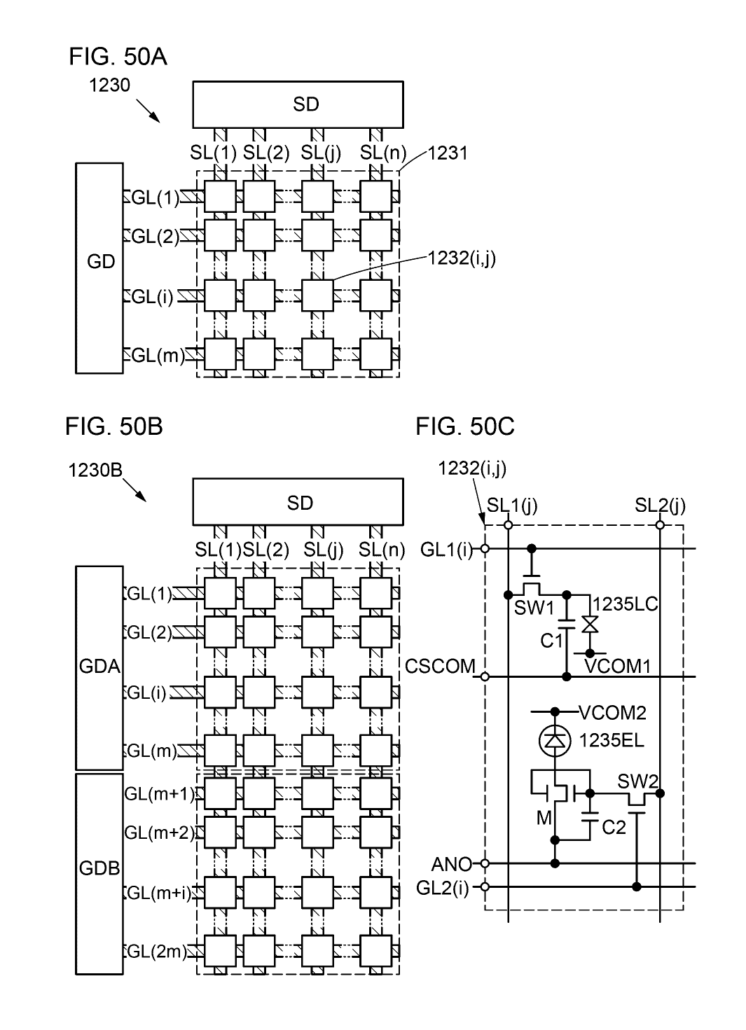

FIG. 50A is a block diagram illustrating a configuration of a display portion 1230. FIG. 50B is a block diagram illustrating a configuration of a display portion 1230B. FIG. 50C is a circuit diagram illustrating the configuration of a pixel 1232(i,j).

### <Structure Example of Data Processing Device>

The data processing device 1200 described in this embodiment includes an arithmetic device 1210 and an input/output device 1220 (see FIG. 49A).

The arithmetic device 1210 has a function of receiving positional data P1 and supplying image data V1 and control data.

The input/output device 1220 has a function of supplying the positional data P1 and receiving the image data V1 and the control data.

The input/output device 1220 includes the display portion 1230 that displays the image data V1 and an input portion 1240 that supplies the positional data P1.

The display portion 1230 includes a first display element and a second display element overlapping with the first display element. The display portion 1230 further includes a first pixel circuit for driving the first display element and a second pixel circuit for driving the second display element.

The input portion 1240 has a function of sensing the position of a pointer and supplying the positional data P1 determined in accordance with the position.

The arithmetic device 1210 has a function of determining the moving speed of the pointer in accordance with the positional data P1.

The arithmetic device 1210 has a function of determining the contrast or brightness of the image data V1 in accordance with the moving speed.

The data processing device 1200 described in this embodiment includes the input/output device 1220 that supplies the positional data P1 and receives the image data V1 and the arithmetic device 1210 that receives the positional data P1 and supplies the image data V1. The arithmetic device 1210 has a function of determining the contrast or brightness of the image data V1 in accordance with the moving speed of the positional data P1.

With this structure, eyestrain on a user caused when the display position of image data is moved can be reduced, that is, eye-friendly display can be achieved. Moreover, the power consumption can be reduced and excellent visibility can be provided even in a bright place exposed to direct sunlight, for example. Thus, the novel data processing device that is highly convenient or reliable can be provided.

### <Configuration>

The data processing device of one embodiment of the present invention includes the arithmetic device 1210 or the input/output device 1220.

### <<Arithmetic Device 1210>>

The arithmetic device 1210 includes an arithmetic portion 1211 and a memory portion 1212. The arithmetic device 1210 further includes a transmission path 1214 and an input/output interface 1215 (see FIG. 49A).

### <<Arithmetic Portion 1211>>

The arithmetic portion 1211 has a function of, for example, executing a program. For example, a CPU described in Embodiment 7 can be used. Thus, power consumption can be sufficiently reduced.

### <<Memory Portion 1212>>

The memory portion 1212 has a function of, for example, storing the program executed by the arithmetic portion 1211, initial data, setting data, an image, or the like.

Specifically, a hard disk, a flash memory, a memory including a transistor including an oxide semiconductor, or the like can be used for the memory portion 1212.

### <<Input/Output Interface 1215 and Transmission Path 1214>>

The input/output interface 1215 includes a terminal or a wiring and has a function of supplying and receiving data. For example, the input/output interface 1215 can be electrically connected to the transmission path 1214 and the input/output device 1220.

The transmission path 1214 includes a wiring and has a function of supplying and receiving data. For example, the transmission path 1214 can be electrically connected to the input/output interface 1215. In addition, the transmission path 1214 can be electrically connected to the arithmetic portion 1211 or the memory portion 1212.

### <<Input/Output Device 1220>>

The input/output device 1220 includes the display portion 1230, the input portion 1240, a sensor portion 1250, or a communication portion 1290.

### <<Display Portion 1230>>

The display portion 1230 includes a display region 1231, a driver circuit GD, and a driver circuit SD (see FIG. 50A). For example, the display device described in Embodiment 1 can be used. Thus, low power consumption can be achieved.

The display region 1231 includes a plurality of pixels 1232(i,1) to 1232 (i,n) arranged in the row direction, a plurality of pixels 1232(1,j) to 1232 (m,j) arranged in the column direction, a scan line GL1(i) and a scan line GL2(i) electrically connected to the plurality of pixels 1232(i,1) to 1232 (i,n), and a signal line SL1(j) and a signal line SL2(j) electrically connected to the plurality of pixels 1232(i,j) to 1232 (m,j). Note that i is an integer greater than or equal to 1 and less than or equal to m, j is an integer greater than or equal to 1 and less than or equal to n, and each of m and n is an integer greater than or equal to 1.

Note that the pixel 1232(i,j) includes a switch SW1, a switch SW2, a transistor M, the capacitor C1, and the capacitor C2, as a pixel circuit. The pixel 1232(i,j) is electrically connected to the scan line GL1(i), the scan line GL2(i), the signal line SL1(j), the signal line SL2(j), the wiring ANO, the wiring CSCOM, the wiring VCOM1, and the wiring VCOM2 (see FIG. 50C).

The display portion can include a plurality of driver circuits. For example, the display portion 1230B can include a driver circuit GDA and a driver circuit GDB (see FIG. 50B).

### <<Driver Circuit GD>>

The driver circuit GD has a function of supplying a selection signal in accordance with the control data.

For example, the driver circuit GD has a function of supplying a selection signal to one scan line at a frequency of 30 Hz or higher, preferably 60 Hz or higher, in accordance with the control data. Accordingly, moving images can be smoothly displayed.

For example, the driver circuit GD has a function of supplying a selection signal to one scan line at a frequency of lower than 30 Hz, preferably lower than 1 Hz, and further preferably less than once per minute, in accordance with the control data. Accordingly, a still image can be displayed while flickering is suppressed.

For example, in the case where a plurality of driver circuits are provided, the driver circuits GDA and GDB may supply the selection signals at different frequencies. Specifically, the selection signal can be supplied at a higher frequency to a region on which moving images are smoothly displayed than to a region on which a still image is displayed in a state where flickering is suppressed.

### <<Driver Circuit SD>>

The driver circuit SD has a function of supplying an image signal in accordance with the image data V1.

<<Pixel 1232(i,j)>>

The pixel 1232(i,j) includes a first display element 1235LC and a second display element 1235EL overlapping with the first display element 1235LC. The pixel 1232(i,j) further includes a pixel circuit for driving the first display element 1235LC and a pixel circuit for driving the second display element 1235EL (see FIG. 50C).

<<First display element 1235LC>>

For example, a display element having a function of controlling light reflection or transmission can be used as the first display element 1235LC. For example, a combined structure of a polarizing plate and a liquid crystal element or a MEMS shutter display element can be used. The use of a reflective display element can reduce power consumption of a display device. Specifically, a reflective liquid crystal display element can be used as the first display element 1235LC.

The first display element 1235LC includes a first electrode, a second electrode, and a liquid crystal layer. The liquid crystal layer contains a liquid crystal material whose orientation is controlled by voltage applied between the first electrode and the second electrode. For example, the orientation of the liquid crystal material can be controlled by an electric field in the thickness direction (also referred to as the vertical direction), the horizontal direction, or the diagonal direction of the liquid crystal layer.

<<Second display element 1235EL>>

A display element having a function of emitting light, such as an organic EL element or an inorganic EL element, can be used as the second display element 1235EL.

Specifically, an organic EL element or an inorganic EL element which emits white light can be used as the second display element 1235EL. Alternatively, an organic EL element or an inorganic EL element which emits blue light, green light, or red light can be used as the second display element 1235EL.

### <<Pixel Circuit>>

A pixel circuit including a circuit which has a function of driving the first display element or the second display element can be used.

Alternatively, for example, a switch, a transistor, a diode, a resistor, a capacitor, or an inductor can be used in the pixel circuit.

For example, one or a plurality of transistors can be used as a switch. Alternatively, a plurality of transistors connected in parallel, in series, or in combination of parallel connection and series connection can be used as a switch.

### <<Transistor>>

For example, a semiconductor film formed through the same process can be used for transistors in the driver circuit and the pixel circuit.

As the transistors in the driver circuit and the pixel circuit, bottom-gate transistors, top-gate transistors, or the like can be used.

For example, a manufacturing line for a bottom-gate transistor including amorphous silicon as a semiconductor can be easily remodeled into a manufacturing line for a bottom-gate transistor including an oxide semiconductor as a semiconductor. Furthermore, for example, a manufacturing line for a top-gate transistor including polysilicon as a semiconductor can be easily remodeled into a manufacturing line for a top-gate transistor including an oxide semiconductor as a semiconductor.

For example, a transistor including a semiconductor containing an element of Group 14 can be used. Specifically, a semiconductor containing silicon can be used for a semiconductor film. For example, single crystal silicon, polysilicon, microcrystalline silicon, or amorphous silicon can be used for the semiconductor film of the transistor.

Note that the temperature for forming a transistor using polysilicon in a semiconductor is lower than the temperature for forming a transistor using single crystal silicon in a semiconductor.

In addition, the transistor using polysilicon in a semiconductor has higher field-effect mobility than the transistor using amorphous silicon in a semiconductor, and therefore a pixel including the transistor using polysilicon can have a high aperture ratio. Moreover, pixels arranged at a high resolution, a gate driver circuit, and a source driver circuit can be formed over the same substrate. As a result, the number of components included in an electronic device can be reduced.

In addition, the transistor using polysilicon in a semiconductor has higher reliability than the transistor using amorphous silicon in a semiconductor.

For example, a transistor using an oxide semiconductor can be used. Specifically, an oxide semiconductor containing indium or an oxide semiconductor containing indium, gallium, and zinc can be used for a semiconductor film.

For example, a transistor having a lower leakage current in an off state than a transistor using amorphous silicon for a semiconductor film can be used. Specifically, a transistor using an oxide semiconductor for a semiconductor film can be used.

A pixel circuit in the transistor using an oxide semiconductor for the semiconductor film can hold an image signal for a longer time than a pixel circuit in a transistor using amorphous silicon for a semiconductor film. Specifically, the selection signal can be supplied at a frequency of lower than 30 Hz, preferably lower than 1 Hz, and further preferably less than once per minute, while flickering is suppressed. Consequently, eyestrain on a user of the data processing device can be reduced, and power consumption for driving can be reduced.

Alternatively, for example, a transistor using a compound semiconductor can be used. Specifically, a semiconductor containing gallium arsenide can be used for a semiconductor film.

For example, a transistor using an organic semiconductor can be used. Specifically, an organic semiconductor containing any of polyacenes and graphene can be used for the semiconductor film.

### <<Input Portion 1240>>

A variety of human interfaces or the like can be used as the input portion 1240 (see FIG. 49A).

For example, a keyboard, a mouse, a touch sensor, a microphone, a camera, or the like can be used as the input portion 1240. Note that a touch sensor having a region overlapping with the display portion 1230 can be used. An input/output device including the display portion 1230 and a touch sensor having a region overlapping with the display portion 1230 can be referred to as a touch panel.

For example, a user can make various gestures (e.g., tap, drag, swipe, and pinch in) using his/her finger as a pointer on the touch panel.

The arithmetic device 1210, for example, analyzes data on the position, track, or the like of the finger on the touch panel and determines that a specific gesture is supplied when the analysis results meet predetermined conditions. Therefore, the user can supply a certain operation instruction associated with a certain gesture to the input portion 1240 by using the gesture.

For instance, the user can supply a “scrolling instruction” for changing a portion where image data is displayed by using a gesture of touching and moving his/her finger on the touch panel.

### <<Sensor Portion 1250>>

The sensor portion 1250 has a function of acquiring data P2 by sensing the surrounding state.

For example, an imaging element, an acceleration sensor, a direction sensor, a pressure sensor, a temperature sensor, a humidity sensor, an illuminance sensor, or a global positioning system (GPS) signal receiving circuit can be used as the sensor portion 1250.

For example, when the arithmetic device 1210 determines that the ambient light level sensed by an illuminance sensor of the sensor portion 1250 is sufficiently higher than the predetermined illuminance, image data is displayed using the first display element 1235LC. When the arithmetic device 1210 determines that it is dim, image data is displayed using the first display element 1235LC and the second display element 1235EL. When the arithmetic device 1210 determines that it is dark, image data is displayed using the second display element 1235EL.

Specifically, an image is displayed with a reflective liquid crystal element and/or an organic EL element depending on the ambient brightness.

Thus, image data can be displayed in such a manner that, for example, a reflective display element is used in an environment with strong external light and a self-luminous display element is used in a dim environment. Thus, a novel data processing device which has low power consumption and is highly convenient or reliable can be provided.

For example, a sensor having a function of detecting chromaticity of ambient light, such as a CCD camera, can be used in the sensor portion 1250, whereby white balance can be adjusted in accordance with the chromaticity of ambient light detected by the sensor portion 1250.

Specifically, in the first step, imbalance disruption of white balance of ambient light is detected.

In the second step, the intensity of light of a color which is insufficient in an image to be displayed by the first display element using reflection of ambient light is estimated.

In the third step, ambient light is reflected by the first display element, and light is emitted from the second display element so that light of the insufficient color is supplemented, whereby the image is displayed.

In this manner, display can be performed with adjusted white balance by utilizing light reflected by the first display element and light emitted from the second display element. Thus, a novel data processing device which can display an image with low power consumption or with adjusted white balance and which is highly convenient or reliable can be provided.

### <<Communication Portion 1290>>

The communication portion 1290 has a function of supplying and acquiring data to/from a network.

### <<Program>>

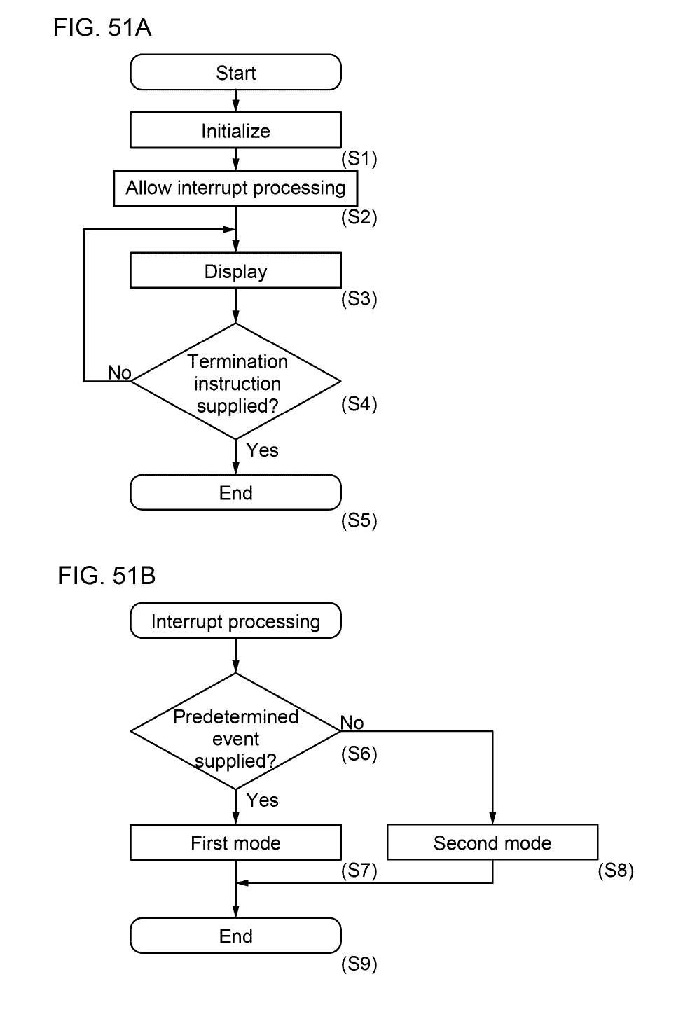

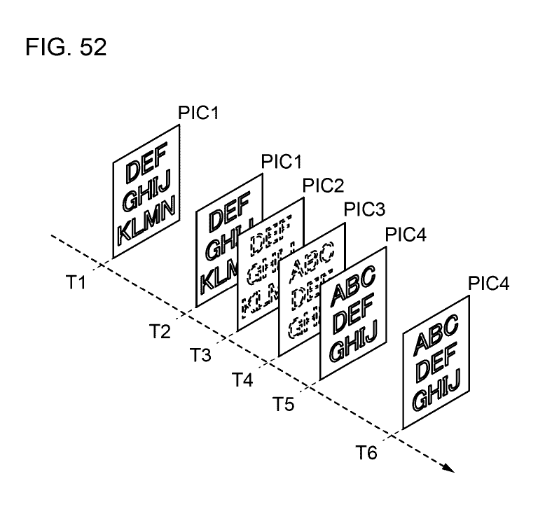

A program of one embodiment of the present invention is described with reference to FIGS. 51A and 51B and FIG. 52.

FIG. 51A is a flow chart showing main processing of the program of one embodiment of the present invention, and FIG. 51B is a flow chart showing interrupt processing.

FIG. 52 schematically illustrates a method for displaying image data on the display portion 1230.

The program of one embodiment of the present invention has the following steps (see FIG. 51A).

In a first step, setting is initialized (see S1 in FIG. 51A).

For instance, predetermined image data and the second mode can be used for the initialization.

For example, a still image can be used as the predetermined image data. Alternatively, a mode in which the selection signal is supplied at a frequency of lower than 30 Hz, preferably lower than 1 Hz, and further preferably less than once per minute, can be used as the second mode.

In a second step, interrupt processing is allowed (see S2 in FIG. 51A). Note that an arithmetic device allowed to execute the interrupt processing can perform the interrupt processing in parallel with the main processing. The arithmetic device which has returned from the interrupt processing to the main processing can reflect the results of the interrupt processing in the main processing.

The arithmetic device may execute the interrupt processing when a counter has an initial value, and the counter may be set at a value other than the initial value when the arithmetic device returns from the interrupt processing. Thus, the interrupt processing is ready to be executed after the program is started up.

In a third step, image data is displayed in a mode selected in the first step or the interrupt processing (see S3 in FIG. 51A).

For instance, predetermined image data is displayed in the second mode, in accordance with the initialization.

Specifically, the predetermined image data is displayed in a mode in which the selection signal is supplied to one scan line at a frequency of lower than 30 Hz, preferably lower than 1 Hz, and further preferably less than once per minute.

For example, the selection signal is supplied at Time T1 so that first image data PIC1 is displayed on the display portion 1230 (see FIG. 52). At Time T2, which is, for example, one second after Time T1, the selection signal is supplied so that the predetermined image data is displayed.

Alternatively, in the case where a predetermined event is not supplied in the interrupt processing, image data is displayed in the second mode.

For example, the selection signal is supplied at Time T5 so that fourth image data PIC4 is displayed on the display portion 1230. At Time T6, which is, for example, one second after Time T5, the selection signal is supplied so that the same image data is displayed. Note that the length of a period from Time T5 to Time T6 can be equal to that of a period from Time T1 to Time T2.

For instance, in the case where the predetermined event is supplied in the interrupt processing, predetermined image data is displayed in the first mode.

Specifically, in the case where an event associated with a “page turning instruction” is supplied in the interrupt processing, image data is switched from one to another in a mode in which the selection signal is supplied to one scan line at a frequency of 30 Hz or higher, preferably 60 Hz or higher.

Alternatively, in the case where an event associated with the “scrolling instruction” is supplied in the interrupt processing, second image data PIC2, which includes part of the displayed first image data PIC1 and the following part, is displayed in a mode in which the selection signal is supplied to one scan line at a frequency of 30 Hz or higher, preferably 60 Hz or higher.

Thus, for example, moving images in which images are gradually switched in accordance with the “page turning instruction” can be displayed smoothly. Alternatively, a moving image in which an image is gradually moved in accordance with the “scrolling instruction” can be displayed smoothly.

Specifically, the selection signal is supplied at Time T3 after the event associated with the “scrolling instruction” is supplied so that the second image data PIC2 whose display position and the like are changed from those of the first image data PIC1 is displayed (see FIG. 52). The selection signal is supplied at Time T4 so that third image data PIC3 whose display position and the like are changed from those of the second image data PIC2 is displayed. Note that each of a period from Time T2 to Time T3, a period from Time T3 to Time T4, and a period from Time T4 to Time T5 is shorter than the period from Time T1 to Time T2.

In the fourth step, the program moves to the fifth step when a termination instruction is supplied, and the program moves to the third step when the termination instruction is not supplied (see S4 in FIG. 51A).

Note that in the interrupt processing, for example, the termination instruction can be supplied.

In the fifth step, the program terminates (see S5 in FIG. 51A).

The interrupt processing includes sixth to ninth steps described below (see FIG. 51B).

In the sixth step, the processing proceeds to the seventh step when a predetermined event has been supplied during a predetermined period, whereas the processing proceeds to the eighth step when the predetermined event has not been supplied (see S6 in FIG. 51B).

For example, the predetermined period is shorter than 0.5 seconds, preferably shorter than 0.1 seconds.

For example, the predetermined event can include an event associated with the termination instruction.

In the seventh step, the first mode is selected (see S7 in FIG. 51B).

In the eighth step, the second mode is selected (see S8 in FIG. 51B).

In the ninth step, the operation returns from the interrupt processing (see S9 in FIG. 51B).

### <<Predetermined Event>>

A variety of instructions can be associated with a variety of events.

The following instructions can be given as examples: “page-turning instruction” for switching displayed image data from one to another and “scroll instruction” for moving the display position of part of image data and displaying another part continuing from that part.

For example, the following events can be used: events supplied using a pointing device such as a mouse (e.g., “click” and “drag”) and events supplied to a touch panel with a finger or the like used as a pointer (e.g., “tap”, “drag”, and “swipe”).

For example, the position of a slide bar pointed by a pointer, the swipe speed, and the drag speed can be used as parameters of various instructions.

Specifically, a parameter that determines the page-turning speed or the like can be used to execute the “page-turning instruction” and a parameter that determines the moving speed of the display position or the like can be used to execute the “scroll instruction”.

For example, the display brightness, contrast, or saturation may be changed in accordance with the page-turning speed and/or the scroll speed.

Specifically, in the case where the page-turning speed and/or the scroll speed are/is higher than the predetermined speed, the display brightness may be decreased in synchronization with the speed.

Alternatively, in the case where the page-turning speed and/or the scroll speed are/is higher than the predetermined speed, the contrast may be decreased in synchronization with the speed.

For example, the speed at which user's eyes cannot follow displayed images can be used as the predetermined speed.

The contrast can be reduced in such a manner that the gray level of a bright region (with a high gray level) included in image data is brought close to the gray level of a dark region (with a low gray level) included in the image data.

Alternatively, the contrast can be reduced in such a manner that the gray level of the dark region included in image data is brought close to the gray level of the bright region included in the image data.

Specifically, in the case where the page-turning speed and/or the scroll speed are/is higher than the predetermined speed, display may be performed such that the yellow tone is increased or the blue tone is decreased in synchronization with the speed.

Image data may be generated on the basis of data of the usage environment of the data processing device acquired by the sensor portion 1250. For example, user's favorite color can be used as the background color of the image data in accordance with the acquired ambient brightness or the like (see FIG. 49B).

Image data may be generated in accordance with received data delivered to a specific space using the communication portion 1290. For example, educational materials can be fed from a classroom of, for example, a school or a university and displayed to be used as a schoolbook. Alternatively, materials distributed from a conference room in, for example, a company can be received and displayed (see FIG. 49C).

Thus, favorable environment can be provided for a user of the data processing device 1200.

This embodiment can be implemented in appropriate combination with any of the other embodiments and examples in this specification.

### Embodiment 7

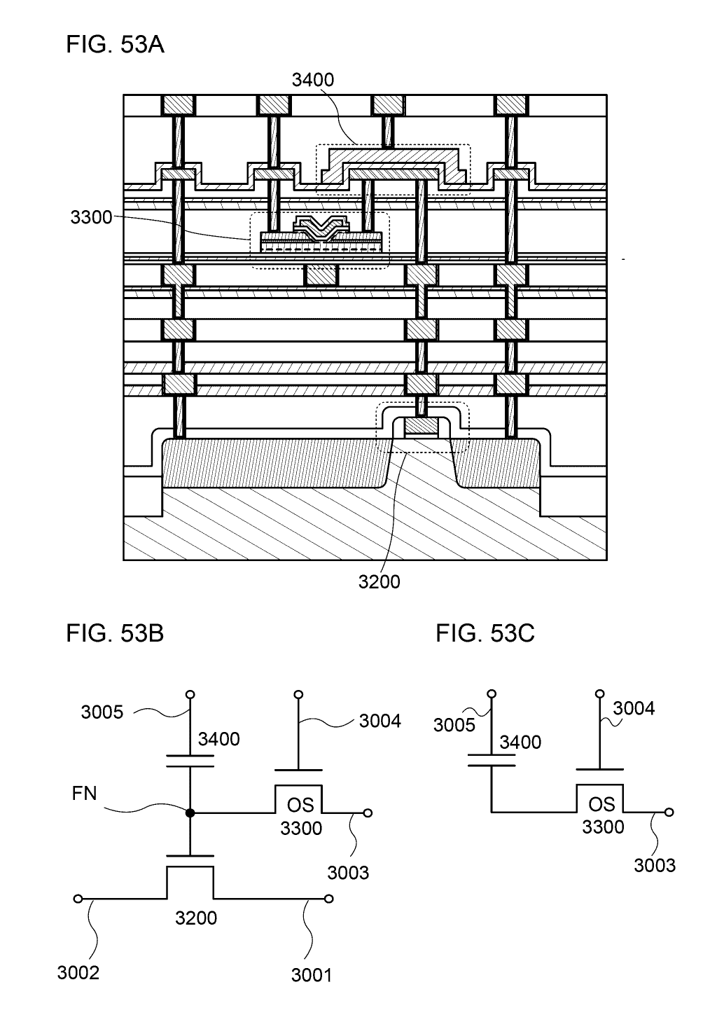

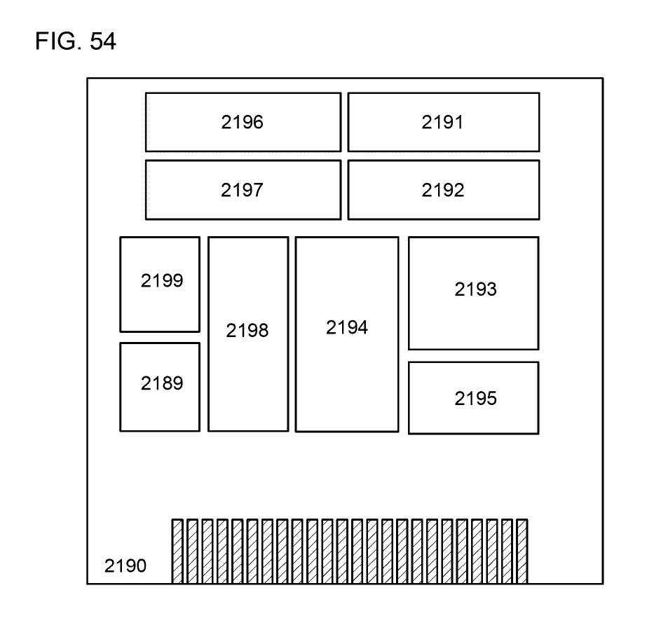

In this embodiment, a semiconductor device (memory device) that can retain stored data even when not powered and that has an unlimited number of write cycles, and a CPU including the semiconductor device will be described with reference to FIGS. 53A to 53C, FIG. 54, and FIG. 55. The CPU described in this embodiment can be used for the data processing device described in Embodiment 5, for example.

### <Memory Device>

An example of a semiconductor device (memory device) which can retain stored data even when not powered and which has an unlimited number of write cycles is shown in FIGS. 53A to 53C. Note that FIG. 53B is a circuit diagram of the structure in FIG. 53A.

The semiconductor device illustrated in FIGS. 53A and 53B includes a transistor 3200 using a first semiconductor material, a transistor 3300 using a second semiconductor material, and a capacitor 3400.

The first and second semiconductor materials preferably have different energy gaps. For example, the first semiconductor material can be a semiconductor material other than an oxide semiconductor (examples of such a semiconductor material include silicon (including strained silicon), germanium, silicon germanium, silicon carbide, gallium arsenide, aluminum gallium arsenide, indium phosphide, gallium nitride, and an organic semiconductor), and the second semiconductor material can be an oxide semiconductor. A transistor using a material other than an oxide semiconductor, such as single crystal silicon, can operate at high speed easily. On the other hand, a transistor including an oxide semiconductor has a low off-state current.

The transistor 3300 is a transistor in which a channel is formed in a semiconductor layer including an oxide semiconductor. Since the off-state current of the transistor 3300 is small, stored data can be retained for a long period. In other words, power consumption can be sufficiently reduced because a semiconductor memory device in which refresh operation is unnecessary or the frequency of refresh operation is extremely low can be provided.

In FIG. 53B, a first wiring 3001 is electrically connected to a source electrode of the transistor 3200. A second wiring 3002 is electrically connected to a drain electrode of the transistor 3200. A third wiring 3003 is electrically connected to one of a source electrode and a drain electrode of the transistor 3300. A fourth wiring 3004 is electrically connected to a gate electrode of the transistor 3300. A gate electrode of the transistor 3200 and the other of the source electrode and the drain electrode of the transistor 3300 are electrically connected to one electrode of the capacitor 3400. A fifth wiring 3005 is electrically connected to the other electrode of the capacitor 3400.

The semiconductor device in FIG. 53A has a feature that the potential of the gate electrode of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to the gate electrode of the transistor 3200 and the capacitor 3400. That is, a predetermined charge is supplied to the gate electrode of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge supplied to the gate electrode of the transistor 3200 is held (retaining).

Since the off-state current of the transistor 3300 is extremely small, the charge of the gate electrode of the transistor 3200 is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the gate electrode of the transistor 3200. This is because in the case of using an n-channel transistor as the transistor 3200, an apparent threshold voltage Vₜₕ_{_}_{H} at the time when the high-level charge is given to the gate electrode of the transistor 3200 is lower than an apparent threshold voltage Vₜₕ_{_}_{L} at the time when the low-level charge is given to the gate electrode of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_}_{H} and Vₜₕ_{_}_{L}, whereby charge supplied to the gate electrode of the transistor 3200 can be determined. For example, in the case where the high-level charge is supplied to the gate electrode of the transistor 3200 in writing and the potential of the fifth wiring 3005 is V₀ (>Vₜₕ_{_}_{H}), the transistor 3200 is turned on. In the case where the low-level charge is supplied to the gate electrode of the transistor 3200 in writing, even when the potential of the fifth wiring 3005 is V₀ (<Vₜₕ_{_}_{L}), the transistor 3200 remains off. Thus, the data retained in the gate electrode of the transistor 3200 can be read by determining the potential of the second wiring 3002.

The semiconductor device illustrated in FIG. 53C is different from the semiconductor device illustrated in FIG. 53A in that the transistor 3200 is not provided. Also in this case, writing and retaining operation of data can be performed in a manner similar to the semiconductor device illustrated in FIG. 53A.

Next, reading of data of the semiconductor device illustrated in FIG. 53C is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in the potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁(=(C_{B}×V_{B0}+C×V₁)/(C_{B}+C)) is higher than the potential of the third wiring 3003 in the case of retaining the potential V₀(=(C_{B}×V_{B0}+C×V₀)/(C_{B}+C)).

Then, by comparing the potential of the third wiring 3003 with a predetermined potential, data can be read.

In this case, a transistor including the first semiconductor material may be used for a driver circuit for driving a memory cell, and a transistor including the second semiconductor material may be stacked over the driver circuit as the transistor 3300.

When including a transistor in which a channel formation region is formed using an oxide semiconductor and which has an extremely small off-state current, the semiconductor device described in this embodiment can retain stored data for an extremely long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Furthermore, in the semiconductor device described in this embodiment, high voltage is not needed for writing data and there is no problem of deterioration of elements. Unlike in a conventional nonvolatile memory, for example, it is not necessary to inject and extract electrons into and from a floating gate; thus, a problem such as deterioration of a gate insulating film is not caused. That is, the semiconductor device described in this embodiment does not have a limit on the number of times data can be rewritten, which is a problem of a conventional nonvolatile memory, and the reliability thereof is drastically improved. Furthermore, data is written depending on the state of the transistor (on or off), whereby high-speed operation can be easily achieved.

The above memory device can also be used in an LSI such as a digital signal processor (DSP), a custom LSI, or a programmable logic device (PLD), and a radio frequency identification (RF-ID) tag, in addition to a central processing unit (CPU), for example.

### <CPU>

A CPU including the above memory device is described below.

FIG. 54 is a block diagram illustrating a configuration example of the CPU including the above memory device.

The CPU illustrated in FIG. 54 includes, over a substrate 2190, an arithmetic logic unit (ALU) 2191, an ALU controller 2192, an instruction decoder 2193, an interrupt controller 2194, a timing controller 2195, a register 2196, a register controller 2197, a bus interface (BUS I/F) 2198, a rewritable ROM 2199, and a ROM interface (ROM I/F) 2189. A semiconductor substrate, an SOI substrate, a glass substrate, or the like is used as the substrate 2190. The rewritable ROM 2199 and the ROM interface 2189 may be provided over a separate chip. Needless to say, the CPU in FIG. 54 is just an example in which the configuration is simplified, and an actual CPU may have a variety of configurations depending on the application. For example, the CPU may have the following configuration: a configuration including the CPU illustrated in FIG. 54 or an arithmetic circuit is considered as one core; a plurality of the cores are included; and the cores operate in parallel. The number of bits that the CPU can process in an internal arithmetic circuit or in a data bus can be, for example, 8, 16, 32, or 64.

An instruction that is input to the CPU through the bus interface 2198 is input to the instruction decoder 2193 and decoded therein, and then, input to the ALU controller 2192, the interrupt controller 2194, the register controller 2197, and the timing controller 2195.

The ALU controller 2192, the interrupt controller 2194, the register controller 2197, and the timing controller 2195 conduct various controls in accordance with the decoded instruction. Specifically, the ALU controller 2192 generates signals for controlling the operation of the ALU 2191. While the CPU is executing a program, the interrupt controller 2194 processes an interrupt request from an external input/output device or a peripheral circuit depending on its priority or a mask state. The register controller 2197 generates an address of the register 2196, and reads/writes data from/to the register 2196 depending on the state of the CPU.

The timing controller 2195 generates signals for controlling operation timings of the ALU 2191, the ALU controller 2192, the instruction decoder 2193, the interrupt controller 2194, and the register controller 2197. For example, the timing controller 2195 includes an internal clock generator for generating an internal clock signal on the basis of a reference clock signal, and supplies the internal clock signal to the above circuits.

In the CPU illustrated in FIG. 54, a memory device is provided in the register 2196.

In the CPU illustrated in FIG. 54, the register controller 2197 selects operation of retaining data in the register 2196 in accordance with an instruction from the ALU 2191. That is, the register controller 2197 selects whether data is retained by a flip-flop or by a capacitor in the memory device included in the register 2196. When data retaining by the flip-flop is selected, a power supply voltage is supplied to the memory device in the register 2196. When data retaining by the capacitor is selected, the data is rewritten in the capacitor, and supply of the power supply voltage to the memory device in the register 2196 can be stopped.

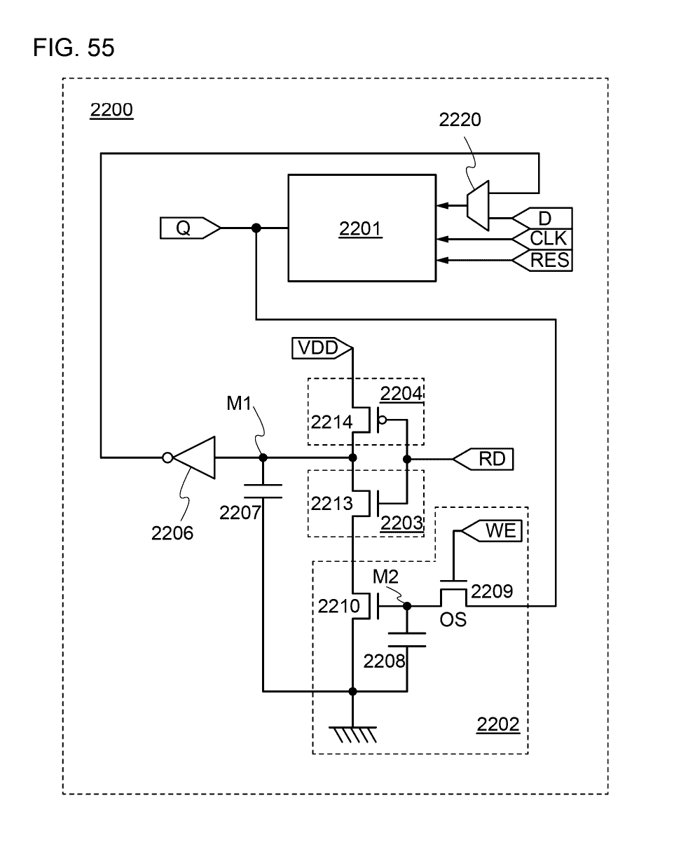

FIG. 55 is an example of a circuit diagram of a memory element that can be used for the register 2196. A memory element 2200 includes a circuit 2201 in which stored data is volatile when power supply is stopped, a circuit 2202 in which stored data is nonvolatile even when power supply is stopped, a switch 2203, a switch 2204, a logic element 2206, a capacitor 2207, and a circuit 2220 having a selecting function. The circuit 2202 includes a capacitor 2208, a transistor 2209, and a transistor 2210. Note that the memory element 2200 may further include another element such as a diode, a resistor, or an inductor, as needed.

Here, the above-described memory device can be used as the circuit 2202. When supply of a power supply voltage to the memory element 2200 is stopped, a ground potential (0 V) or a potential at which the transistor 2209 in the circuit 2202 is turned off continues to be input to a gate of the transistor 2209. For example, the gate of the transistor 2209 is grounded through a load such as a resistor.

Shown here is an example in which the switch 2203 is a transistor 2213 having one conductivity type (e.g., an n-channel transistor) and the switch 2204 is a transistor 2214 having a conductivity type opposite to the one conductivity type (e.g., a p-channel transistor). A first terminal of the switch 2203 corresponds to one of a source and a drain of the transistor 2213, a second terminal of the switch 2203 corresponds to the other of the source and the drain of the transistor 2213, and conduction or non-conduction between the first terminal and the second terminal of the switch 2203 (i.e., the on/off state of the transistor 2213) is selected by a control signal RD input to a gate of the transistor 2213. A first terminal of the switch 2204 corresponds to one of a source and a drain of the transistor 2214, a second terminal of the switch 2204 corresponds to the other of the source and the drain of the transistor 2214, and conduction or non-conduction between the first terminal and the second terminal of the switch 2204 (i.e., the on/off state of the transistor 2214) is selected by the control signal RD input to a gate of the transistor 2214.

One of a source and a drain of the transistor 2209 is electrically connected to one of a pair of electrodes of the capacitor 2208 and a gate of the transistor 2210. Here, the connection portion is referred to as a node M2. One of a source and a drain of the transistor 2210 is electrically connected to a wiring that can supply a low power supply potential (e.g., a GND line), and the other is electrically connected to the first terminal of the switch 2203 (the one of the source and the drain of the transistor 2213). The second terminal of the switch 2203 (the other of the source and the drain of the transistor 2213) is electrically connected to the first terminal of the switch 2204 (the one of the source and the drain of the transistor 2214). The second terminal of the switch 2204 (the other of the source and the drain of the transistor 2214) is electrically connected to a wiring that can supply a power supply potential VDD. The second terminal of the switch 2203 (the other of the source and the drain of the transistor 2213), the first terminal of the switch 2204 (the one of the source and the drain of the transistor 2214), an input terminal of the logic element 2206, and one of a pair of electrodes of the capacitor 2207 are electrically connected to each other. Here, the connection portion is referred to as a node M1. The other of the pair of electrodes of the capacitor 2207 can be supplied with a constant potential. For example, the other of the pair of electrodes of the capacitor 2207 can be supplied with a low power supply potential (e.g., GND) or a high power supply potential (e.g., VDD). The other of the pair of electrodes of the capacitor 2207 is electrically connected to the wiring that can supply a low power supply potential (e.g., a GND line). The other of the pair of electrodes of the capacitor 2208 can be supplied with a constant potential. For example, the other of the pair of electrodes of the capacitor 2208 can be supplied with a low power supply potential (e.g., GND) or a high power supply potential (e.g., VDD). The other of the pair of electrodes of the capacitor 2208 is electrically connected to the wiring that can supply a low power supply potential (e.g., a GND line).

The capacitor 2207 and the capacitor 2208 are not necessarily provided as long as the parasitic capacitance of the transistor, the wiring, or the like is actively utilized.

A control signal WE is input to the gate of the transistor 2209. As for each of the switches 2203 and 2204, a conduction state or a non-conduction state between the first terminal and the second terminal is selected by the control signal RD that is different from the control signal WE. When the first terminal and the second terminal of one of the switches are in the conduction state, the first terminal and the second terminal of the other of the switches are in the non-conduction state.

A signal corresponding to data retained in the circuit 2201 is input to the other of the source and the drain of the transistor 2209. FIG. 55 illustrates an example in which a signal output from the circuit 2201 is input to the other of the source and the drain of the transistor 2209. The logic value of a signal output from the second terminal of the switch 2203 (the other of the source and the drain of the transistor 2213) is inverted by the logic element 2206, and the inverted signal is input to the circuit 2201 through the circuit 2220.

In the example of FIG. 55, a signal output from the second terminal of the switch 2203 (the other of the source and the drain of the transistor 2213) is input to the circuit 2201 through the logic element 2206 and the circuit 2220; however, one embodiment of the present invention is not limited thereto. The signal output from the second terminal of the switch 2203 (the other of the source and the drain of the transistor 2213) may be input to the circuit 2201 without its logic value being inverted. For example, in the case where the circuit 2201 includes a node in which a signal obtained by inversion of the logic value of a signal input from the input terminal is retained, the signal output from the second terminal of the switch 2203 (the other of the source and the drain of the transistor 2213) can be input to the node.

In FIG. 55, the transistors included in the memory element 2200 except for the transistor 2209 can each be a transistor in which a channel is formed in a layer formed using a semiconductor other than an oxide semiconductor or in the substrate 2190. For example, the transistor can be a transistor whose channel is formed in a silicon layer or a silicon substrate. Alternatively, a transistor in which a channel is formed in an oxide semiconductor film can be used for all the transistors in the memory element 2200. Further alternatively, in the memory element 2200, a transistor in which a channel is formed in an oxide semiconductor film can be included besides the transistor 2209, and a transistor in which a channel is formed in a layer formed using a semiconductor other than an oxide semiconductor or the substrate 2190 can be used for the rest of the transistors.

As the circuit 2201 in FIG. 55, for example, a flip-flop circuit can be used. As the logic element 2206, for example, an inverter or a clocked inverter can be used.

In a period during which the memory element 2200 is not supplied with the power supply voltage, the semiconductor device described in this embodiment can retain data stored in the circuit 2201 by the capacitor 2208 that is provided in the circuit 2202.

The off-state current of a transistor in which a channel is formed in an oxide semiconductor film is extremely small. For example, the off-state current of a transistor in which a channel is formed in an oxide semiconductor film is significantly smaller than that of a transistor in which a channel is formed in silicon having crystallinity. Thus, when the transistor in which a channel is formed in an oxide semiconductor film is used as the transistor 2209, a signal is retained in the capacitor 2208 for a long time also in a period during which the power supply voltage is not supplied to the memory element 2200. The memory element 2200 can accordingly retain the stored content (data) also in a period during which the supply of the power supply voltage is stopped.

Since the memory element performs pre-charge operation with the switches 2203 and 2204, the time required for the circuit 2201 to retain original data again after the supply of the power supply voltage is restarted can be shortened.

In the circuit 2202, a signal retained by the capacitor 2208 is input to the gate of the transistor 2210. Thus, after supply of the power supply voltage to the memory element 2200 is restarted, the state (the on state or the off state) of the transistor 2210 is determined in accordance with the signal retained by the capacitor 2208 and can be read from the circuit 2202.

Consequently, an original signal can be accurately read even when a potential corresponding to the signal retained by the capacitor 2208 changes to some degree.

By using the above-described memory element 2200 in a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Thus, the power supply can be stopped even for a short time in the processor or one or a plurality of logic circuits included in the processor, resulting in lower power consumption.

Although the memory element 2200 is used in a CPU in this embodiment, the memory element 2200 can also be used in an LSI such as a digital signal processor (DSP), a custom LSI, or a programmable logic device (PLD), and a radio frequency identification (RF-ID).

At least part of this embodiment can be implemented in appropriate combination with any of the other embodiments and examples in this specification.

### Embodiment 8

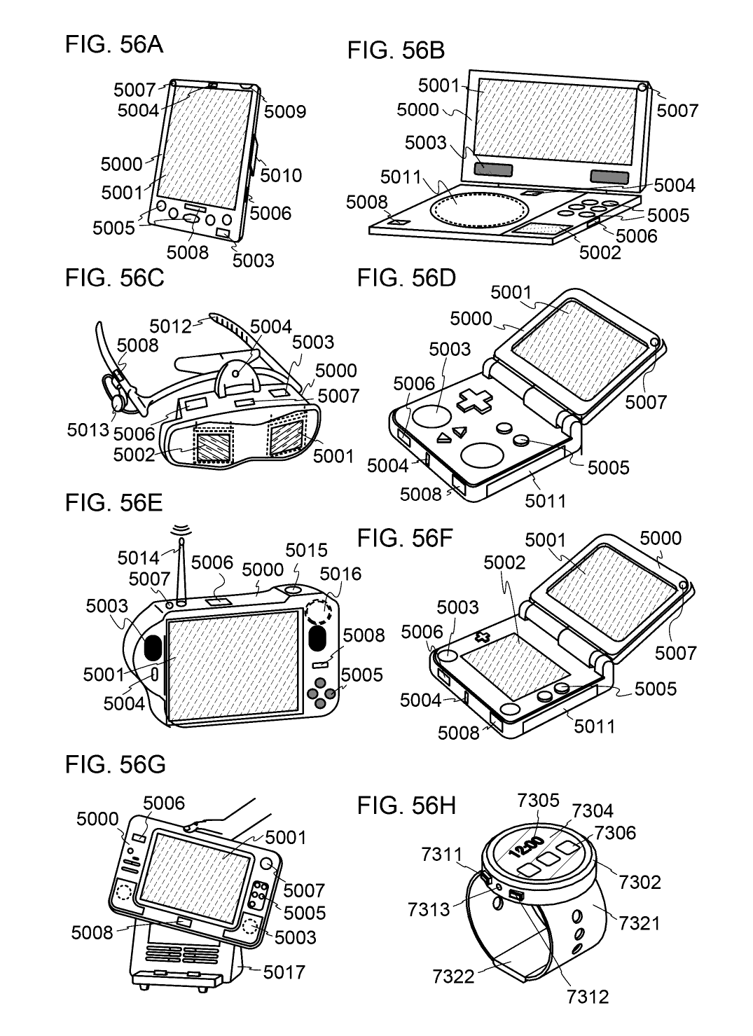

In this embodiment, electronic devices that include a display device of one embodiment of the present invention will be described with reference to FIGS. 56A to 56H.

FIGS. 56A to 56G illustrate electronic devices. These electronic devices can include a housing 5000, a display portion 5001, a speaker 5003, an LED lamp 5004, operation keys 5005 (including a power switch and an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 56A illustrates a mobile computer that can include a switch 5009, an infrared port 5010, and the like in addition to the above components. FIG. 56B illustrates a portable image reproducing device (e.g., a DVD reproducing device) provided with a recording medium, and the portable image reproducing device can include a second display portion 5002, a recording medium reading portion 5011, and the like in addition to the above components. FIG. 56C illustrates a goggle-type display that can include the second display portion 5002, a support portion 5012, an earphone 5013, and the like in addition to the above components. FIG. 56D illustrates a portable game console that can include the recording medium reading portion 5011 and the like in addition to the above components. FIG. 56E illustrates a digital camera with a television reception function, and the digital camera can include an antenna 5014, a shutter button 5015, an image receiving portion 5016, and the like in addition to the above components. FIG. 56F illustrates a portable game console that can include the second display portion 5002, the recording medium reading portion 5011, and the like in addition to the above components. FIG. 56G illustrates a portable television receiver that can include a charger 5017 capable of transmitting and receiving signals, and the like in addition to the above components.

The electronic devices in FIGS. 56A to 56G can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, the electronic device including an image receiving portion can have a function of shooting a still image, a function of taking moving images, a function of automatically or manually correcting a shot image, a function of storing a shot image in a recording medium (an external recording medium or a recording medium incorporated in the camera), a function of displaying a shot image on the display portion, or the like. Note that functions of the electronic devices in FIGS. 56A to 56G are not limited thereto, and the electronic devices can have a variety of functions.

FIG. 56H illustrates a smart watch, which includes a housing 7302, a display device 7304, operation buttons 7311 and 7312, a connection terminal 7313, a band 7321, a clasp 7322, and the like.

The display device 7304 mounted in the housing 7302 serving as a bezel includes a non-rectangular display region. The display device 7304 may have a rectangular display region. The display device 7304 can display an icon 7305 indicating time, another icon 7306, and the like.

The smart watch in FIG. 56H can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting element for the display device 7304.

As a material of the housings 5000 and 7302, an alloy, plastic, ceramic, or a material containing carbon fiber can be used. As the material containing carbon fiber, carbon fiber reinforced plastic (CFRP) has advantages of lightweight and corrosion-free; however, it is black and thus limits the exterior and design of the housing. The CFRP can be regarded as a kind of reinforced plastic, which may use glass fiber or aramid fiber. Since the fiber might be separated from a resin by high impact, the alloy is preferred. As the alloy, an aluminum alloy and a magnesium alloy can be given. An amorphous alloy (also referred to as metallic glass) containing zirconium, copper, nickel, and titanium especially has high elastic strength. This amorphous alloy has a glass transition region at room temperature, which is also referred to as a bulk-solidifying amorphous alloy and substantially has an amorphous atomic structure. An alloy material is molded in a mold of at least the part of the housing and coagulated by a solidification casting method, whereby part of the housing is formed with the bulk-solidifying amorphous alloy. The amorphous alloy may contain beryllium, silicon, niobium, boron, gallium, molybdenum, tungsten, manganese, iron, cobalt, yttrium, vanadium, phosphorus, carbon, or the like in addition to zirconium, copper, nickel, and titanium. The amorphous alloy may be formed by a vacuum evaporation method, a sputtering method, an electroplating method, an electroless plating method, or the like instead of the solidification casting method. The amorphous alloy may include a microcrystal or a nanocrystal as long as a state without a long-range order (a periodic structure) is maintained as a whole. Note that the term alloy includes both a complete solid solution alloy having a single solid-phase structure and a partial solution having two or more phases. The housings 5000 and 7302 using the amorphous alloy can have high elastic strength. Even if the electronic device or smart watch is dropped and the impact causes temporary deformation, the use of the amorphous alloy in the housing allows a return to the original shape; thus, the impact resistance of the electronic device or smart watch can be improved.

This embodiment can be combined with any of the other embodiments and examples in this specification as appropriate.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### Example 1

In this example, light-emitting elements of one embodiment of the present invention were fabricated and emission characteristics of the light-emitting elements were measured.

Table 1 shows details of the element structure of each of the light-emitting elements fabricated in this example. In addition, structures and abbreviations of compounds used here are given below. Note that the cross-sectional structures of the light-emitting elements fabricated in this example each correspond to the cross-sectional structure of the light-emitting element illustrated as an example in FIG. 24B.

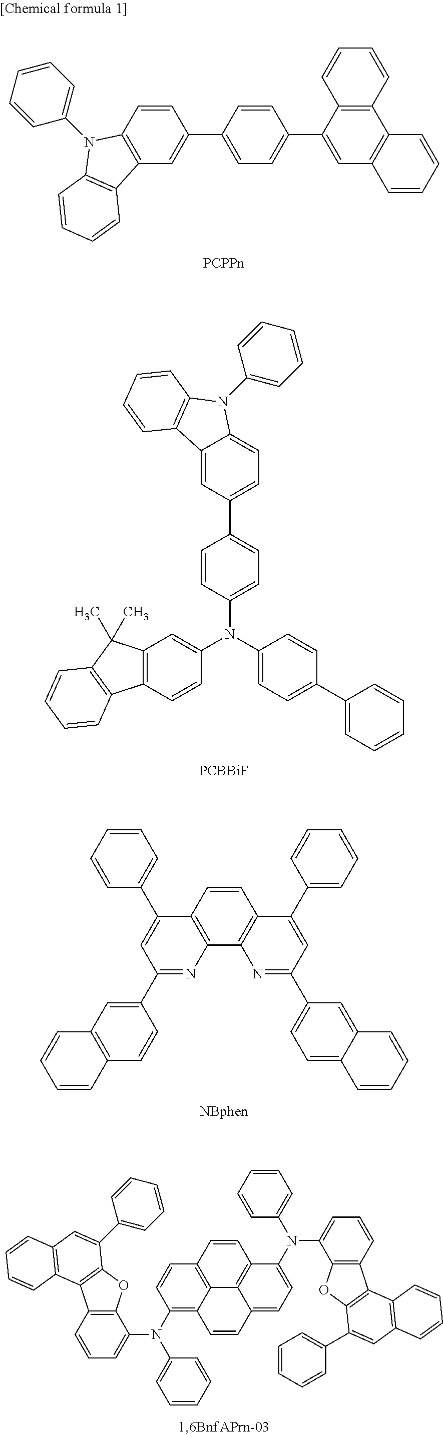

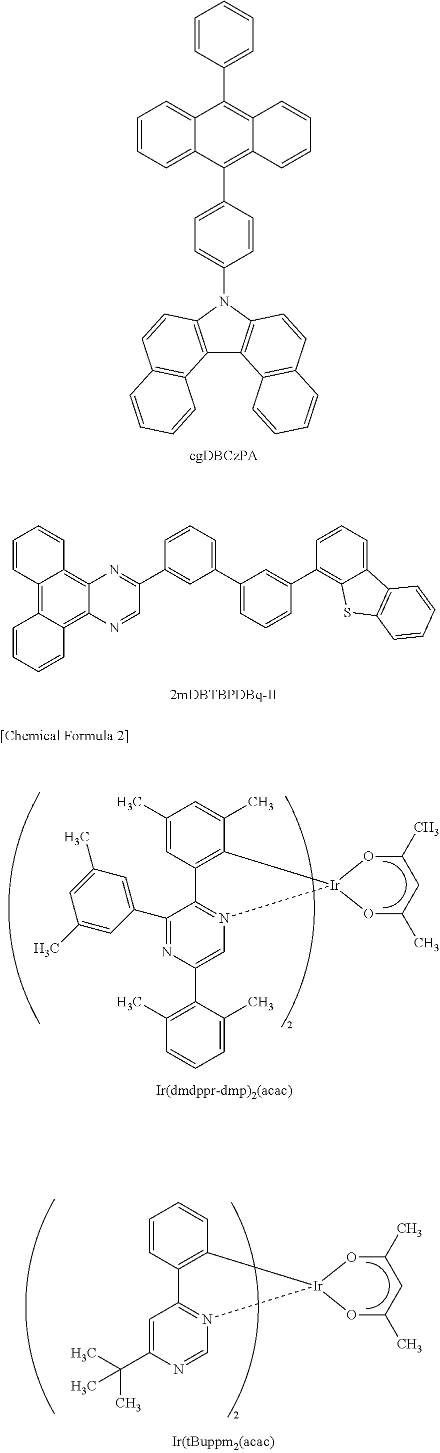

TABLE 1

| | | Thickness | | |
|---|---|---|---|---|
| | Layer | (nm) | Material | Weight ratio |
| Light- | Electrode | 120 | Al | — |
| emitting | Electron-injection layer | 1 | LiF | — |
| element 1 | Electron transport layer | 15 | NBphen | — |
| | | 5 | cgDBCzPA | — |
| | | 25 | cgDBCzPA:1,6BnfAPrn-03 | 1:0.05 |
| | Light-emitting layer | 30 | 2mDBTBPDBq-II:PCBBiF:Ir(dmdppr-dmp)₂(acac) | 0.8:0.2:0.06 |
| | Hole-transport layer | 30 | PCBBiF | — |
| | | 10 | PCPPn | — |
| | Hole-injection layer | 10 | PCPPn:MoO₃ | 1:0.5 |
| | Electrode | 10 | ITSO | — |
| | | 20 | APC | — |
| | | 70 | ITSO | — |
| Light- | Electrode | 120 | Al | — |
| emitting | Electron-injection layer | 1 | LiF | — |
| element 2 | Electron-transport layer | 15 | NBphen | — |
| | | 5 | cgDBCzPA | — |
| | | 25 | cgDBCzPA:1,6BnfCAPm-03 | 1:0.05 |
| | Light-emitting layer | 10 | 2mDBTBPDBq-II:Ir(tBuppm)₂(acac) | 0.7:0.06 |
| | | 20 | 2mDBTBPDBq-II:PCBBiF:Ir(tBuppm)₂(acac) | 0.7:0.3:0.06 |
| | Hole-transport layer | 10 | PCPPn | — |
| | Hole-injection layer | 10 | PCPPn:MoO₃ | 1:0.5 |
| | Electrode | 10 | ITSO | — |
| | | 20 | APC | — |
| | | 70 | ITSO | — |
| Light- | Electrode | 120 | Al | — |
| emitting | Electrode-injection layer | 1 | LiF | — |
| element 3 | Electron-transport layer | 15 | NBphen | — |
| | | 5 | cgDBCzPA | — |
| | Light-emitting layer | 25 | cgDBCzPA:1,6BnfAPrn-03 | 1:0.05 |
| | Hole-transport layer | 10 | PCPPn | — |
| | Hole-injection layer | 10 | PCPPn:MoO₃ | 1:0.5 |
| | Electrode | 10 | ITSO | — |
| | | 20 | APC | — |
| | | 70 | ITSO | — |

### <Fabrication of Light-Emitting Elements>

### <<Fabrication of Light-Emitting Element 1>>

The electrode 551 was formed such that ITSO, an alloy of silver, palladium, and copper (also referred to as Ag—Pd—Cu or APC), and ITSO were deposited over a glass substrate in this order to a thickness of 70 nm, a thickness of 20 nm, and a thickness of 10 nm as the conductive film 551A, the reflective film 551B, and the conductive film 551C, respectively. The electrode area of the electrode 551 was set to 4 mm² (2 mm×2 mm).

Next, as the hole-injection layer 561, 3-[4-(9-phenanthryl)-phenyl]-9-phenyl-9H-carbazole (abbreviation: PCPPn) and molybdenum oxide (MoO₃) were deposited over the electrode 551 by co-evaporation such that the deposited layer has a weight ratio of PCPPn to MoO₃ of 1:0.5 and a thickness of 10 nm.

As the hole-transport layer 562, PCPPn was deposited over the hole-injection layer 561 by evaporation to a thickness of 10 nm. Subsequently, N-(1,1′-biphenyl-4-yl)-N-[4-(9-phenyl-9H-carbazol-3-yl)phenyl]-9,9-dimethyl-9H-fluoren-2-amine (abbreviation: PCBBiF) was deposited to a thickness of 30 nm.

Then, as the light-emitting layer 553, 2-[3′-(dibenzothiophen-4-yl)biphenyl-3-yl]dibenzo[f,h]quinoxaline (abbreviation: 2mDBTBPDBq-II), PCBBiF, and bis {4,6-dimethyl-2-[5-(2,6-dimethylphenyl)-3-(3,5-dimethylphenyl)-2-pyrazinyl-κN]phenyl-κC}(2,4-pentanedionato-κ²O,O′)iridium(III) (abbreviation: [Ir(dmdppr-dmp)₂(acac)]) were deposited over the hole-transport layer 562 by co-evaporation such that the deposited layer has a weight ratio of 2mDBTBPDBq-II to PCBBiF and Ir(dmdppr-dmp)₂(acac) of 0.8:0.2:0.06 and a thickness of 30 nm. Note that in the light-emitting layer 553, Ir(dmdppr-dmp)₂(acac) corresponds to a light-emitting material.

Next, as the electron-transport layer 568, 7-[4-(10-phenyl-9-anthryl)phenyl]-7H-dibenzo[c,g]carbazole (abbreviation: cgDBCzPA) and N,N′-(pyrene-1,6-diyl)bis[(6,N-diphenylbenzo[b]naphtho[1,2-d]furan)-8-amine] (abbreviation: 1,6BnfAPrn-03) were deposited over the light-emitting layer 553 by co-evaporation such that the deposited layer has a weight ratio of cgDBCzPA to 1,6BnfAPrn-03 of 1:0.05 and a thickness of nm. Furthermore, cgDBCzPA and 2,9-bis(naphthalen-2-yl)-4,7-diphenyl-1,10-phenanthroline (abbreviation: NBPhen) were deposited by evaporation in this order to a thickness of 5 nm and a thickness of 15 nm, respectively.

Then, as the electron-injection layer 569, lithium fluoride (LiF) was deposited over the electron-transport layer 568 by evaporation to a thickness of 1 nm.

As the electrode 552, aluminum (Al) was deposited over the electron-injection layer 569 to a thickness of 120 nm.

Next, the glass substrate over which the organic materials were formed was sealed using a sealant for an organic EL device in a glove box containing a nitrogen atmosphere. Through the above-described process, the light-emitting element 1 was obtained.

### <<Fabrication of Light-Emitting Element 2>>

A light-emitting element 2 was fabricated through the same process as those for the light-emitting element 1 except for the steps of forming the hole-transport layer 562 and the light-emitting layer 553.

As the hole-transport layer 562 of the light-emitting element 2, PCPPn was deposited by evaporation to a thickness of 10 nm.

As the light-emitting layer 553 of the light-emitting element 2, 2mDBTBPDBq-II, PCBBiF, and (acetylacetonato)bis(6-tert-butyl-4-phenylpyrimidinato)iridium(III) (abbreviation: Ir(tBuppm)₂(acac)) were deposited by co-evaporation such that the deposited layer has a weight ratio of 2mDBTBPDBq-II to PCBBiF and Ir(tBuppm)₂(acac) of 0.7:0.3:0.06 and a thickness of nm. Subsequently, 2mDBTBPDBq-II and Ir(tBuppm)₂(acac) were deposited by co-evaporation such that the deposited layer has a weight ratio of 2mDBTBPDBq-II to Ir(tBuppm)₂(acac) of 0.7:0.06 and a thickness of 10 nm. Note that in the light-emitting layer 553, Ir(tBuppm)₂(acac) corresponds to a light-emitting material.

### <<Fabrication of Light-Emitting Element 3>>

A light-emitting element 3 was formed such that the light-emitting layer 553 formed in the above light-emitting element 2 was not formed and the film formed by co-evaporation of cgDBCzPA and 1,6BnfAPrn-03 as the electron-transport layer was used as a light-emitting layer. Note that in the light-emitting element 3, 1,6BnfAPrn-03 corresponds to a light-emitting material.

### <Characteristics of Light-Emitting Elements>

Next, the characteristics of the fabricated light-emitting elements 1 to 3 were measured. For measuring the luminance and the CIE chromaticity, a luminance colorimeter (BM-5A produced by Topcon Technohouse Corporation) was used. For measuring the electroluminescence spectrum, a multi-channel spectrometer (PMA-11 produced by Hamamatsu Photonics K.K.) was used.

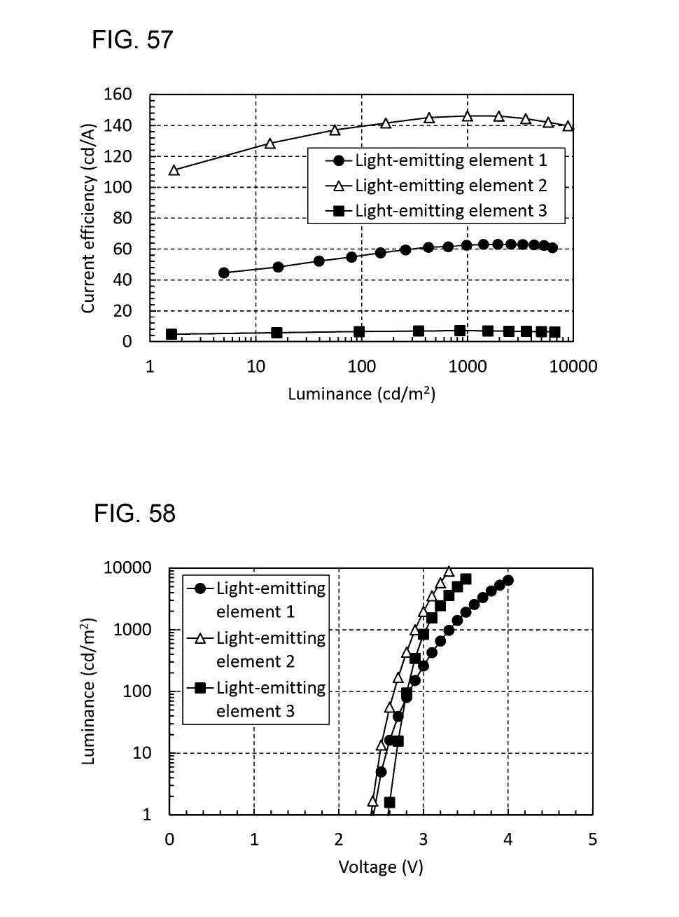

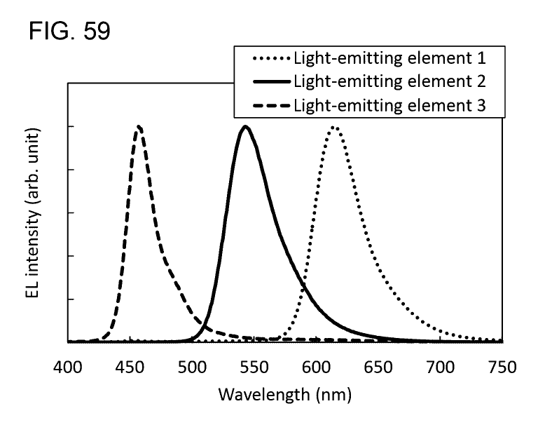

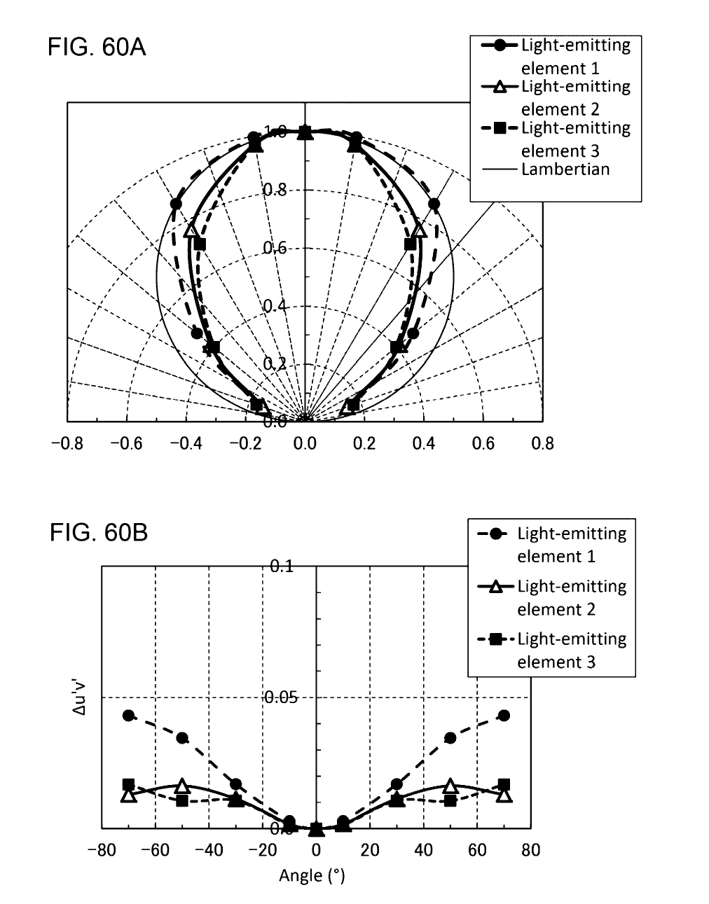

FIG. 57 shows current efficiency-luminance characteristics of the light-emitting elements 1 to 3. Moreover, FIG. 58 shows luminance-voltage characteristics thereof. FIG. 59 shows electroluminescence spectra when a current at a current density of 2.5 mA/cm² was supplied to the light-emitting elements 1 to 3. FIGS. 60A and 60B show result of measurement of angle distribution of light from the light-emitting elements 1 to 3. The measurement of the light-emitting elements was performed at room temperature (in an atmosphere kept at 23° C.).

Table 2 shows the characteristics of the light-emitting elements 1 to 3.

TABLE 2

| | | Current | CIE | | Current | Power |
|---|---|---|---|---|---|---|
| | Voltage | density | chromaticity | Luminance | efficiency | consumption |
| | (V) | (mA/cm²) | (x, y) | (cd/m²) | (cd/A) | (mW) |
| Light-emitting | 3.1 | 0.756 | (0.665, 0.335) | 463 | 61.3 | 14 |
| element 1 | | | | | | |
| Light-emitting | 3.0 | 1.28 | (0.355, 0.638) | 1867 | 146 | 23 |
| element 2 | | | | | | |
| Light-emitting | 2.9 | 3.62 | (0.139, 0.069) | 242 | 6.68 | 62 |
| element 3 | | | | | | |

As shown in FIG. 59, the maximum values of the electroluminescence spectra of light from the light-emitting element 1, the light-emitting element 2, and the light-emitting element 3 were 616 nm, 543 nm, and 457 nm, respectively, and full widths at half maximum were 44 nm, 45 nm, and 26 nm, respectively. In this manner, the light-emitting elements 1 to 3 each showed an electroluminescence spectrum with a small full width at half maximum.

As shown in FIGS. 57 to 59 and Table 2, the light-emitting element 1 emits red light with high color purity, which exhibits high current efficiency as a light-emitting element emitting red light. The light-emitting element 2 emits green light with high color purity, which exhibits high current efficiency as a light-emitting element emitting green light. The light-emitting element 3 emits blue light with high color purity, which exhibits high current efficiency as a light-emitting element emitting blue light.

As shown in FIG. 60A, differences of angular distributions of luminance of the light-emitting element 1, luminance of the light-emitting element 2, and luminance of the light-emitting element 3 from a perfectly diffusing surface (also referred to as a Lambertian surface) were almost equivalent, which were 88.1%, 76.0%, and 72.2%, respectively.

As shown in FIG. 60B, as a result of calculating a chromaticity difference Δu′v′ between light in the oblique direction and light in the front direction to evaluate viewing angle dependence of chromaticity of each of the light-emitting elements 1 to 3, the chromaticity differences Δu′v′ of the light-emitting element 1, the light-emitting element 2, and the light-emitting element 3 were small even in measurement at an angle of 70° to the front direction, which were 0.043, 0.013, and 0.017, respectively. The above results show that the light-emitting elements 1 to 3 are light-emitting elements that can obtain a favorable emission state not only from the front direction but also from the oblique direction.

Next, power consumption of the display devices using the fabricated light-emitting elements 1 to 3 was estimated.

The power consumption of the display devices was estimated on the assumption that the display region of the display device had an aspect ratio of 16:9, a diagonal of 4.3 inches, and an area of 50.97 cm², and the aperture ratio was 35%.

In the case where the light-emitting elements 1 to 3 were used as the display elements of the display devices having the above specifications, when luminance of a display element having the structure of the light-emitting element 1 was 463 cd/m², luminance of a display element having the structure of the light-emitting element 2 was 1867 cd/m², and luminance of a display element having the structure of the light-emitting element 3 was 242 cd/m², white color (chromaticity coordinates (x,y)=(0.313,0.329)) with a color temperature of 6500 K was able to be displayed at 300 cd/m² on the entire display region. At this time, power consumption of these display elements was able to be estimated to be 98 mW.

As described above, the display elements having the structures of the light-emitting elements 1 to 3 have low power consumption. Furthermore, the above result indicates that a display device with low power consumption can be provided using the display elements as described above.

The structure described in this example can be used in appropriate combination with any of the structures described in the other example and embodiments.

### Example 2

In this example, a display device of one embodiment of the present invention was fabricated and power consumption of the display device was measured.

The display device used in this example is the display device having the cross-sectional structure in FIG. 2A. For the manufacturing method of the display device, Embodiment 1 can be referred to.

### <Fabrication of Display Device>

A 30-nm-thick tungsten was deposited over the substrate 510 as the separation film 501W by a sputtering method.

As the intermediate film 354, a material containing indium, gallium, and zinc was deposited to a thickness of 50 nm by a sputtering method using the material as a target and was processed into a predetermined shape.

As the insulating film 501A, a 200-nm-thick silicon oxide containing nitrogen and a 200-nm-thick silicon nitride were deposited by a plasma-enhanced chemical vapor deposition (PECVD) method and were processed into a predetermined shape.

As the electrode 351, ITSO was deposited to a thickness of 20 nm by a sputtering method. Next, APC was deposited to a thickness of 100 nm by a sputtering method and was processed into a predetermined shape. Then, ITSO was deposited to a thickness of 100 nm by a sputtering method, and the 20-nm-thick ITSO and the 100-nm-thick ITSO were each processed into a predetermined shape. Here, the 20-nm-thick ITSO, the 100-nm-thick APC, and the 100-nm-thick ITSO serve as the conductive film 351A, the reflective film 351B, and the conductive film 351C, respectively. Note that an opening of the reflective film 351B serves as the opening 351H.

As the insulating film 501C, a 200-nm-thick silicon oxide containing nitrogen was used.

Then, the transistor included in the pixel circuit 302 was formed. For the transistor, the conductive film 504, the insulating film 506, the semiconductor film 508, the conductive films 512A and 512B, the insulating film 516, the conductive film 524, and the insulating film 518 were formed in this order.

As the conductive film 504, tantalum containing nitrogen was deposited to a thickness of 10 nm and then copper was deposited to a thickness of 100 nm.

As the insulating film 506, silicon nitride and silicon oxide containing nitrogen were deposited to a thickness of 450 nm in total.

As the semiconductor film 508, deposition was performed to a thickness of 10 nm by a sputtering method using an oxide semiconductor containing indium, gallium, and zinc having an atomic ratio of In:Ga:Zn=4:2:4.1 as a target and then deposition was performed to a thickness of 15 nm by a sputtering method using an oxide semiconductor containing indium, gallium, and zinc having an atomic ratio of In:Ga:Zn=1:1:1.2 as a target.

As the conductive films 512A and 512B, tungsten, aluminum, and titanium were deposited in this order to a thickness of 50 nm, a thickness of 400 nm, and a thickness of 100 nm, respectively.

As the insulating film 516, silicon oxide containing nitrogen was deposited to a thickness of 430 nm.

As the conductive film 524, deposition was performed to a thickness of 50 nm by a sputtering method using an oxide semiconductor containing indium, gallium, and zinc having an atomic ratio of In:Ga:Zn=4:2:4.1 as a target. Note that the resistivity of the conductive film 524 was reduced by the method described as an example in Embodiment 1.

As the insulating film 518, silicon nitride was deposited to a thickness of 100 nm.

Note that the silicon oxide containing nitrogen and the silicon nitride were deposited by a PECVD method. The conductive films were formed by a sputtering method. The semiconductor film, the conductive films, and the insulating films that form the transistor were each processed into a predetermined shape by a lithography method and an etching method after deposition.

As the electrode 551, ITSO was deposited to a thickness of 70 nm by a sputtering method. Next, APC was deposited to a thickness of 20 nm by a sputtering method and was processed into a predetermined shape. Then, ITSO was deposited to a thickness of 10 nm by a sputtering method, and the 70-nm-thick ITSO and the 10-nm-thick ITSO were each processed into a predetermined shape. Here, the 70-nm-thick ITSO, the 20-nm-thick APC, and the 10-nm-thick ITSO serve as the conductive film 551A, the reflective film 551B, and the conductive film 551C, respectively.

Therefore, in the display device fabricated in this example, the reflective films 551B and 351B each have a region including APC. The conductive films 551A, 551C, 351A, and 351C each have a region including ITSO. The reflective film 551B has a region interposed between the conductive films 551A and 551C. The reflective film 351B has a region interposed between the conductive films 351A and 351C.

In the display device of this example, a light-emitting element corresponding to any of the light-emitting elements 1 to 3 fabricated in Example 1 was used as the second display element 550.

After the second display element 550 was formed, the intermediate film 354 and the insulating film 501A were separated from the separation film 501W and the substrate 510 used as a process substrate. After that, a liquid crystal element was formed as the first display element 350.

To form the first display element 350, an alignment film was formed over the intermediate film 354 and the insulating film 501A and was subjected to rubbing treatment, whereby the alignment film 331 was formed. After that, a liquid crystal material was provided, and the substrate 370 including the alignment film 332 which was subjected to rubbing treatment was bonded.

Through the above-described process, the display device including the first display element 350, the second display element 550, and the transistor was fabricated.

Table 3 shows specifications of the display device fabricated in this example.

TABLE 3

| | | Specifications |
|---|---|---|
| Panel size | | 1.55 inches in diagonal |
| Number of effective pixels | | 320 × RGB × 320 |
| Resolution | | 292 ppi |
| Liquid crystal element | Mode | Reflective Twisted ECB mode |
| | Color method | Color filter method |
| | Aperture ratio | 69.0% |
| Light-emitting element | Color method | Separate coloring method |
| (organic EL element) | Aperture ratio | 3.9% |

### <Measurement of Power Consumption of Display Device>

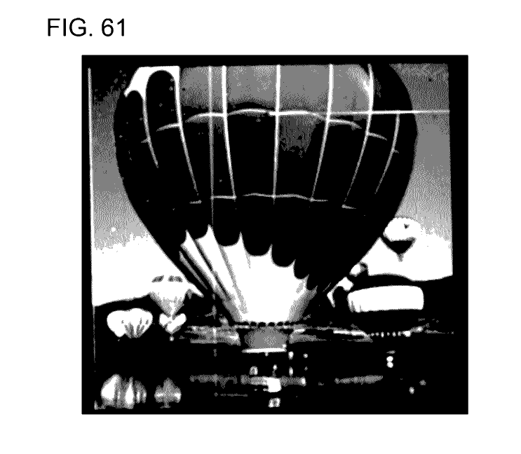

FIG. 61 shows a display example of the above fabricated display device.

As shown in FIG. 61, the display device fabricated in this example can provide an excellent display state.

Next, power consumption of the display device was measured.

Measurement was performed in a dark environment, and power consumption of the display device which performed display so as to obtain white luminance of 75 cd/m² was measured. In the above display setting, power consumption for red display, power consumption for green display, and power consumption for blue display were measured in addition to the power consumption for white display. Table 4 shows the measurement results. Note that Example 1 may be referred to for the measurement method.

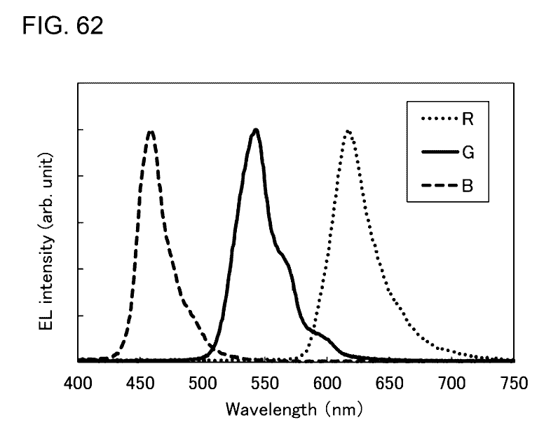

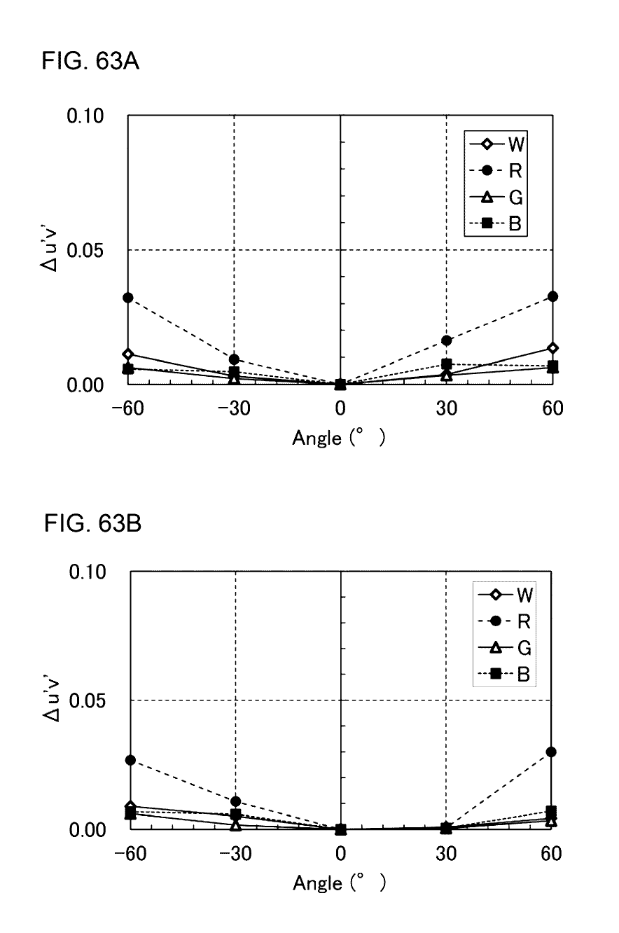

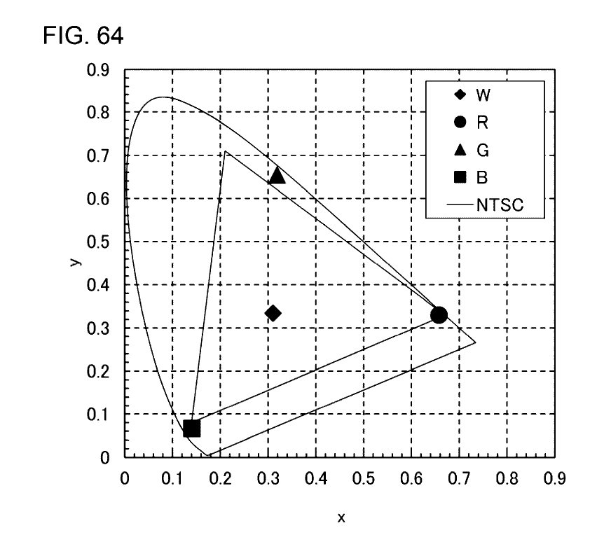

FIG. 62 shows electroluminescence spectra of light emitted from the display device when display of red (R), green (G), and blue (B) was performed. FIGS. 63A and 63B show results of measurement of a chromaticity difference Δu′v′ between light in the oblique direction and light in the front direction to evaluate viewing angle dependence of chromaticity of light emitted from the display device when display of red (R), green (G), blue (B), and white (W) was performed. FIG. 64 shows results of measurement of CIE chromaticity (x,y) of light emitted from the display device when display of red (R), green (G), blue (B), and white (W) was performed. Note that FIG. 63A shows results of measurement in a direction in which pixels emitting light of different colors are adjacent to each other, and FIG. 63B shows results of measurement in a direction in which pixels emitting light of the same colors are adjacent to each other.

TABLE 4

| | Power consumption |
|---|---|
| | (mW) |
| Red | 8.70 |
| Green | 17.1 |
| Blue | 44.4 |
| White | 60.4 |

As shown in FIG. 62 and FIG. 64, light emission of red (R), green (G), and blue (B) similar to light emission from the light-emitting element in Example 1 was obtained from the display device fabricated in this example.

As shown in FIGS. 63A and 63B, as a result of calculating a chromaticity difference Δu′v′ between light in the oblique direction and light in the front direction, the chromaticity difference Δu′v′ was as small as 0.04 or less even in measurement of any light emission color in either direction.

As shown in Table 4, power consumption of the display device fabricated in this example was low.

The above results show that the display device fabricated in this example is a display device that can provide a favorable display state both in the front direction and in the oblique direction.

That is, it was found that power consumption of the display device was able to be reduced in the following respects: the electrode 351 included the reflective film and the conductive films; the electrode 551 included the reflective film and the conductive films; and the reflective film included in the electrode 351 and the reflective film included in the electrode 551 each had a region containing the same metal. In addition, it was found that the conductive film included in the electrode 351 and the conductive film included in the electrode 551 preferably each had a region containing the same metal. It was further found that the reflective film included in the electrode 351 preferably had a region interposed between the conductive films and the reflective film included in the electrode 551 preferably had a region interposed between the conductive films.

The structure described in this example can be used in appropriate combination with any of the structures described in the other example and embodiments.

### REFERENCE NUMERALS

ANO: wiring, C1: capacitor, C2: capacitor, CSCOM: wiring, GD: driver circuit, GDA: driver circuit, GDB: driver circuit, GL1: scan line, GL2: scan line, I1: insulator, I2: insulator, M1: node, M2: node, P1: positional data, P2: data, PIC1: image data, PIC2: image data, PIC3: image data, PIC4: image data, S1: oxide semiconductor, S2: oxide semiconductor, S3: oxide semiconductor, SL1: signal line, SL2: signal line, SD: driver circuit, VCOM1: wiring, VCOM2: wiring, 200: transistor, 202: substrate, 204: conductive film, 206: insulating film, 207: insulating film, 208: oxide semiconductor film, 208a: oxide semiconductor film, 208b: oxide semiconductor film, 208c: oxide semiconductor film, 208d: drain region, 208i: channel region, 208s: source region, 212: conductive film, 212a: conductive film, 212b: conductive film, 214: insulating film, 216: insulating film, 218: insulating film, 220: conductive film, 220a: conductive film, 220b: conductive film, 230: barrier film, 240: oxygen, 250: transistor, 250A: transistor, 250B: transistor, 251a: opening, 251b: opening, 252: opening, 252a: opening, 252b: opening, 252c: opening, 260: transistor, 270: transistor, 280: transistor, 290: transistor, 300: display device, 300B: display device, 300C: display device, 300D: display device, 302: pixel circuit, 305: sealant, 331: alignment film, 332: alignment film, 335: structure body, 337: conductor, 339: conductive material, 350: display element, 351: electrode, 351A: conductive film, 351B: reflective film, 351C: conductive film, 351H: opening, 352: electrode, 353: liquid crystal layer, 354: intermediate film, 370: substrate, 370D: functional film, 370P: functional film, 371: insulating film, 373: light-blocking film, 375: coloring layer, 377: flexible printed circuit, 381: insulating film, 382: conductive film, 501A: insulating film, 501C: insulating film, 502: pixel portion, 504: conductive film, 505: bonding layer, 506: insulating film, 508: semiconductor film, 508A: region, 508B: region, 508C: region, 510: substrate, 511B: conductive film, 511C: conductive film, 512A: conductive film, 512B: conductive film, 516: insulating film, 518: insulating film, 519B: terminal, 519C: terminal, 520: functional layer, 521: insulating film, 522: connection portion, 524: conductive film, 528: insulating film, 531: host material, 532: guest material, 541: host material, 541_1: organic compound, 541_2: organic compound, 542: guest material, 550: display element, 550A: light-emitting element, 550B: light-emitting element, 550C: light-emitting element, 550D: light-emitting element, 551: electrode, 551A: conductive film, 551B: reflective film, 551C: conductive film, 552: electrode, 553: light-emitting layer, 553B: light-emitting layer, 553G: light-emitting layer, 553R: light-emitting layer, 561: hole-injection layer, 562: hole-transport layer, 563: electron-transport layer, 564: electron-injection layer, 565: charge-generation layer, 566: hole-injection layer, 567: hole-transport layer, 568: electron-transport layer, 569: electron-injection layer, 570: substrate, 571B: region, 571G: region, 571R: region, 575: coloring layer, 575B: coloring layer, 575G: coloring layer, 575R: coloring layer, 581: switch, 581B: switch, 582: switch, 585: transistor, 585B: transistor, 586: transistor, 586B: transistor, 591A: opening, 591B: opening, 591C: opening, 592A: opening, 592B: opening, 592C: opening, 662: light-blocking film, 663: insulating film, 664: conductive film, 665: conductive film, 666: insulating film, 667: conductive film, 668: insulating film, 670: substrate, 672: substrate, 674: adhesive agent, 691: touch panel, 692: touch panel, 693: touch panel, 800: input/output device, 801: upper cover, 802: lower cover, 803: FPC, 804: touch sensor, 805: FPC, 806: display device, 809: frame, 810: driver circuit, 811: battery, 1200: data processing device, 1210: arithmetic device, 1211: arithmetic portion, 1212: memory portion, 1214: transmission path, 1215: input/output interface, 1220: input/output device, 1230: display portion, 1230B: display portion, 1231: display region, 1232: pixel, 1235EL: display element, 1235LC: display element, 1240: input portion, 1250: sensor portion, 1290: communication portion, 2189: ROM interface, 2190: substrate, 2191: ALU, 2192: ALU controller, 2193: instruction decoder, 2194: interrupt controller, 2195: a timing controller, 2196: register, 2197: register controller, 2198: bus interface, 2199: ROM, 2200: memory element, 2201: circuit, 2202: circuit, 2203: switch, 2204: switch, 2206: logic element, 2207: capacitor, 2208: capacitor, 2209: transistor, 2210: transistor, 2213: transistor, 2214: transistor, 2220: circuit, 3001: wiring, 3002: wiring, 3003: wiring, 3004: wiring, 3005: wiring, 3200: transistor, 3300: transistor, 3400: capacitor, 5000: housing, 5001: display portion, 5002: display portion, 5003: speaker, 5004: LED lamp, 5005: operation key, 5006: connection terminal, 5007: sensor, 5008: microphone, 5009: switch, 5010: infrared port, 5011: memory medium reading portion, 5012: support, 5013: earphone, 5014: antenna, 5015: shutter button, 5016: image receiving portion, 5017: charger, 7302: housing, 7304: display device, 7305: icon, 7306: icon, 7311: operation button, 7312: operation button, 7313: connection terminal, 7321: band, 7322: clasp.

This application is based on Japanese Patent Application serial No. 2015-214087 filed with Japan Patent Office on Oct. 30, 2015 and Japanese Patent Application serial No. 2015-234396 filed with Japan Patent Office on Dec. 1, 2015, the entire contents of which are hereby incorporated by reference.

1. A display device comprising:
a first display element including a first electrode and a liquid crystal layer;
a second display element including a second electrode and a light-emitting layer;
a first transistor; and
a second transistor,
wherein the first transistor is electrically connected to the first electrode,
wherein the second transistor is electrically connected to the second electrode,
wherein the first electrode includes a first reflective film and a first conductive film,
wherein the second electrode includes a second reflective film and a second conductive film, and
wherein the first reflective film includes a region containing a metal contained in the second reflective film.

2. The display device according to claim 1, wherein the first reflective film and the second reflective film each contain at least one of Ag and Al.

3. A display device comprising:
a first display element including a first electrode and a liquid crystal layer;
a second display element including a second electrode, a third electrode and a light-emitting layer;
a first transistor; and
a second transistor,
wherein the first transistor is electrically connected to the first electrode,
wherein the second transistor is electrically connected to the second electrode,
wherein the first electrode includes a first reflective film and a first conductive film,
wherein the second electrode includes a second reflective film and a second conductive film,
wherein the third electrode includes a third reflective film,
wherein the first reflective film includes a region containing a metal contained in the second reflective film, and
wherein the second reflective film includes a region containing a metal contained in the third reflective film.

4. The display device according to claim 3, wherein the first reflective film, the second reflective film, and the third reflective film each contain at least one of Ag and Al.

5. The display device according to claim 1 or 3, wherein the first conductive film and the second conductive film each contain at least one of In and Zn.

6. The display device according to claim 1 or 3,
wherein the first electrode further comprises a third conductive film,
wherein the second electrode further comprises a fourth conductive film,
wherein the first reflective film includes a region interposed between the first conductive film and the third conductive film, and
wherein the second reflective film includes a region interposed between the second conductive film and the fourth conductive film.

7. The display device according to 6, wherein the third conductive film and the fourth conductive film each contain at least one of In and Zn.

8. The display device according to claim 6,
wherein the third conductive film includes a region containing a metal contained in the first conductive film, and
wherein the fourth conductive film includes a region containing a metal contained in the second conductive film.

9. The display device according to claim 1 or 3,
wherein the first reflective film includes an opening, and
wherein the opening includes a region overlapping with the first conductive film, the second reflective film, and the second conductive film.

10. The display device according to claim 9,
wherein the second display element is configured to emit light toward the opening, and
wherein the second display element is configured to perform display in the same direction as the first display element.

11. The display device according to claim 1 or 3, wherein the first transistor and the second transistor each contain an oxide semiconductor.

12. An electronic device comprising a housing, a touch sensor, and the display device according to claim 1 or 3.
